(19) United States
(12) Patent Application Publication
(10) Pub. No.: US 2024/0251654 A1
(43) Pub. Date: Jul. 25, 2024

(54) ORGANIC ELECTROLUMINESCENT DEVICE

(71) Applicant: BEIJING SUMMER SPROUT TECHNOLOGY CO., LTD., Beijing (CN)

(72) Inventors: Ming Sang, Beijing (CN); Chunliang Zhao, Beijing (CN); Xuechao Tian, Beijing (CN); Liuhuan Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/392,798

(22) Filed: Dec. 21, 2023

(30) Foreign Application Priority Data
Dec. 27, 2022 (CN) 202211673880.X
Nov. 10, 2023 (CN) 202311497183.8

(51) Int. Cl. H10K 85/30; C07F 15/00; C09K 11/06; H10K 50/12; H10K 101/00

(52) U.S. Cl. CPC H10K 85/346; C07F 15/0086; C09K 11/06; C07B 2200/05; C09K 2211/1044; C09K 2211/185; H10K 50/12; H10K 2101/90

(57) ABSTRACT

Provided is an organic electroluminescent device. The organic electroluminescent device includes an anode, a cathode and an organic layer disposed between the anode and the cathode, where the organic layer comprises at least a light-emitting layer, where the light-emitting layer comprises a first compound having a structure of Formula 1, a first host material having a high triplet energy level and a second host material having a high triplet energy level. The electroluminescent device exhibits excellent overall device performance, for example, a low voltage, high efficiency and a long lifetime. Further provided are an electronic device comprising the organic electroluminescent device and a compound composition comprising a first compound having a structure of Formula 1, a first host material having a high triplet energy level and a second host material having a high triplet energy level.

### CROSS-REFERENCE TO RELATED APPLICATION(S)

This application claims priority to Chinese Patent Application No. 202211673880.X filed on Dec. 27, 2022 and Chinese Patent Application No. 202311497183.8 filed on Nov. 10, 2023, the disclosure of which are incorporated herein by reference in their entireties.

### TECHNICAL FIELD

The present disclosure relates to organic electronic devices, for example, organic electroluminescent devices. In particular, the present disclosure relates to an organic electroluminescent device comprising a new material combination consisting of a first compound having a structure of Formula 1, a first host material having a high triplet energy level and a second host material having a high triplet energy level in an organic light-emitting layer, an electronic device comprising the organic electroluminescent device and a compound composition comprising a first compound having a structure of Formula 1, a first host material having a high triplet energy level and a second host material having a high triplet energy level.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20210284672A1 discloses a metal complex comprising the following general formula and a use of the metal complex in an organic electroluminescent device:

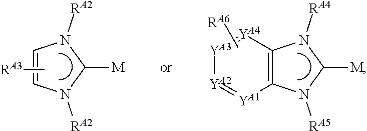

wherein at least one of R^{A1}, R^{A2}, R^{A4}, R^{A5} and R^{A6} comprises a structure represented by

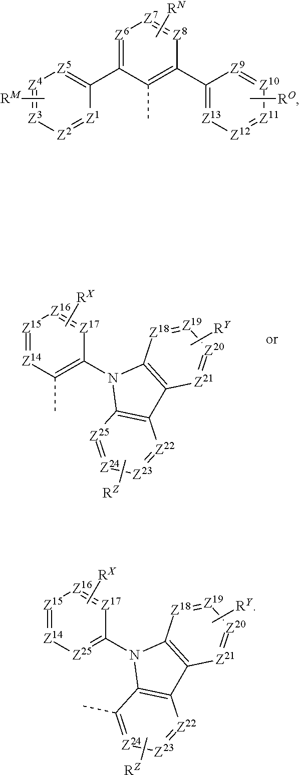

When the compound is selected from the structure

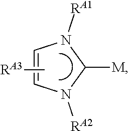

one of R^{A1} and R^{A2} is

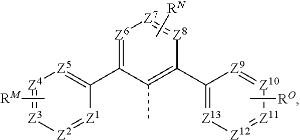

wherein at least one of R^{M}, R^{N} and R^{O} is selected from deuterium, alkyl, cycloalkyl, heteroalkyl, heterocycloalkyl, aryl, heteroaryl and combinations thereof. This application discloses some platinum metal compounds having the following specific structures:

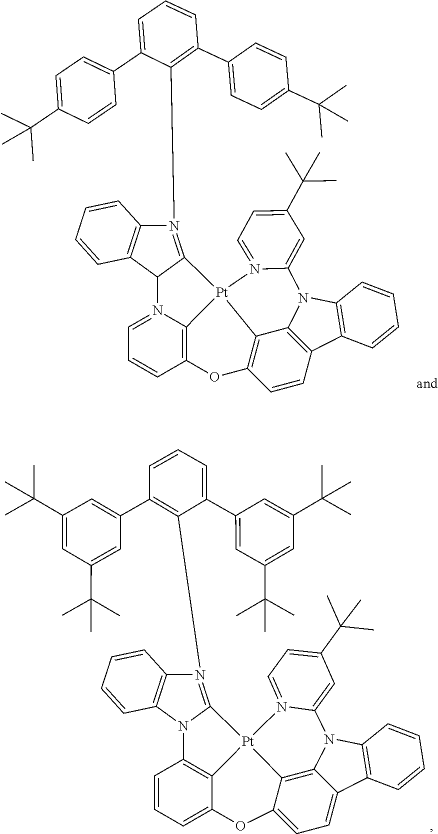

and discloses in a device example that the metal complex as a light-emitting material and the compound

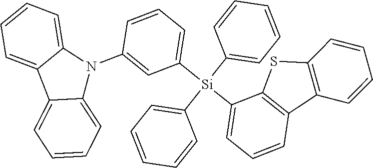 [SMILES: c1ccc([Si](c2ccccc2)(c2cccc(-n3c4ccccc4c4ccccc43)c2)c2cccc3c2sc2ccccc23)cc1]

as a single host are applied to the organic electroluminescent device to obtain a relatively good effect. However, this application has neither disclosed nor taught a combination of the metal complex with dual host materials and has neither disclosed nor taught a use of the combination of the metal complex with the dual host materials in the organic electroluminescent device.

US20220112231A1 discloses a light-emitting device. The light-emitting device comprises a guest metal light-emitting material in a light-emitting layer and has a general formula of

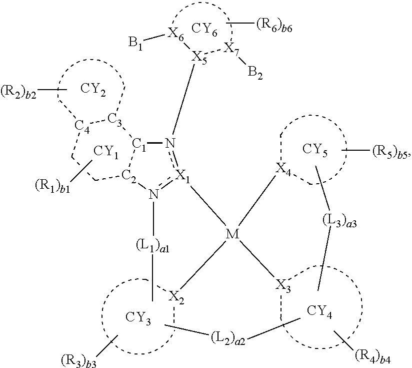

wherein CY₁ to CY₆ are each independently selected from a C₃-C₆₀ carbocyclic ring or a C₁-C₆₀ heterocyclic ring. It can be seen that this application discloses a metal complex where benzimidazole has a particular fused ring structure. This application discloses the following structures in the specific structures:

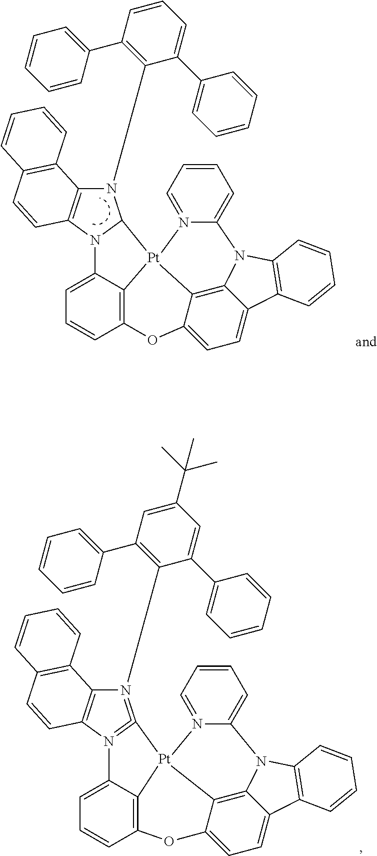

and discloses in a device example that the metal complex is used as a light-emitting material and CBP is used as a single host to study the performance of the light-emitting device of this application. However, this application has neither disclosed nor taught a combination of the metal complex with dual host materials and has neither disclosed nor taught a use of the combination of the metal complex with the dual host materials in an organic electroluminescent device.

The above related art discloses some metal complexes each having a multi-substituted aromatic group at an N position of imidazolecarbene, and the metal complexes can be combined with different types of host materials and used in devices emitting blue light. However, in researches of these blue phosphorescent devices, certain limitations are still in voltages, device efficiency and lifetimes of these blue phosphorescent devices. Therefore, blue phosphorescent devices are worthy of further research and development. After intensive research, the inventors of the present disclosure have discovered a new material combination that is a combination of a metal complex having a particular multi-substituted aromatic group on an imidazolecarbene ring as a light-emitting material and dual host materials each having a high triplet. This new material combination is used in blue phosphorescent devices to unexpectedly obtain more excellent device performance.

### SUMMARY

The present disclosure aims to provide an organic electroluminescent device having a new material combination to solve at least part of the above-mentioned problems. A new material combination consisting of a first compound having a structure of Formula 1, a first host material having a high triplet energy level and a second host material having a high triplet energy level is used in the organic electroluminescent device, and this new material combination can be used in a light-emitting layer of the organic electroluminescent device. This new material combination can exhibit excellent overall device performance in the device, for example, a low voltage, high efficiency and/or a long lifetime, and these advantages are of great help to improve a level of a device emitting blue light in particular.

According to an embodiment of the present disclosure, disclosed is an organic electroluminescent device, the organic electroluminescent device comprises:
an anode,
a cathode, and
an organic layer disposed between the anode and the cathode, wherein the organic layer comprises a light-emitting layer, wherein the light-emitting layer comprises a first compound, a first host material and a second host material;
wherein a triplet energy level of the first host material and a triplet energy level of the second host material are both higher than a triplet energy level of the first compound;
wherein the first compound has a structure represented by Formula 1:

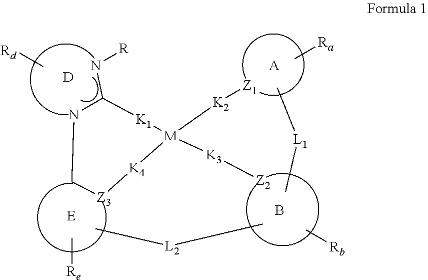

wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 3 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2:

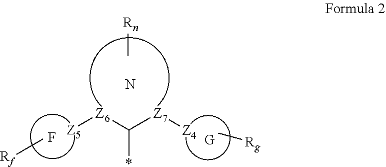

wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“★” represents a position where Formula 2 is joined; and
adjacent substituents R″, Rₐ, R_{b}, R_{d}, Rₑ, R_{f}, R_{g} and Rₙ can be optionally joined to form a ring.

According to another embodiment of the present disclosure, further disclosed is an electronic device, the electronic device comprises the organic electroluminescent device described above.

According to another embodiment of the present disclosure, further disclosed is a compound composition, the compound composition comprises at least a first compound, a first host material and a second host material.

The present disclosure discloses the new organic electroluminescent device. The new material combination consisting of the first compound, the first host material and the second host material is used in the organic electroluminescent device, and this new material combination can be used in the light-emitting layer of the electroluminescent device. This new material combination can exhibit the excellent overall device performance in the device, for example, the low voltage, the high efficiency and the long lifetime.

### BRIEF DESCRIPTION OF DRAWINGS

FIG. 1 is a schematic diagram of an organic light-emitting apparatus that may contain a compound composition disclosed herein.

FIG. 2 is a schematic diagram of another organic light-emitting apparatus that may contain a compound composition disclosed herein.

### DETAILED DESCRIPTION

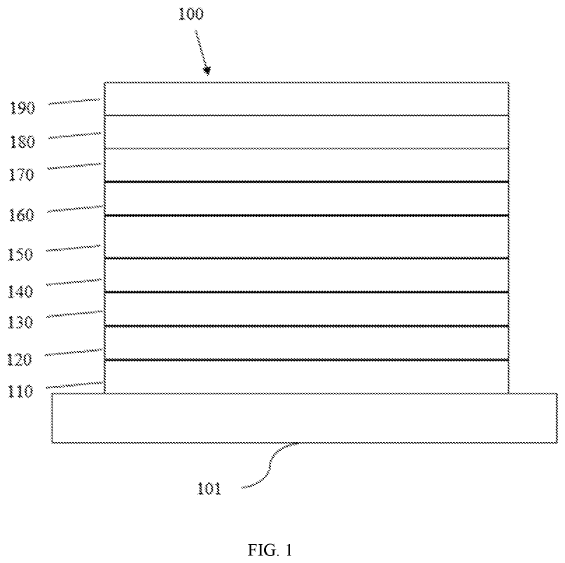

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

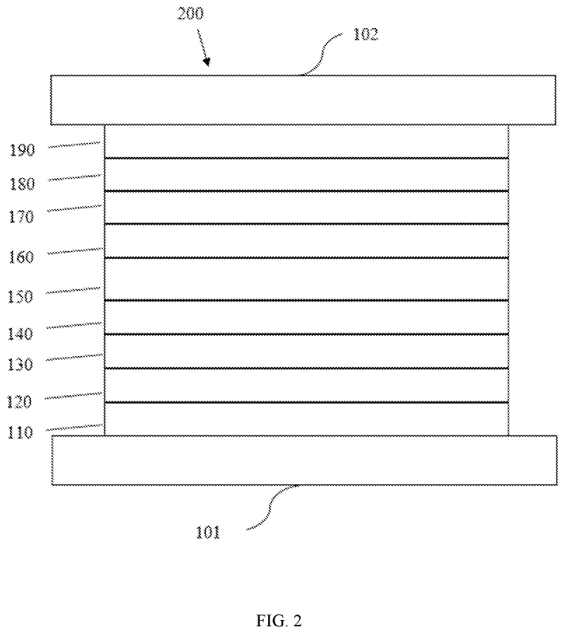

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

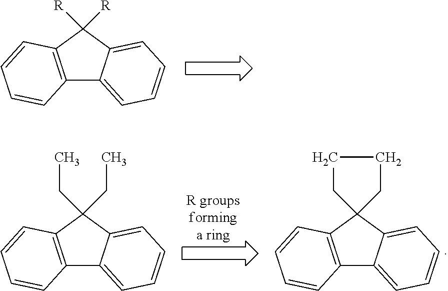

The expression that adjacent substituents can be optionally joined to form a ring is also intended to mean that two substituents bonded to carbon atoms which are directly bonded to each other are joined to each other via a chemical bond to form a ring, which can be exemplified by the following formula:

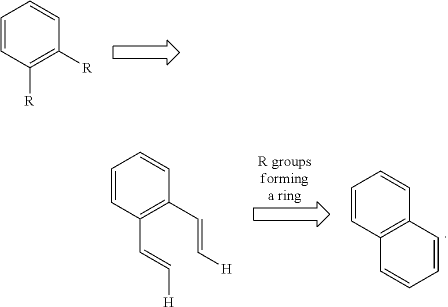

The expression that adjacent substituents can be optionally joined to form a ring is also intended to mean that two substituents bonded to further distant carbon atoms are joined to each other via a chemical bond to form a ring, which can be exemplified by the following formula:

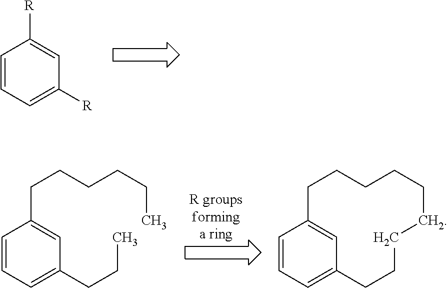

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

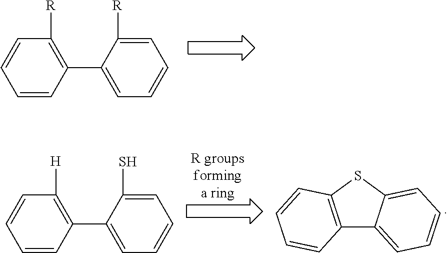

According to an embodiment of the present disclosure, disclosed is an organic electroluminescent device, the organic electroluminescent device comprises:
an anode,
a cathode, and
an organic layer disposed between the anode and the cathode, wherein the organic layer comprises a light-emitting layer, wherein the light-emitting layer comprises a first compound, a first host material and a second host material;
wherein a triplet energy level of the first host material and a triplet energy level of the second host material are both higher than a triplet energy level of the first compound;
wherein the first compound has a structure represented by Formula 1:

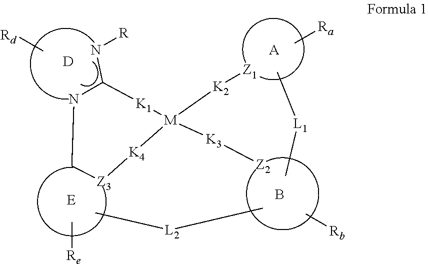

wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 3 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2:

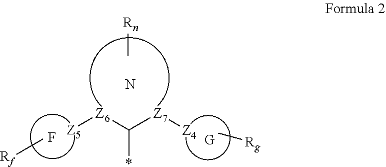

wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof; Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined; and
adjacent substituents R″, Rₐ, R_{b}, R_{d}, Rₑ, R_{f}, R_{g} and Rₙ can be optionally joined to form a ring.

In this embodiment, adjacent two substituents Rₐ can be optionally joined to form a ring, and the ring is a ring not comprising Te, O, S and Se.

In this embodiment, adjacent two substituents Rₐ can be optionally joined to form a carbocyclic ring or a heterocyclic ring that comprises one or more hetero-atoms selected from B, N, Si, P and Ge atoms; the carbocyclic ring comprises an aromatic unsaturated carbocyclic ring and a non-aromatic unsaturated carbocyclic ring, and the heterocyclic ring comprises an aromatic unsaturated heterocyclic ring and a non-aromatic unsaturated heterocyclic ring.

Herein, “an unsaturated carbocyclic ring having 5 to 30 carbon atoms” comprises an aromatic unsaturated carbocyclic ring and a non-aromatic unsaturated carbocyclic ring each having 5 to 30 carbon atoms; “an unsaturated heterocyclic ring having 3 to 30 carbon atoms” comprises an aromatic unsaturated heterocyclic ring and a non-aromatic unsaturated heterocyclic ring each having 3 to 30 carbon atoms.

Herein, the expression that adjacent substituents R″, Rₐ, R_{b}, R_{d}, Rₑ, R_{f}, R_{g} and Rₙ can be optionally joined to form a ring is intended to mean that any one or more of groups of adjacent substituents, such as two substituents R″, two substituents Rₐ, two substituents R_{b}, two substituents R_{d}, two substituents Rₑ, two substituents R_{f}, two substituents R_{g}, and two substituents Rₙ, can be joined to form a ring. Obviously, it is also possible that none of these groups of adjacent substituents are joined to form a ring.

According to an embodiment of the present disclosure, the first compound has a structure represented by a general formula of M(Lₐ)(L_{b}), wherein Lₐ and L_{b} are a first ligand and a second ligand coordinated to the metal M, respectively, the Lₐ has a structure represented by Formula A:

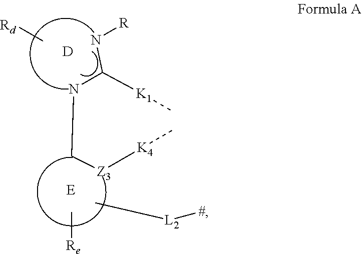

wherein in Formula A, “#” represents a position where L_{b} is joined; the L_{b} has a structure represented by Formula B:

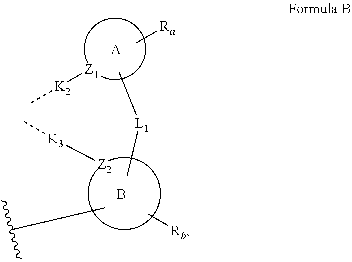

wherein in Formula B, “ [symbol] ” represents a position where Lₐ is joined.

According to an embodiment of the present disclosure, wherein the M is selected from Cu, Ag, Au, Ru, Rh, Pd, Os, Ir or Pt.

According to an embodiment of the present disclosure, wherein the M is selected from Pt or Pd.

According to an embodiment of the present disclosure, wherein the M is selected from Pt.

According to an embodiment of the present disclosure, wherein the ring A, the ring B, the ring E, the ring F, the ring G and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof.

According to an embodiment of the present disclosure, wherein the ring A, the ring B, the ring E, the ring F, the ring G and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof.

According to an embodiment of the present disclosure, wherein the ring A, the ring B, the ring E, the ring F, the ring G and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring or a combination thereof.

According to an embodiment of the present disclosure, wherein the ring D is, at each occurrence identically or differently, selected from an unsaturated heterocyclic ring having 3 to 18 carbon atoms.

According to an embodiment of the present disclosure, wherein the ring D is, at each occurrence identically or differently, selected from an imidazolecarbene ring or a benzimidazolecarbene ring.

According to an embodiment of the present disclosure, wherein the L₁ is selected from a single bond, O, S, (SiR″R″)_{y}, NR″ or a combination thereof, wherein y is 1 or 2.

According to an embodiment of the present disclosure, wherein the L₁ is selected from a single bond, O or S.

According to an embodiment of the present disclosure, wherein the L₁ is selected from a single bond.

According to an embodiment of the present disclosure, wherein the K₁ to K₄ are selected from a single bond.

According to an embodiment of the present disclosure, wherein the Z₁ is selected from N, and Z₂ and Z₃ are selected from C.

According to an embodiment of the present disclosure, wherein the Z₄ to Z₇ are selected from C.

According to an embodiment of the present disclosure, wherein the first compound has a structure represented by one of Formula 1-1 to Formula 1-20:

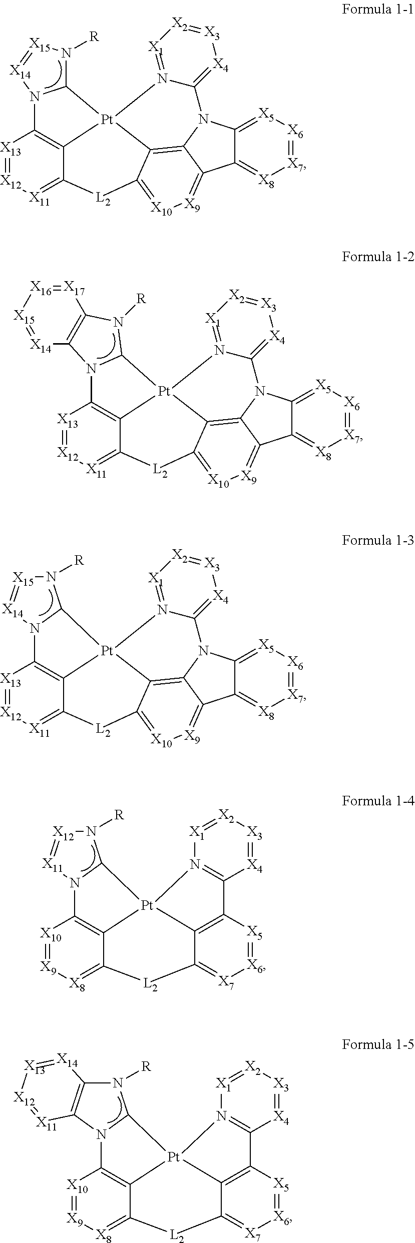

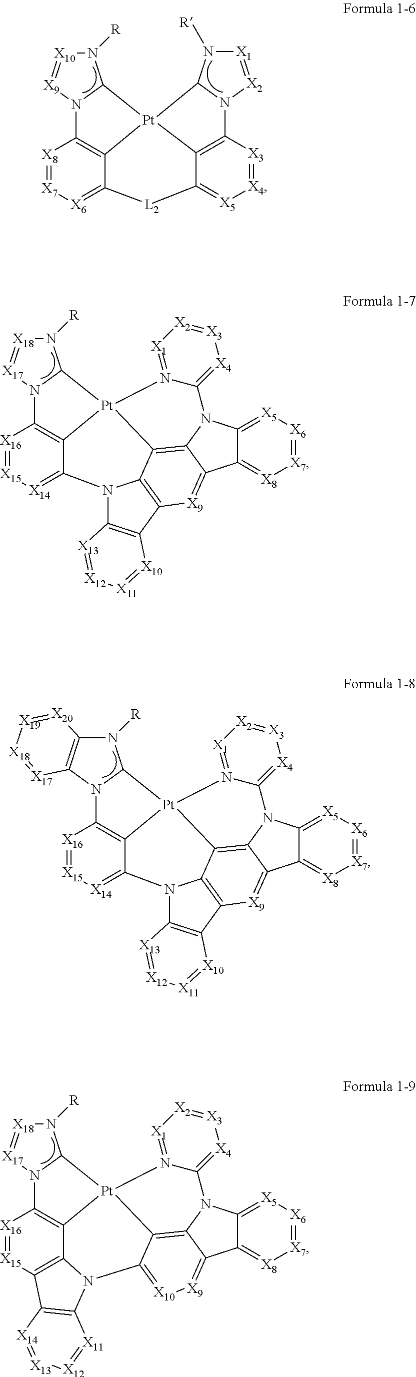

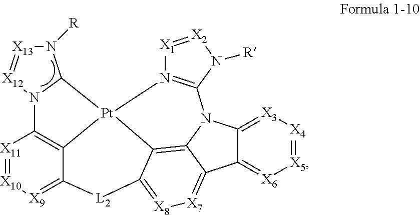

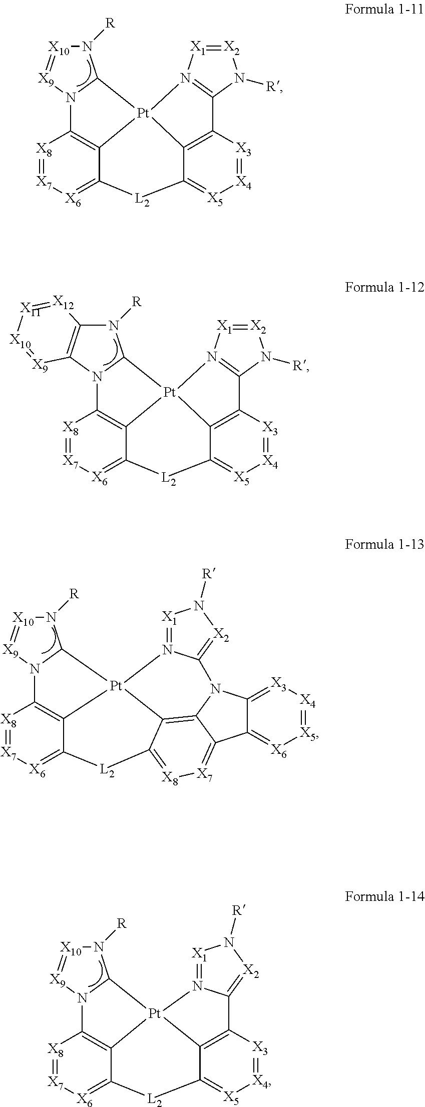

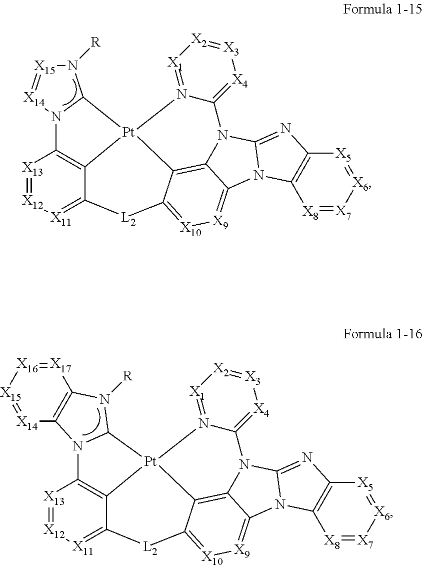

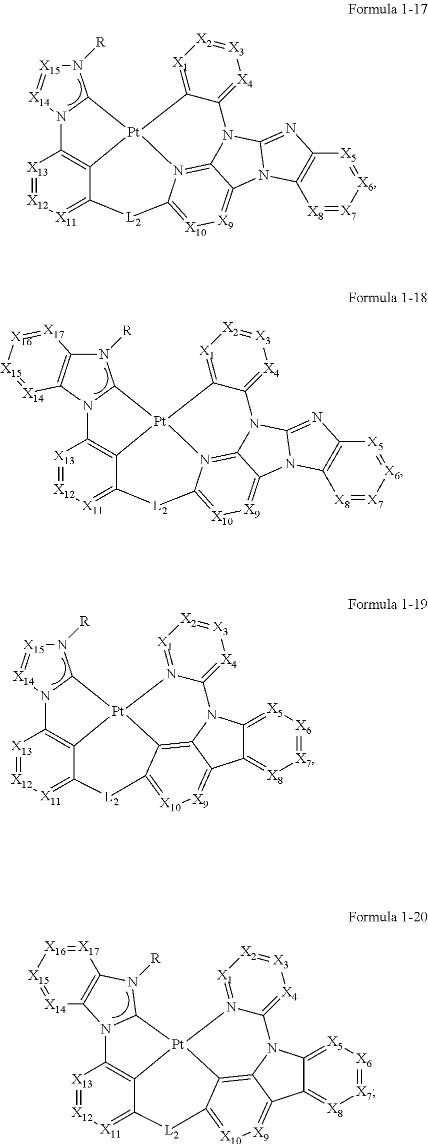

wherein in Formula 1-1 to Formula 1-20,
L₂ is, at each occurrence identically or differently, selected from a single bond, O, S, Se, (SiR″R″)_{y}, PR″, NR″, substituted or unsubstituted arylene having 6 to 30 carbon atoms or a combination thereof;
y is, at each occurrence identically or differently, selected from 1, 2, 3, 4 or 5;
X₁ to X₂₀ are, at each occurrence identically or differently, selected from CRₓ or N;
R has a structure represented by Formula 2-1:

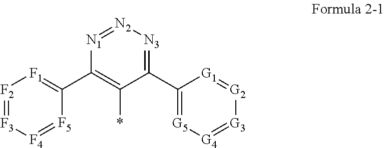

wherein in Formula 2-1, F₁ to F₅ are each independently selected from CR_{f} or N; G₁ to G₅ are each independently selected from CR_{g} or N; N₁ to N₃ are each independently selected from CRₙ or N, and at least one of N₁ to N₃ is CRₙ;
R′, R″, Rₓ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
wherein at least one Rₙ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and adjacent substituents R′, R″, Rₓ, R_{f}, R_{g} and Rₙ can be optionally joined to form a ring.

In this embodiment, adjacent two substituents Rₓ can be optionally joined to form a ring, and the ring is a ring not comprising Te, O, S and Se.

In this embodiment, adjacent two substituents Rₓ can be optionally joined to form a carbocyclic ring or a heterocyclic ring that comprises one or more hetero-atoms selected from B, N, Si, P and Ge atoms; the carbocyclic ring comprises an aromatic unsaturated carbocyclic ring and a non-aromatic unsaturated carbocyclic ring, and the heterocyclic ring comprises an aromatic unsaturated heterocyclic ring and a non-aromatic unsaturated heterocyclic ring.

Herein, the expression that adjacent substituents R′, R″, Rₓ, R_{f}, R_{g} and Rₙ can be optionally joined to form a ring is intended to mean that any one or more of groups of adjacent substituents, such as two substituents R″, two substituents Rₓ, two substituents R_{f}, two substituents R_{g}, and two substituents Rₙ, can be joined to form a ring. Obviously, it is also possible that none of these groups of adjacent substituents are joined to form a ring.

According to an embodiment of the present disclosure, wherein the first compound has a structure represented by Formula 1-1 or Formula 1-2.

According to an embodiment of the present disclosure, wherein the first compound does not comprise the structure

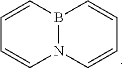

According to an embodiment of the present disclosure, wherein none of Rₓ, R′, R_{f}, R_{g} and Rₙ comprise the structure

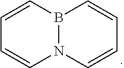

According to an embodiment of the present disclosure, wherein Rₓ, R′, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group comprising one or more hetero-atoms selected from O, S, Se, Si, P and Ge atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl comprising one or more hetero-atoms selected from O, S, Se, Si, P and Ge atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, wherein N₂ is selected from CRₙ, wherein Rₙ is, at each occurrence identically or differently, selected from the group consisting of: deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, wherein N₂ is selected from CRₙ, wherein Rₙ is, at each occurrence identically or differently, selected from the group consisting of: deuterium, halogen, a cyano group, substituted or unsubstituted alkyl having 2 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, wherein N₂ is selected from CRₙ, wherein Rₙ is, at each occurrence identically or differently, selected from the group consisting of: deuterium, halogen, a cyano group, substituted or unsubstituted alkyl having 4 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, wherein N₂ is selected from CRₙ, wherein Rₙ is, at each occurrence identically or differently, selected from the group consisting of: deuterium, halogen, a cyano group, substituted or unsubstituted alkyl having 4 to 10 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, wherein N₂ is selected from CRₙ, wherein Rₙ is selected from

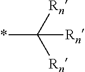

(“*” represents a joined position), wherein Rₙ′ is, at each occurrence identically or differently, selected from the group consisting of: halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof.

According to an embodiment of the present disclosure, wherein N₁ and N₃ are each independently selected from CH or CD.

According to an embodiment of the present disclosure, wherein N₂ is selected from CRₙ, wherein Rₙ is, at each occurrence identically or differently, selected from the group consisting of: deuterium, fluorine, a cyano group, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms and combinations thereof.

According to an embodiment of the present disclosure, wherein N₂ is selected from CRₙ, wherein Rₙ is, at each occurrence identically or differently, selected from unsubstituted alkyl having 1 to 6 carbon atoms, partially or fully deuterated alkyl having 1 to 6 carbon atoms, unsubstituted cycloalkyl having 3 to 6 ring carbon atoms or partially or fully deuterated cycloalkyl having 3 to 6 ring carbon atoms.

According to an embodiment of the present disclosure, wherein N₂ is selected from CRₙ, wherein Rₙ is, at each occurrence identically or differently, selected from the group consisting of: methyl, deuterated methyl, ethyl, partially or fully deuterated ethyl, n-propyl, partially or fully deuterated n-propyl, isopropyl, partially or fully deuterated isopropyl, cyclopropyl, partially or fully deuterated cyclopropyl, n-butyl, partially or fully deuterated n-butyl, isobutyl, partially or fully deuterated isobutyl, t-butyl, partially or fully deuterated t-butyl, cyclopentyl, partially or fully deuterated cyclopentyl, cyclohexyl, partially or fully deuterated cyclohexyl and combinations thereof.

According to an embodiment of the present disclosure, wherein X₁ to X₂₀ are, at each occurrence identically or differently, selected from CRₓ.

According to an embodiment of the present disclosure, wherein X₉ and X₁₀ are, at each occurrence identically or differently, selected from CRₓ, wherein Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group comprising one or more hetero-atoms selected from O, S, Se, B, Si, P and Ge atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl comprising one or more hetero-atoms selected from O, S, Se, B, Si, P and Ge atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, wherein F₁ to F₅ are each independently selected from CR_{f}.

According to an embodiment of the present disclosure, wherein G₁ to G₅ are each independently selected from CR_{g}.

According to an embodiment of the present disclosure, wherein N₁ to N₃ are each independently selected from CRₙ.

According to an embodiment of the present disclosure, wherein L₂ is selected from a single bond, O, S, (SiR″R″)_{y}, NR″ or a combination thereof.

According to an embodiment of the present disclosure, wherein R″ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, wherein R″ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, wherein L₂ is selected from a single bond, O or S.

According to an embodiment of the present disclosure, wherein L₂ is selected from O.

According to an embodiment of the present disclosure, wherein Rₓ, R′, R_{f} and R_{g} are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, wherein Rₓ, R′, R_{f} and R_{g} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, wherein at least one R_{f} is selected from deuterium, halogen or substituted or unsubstituted alkyl having 1 to 20 carbon atoms.

According to an embodiment of the present disclosure, wherein at least one R_{g} is selected from deuterium, halogen or substituted or unsubstituted alkyl having 1 to 20 carbon atoms.

According to an embodiment of the present disclosure, wherein R_{f} is selected from deuterium.

According to an embodiment of the present disclosure, wherein R_{g} is selected from deuterium.

According to an embodiment of the present disclosure, wherein Formula 2-1 is, at each occurrence identically or differently, selected from the group consisting of An-1 to An-82 and An-92, wherein the specific structures of An-1 to An-82 and An-92 are referred to claim 13.

According to an embodiment of the present disclosure, hydrogens in the structures An-1 to An-82 and An-92 can be partially or fully substituted with deuterium.

According to an embodiment of the present disclosure, wherein the first compound has a structure represented by Pt(Lₐ)(L_{b}) or Pd(Lₐ)(L_{b}), wherein Lₐ and L_{b} are a first ligand and a second ligand coordinated to the metal Pt or Pd, respectively, Lₐ is selected from the group consisting of Lₐ1-1 to Lₐ1-76, Lₐ1-86 to Lₐ1-93, Lₐ2-1 to Lₐ2-42, Lₐ3-1 to Lₐ3-40, Lₐ4-1 to Lₐ4-17 and Lₐ4-19 to Lₐ4-53, and L_{b} is selected from the group consisting of L_{b}1-1 to L_{b}1-9, L_{b}1-12 to L_{b}1-22, L_{b}2-1 to L_{b}2-30, L_{b}3-1 to L_{b}3-26, L_{b}4-1 to L_{b}4-25 and L_{b}5-1 to L_{b}5-11, wherein the specific structures of Lₐ1-1 to Lₐ1-76, Lₐ1-86 to Lₐ1-93, Lₐ2-1 to Lₐ2-42, Lₐ3-1 to Lₐ3-40, Lₐ4-1 to Lₐ4-17, Lₐ4-19 to Lₐ4-53, L_{b}1-1 to L_{b}1-9, L_{b}1-12 to L_{b}1-22, L_{b}2-1 to L_{b}2-30, L_{b}3-1 to L_{b}3-26, L_{b}4-1 to L_{b}4-25 and L_{b}5-1 to L_{b}5-11 are referred to claim 14.

According to an embodiment of the present disclosure, wherein the first compound is selected from the group consisting of Compound Pt1 to Compound Pt76, Compound Pt86 to Compound Pt180, Compound Pt182 to Compound Pt260, Compound Pt305 to Compound Pt680 and Compound Pd1 to Compound Pd24, wherein the specific structures of Compound Pt1 to Compound Pt76, Compound Pt86 to Compound Pt180, Compound Pt182 to Compound Pt260, Compound Pt305 to Compound Pt680 and Compound Pd1 to Compound Pd24 are referred to claim 14.

According to an embodiment of the present disclosure, wherein the first compound is selected from the group consisting of Compound Pt1 to Compound Pt76, Compound Pt86 to Compound Pt180, Compound Pt182 to Compound Pt260, Compound Pt305 to Compound Pt681 and Compound Pd1 to Compound Pd24, wherein the specific structures of Compound Pt1 to Compound Pt76, Compound Pt86 to Compound Pt180, Compound Pt182 to Compound Pt260, Compound Pt305 to Compound Pt680 and Compound Pd1 to Compound Pd24 are referred to claim 14, and the specific structure of Compound Pt681 is

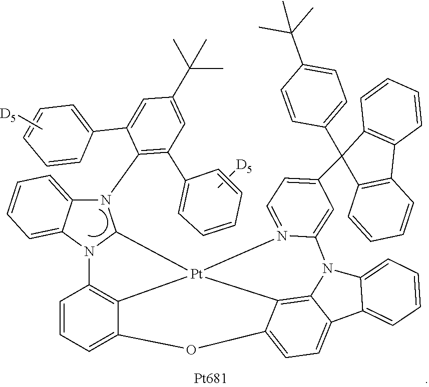

According to an embodiment of the present disclosure, wherein the triplet energy level of the first host material is higher than 2.69 eV.

According to an embodiment of the present disclosure, wherein the first host material has a structure represented by any one of Formula 3 to Formula 5:

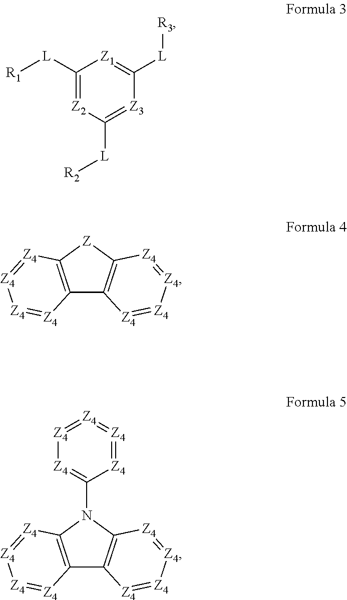

wherein in Formula 3, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
in Formula 4 or Formula 5, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

In this embodiment, the expression that adjacent substituents R₄ can be optionally joined to form a ring is intended to mean that any two substituents R₄ can be joined to form a ring. Obviously, it is also possible that any two substituents R₄ are not joined to form a ring.

According to an embodiment of the present disclosure, the first host material is a deuterated compound.

Herein, “deuterated compound” means that at least one H in a compound is substituted with deuterium (D). For example, the compound may be at least 10% deuteration (“% deuteration” refers to a ratio of deuterium to a sum of hydrogen plus deuterium), or at least 20% deuteration, or at least 30% deuteration, or at least 40% deuteration, or at least 50% deuteration, or at least 60% deuteration, or at least 70% deuteration, or at least 80% deuteration, or at least 90% deuteration, or 100% deuteration.

According to an embodiment of the present disclosure, wherein the first host material has a structure represented by Formula 4.

According to an embodiment of the present disclosure, wherein the first host material has a structure represented by Formula 4-1:

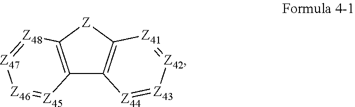

wherein in Formula 4-1,
Z is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof; and
R₄ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 4-1, at least one of Z₄₁ to Z₄₈ is selected from N, and at least two of Z₄₁ to Z₄₈ are selected from CR₄′.

According to an embodiment of the present disclosure, in Formula 4-1, only one of Z₄₁ to Z₄₈ is selected from N, and only two of Z₄₁ to Z₄₈ are selected from CR₄′.

According to an embodiment of the present disclosure, in Formula 4-1, Z₄₂ is selected from N, and Z₄₁ and Z₄₆ are selected from CR₄′.

According to an embodiment of the present disclosure, in Formula 3, at least two of Z₁ to Z₃ are N.

According to an embodiment of the present disclosure, in Formula 3, Z₁ to Z₃ are N.

According to an embodiment of the present disclosure, wherein, in Formula 3, L is, at each occurrence identically or differently, selected from the group consisting of: a single bond, substituted or unsubstituted arylene having 6 to 18 carbon atoms, substituted or unsubstituted heteroarylene having 3 to 18 carbon atoms and combinations thereof.

According to an embodiment of the present disclosure, wherein, in Formula 3, L is, at each occurrence identically or differently, selected from the group consisting of: a single bond, phenylene, biphenylylene, fluorenylene, triphenylenylene, furanylene, thienylene, dibenzofuranylene, dibenzothienylene and combinations thereof.

According to an embodiment of the present disclosure, wherein R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, wherein R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein R₁ to R₄ are, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof.

According to an embodiment of the present disclosure, wherein R₁ to R₄ are, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl, triazinyl and combinations thereof.

According to an embodiment of the present disclosure, wherein R₁ to R₄ are, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl, triazinyl, triphenylsilyl and combinations thereof.

According to an embodiment of the present disclosure, wherein the first host material has a structure represented by Formula 3-1:

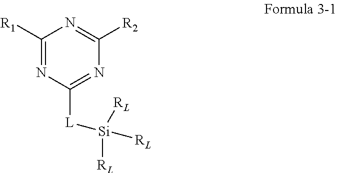

wherein in Formula 3-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof; and
R_{L} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

According to an embodiment of the present disclosure, wherein R₁ and R₂ are each independently selected from the group consisting of: carbazolyl, indolyl, benzofuranyl, dibenzofuranyl, benzosilolyl, dibenzosilolyl, benzothienyl, dibenzothienyl and combinations thereof.

According to an embodiment of the present disclosure, wherein L is selected from a single bond, phenylene, biphenylylene, terphenylene or pyridylene.

According to an embodiment of the present disclosure, wherein R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, wherein R_{L} is, at each occurrence identically or differently, selected from substituted or unsubstituted aryl having 6 to 30 carbon atoms.

According to an embodiment of the present disclosure, wherein R_{L} is, at each occurrence identically or differently, selected from the group consisting of: phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, wherein the first host material is selected from the group consisting of Compound N-1-1 to Compound N-1-60 and Compound N-2-1 to Compound N-2-35, wherein the specific structures of Compound N-1-1 to Compound N-1-60 and Compound N-2-1 to Compound N-2-35 are referred to claim 19.

According to an embodiment of the present disclosure, wherein the first host material is selected from the group consisting of Compound N-1-1 to Compound N-1-60 and Compound N-2-1 to Compound N-2-45, wherein the specific structures of Compound N-1-1 to Compound N-1-60 and Compound N-2-1 to Compound N-2-35 are referred to claim 19, and the specific structures of Compound N-2-36 to Compound N-2-45 are

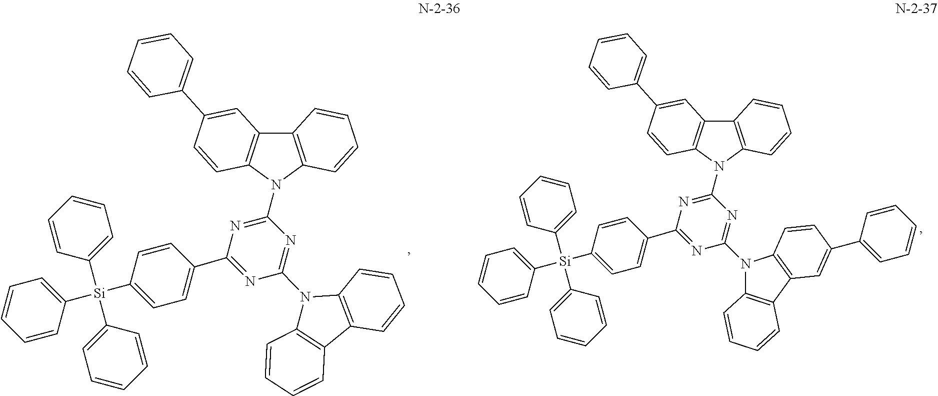 [SMILES: c1ccc(-c2ccc3c(c2)c2ccccc2n3-c2nc(-c3ccc([Si](c4ccccc4)(c4ccccc4)c4ccccc4)cc3)nc(-n3c4ccccc4c4ccccc43)n2)cc1 ; c1ccc(-c2ccc3c(c2)c2ccccc2n3-c2nc(-c3ccc([Si](c4ccccc4)(c4ccccc4)c4ccccc4)cc3)nc(-n3c4ccccc4c4cc(-c5ccccc5)ccc43)n2)cc1]

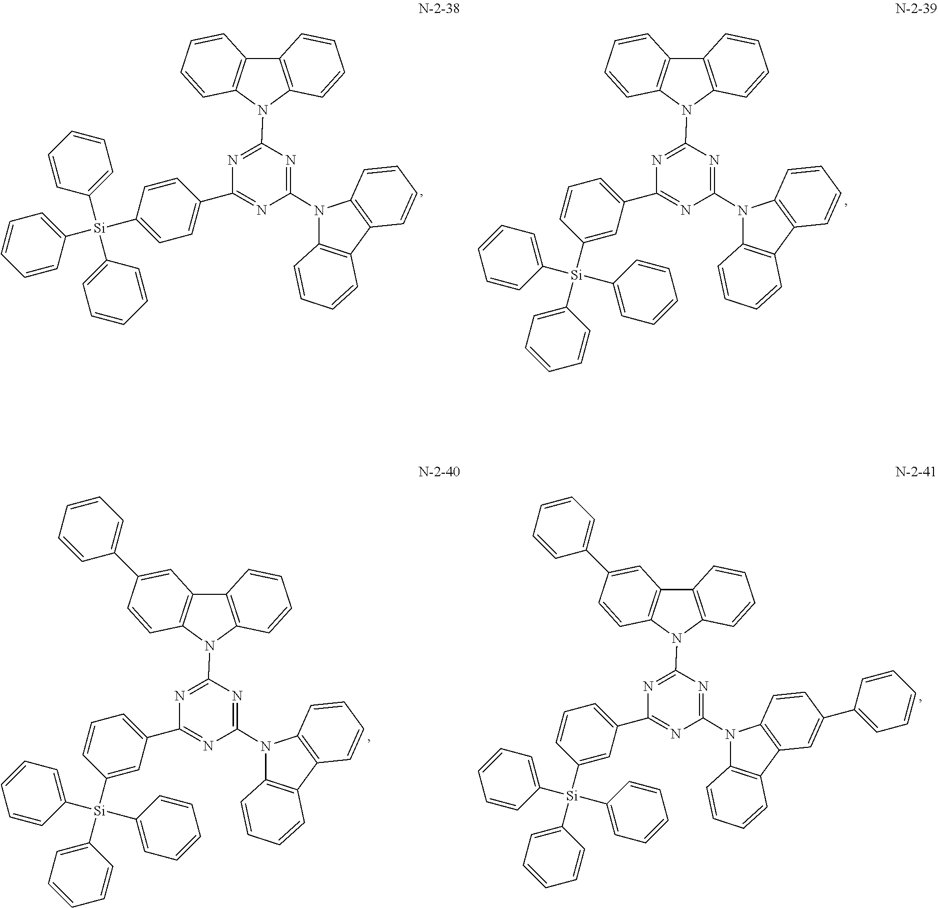 [SMILES: c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1]

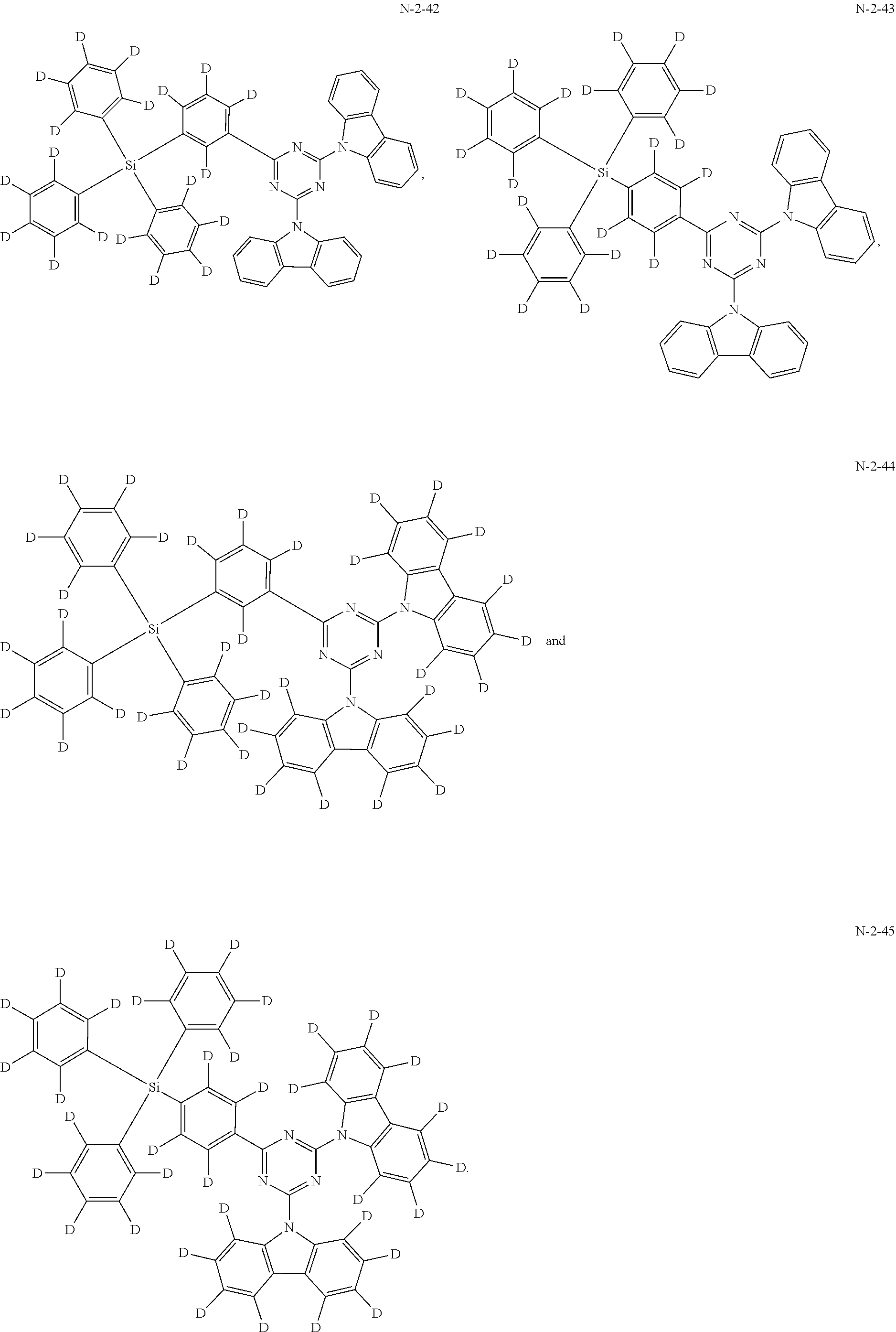

According to an embodiment of the present disclosure, hydrogens in the structures of Compound N-1-1 to Compound N-1-53, Compound N-1-58 and Compound N-2-1 to Compound N-2-32 can be partially or fully substituted with deuterium.

According to an embodiment of the present disclosure, hydrogens in the structures of Compound N-1-1 to Compound N-1-53, Compound N-1-58, Compound N-2-1 to Compound N-2-32 and Compound N-2-36 to Compound N-2-43 can be partially or fully substituted with deuterium.

According to an embodiment of the present disclosure, wherein the triplet energy level of the second host material is higher than 2.69 eV.

According to an embodiment of the present disclosure, wherein the second host material has a structure represented by Formula 6:

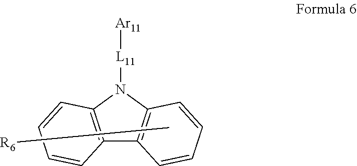

wherein in Formula 6,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

Herein, the expression that adjacent substituents R₆ can be optionally joined to form a ring is intended to mean that two substituents R₆ can be joined to form a ring. Obviously, it is also possible that two substituents R₆ are not joined to form a ring.

According to an embodiment of the present disclosure, the second host material is a deuterated compound.

According to an embodiment of the present disclosure, the second host material has a structure represented by Formula 6-1 or Formula 6-2:

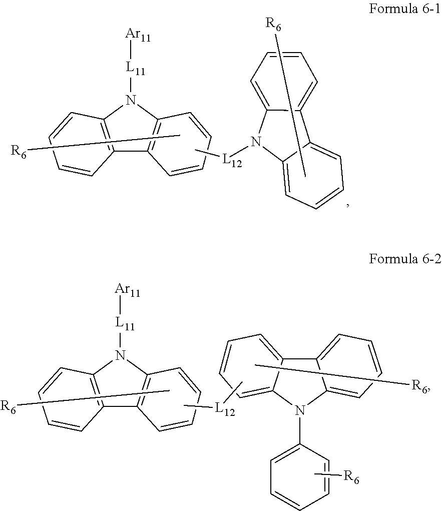

wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

According to an embodiment of the present disclosure, wherein the second host material has a structure represented by Formula 6-3 or Formula 6-4:

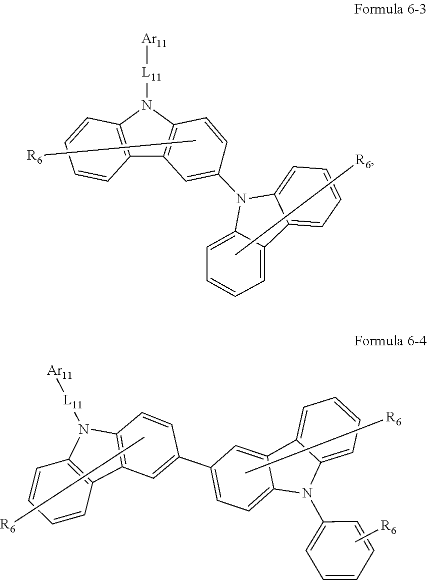

wherein Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
L₁₁ is selected from a single bond, substituted or unsubstituted arylene having 6 to 30 carbon atoms, substituted or unsubstituted heteroarylene having 3 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

According to an embodiment of the present disclosure, wherein R₆ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, wherein R₆ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof.

According to an embodiment of the present disclosure, wherein R₆ is, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, in Formula 6-1 to Formula 6-4, there are a plurality of substituents R₆, and at least one of the plurality of substituents R₆ is carbazolyl, for example, one or two of the plurality of substituents R₆ are carbazolyl.

According to an embodiment of the present disclosure, in Formula 6-1 to Formula 6-4, there are a plurality of substituents R₆, and at least one of the plurality of substituents R₆ and Ar₁₁ is carbazolyl, for example, one or two of the plurality of substituents R₆ and Ar₁₁ are carbazolyl.

According to an embodiment of the present disclosure, wherein the second host material is selected from the group consisting of Compound P-1 to Compound P-31, wherein the specific structures of Compound P-1 to Compound P-31 are referred to claim 22.

According to an embodiment of the present disclosure, hydrogens in the structures of Compound P-1 to Compound P-23 and Compound P-27 to Compound P-31 can be partially or fully substituted with deuterium.

According to an embodiment of the present disclosure, an HOMO energy level of the second host material is greater than −5.69 eV and less than −5.39 eV.

According to an embodiment of the present disclosure, wherein the light-emitting layer comprises only a first compound, a first host material and a second host material.

The HOMO energy level or LUMO energy level of the compound described herein is an electrochemical property of the compound measured through cyclic voltammetry using anhydrous DMF as a solvent. The test is conducted using an electrochemical workstation modelled CorrTest CS120 produced by Wuhan Corrtest Instruments Corp., Ltd and using a three-electrode working system where a platinum disk electrode serves as a working electrode, a Ag/AgNO₃ electrode serves as a reference electrode, and a platinum wire electrode serves as an auxiliary electrode. Anhydrous DMF is used as a solvent, 0.1 mol/L tetrabutylammonium hexafluorophosphate is used as a supporting electrolyte, a compound to be tested is prepared into a solution of 10⁻³ mol/L, and nitrogen is introduced into the solution for 10 min for oxygen removal before the test. The parameters of the instrument are set as follows: a scan rate of 100 mV/s, a potential interval of 0.5 mV, and a test window of −1 V to −2.9 V.

According to an embodiment of the present disclosure, wherein the first compound is a phosphorescent material, the first host material is an n-type host material, and the second host material is a p-type host material.

Herein, the p-type host material is an organic compound comprising a carbazole group or a triarylamine organic compound, and an HOMO energy level of the p-type host material is generally greater than −5.8 eV; the n-type host material is an organic compound comprising chemical groups such as pyridine, pyrimidine, triazine, azadibenzofuran, aza-dibenzothiophene and azacarbazole, and an LUMO energy level of the n-type host material is generally less than −2.3 eV.

According to an embodiment of the present disclosure, wherein the organic electroluminescent device emits blue light.

According to another embodiment of the present disclosure, further disclosed is an electronic device, the electronic device comprises the organic electroluminescent device described in any one of the preceding embodiments.

According to another embodiment of the present disclosure, further disclosed is a compound composition. The compound composition comprises at least a first compound, a first host material and a second host material, wherein the first compound, the first host material and the second host material are described in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, emissive dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### Material Synthesis Example

The method for preparing a first compound selected in the present disclosure is not limited herein. Typically, the following compounds are used as examples without limitations, and synthesis routes and preparation methods thereof are described below.

### Synthesis Example 1: Synthesis of Compound Pt16

### Step 1: Synthesis of Intermediate 1

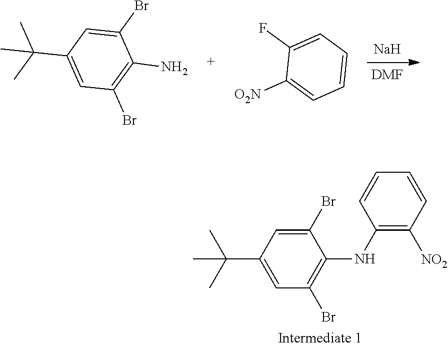

Under a nitrogen condition, 2,6-dibromo-4-tert-butylaniline (61.4 g, 200 mmol) was dissolved in DMF (300 mL), and NaH (12 g, 300 mmol) was added at 0° C. After a reaction was conducted for 0.5 h, 1-fluoro-2-nitrobenzene (42.3 g, 300 mmol) was added slowly, and the reaction was warmed to room temperature and conducted overnight. After the reaction was completed, a reaction solution was extracted with DCM and an aqueous sodium chloride solution, and an organic layer was washed twice with an aqueous sodium chloride solution, dried over anhydrous magnesium sulfate, evaporated to dryness under reduced pressure and purified through column chromatography to obtain Intermediate 1 (49.2 g, 115 mmol).

### Step 2: Synthesis of Intermediate 2

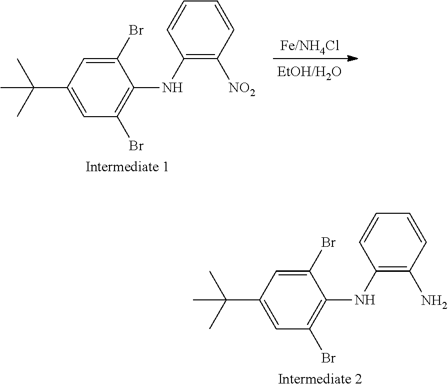 [SMILES: CC(C)(C)c1cc(Br)c(Nc2ccccc2[N+](=O)[O-])c(Br)c1 ; "EtOH/H2O" ; "Fe/NH4Cl" ; CC(C)(C)c1cc(Br)c(Nc2ccccc2N)c(Br)c1]

Intermediate 1 (49.2 g, 115 mmol) was dissolved in EtOH (200 mL) and water (200 mL), Fe (19.4 g, 345 mmol) and NH₄Cl (0.61 g, 11.5 mmol) were added, and a reaction was warmed to reflux and conducted overnight. After the reaction was completed, a reaction solution was filtered through Celite, evaporated to dryness under reduced pressure and extracted with EA and water, and an organic layer was washed twice with an aqueous sodium chloride solution, dried over anhydrous magnesium sulfate, evaporated to dryness under reduced pressure and subjected to column chromatography to obtain Intermediate 2 (40.6 g, 102 mmol).

### Step 3: Synthesis of Intermediate 3

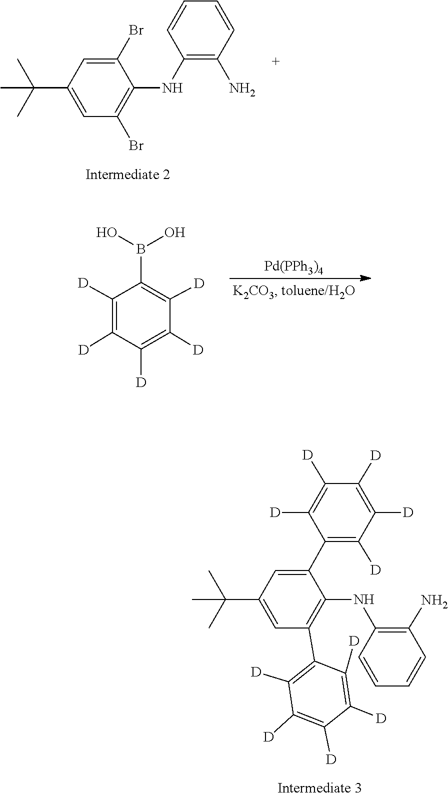 [SMILES: CC(C)(C)c1cc(Br)c(Nc2ccccc2N)c(Br)c1 ; [2H]c1c([2H])c([2H])c(B(O)O)c([2H])c1[2H] ; [2H]c1c([2H])c([2H])c(-c2cc(C(C)(C)C)cc(-c3c([2H])c([2H])c([2H])c([2H])c3[2H])c2Nc2ccccc2N)c([2H])c1[2H] ; "Pd(PPh3)4"]

Under a nitrogen condition, Intermediate 2 (19.8 g, 50 mmol), phenyl-D5-boronic acid (14.1 g, 120 mmol), Pd(PPh₃)₄ (2.9 g, 2.5 mmol) and potassium carbonate (10.4 g, 75 mmol) were dissolved in toluene (150 mL) and water (50 mL), and a reaction was warmed to reflux and conducted overnight. After the reaction was completed, a reaction solution was extracted with EA and water, and an organic layer was washed twice with an aqueous sodium chloride solution, dried over anhydrous magnesium sulfate, evaporated to dryness under reduced pressure and subjected to column chromatography to obtain Intermediate 3 (17.3 g, 43 mmol).

### Step 4: Synthesis of Intermediate 4

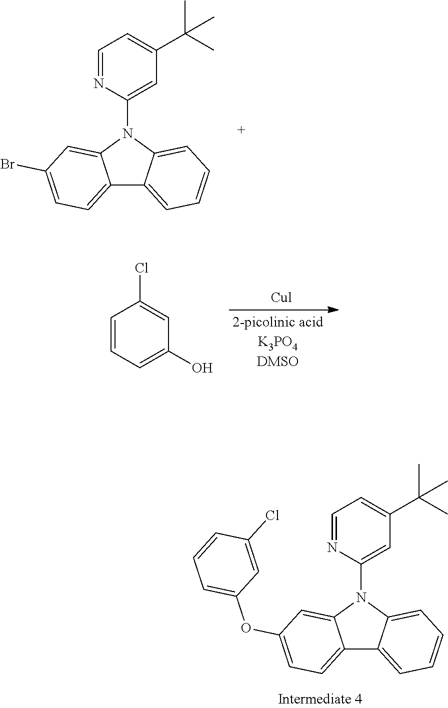 [SMILES: CC(C)(C)c1ccnc(-n2c3ccccc3c3ccc(Br)cc32)c1 ; Oc1cccc(Cl)c1 ; CC(C)(C)c1ccnc(-n2c3ccccc3c3ccc(Oc4cccc(Cl)c4)cc32)c1]

Under a nitrogen condition, 2-bromo-9-(4-(t-butyl)pyridin-2-yl)-9H-carbazole (7.0 g, 18.0 mmol), m-chlorophenol (3.0 g, 23.3 mmol), cuprous iodide (0.34 g, 1.8 mmol), 2-picolinic acid (0.44 g, 3.6 mmol) and potassium phosphate (7.6 g, 36.0 mmol) were added to a 500 mL flask, and dimethylsulfoxide (72 mL) was added. A reaction was heated to 150° C., and a reaction solution was stirred overnight. After the reaction was completed, the reaction solution was purified through column chromatography to obtain Intermediate 4 (4.1 g, 9.6 mmol).

### Step 5: Synthesis of Intermediate 5

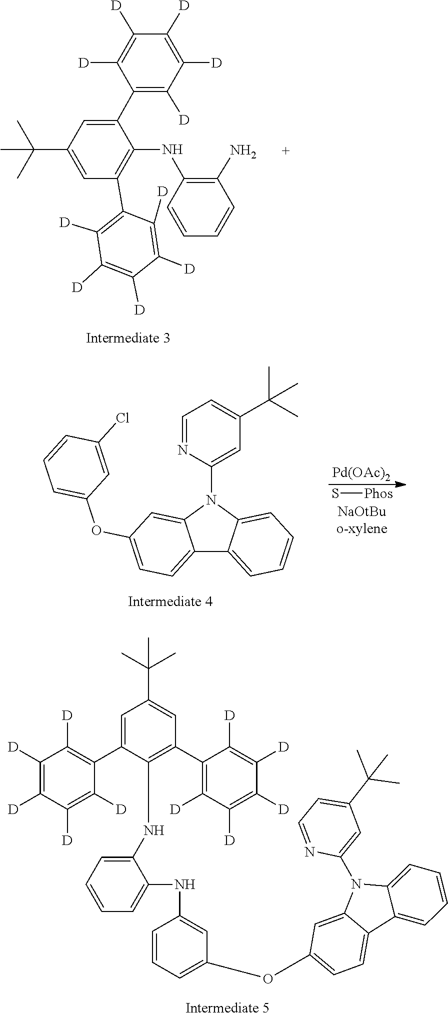

Under a nitrogen condition, Intermediate 3 (3.2 g, 8 mmol), Intermediate 4 (3.4 g, 8 mmol), Pd(OAc)₂ (45 mg, 0.2 mmol), S-Phos (320 mg, 0.4 mmol), NaOt-Bu (1.6 g, 16 mmol) and o-xylene (60 mL) were added to a flask, a reaction was warmed to 140° C., and a reaction solution was stirred overnight, cooled to room temperature, subjected to rotary evaporation to dryness and subjected to column chromatography to obtain Intermediate 5 (3.0 g, 3.5 mmol).

### Step 6: Synthesis of Intermediate 6

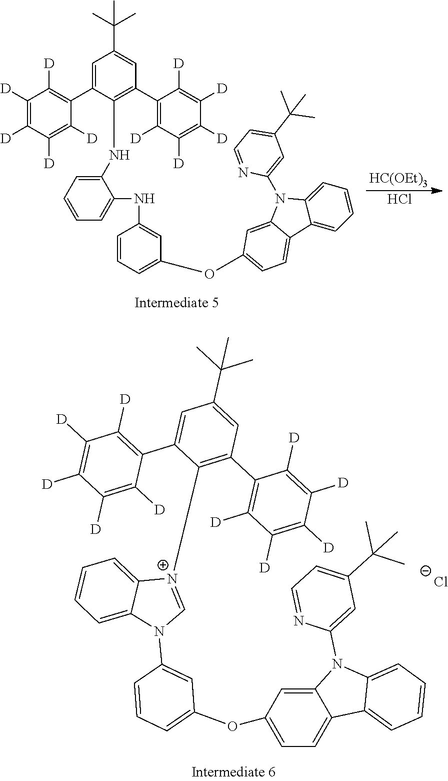 [SMILES: [2H]c1c([2H])c([2H])c(-c2cc(C(C)(C)C)cc(-c3c([2H])c([2H])c([2H])c([2H])c3[2H])c2Nc2ccccc2Nc2cccc(Oc3ccc4c5ccccc5n(-c5cc(C(C)(C)C)ccn5)c4c3)c2)c([2H])c1[2H] ; Cl ; [2H]c1c([2H])c([2H])c(-c2cc(C(C)(C)C)cc(-c3c([2H])c([2H])c([2H])c([2H])c3[2H])c2-[n+]2cn(-c3cccc(Oc4ccc5c6ccccc6n(-c6cc(C(C)(C)C)ccn6)c5c4)c3)c3ccccc32)c([2H])c1[2H] ; [Cl-] ; "HC(OEt)3"]

Under a nitrogen condition, Intermediate 5 (3.0 g, 3.5 mmol), triethyl orthoformate (22.2 g, 150 mmol) and concentrated hydrochloric acid (0.5 mL) were added to a flask, a reaction was warmed to 100° C., and a reaction solution was stirred overnight. After the reaction was finished as detected through TLC, the reaction solution was cooled to room temperature, subjected to rotary evaporation to dryness and subjected to column chromatography to obtain Intermediate 6 (2.53 g, 2.98 mmol).

### Step 7: Synthesis of Compound Pt16

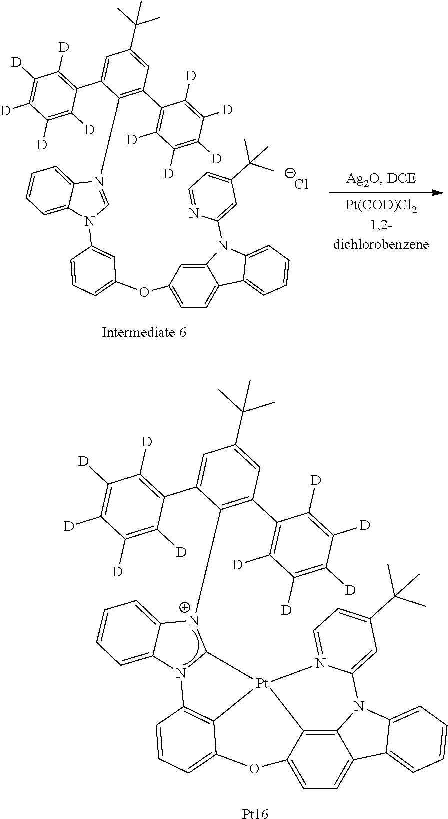

Under a nitrogen condition, Intermediate 6 (2.53 g, 2.98 mmol), Ag₂O (0.26 g, 1.64 mmol) and DCE (20 mL) were added to a flask and reacted for 12 h at room temperature. After the reaction was completed, a solvent was evaporated to dryness under reduced pressure, and (1,5-cyclooctadiene)platinum dichloride (Pt(COD)Cl₂, 1.0 g, 2.68 mmol) was added. After 1,2-dichlorobenzene (30 mL) was added, a reaction was warmed to 190° C., and a reaction solution was stirred for 72 h. After the reaction was cooled to room temperature, the reaction solution was subjected to column chromatography to obtain Compound Pt16 (1.84 g, 1.85 mmol). The product was identified as the target product with a molecular weight of 995.4.

### Synthesis Example 2: Synthesis of Compound Pt39

### Step 1: Synthesis of Intermediate 7

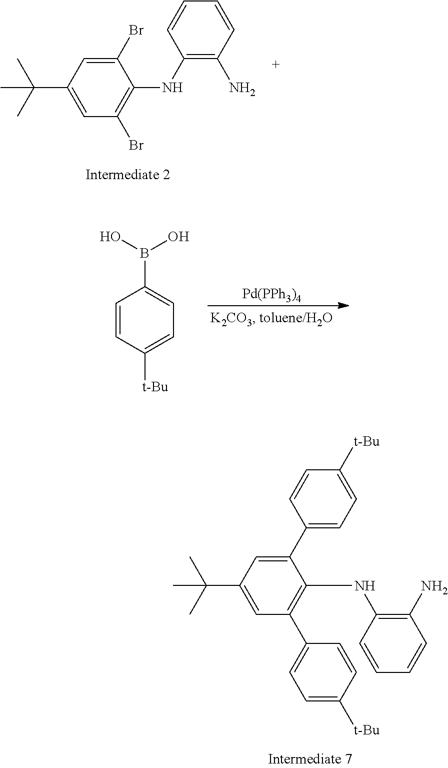 [SMILES: CC(C)(C)c1cc(Br)c(Nc2ccccc2N)c(Br)c1 ; CC(C)(C)c1ccc(B(O)O)cc1 ; CC(C)(C)c1ccc(-c2cc(C(C)(C)C)cc(-c3ccc(C(C)(C)C)cc3)c2Nc2ccccc2N)cc1 ; "Pd(PPh3)4"]

Under a nitrogen condition, Intermediate 2 (12.2 g, 30.6 mmol), 4-t-butylphenylboronic acid (13.6 g, 76.6 mmol), Pd(PPh₃)₄ (1.4 g, 1.2 mmol) and potassium carbonate (6.4 g, 46 mmol) were dissolved in toluene (150 mL) and water (50 mL), and a reaction was warmed to reflux and conducted overnight. After the reaction was completed, a reaction solution was extracted with EA and water, and an organic layer was washed twice with an aqueous sodium chloride solution, dried over anhydrous magnesium sulfate, evaporated to dryness under reduced pressure and subjected to column chromatography to obtain Intermediate 7 (9 g, 17.8 mmol).

### Step 2: Synthesis of Intermediate 8

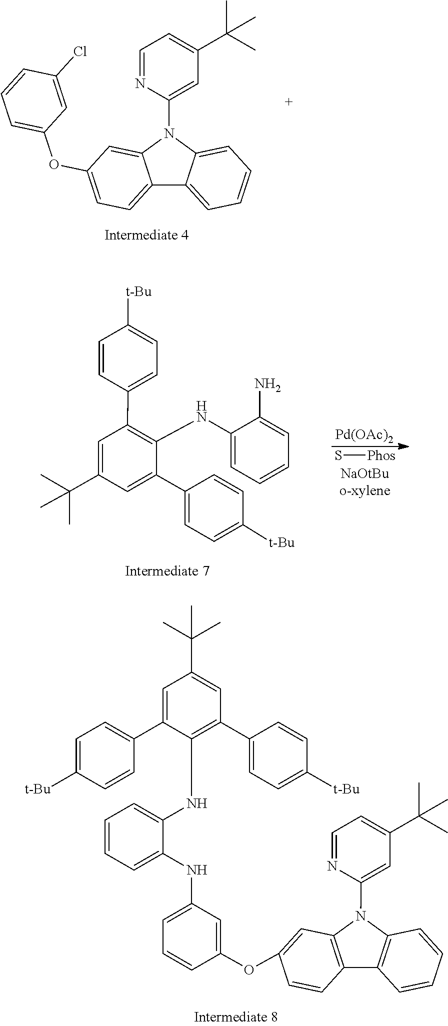

Under a nitrogen condition, Intermediate 4 (3.5 g, 7.4 mmol), Intermediate 7 (3.5 g, 7.0 mmol), Pd(OAc)₂ (68 mg, 0.3 mmol), S-Phos (250 mg, 0.6 mmol), NaOt-Bu (1.5 g, 15 mmol) and o-xylene (60 mL) were added to a flask, a reaction was warmed to 140° C., and a reaction solution was stirred overnight, cooled to room temperature, subjected to rotary evaporation to dryness and subjected to column chromatography to obtain Intermediate 8 (1.8 g, 2.0 mmol).

### Step 3: Synthesis of Intermediate 9

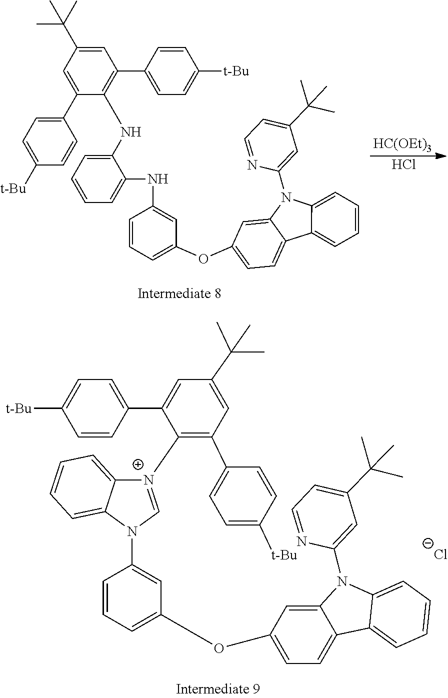 [SMILES: CC(C)(C)c1ccc(-c2cc(C(C)(C)C)cc(-c3ccc(C(C)(C)C)cc3)c2Nc2ccccc2Nc2cccc(Oc3ccc4c5ccccc5n(-c5cc(C(C)(C)C)ccn5)c4c3)c2)cc1 ; Cl ; CC(C)(C)c1ccc(-c2cc(C(C)(C)C)cc(-c3ccc(C(C)(C)C)cc3)c2-[n+]2cn(-c3cccc(Oc4ccc5c6ccccc6n(-c6cc(C(C)(C)C)ccn6)c5c4)c3)c3ccccc32)cc1 ; [Cl-] ; "HC(OEt)3"]

Under a nitrogen condition, Intermediate 8 (1.8 g, 2.0 mmol), triethyl orthoformate (14.8 g, 100 mmol) and concentrated hydrochloric acid (0.5 mL) were added to a flask, a reaction was warmed to 100° C., and a reaction solution was stirred overnight. After the reaction was finished as detected through TLC, the reaction solution was cooled to room temperature, subjected to rotary evaporation to dryness and subjected to column chromatography to obtain Intermediate 9 (1.7 g, 1.87 mmol).

### Step 4: Synthesis of Pt39

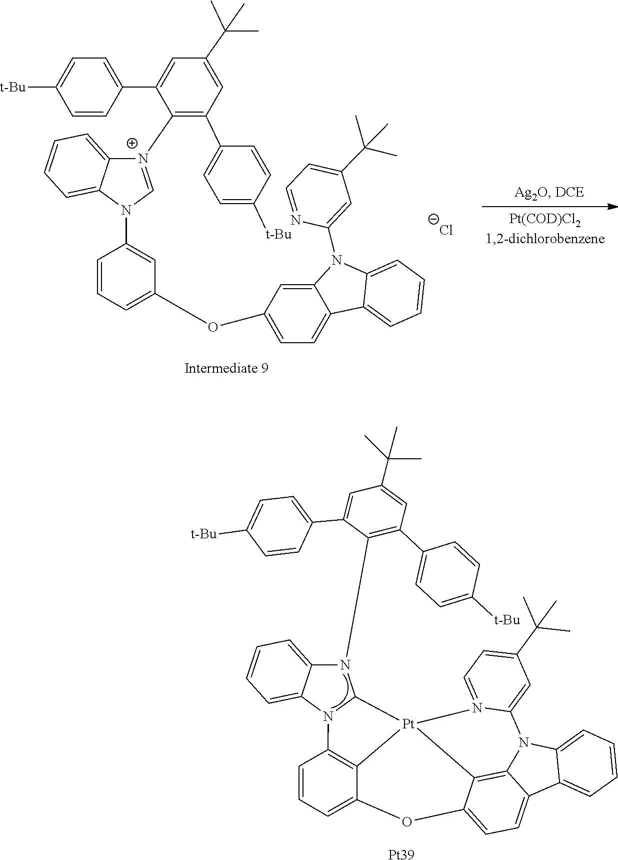

Under a nitrogen condition, Intermediate 9 (1.7 g, 1.87 mmol), Ag₂O (0.24 g, 1.0 mmol) and DCE (20 mL) were added to a flask and reacted for 12 h at room temperature. After the reaction was completed, a solvent was evaporated to dryness under reduced pressure, and (1,5-cyclooctadiene)platinum dichloride (Pt(COD)Cl₂, 0.64 g, 1.7 mmol) was added. After 1,2-dichlorobenzene (30 mL) was added, a reaction was warmed to 190° C., and a reaction solution was stirred for 72 h. After the reaction was cooled to room temperature, the reaction solution was subjected to column chromatography to obtain Compound Pt39 (0.74 g, 0.67 mmol). The product was identified as the target product with a molecular weight of 1097.5.

### Synthesis Comparative Example 1: Synthesis of Compound Pt-A

### Step 1: Synthesis of Intermediate 10

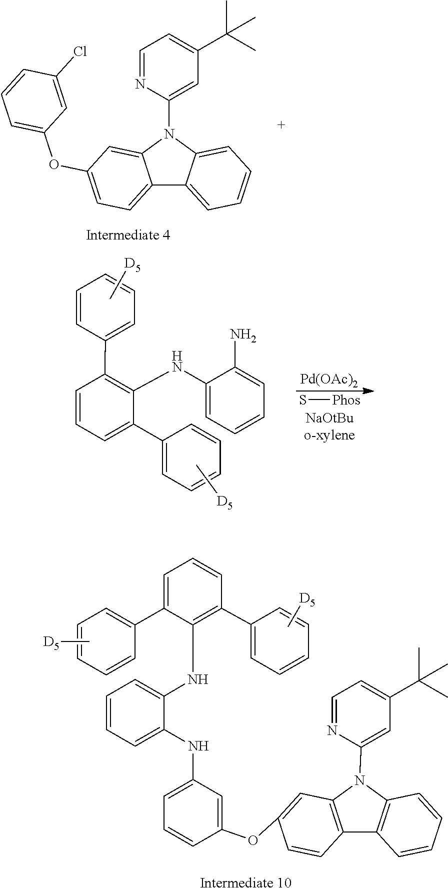

Under a nitrogen condition, Intermediate 4 (4.1 g, 9.6 mmol), N1-([1,1′:3′,1″-terphenyl]-2′-yl-2,2″,3,3″,4,4″,5,5″,6,6″-d10)phenyl-1,2-diamine (2 g, 6 mmol), Pd(OAc)₂ (108 mg, 0.48 mmol), S-Phos (394 mg, 0.96 mmol), NaOt-Bu (1.84 g, 19.2 mmol) and o-xylene (100 mL) were added to a flask, a reaction was warmed to 140° C., and a reaction solution was stirred overnight, cooled to room temperature, subjected to rotary evaporation to dryness and subjected to column chromatography to obtain Intermediate 10 (2.3 g, 3.1 mmol).

### Step 2: Synthesis of Intermediate 11

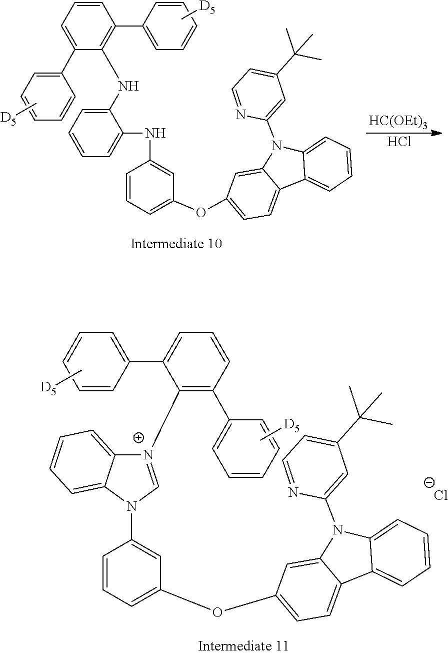

Under a nitrogen condition, Intermediate 10 (2.3 g, 3.1 mmol), triethyl orthoformate (23.0 g, 155 mmol) and concentrated hydrochloric acid (0.4 mL) were added to a flask, a reaction was warmed to 100° C., and a reaction solution was stirred overnight. After the reaction was finished as detected through TLC, the reaction solution was cooled to room temperature, subjected to rotary evaporation to dryness and subjected to column chromatography to obtain Intermediate 11 (3.0 g, 2.5 mmol).

### Step 3: Synthesis of Compound Pt-A

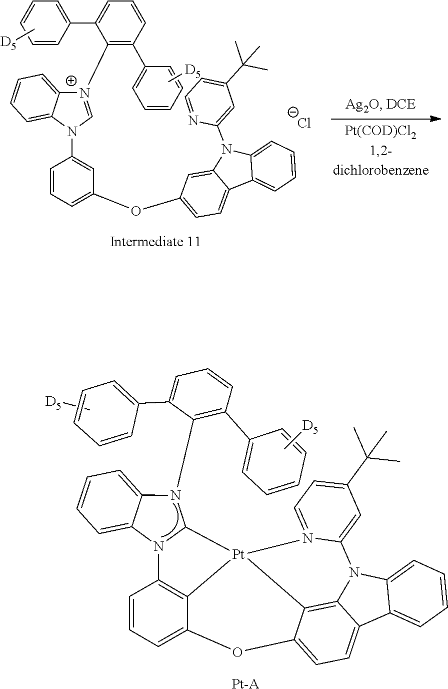

Under a nitrogen condition, Intermediate 11 (2.0 g, 2.5 mmol), Ag₂O (0.29 g, 1.3 mmol) and DCE (25 mL) were added to a flask and reacted for 12 h at room temperature. After the reaction was completed, a solvent was evaporated to dryness under reduced pressure, and Pt(COD)Cl₂ (0.94 g, 2.5 mmol) was added to the flask. After 1,2-dichlorobenzene (25 mL) was added, a reaction was warmed to 200° C., and a reaction solution was stirred for 24 h. After the reaction was cooled to room temperature, the reaction solution was subjected to column chromatography to obtain Compound Pt-A (0.95 g, 1.0 mmol). The product was identified as the target product with a molecular weight of 939.3.

### Synthesis Comparative Example 2: Synthesis of Compound Pt-B

### Step 1: Synthesis of Intermediate 12

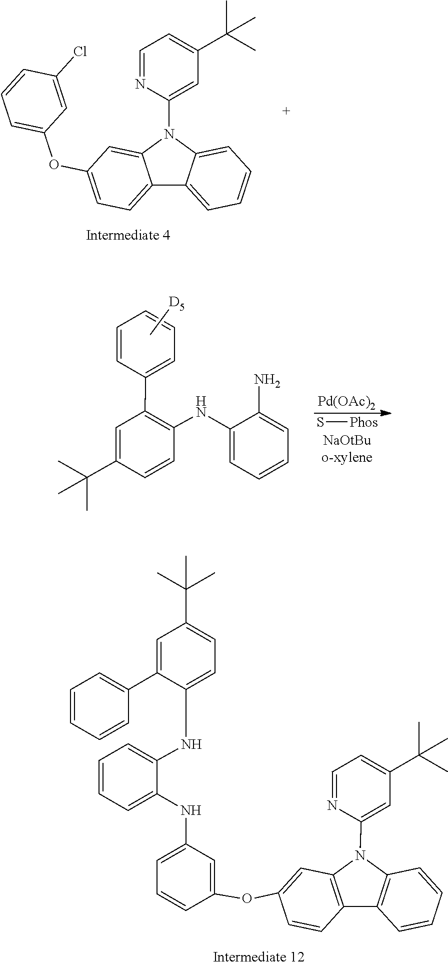

Under a nitrogen condition, Intermediate 4 (2.2 g, 5.2 mmol), N1-(5-t-butyl-[1,1′-biphenyl]-2-yl-2″,3″,4″,5″,6″-d5)phenyl-1,2-diamine (1.6 g, 5 mmol), Pd(OAc)₂ (45 mg, 0.2 mmol), S-Phos (164 mg, 0.4 mmol), NaOt-Bu (0.96 g, 10 mmol) and o-xylene (50 mL) were added to a flask, a reaction was warmed to 140° C., and a reaction solution was stirred overnight, cooled to room temperature, subjected to rotary evaporation to dryness and subjected to column chromatography to obtain Intermediate 12 (2.7 g, 3.5 mmol).

### Step 3: Synthesis of Intermediate 13

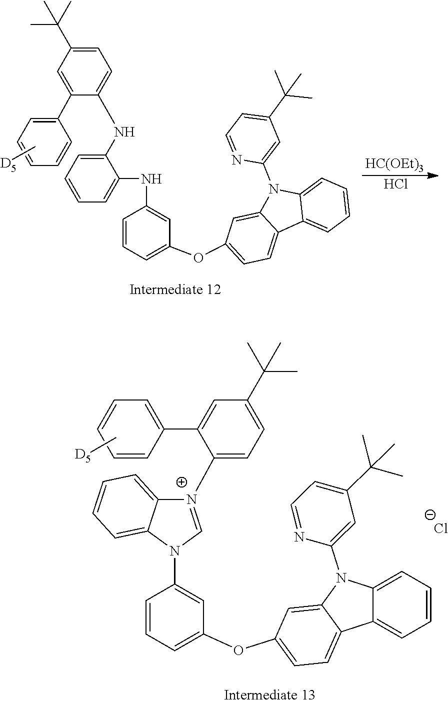

Under a nitrogen condition, Intermediate 12 (2.7 g, 3.5 mmol), triethyl orthoformate (25.9 g, 175 mmol) and concentrated hydrochloric acid (0.7 mL) were added to a flask, a reaction was warmed to 100° C., and a reaction solution was stirred overnight. After the reaction was finished as detected through TLC, the reaction solution was cooled to room temperature, subjected to rotary evaporation to dryness and subjected to column chromatography to obtain Intermediate 13 (2.1 g, 2.7 mmol).

### Step 4: Synthesis of Compound Pt-B

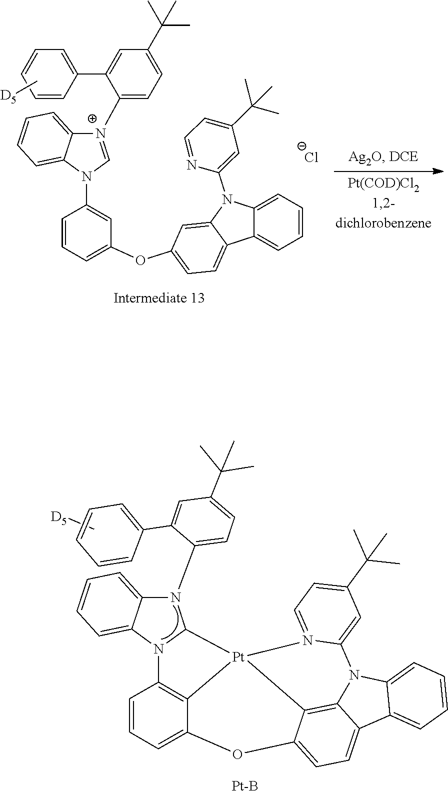

Under a nitrogen condition, Intermediate 13 (2.1 g, 2.7 mmol), Ag₂O (0.35 g, 1.5 mmol) and DCE (25 mL) were added to a flask and reacted for 12 h at room temperature. After the reaction was completed, a solvent was evaporated to dryness under reduced pressure, and Pt(COD)Cl₂ (0.91 g, 2.45 mmol) was added to the flask. After 1,2-dichlorobenzene (25 mL) was added, a reaction was warmed to 190° C., and a reaction solution was stirred for 48 h. After the reaction was cooled to room temperature, the reaction solution was subjected to column chromatography to obtain Compound Pt-B (0.92 g, 1.0 mmol). The product was identified as the target product with a molecular weight of 914.3.

Those skilled in the art will appreciate that the above preparation methods are merely exemplary. Those skilled in the art can obtain other compound structures of the present disclosure through the modifications of the preparation methods.

### Measurement of a Triplet Energy Level

Herein, the triplet energy level (T₁) was measured at an ultra-low temperature using characteristics of long-lived triplet excitons. Specifically, a compound to be tested was dissolved in a 2-methyltetrahydrofuran solvent to prepare a solution having a concentration of 10⁻⁵ M. The solution was loaded into a quartz tube, placed in a Dewar flask and cooled to 77 K. A solution of the compound to be tested was irradiated with a light source of 350 nm to measure a phosphorescence spectrum. The measurement of the spectrum used a spectrophotometer modelled F98 produced by SHANGHAI LENGGUANG TECH. CO., LTD.

In the phosphorescence spectrum, a longitudinal axis represented a phosphorescence intensity, and a horizontal axis represented a wavelength. A minimum value λ₁ (nm) of a peak on a short wavelength side of the phosphorescence spectrum was taken, and the wavelength value was substituted into the following conversion formula F₁ to calculate the triplet energy level of the compound to be tested.

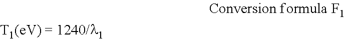

Triplet energy levels T₁ (eV) of the following compounds were measured through the above method. The specific results are shown in Table 1.

TABLE 1
Triplets of compounds

| Compound No. | T₁ (eV) |
|---|---|
| Pt16 | 2.69 |
| Pt39 | 2.69 |
| Pt681 | 2.67 |
| P-21 | 2.80 |
| P-22 | 2.95 |
| P-25 | 2.95 |
| N-1-15 | 2.89 |
| N-2-39 | 2.75 |
| H-1 | 2.85 |

As can be seen from the above results in Table 1, in the present disclosure, the triplet energy level of the first host material and triplet energy level of the second host material are both higher than the triplet energy level (2.69 eV) of the first compound as a light-emitting material. Therefore, the first host material, the second host material and the first compound can be well matched to achieve phosphorescence of blue light. Device examples are provided below for verification.

The method for preparing an electroluminescent device is not limited. The preparation methods in the following examples are merely examples and are not to be construed as limitations. Those skilled in the art can make reasonable improvements on the preparation methods in the following examples based on the related art. Exemplarily, the proportions of various materials in an emissive layer are not particularly limited. Those skilled in the art can reasonably select the proportions within a certain range based on the related art. For example, taking the total weight of the materials in the emissive layer as reference, a host material may account for 80% to 99% and a light-emitting material may account for 1% to 20%; or the host material may account for 85% to 99% and the light-emitting material may account for 1% to 15%. Further, the host material include two materials, where a ratio of two host materials may be 99:1 to 1:99; or the ratio may be 80:20 to 20:80. In the examples of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well-known to the persons skilled in the art.

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10⁻⁸ torr. Compound HI and Compound HT were co-deposited for use as a hole injection layer (HIL) with a thickness of 100 Å. Compound HT was used as a hole transporting layer (HTL) with a thickness of 250 Å. Compound P-21 was used as an electron blocking layer (EBL) with a thickness of 50 Å. Then, Compound N-1-15 as a first host material, Compound P-21 as a second host material and a first compound Pt16 as a dopant were co-deposited for use as an emissive layer (EML) with a thickness of 350 Å. Compound N-1-15 was used as a hole blocking layer (HBL) with a thickness of 50 Å. On the HBL, Compound ET and 8-hydroxyquinolinolato-lithium (Liq) were co-deposited for use as an electron transporting layer (ETL) with a thickness of 310 Å. Finally, LiF was deposited for use as an electron injection layer with a thickness of 15 Å and Al was deposited for use as a cathode with a thickness of 1200 Å. The device was transferred back to the glovebox and encapsulated with a glass lid and a moisture getter to complete the device.

### Device Example 2

The preparation method in Device Example 2 was the same as that in Device Example 1, except that Compound P-21 was replaced with Compound P-22 as the second host material and a weight ratio of Compound P-22 to Compound N-1-15 to Compound Pt16 was 52.8:35.2:12 in the emissive layer (EML).

### Device Example 3

The preparation method in Device Example 3 was the same as that in Device Example 2, except that Compound P-22 was replaced with Compound P-25 as the second host material in the emissive layer (EML).

### Device Example 5

The preparation method in Device Example 5 was the same as that in Device Example 1, except that Compound HT was replaced with Compound HT-1 and a weight ratio of Compound HT-1 to Compound HI was 97:3 in the hole injection layer (HIL), Compound HT was replaced with Compound HT-1 in the hole transporting layer (HTL) and Compound P-21 was replaced with Compound P-22 as the second host material, Compound Pt16 was replaced with Compound Pt681 as the first compound and a weight ratio of Compound P-22 to Compound N-1-15 to Compound Pt681 was 61.6:26.4:12 in the emissive layer (EML).

### Device Example 6

The preparation method in Device Example 6 was the same as that in Device Example 1, except that Compound HT was replaced with Compound HT-1 and a weight ratio of Compound HT-1 to Compound HI was 97:3 in the hole injection layer (HIL), Compound HT was replaced with Compound HT-1 in the hole transporting layer (HTL), Compound N-1-15 was replaced with Compound N-2-39 as the first host material and a weight ratio of Compound P-21 to Compound N-2-39 to Compound Pt16 was 35.2:52.8:12 in the emissive layer (EML) and Compound N-1-15 was replaced with Compound N-2-39 in the hole blocking layer (HBL).

### Device Example 7

The preparation method in Device Example 7 was the same as that in Device Example 6, except that Compound P-21 was replaced with Compound P-22 as the second host material and a weight ratio of Compound P-22 to Compound N-2-39 to Compound Pt16 was 52.8:35.2:12 in the emissive layer (EML).

### Device Comparative Example 1

The preparation method in Device Comparative Example 1 was the same as that in Device Example 1, except that Compound Pt16 was replaced with Compound Pt-A in the emissive layer (EML).

### Device Comparative Example 2

The preparation method in Device Comparative Example 2 was the same as that in Device Example 1, except that Compound Pt16 was replaced with Compound Pt-B in the emissive layer (EML).

### Device Comparative Example 3

The preparation method in Device Comparative Example 3 was the same as that in Device Example 1, except that Compound P-21 was used as a host material, Compound Pt16 was used as the dopant and a weight ratio of Compound P-21 to Compound Pt16 was 88:12 in the emissive layer (EML).

### Device Comparative Example 4

The preparation method in Device Comparative Example 4 was the same as that in Device Example 1, except that Compound N-1-15 was used as a host material, Compound Pt16 was used as the dopant and a weight ratio of Compound N-1-15 to Compound Pt16 was 88:12 in the emissive layer (EML).

### Device Comparative Example 5

The preparation method in Device Comparative Example 5 was the same as that in Device Example 1, except that Compound H-1 was used as a host material, Compound Pt16 was used as the dopant and a weight ratio of Compound H-1 to Compound Pt16 was 88:12 in the emissive layer (EML).

Detailed structures and thicknesses of layers of the devices are shown in the following table. A layer using more than one material is obtained by doping different compounds at their weight ratio as recorded.

TABLE 2
Part of device structures in device examples and comparative examples

| Device ID | HIL | HTL | EBL | EML | HBL | ETL |
|---|---|---|---|---|---|---|
| Example 1 | Compound | Compound | Compound | Compound P- | Compound | Compound |
| | HT:Compound | HT | P-21 | 21:Compound N- | N-1-15 | ET:Liq |
| | HI (97:3) | (250 Å) | (50 Å) | 1-15:Compound | (50 Å) | (40:60) |
| | (100 Å) | | | Pt16 | | (310 Å) |
| | | | | (61.6:26.4:12) | | |
| | | | | (350 Å) | | |
| Example 2 | Compound | Compound | Compound | Compound P- | Compound | Compound |
| | HT:Compound | HT | P-21 | 22:Compound N- | N-1-15 | ET:Liq |
| | HI (97:3) | (250 Å) | (50 Å) | 1-15:Compound | (50 Å) | (40:60) |
| | (100 Å) | | | Pt16 | | (310 Å) |
| | | | | (52.8:35.2:12) | | |
| | | | | (350 Å) | | |
| Example 3 | Compound | Compound | Compound | Compound P- | Compound | Compound |
| | HT:Compound | HT | P-21 | 25:Compound N- | N-1-15 | ET:Liq |
| | HI (97:3) | (250 Å) | (50 Å) | 1-15:Compound | (50 Å) | (40:60) |
| | (100 Å) | | | Pt16 | | (310 Å) |
| | | | | (52.8:35.2:12) | | |
| | | | | (350 Å) | | |
| Example 5 | Compound | Compound | Compound | Compound P- | Compound | Compound |
| | HT- | HT-1 | P-21 | 22:Compound N- | N-1-15 | ET:Liq |
| | 1:Compound | (250 Å) | (50 Å) | 1-15:Compound | (50 Å) | (40:60) |
| | HI (97:3) | | | Pt681 | | (310 Å) |
| | (100 Å) | | | (61.6:26.4:12) | | |
| | | | | (350 Å) | | |
| Example 6 | Compound | Compound | Compound | Compound P- | Compound | Compound |
| | HT- | HT-1 | P-21 | 21:Compound N- | N-2-39 | ET:Liq |
| | 1:Compound | (250 Å) | (50 Å) | 2-39:Compound | (50 Å) | (40:60) |
| | HI (97:3) | | | Pt16 | | (310 Å) |
| | (100 Å) | | | (35.2:52.8:12) | | |
| | | | | (350 Å) | | |
| Example 7 | Compound | Compound | Compound | Compound P- | Compound | Compound |
| | HT- | HT-1 | P-21 | 22:Compound N- | N-2-39 | ET:Liq |
| | 1:Compound | (250 Å) | (50 Å) | 2-39:Compound | (50 Å) | (40:60) |
| | HI (97:3) | | | Pt16 | | (310 Å) |
| | (100 Å) | | | (52.8:35.2:12) | | |
| | | | | (350 Å) | | |
| Comparative | Compound | Compound | Compound | Compound P- | Compound | Compound |
| Example 1 | HT:Compound | HT | P-21 | 21:Compound N- | N-1-15 | ET:Liq |
| | HI (97:3) | (250 Å) | (50 Å) | 1-15:Compound | (50 Å) | (40:60) |
| | (100 Å) | | | Pt-A | | (310 Å) |
| | | | | (61.6:26.4:12) | | |
| | | | | (350 Å) | | |
| Comparative | Compound | Compound | Compound | Compound P- | Compound | Compound |
| Example 2 | HT:Compound | HT | P-21 | 21:Compound N- | N-1-15 | ET:Liq |
| | HI (97:3) | (250 Å) | (50 Å) | 1-15:Compound | (50 Å) | (40:60) |
| | (100 Å) | | | Pt-B | | (310 Å) |
| | | | | (61.6:26.4:12) | | |
| | | | | (350 Å) | | |
| Comparative | Compound | Compound | Compound | Compound P- | Compound | Compound |
| Example 3 | HT:Compound | HT | P-21 | 21:Compound | N-1-15 | ET:Liq |
| | HI (97:3) | (250 Å) | (50 Å) | Pt16 (88:12) (350 | (50 Å) | (40:60) |
| | (100 Å) | | | Å) | | (310 Å) |
| Comparative | Compound | Compound | Compound | Compound N-1- | Compound | Compound |
| Example 4 | HT:Compound | HT | P-21 | 15:Compound | N-1-15 | ET:Liq |
| | HI (97:3) | (250 Å) | (50 Å) | Pt16 (88:12) (350 | (50 Å) | (40:60) |
| | (100 Å) | | | Å) | | (310 Å) |
| Comparative | Compound | Compound | Compound | Compound H- | Compound | Compound |
| Example 5 | HT:Compound | HT | P-21 | 1:Compound Pt16 | N-1-15 | ET:Liq |
| | HI (97:3) | (250 Å) | (50 Å) | (88:12) (350 Å) | (50 Å) | (40:60) |
| | (100 Å) | | | | | (310 Å) |

The materials used in the devices have the following structures:

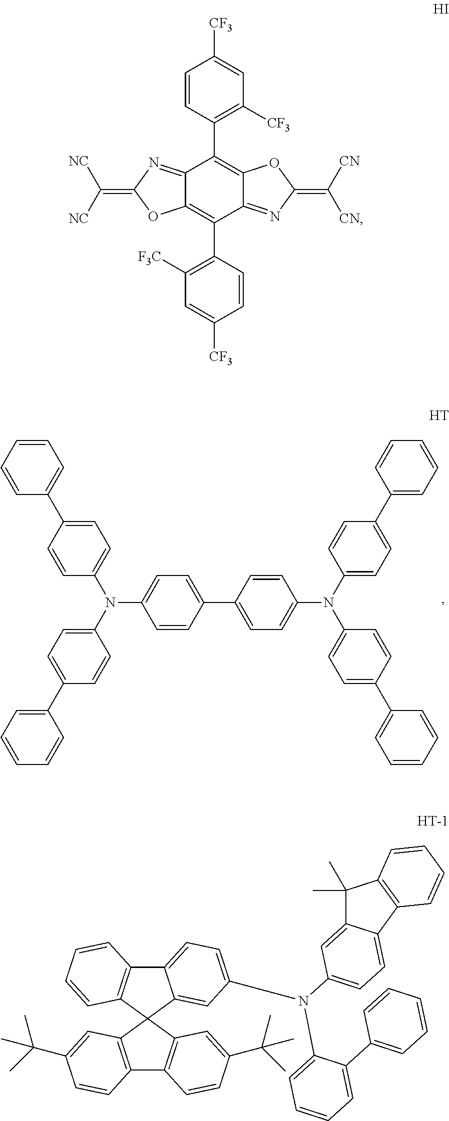 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

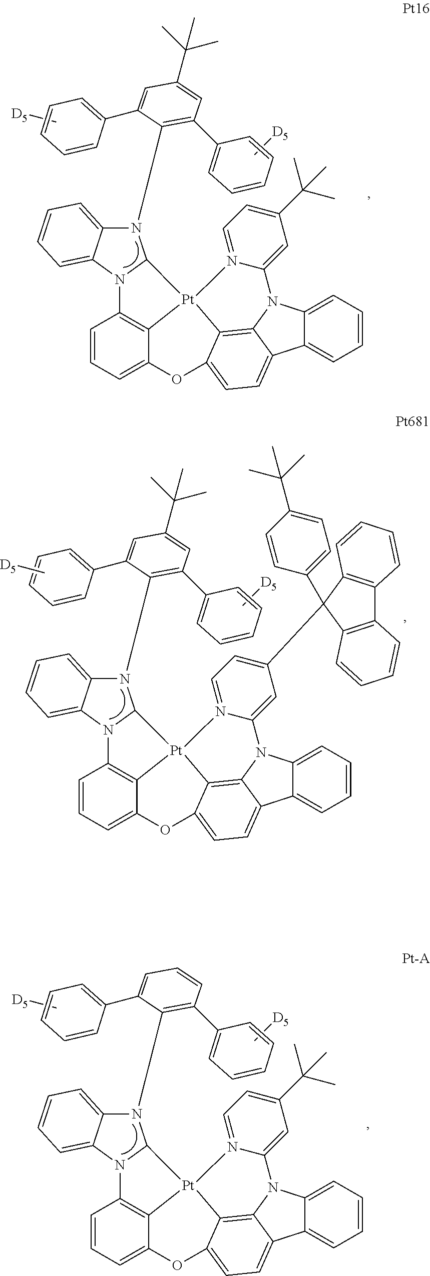

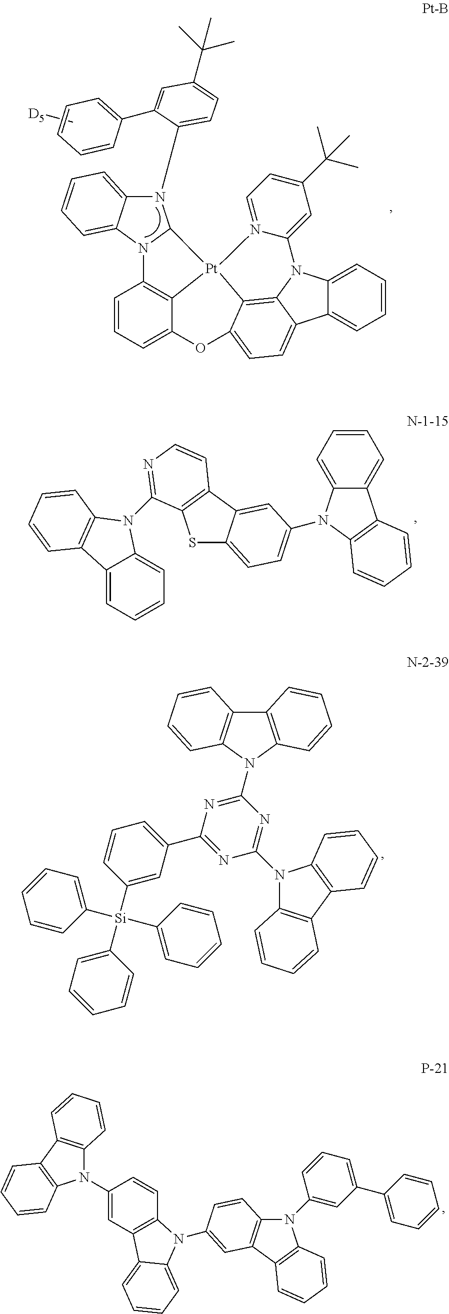

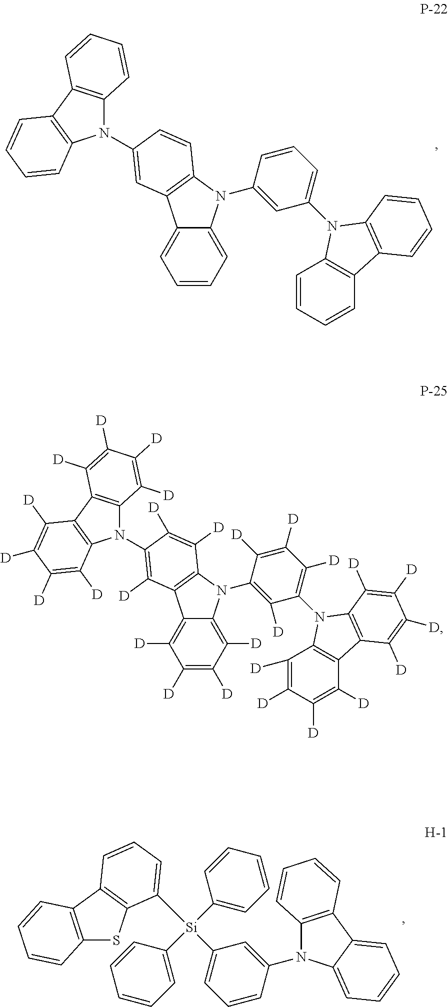

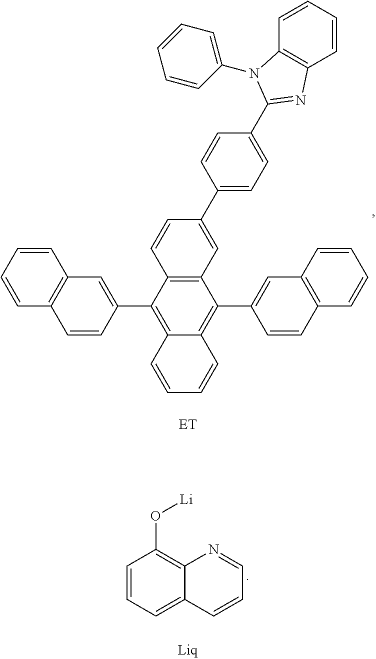

The CIE values, maximum emission wavelengths (λₘₐₓ), current efficiency CE (cd/A), voltages (V), external quantum efficiency (EQE) and device lifetimes (LT95) of Examples 1 to 3, Example 5 and Comparative Examples 1 to 5 were measured at 1000 cd/m². The related data are shown in Table 3.

TABLE 3
Device data

| | | λₘₐₓ | CE | Voltage | EQE | LT95 |
|---|---|---|---|---|---|---|
| Device No. | CIE (x, y) | [nm] | [cd/A] | [V] | (%) | (h) |
| Example 1 | 0.131, 0.151 | 462 | 19.69 | 3.55 | 16.82 | 13.04 |
| Example 2 | 0.131, 0.152 | 462 | 21.32 | 3.73 | 18.03 | 25.46 |
| Example 3 | 0.132, 0.152 | 461 | 21.65 | 3.79 | 18.29 | 28.23 |
| Example 5 | 0.127, 0.181 | 467 | 30.55 | 3.65 | 23.49 | 20.49 |
| Comparative | 0.131, 0.160 | 463 | 18.49 | 3.55 | 15.09 | 12.73 |
| Example 1 | | | | | | |
| Comparative | 0.139, 0.160 | 461 | 16.25 | 3.67 | 13.07 | 10.07 |
| Example 2 | | | | | | |
| Comparative | 0.131, 0.143 | 462 | 8.37 | 4.26 | 7.39 | 3.41 |
| Example 3 | | | | | | |
| Comparative | 0.132, 0.167 | 462 | 15.68 | 3.34 | 12.42 | 4.88 |
| Example 4 | | | | | | |
| Comparative | 0.133, 0.141 | 460 | 10.54 | 5.95 | 9.33 | 3.82 |
| Example 5 | | | | | | |

As can be seen from the data in Table 3, the examples of the present disclosure all have more excellent overall device performance. Example 1 uses a particular combination of the first compound Pt16 having a structure of Formula 1 having a particular substitution of a structure of Formula 2 on an imidazolecarbene ring of the present disclosure and the first host material and the second host material of the present disclosure. Compared with Comparative Example 1 using a combination of Compound Pt-A not having the particular multi-substituted structure of the present disclosure, the first host material and the second host material, the voltage of Example 1 is the same as that of Comparative Example 1 and at a low voltage level, and the current efficiency CE and the lifetime are both improved. More importantly, the EQE is further improved by 11.5% based on a very high efficiency level of Comparative Example 1, and the efficiency of Example 1 can reach 16.82%, which is very rare in a device emitting blue light. Similarly, compared with Comparative Example 2 using a combination of another compound Pt-B not having the particular multi-substituted structure and the first host material and the second host material of the present disclosure, the voltage of Example 1 is reduced, the CE is significantly improved by 21.2%, the EQE is significantly improved by 28.7%, and the device lifetime is also significantly prolonged by 29.5%. These data comparisons indicate advantages of the particular combination of the first compound having the structure of Formula 1 having the particular substitution of the structure of Formula 2 on the imidazolecarbene ring, the first host material and the second host material of the present disclosure.

Example 1 uses the particular combination of the first compound of the present disclosure as a light-emitting material and the first host material and the second host material as dual hosts. Compared with Comparative Example 3 using the first compound of the present disclosure as a light-emitting material and using the second host material of the present disclosure alone as a single host, the voltage of Example 1 is reduced by 0.71 V, the CE is significantly improved by 135.2%, the EQE is significantly improved by 127.6%, and the device lifetime is significantly improved by 282.4%. Compared with Comparative Example 4 using the first compound of the present disclosure as a light-emitting material and using the first host material of the present disclosure alone as a single host, the voltage of Example 1 is slightly higher than that of Comparative Example 4 but is still at a low voltage level, the CE is significantly improved by 25.5%, the EQE is significantly improved by nearly 35.4%, and the device lifetime is significantly prolonged by 167.2%. The above data prove advantages of the particular combination of the first compound of the present disclosure and the first host material and the second host material of the present disclosure over the use of one host material alone. Compared with Comparative Example 5 using the first compound of the present disclosure as a light-emitting material and using the host material H-1 having a high triplet energy level in the related art alone as a single host, the voltage of Example 1 is significantly reduced by 2.4 V, the CE is significantly improved by 86.8%, the EQE is significantly improved by 80.3%, and the device lifetime is significantly prolonged by 241.4%, proving advantages of the particular combination of the first compound, the first host material and the second host material of the present disclosure over the single host material used in the related art.

In Examples 2 and 3, the second host materials Compound P-22 and Compound P-25 having different structures selected in the present disclosure are separately combined with the first compound Pt16 selected in the present disclosure and the first host material N-1-15 selected in the present disclosure. Compared with Example 1, the voltages of Examples 2 and 3 are slightly improved but are also at low voltage levels, the CE and the EQE are both further improved on the basis of very high levels of Example 1, and the lifetimes are also significantly improved. It is worth mentioning that the EQE of Example 3 is up to 18.29% and the lifetime is prolonged to 28.23 h, which is of great help to improve a level of the device emitting blue light. These data indicate that the particular combinations of the second host materials having the different structures of the present disclosure and the first compound and the first host material of the present disclosure can both obtain excellent overall device performance, further proving the superiority of the particular combinations of the first compound, the first host material and the second host materials of the present disclosure.

Example 5 uses a particular combination of the first compound Pt681 having the structure of Formula 1 having the particular substitution of the structure of Formula 2 on an imidazolecarbene ring of the present disclosure and the first host material and the second host material of the present disclosure. Compared with Comparative Example 1 using the combination of Compound Pt-A not having the particular multi-substituted structure of the present disclosure, the first host material and the second host material, the voltage of Example 5 is slightly higher than that of Comparative Example 1 but still at a low voltage level. Importantly, the CE is significantly improved by 65.2%, the EQE is significantly improved by 55.7%, and the device lifetime is significantly prolonged by 60.9%. These data further prove advantages of the particular combination of the first compound having the structure of Formula 1 having the particular substitution of the structure of Formula 2 on the imidazolecarbene ring, the first host material and the second host material of the present disclosure.

The CIE values, maximum emission wavelengths (λₘₐₓ), current efficiency CE (cd/A), voltages (V), external quantum efficiency (EQE) and device lifetimes (LT95) of Examples 6 and 7 were measured at 1000 cd/m². The related data are shown in Table 6.

TABLE 6
Device data

| Device | | λₘₐₓ | CE | Voltage | EQE | LT95 |
|---|---|---|---|---|---|---|
| No. | CIE (x, y) | [nm] | [cd/A] | [V] | (%) | (h) |
| Example 6 | 0.138, 0.166 | 462 | 25.84 | 3.51 | 20.19 | 60.15 |
| Example 7 | 0.135, 0.149 | 461 | 25.36 | 3.77 | 21.60 | 73.43 |

In Comparative Example 1, the first host material Compound N-1-15 of the present disclosure and the second host material Compound P-21 of the present disclosure are combined with the first compound Pt-A instead of the first compound of the present disclosure. As can be seen from the above Table 3, the device data of Comparative Example 1 is the most excellent among those of the comparative examples. In Examples 6 and 7, the first host material Compound N-2-39 having a different structure of the present disclosure is combined with the first compound Pt16 of the present disclosure and the second host material Compound P-21 or Compound P-22 of the present disclosure. Compared with Comparative Example 1, the voltage of Example 6 is substantially equivalent to that of Comparative Example 1, and the voltage of Example 7 is slightly higher than that of Comparative Example 1 but still at a low voltage level. Importantly, the CE and EQE of Examples 6 and 7 are further significantly improved on the basis of those of Comparative Example 1, the CE is improved by 39.7% and 37.2%, respectively, the EQE is improved by 33.4% and 43.1%, respectively, and the device lifetimes are multifoldly improved, which are improved by 3.72 times and 4.77 times, respectively. It is worth mentioning that the CE, EQE and device lifetimes of Examples 6 and 7 all reach very high levels, which is very rare in blue phosphorescent devices and significantly improves device performance. These data indicate that the particular combinations of the first host material having the different structure of the present disclosure and the first compound and the second host materials of the present disclosure can both obtain excellent overall device performance, further proving the superiority of the particular combinations of the first compound, the first host material and the second host materials of the present disclosure.

### Device Example 4

The preparation method in Device Example 4 was the same as that in Device Example 1, except that Compound Pt16 was replaced with Compound Pt39 in the emissive layer (EML).

Detailed structures and thicknesses of layers of the device are shown in the following table. A layer using more than one material is obtained by doping different compounds at their weight ratio as recorded.

TABLE 4
Part of device structures in Device Example 4

| Device | | | | | | |
|---|---|---|---|---|---|---|
| ID | HIL | HTL | EBL | EML | HBL | ETL |
| Example | Compound | Compound | Compound | Compound P- | Compound | Compound |
| 4 | HT:Compound | HT | P-21 | 21: Compound N-1- | N-1-15 | ET:Liq |
| | HI (97:3) | (250 Å) | (50 Å) | 15:Compound Pt39 | (50 Å) | (40:60) |
| | (100 Å) | | | (61.6:26.4:12) (350 Å) | | (310 Å) |

The new material used in the device has the following structure:

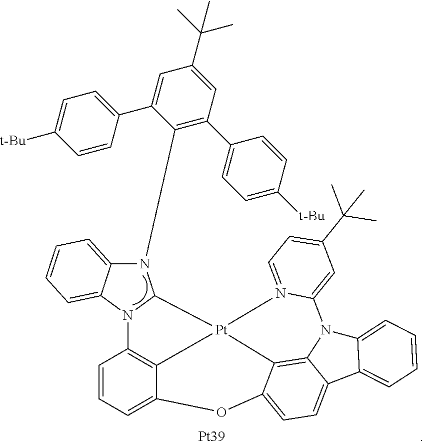

The CIE value, maximum emission wavelength (λₘₐₓ), current efficiency CE (cd/A), voltage (V) and external quantum efficiency (EQE) of Example 4 were measured at 1000 cd/m². The related data are shown in Table 5.

TABLE 5
Device data

| | | λₘₐₓ | CE | Voltage | EQE |
|---|---|---|---|---|---|
| Device No. | CIE (x, y) | [nm] | [cd/A] | [V] | (%) |
| Example 4 | 0.132, 0.141 | 461 | 18.92 | 3.52 | 16.85 |

As can be seen from the data in Table 5, Example 4 using a particular combination of another first compound Pt39 having the particular substitution of the structure of Formula 2 on an imidazolecarbene ring of the present disclosure and the first host material and the second host material of the present disclosure also exhibits excellent device performance. The voltage of Example 4 is at a low voltage level, the CE reaches 18.92, the EQE is up to 16.85% and, in particular, the CIEy is as low as 0.141, which is very advantageous in a blue phosphorescent device.

The above results indicate that using the first compound where the structure of Formula 1 having a particular multi-substituted aromatic group of Formula 2 is introduced on the imidazolecarbene ring of Formula 1 of the present disclosure as a light-emitting material in combination with the first host material having a high triplet energy level and the second host material having a high triplet energy level for a blue phosphorescent electroluminescent device can obtain the low voltage, the high efficiency (the EQE and the CE) and a long lifetime, having excellent overall device performance. These advantages are of great help to improve the level of the device emitting blue light.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
an organic layer disposed between the anode and the cathode, wherein the organic layer comprises a light-emitting layer, wherein the light-emitting layer comprises a first compound, a first host material and a second host material;
wherein a triplet energy level of the first host material and a triplet energy level of the second host material are both higher than a triplet energy level of the first compound;
wherein the first compound has a structure represented by Formula 1: 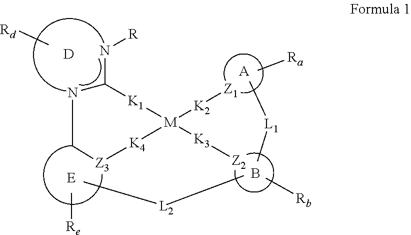
wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 3 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof, wherein y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2: 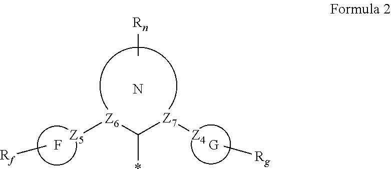
wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“★” represents a position where Formula 2 is joined; and
adjacent substituents R″, Rₐ, R_{b}, R_{d}, Rₑ, R_{f}, R_{g} and Rₙ can be optionally joined to form a ring.

2. The organic electroluminescent device according to claim 1, wherein M is selected from Cu, Ag, Au, Ru, Rh, Pd, Os, Ir or Pt; preferably, M is selected from Pt or Pd; more preferably, M is selected from Pt.

3. The organic electroluminescent device according to claim 1, wherein the ring A, the ring B, the ring E, the ring F, the ring G and the ring N are, at each occurrence identically or differently, selected from a five-membered unsaturated carbocyclic ring, an aromatic ring having 6 to 30 carbon atoms, a heteroaromatic ring having 3 to 30 carbon atoms or a combination thereof;
preferably, the ring A, the ring B, the ring E, the ring F, the ring G and the ring N are, at each occurrence identically or differently, selected from a five-membered unsaturated carbocyclic ring, an aromatic ring having 6 to 18 carbon atoms, a heteroaromatic ring having 3 to 18 carbon atoms or a combination thereof; and
more preferably, the ring A, the ring B, the ring E, the ring F, the ring G and the ring N are, at each occurrence identically or differently, selected from a benzene ring, a pyridine ring, an indene ring, a fluorene ring, an indole ring, a carbazole ring, an indolocarbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring, a silole ring or a combination thereof.

4. The organic electroluminescent device according to claim 1, wherein the ring D is, at each occurrence identically or differently, selected from an unsaturated heterocyclic ring having 3 to 18 carbon atoms; and
preferably, the ring D is, at each occurrence identically or differently, selected from an imidazolecarbene ring or a benzimidazolecarbene ring.

5. The organic electroluminescent device according to claim 1, wherein L₁ is selected from a single bond, O, S, (SiR″R″)_{y}, NR″ or a combination thereof, wherein y is 1 or 2;
preferably, L₁ is selected from a single bond, O or S; and
more preferably, L₁ is selected from a single bond.

6. The organic electroluminescent device according to claim 1, wherein K₁ to K₄ are selected from a single bond.

7. The organic electroluminescent device according to claim 1, wherein Z₁ is selected from N, and Z₂ and Z₃ are selected from C.

8. The organic electroluminescent device according to claim 1, wherein the first compound has a structure represented by one of Formula 1-1 to Formula 1-20: 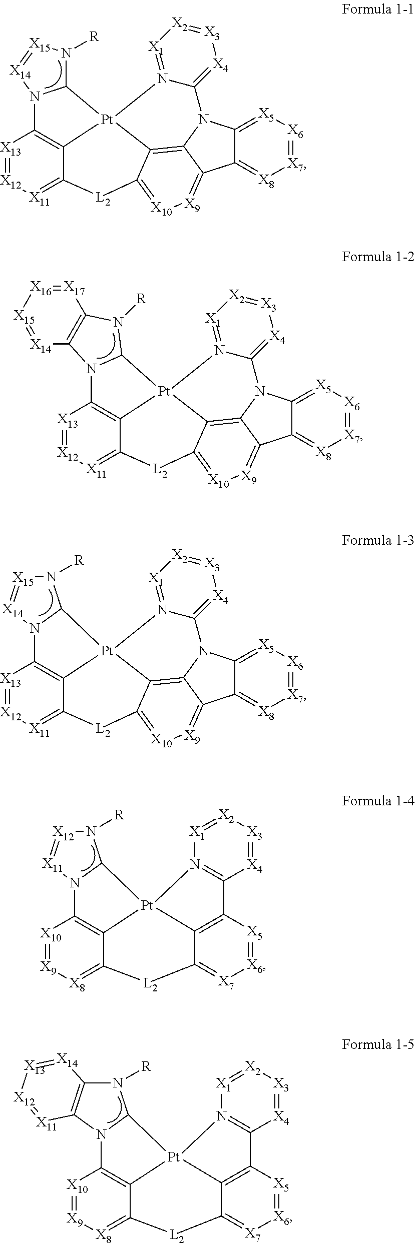 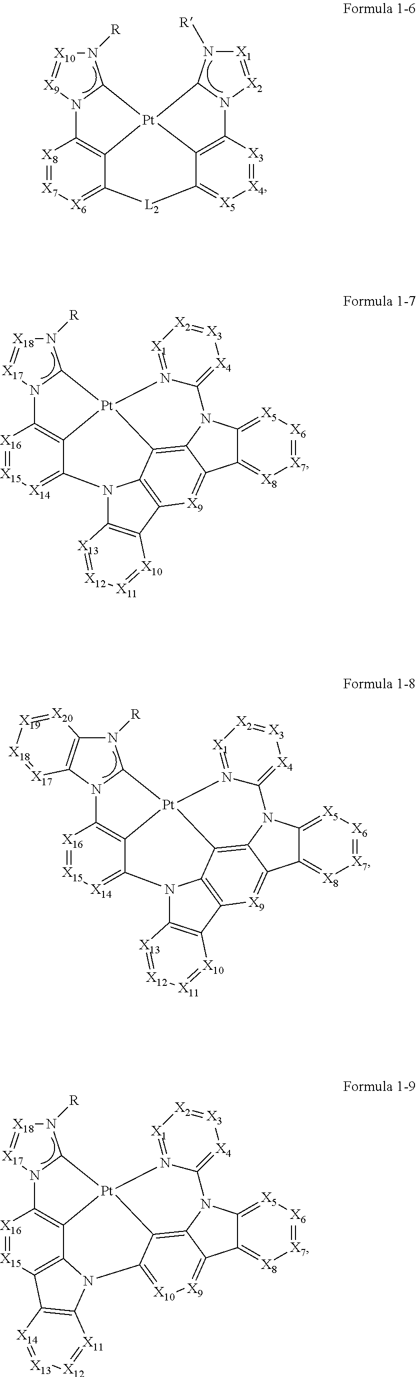 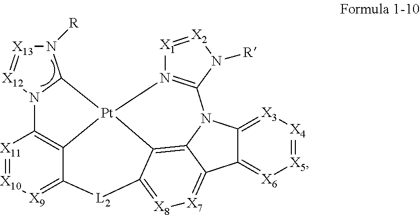 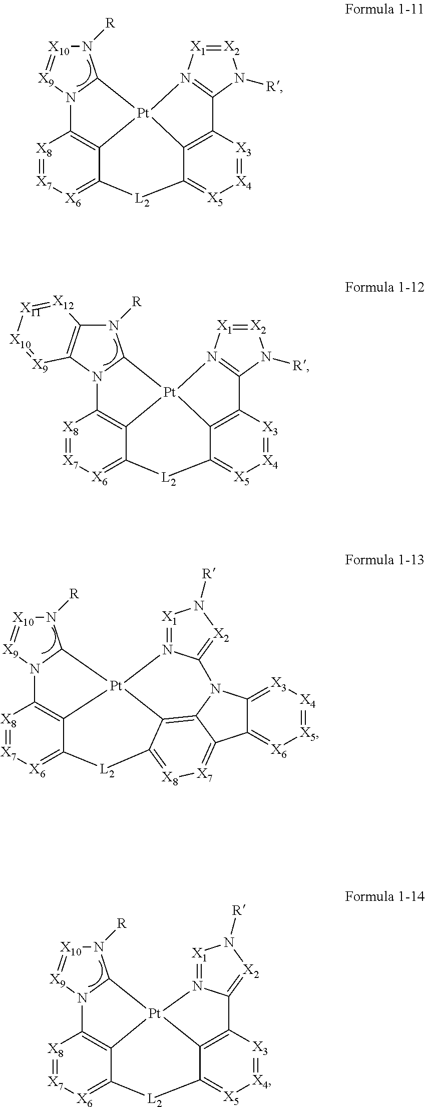 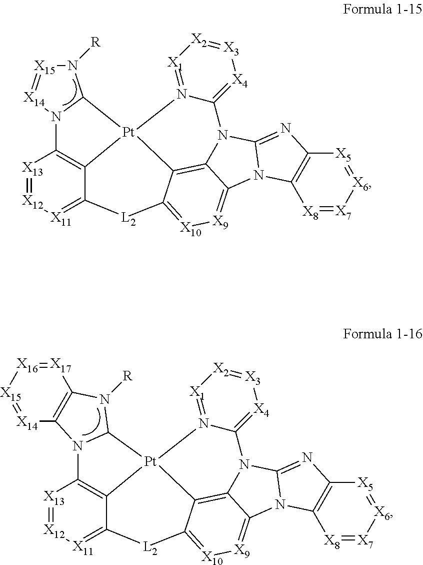 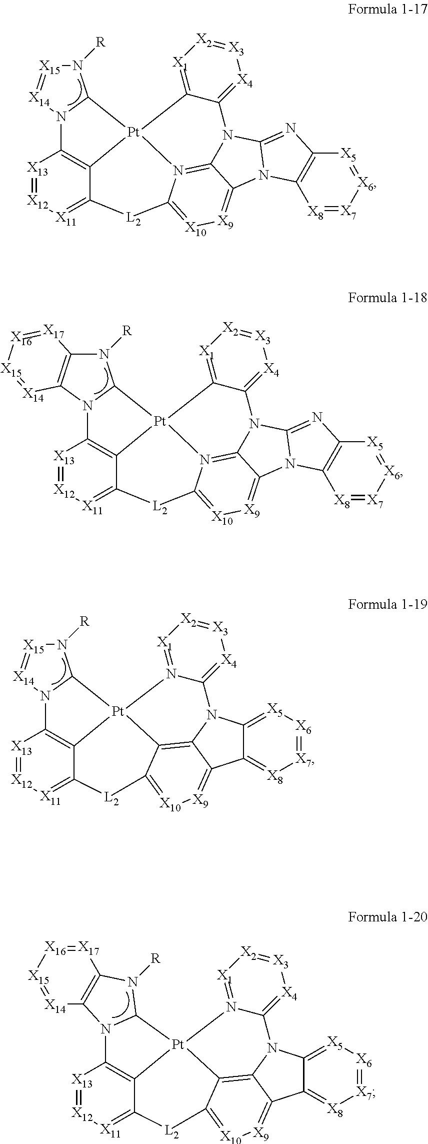
wherein in Formula 1-1 to Formula 1-20,
L₂ is, at each occurrence identically or differently, selected from a single bond, O, S, Se, (SiR″R″)_{y}, PR″, NR″, substituted or unsubstituted arylene having 6 to 30 carbon atoms or a combination thereof;
y is, at each occurrence identically or differently, selected from 1, 2, 3, 4 or 5;
X₁ to X₂₀ are, at each occurrence identically or differently, selected from CRₓ or N;
R has a structure represented by Formula 2-1: 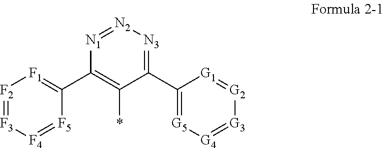
wherein in Formula 2-1, F₁ to F₅ are each independently selected from CR_{f} or N; G₁ to G₅ are each independently selected from CR_{g} or N; N₁ to N₃ are each independently selected from CRₐ or N, and at least one of N₁ to N₃ is CRₙ;
R′, R″, Rₓ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R′, R″, Rₓ, R_{f}, R_{g} and Rₙ can be optionally joined to form a ring; and
preferably, the first compound has a structure represented by Formula 1-1 or Formula 1-2.

9. The organic electroluminescent device according to claim 8, wherein N₁ or N₂ is selected from CRₙ, wherein the R, is, at each occurrence identically or differently, selected from the group consisting of: deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylsilyl having 6 to 20 carbon atoms and combinations thereof;
preferably, the Rₙ is, at each occurrence identically or differently, selected from the group consisting of: deuterium, fluorine, a cyano group, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, substituted or unsubstituted alkylgermanyl having 3 to 6 carbon atoms and combinations thereof;
more preferably, the Rₙ is, at each occurrence identically or differently, selected from unsubstituted alkyl having 1 to 6 carbon atoms, partially or fully deuterated alkyl having 1 to 6 carbon atoms, unsubstituted cycloalkyl having 3 to 6 ring carbon atoms or partially or fully deuterated cycloalkyl having 3 to 6 ring carbon atoms; and
most preferably, the Rₙ is, at each occurrence identically or differently, selected from the group consisting of: methyl, deuterated methyl, ethyl, partially or fully deuterated ethyl, n-propyl, partially or fully deuterated n-propyl, isopropyl, partially or fully deuterated isopropyl, cyclopropyl, partially or fully deuterated cyclopropyl, n-butyl, partially or fully deuterated n-butyl, isobutyl, partially or fully deuterated isobutyl, t-butyl, partially or fully deuterated t-butyl, cyclopentyl, partially or fully deuterated cyclopentyl, cyclohexyl, partially or fully deuterated cyclohexyl and combinations thereof.

10. The organic electroluminescent device according to claim 8, wherein X₁ to X₂₀ are, at each occurrence identically or differently, selected from CRₓ.

11. The organic electroluminescent device according to claim 8, wherein L₂ is selected from a single bond, O, S, (SiR″R″)_{y}, NR″ or a combination thereof, wherein R″ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
preferably, L₂ is selected from a single bond, O or S; and
more preferably, L₂ is selected from O.

12. The organic electroluminescent device according to claim 8, wherein Rₓ, R′, R_{f} and R_{g} are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof; and
preferably, Rₓ, R′, R_{f} and R_{g} are, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuranyl, dibenzofuranyl, benzosilolyl, dibenzosilolyl, benzothienyl, dibenzothienyl, dibenzoselenophenyl and combinations thereof.

13. The organic electroluminescent device according to claim 1, wherein R is, at each occurrence identically or differently, selected from the group consisting of structure An-1 to structure An-82, and structure An-92: 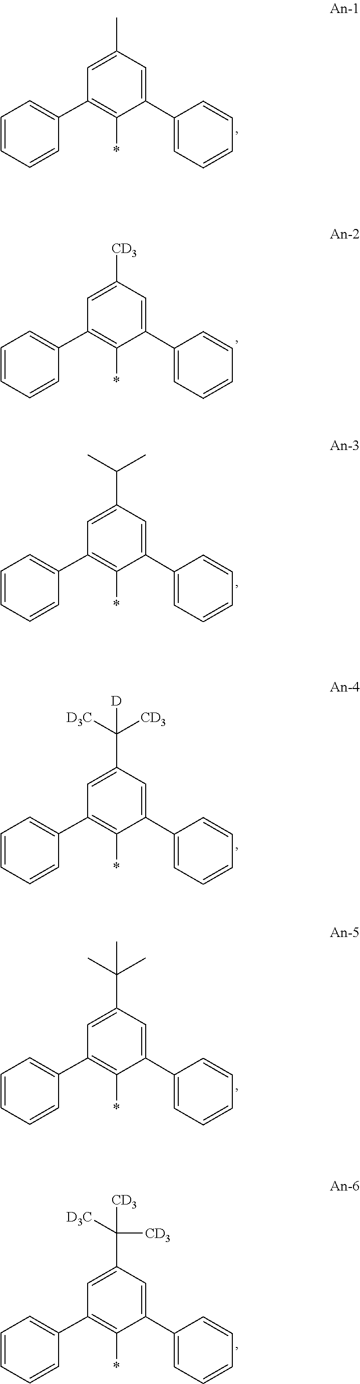 [SMILES: *c1c(-c2ccccc2)cc(C)cc1-c1ccccc1 ; *c1c(-c2ccccc2)cc(C([2H])([2H])[2H])cc1-c1ccccc1 ; *c1c(-c2ccccc2)cc(C(C)C)cc1-c1ccccc1 ; *c1c(-c2ccccc2)cc(C([2H])(C([2H])([2H])[2H])C([2H])([2H])[2H])cc1-c1ccccc1 ; *c1c(-c2ccccc2)cc(C(C)(C)C)cc1-c1ccccc1 ; *c1c(-c2ccccc2)cc(C(C([2H])([2H])[2H])(C([2H])([2H])[2H])C([2H])([2H])[2H])cc1-c1ccccc1] 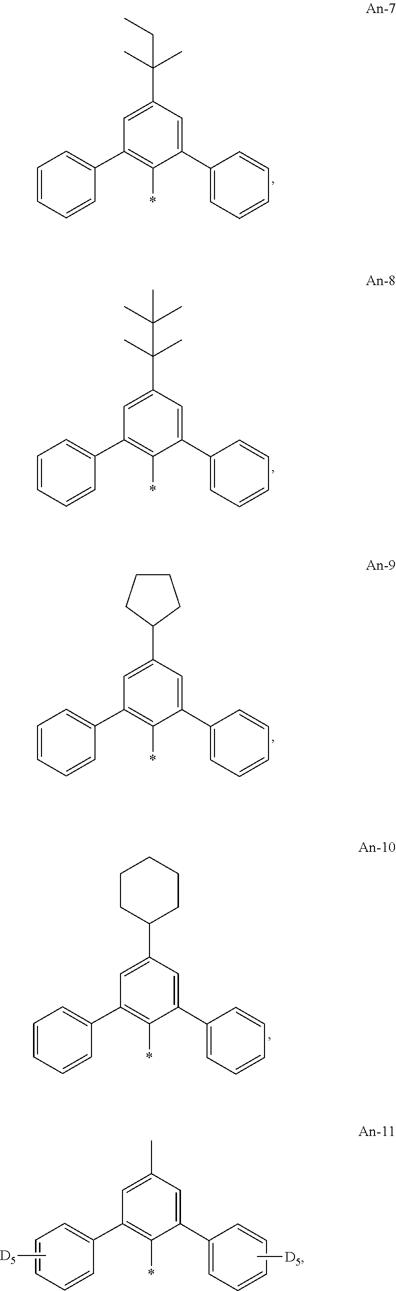 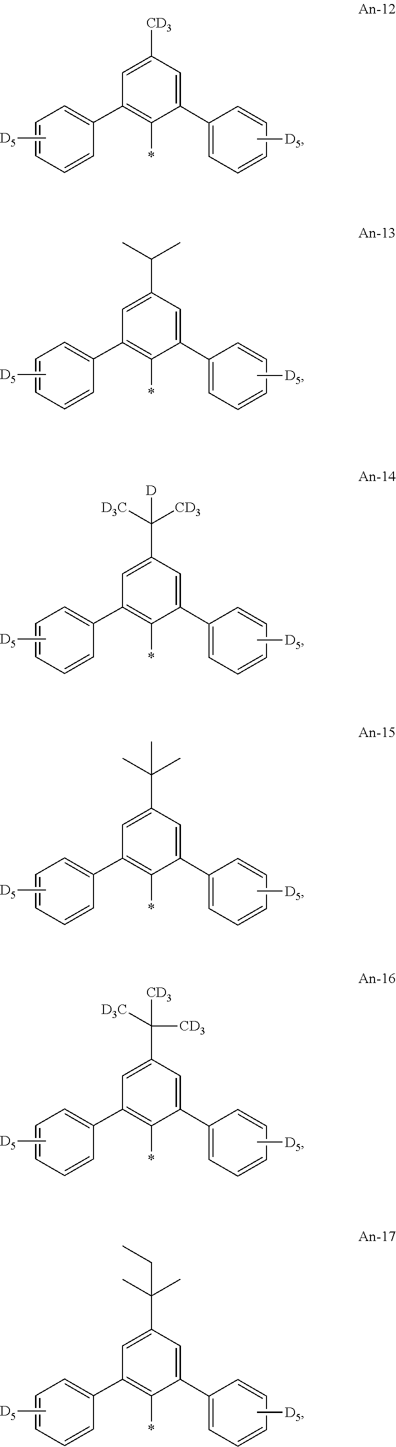 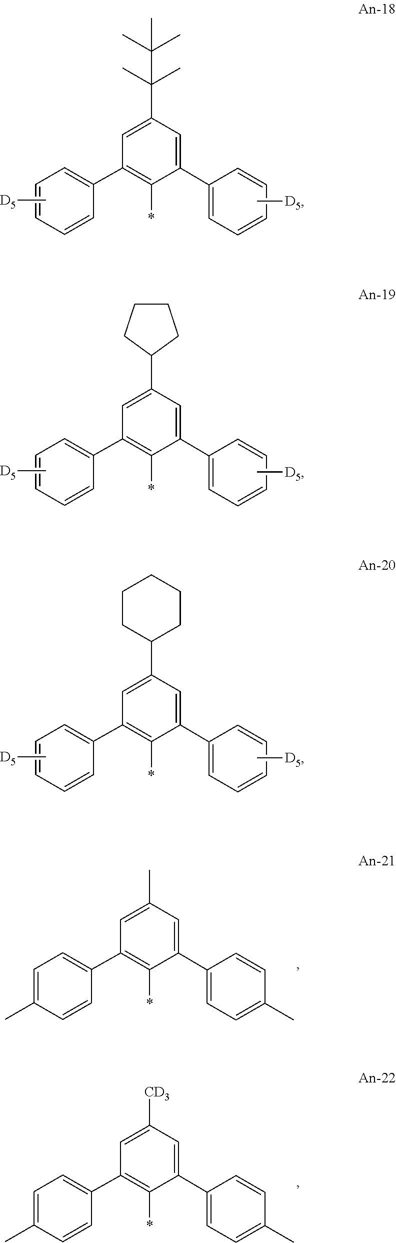 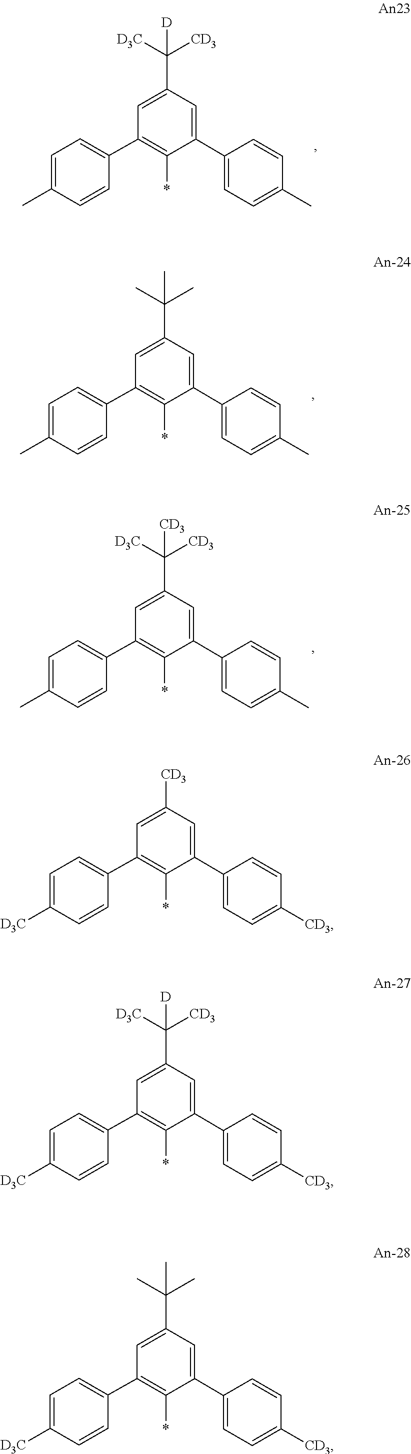 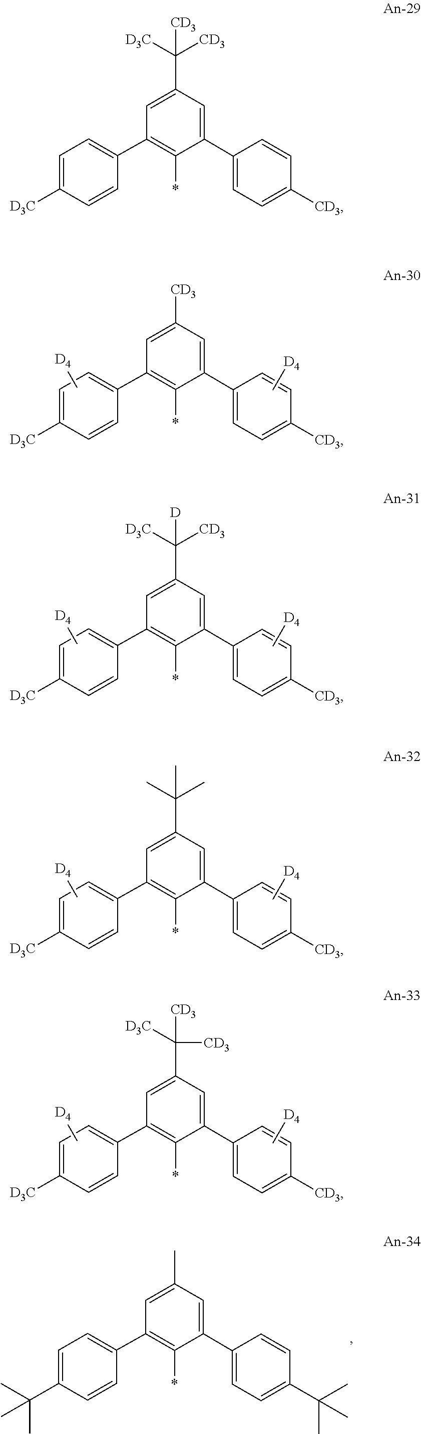 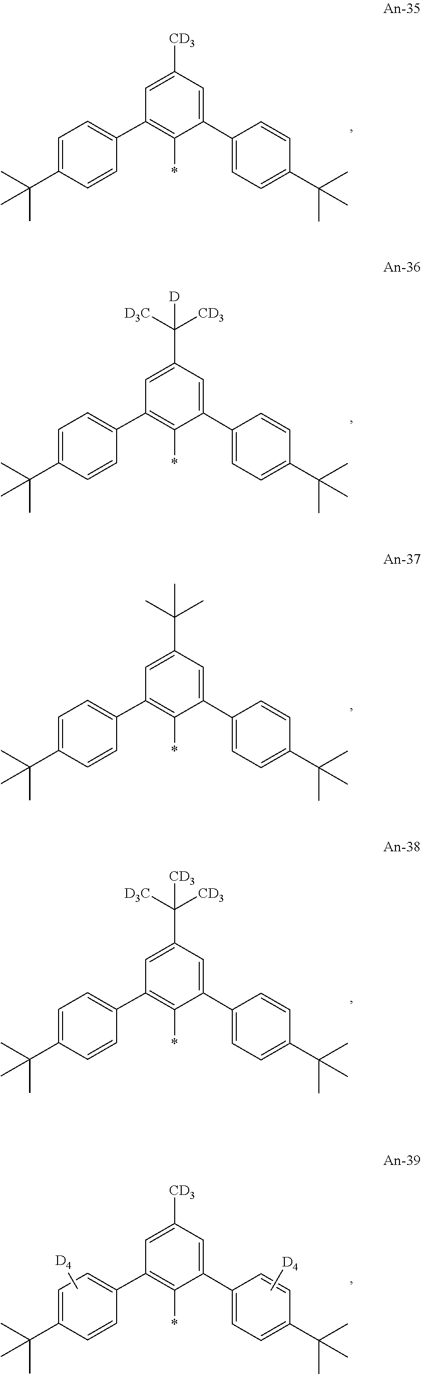 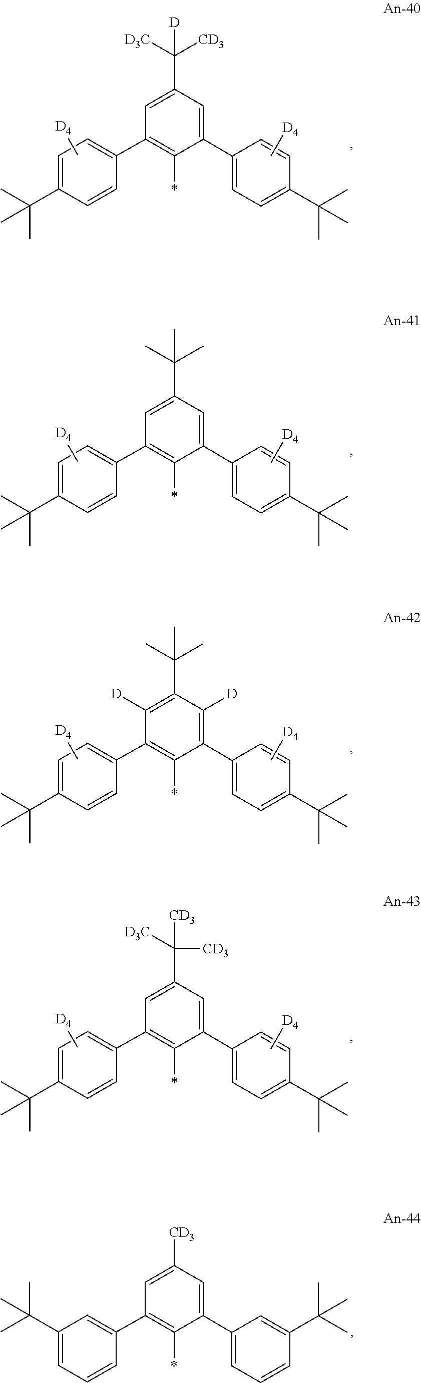 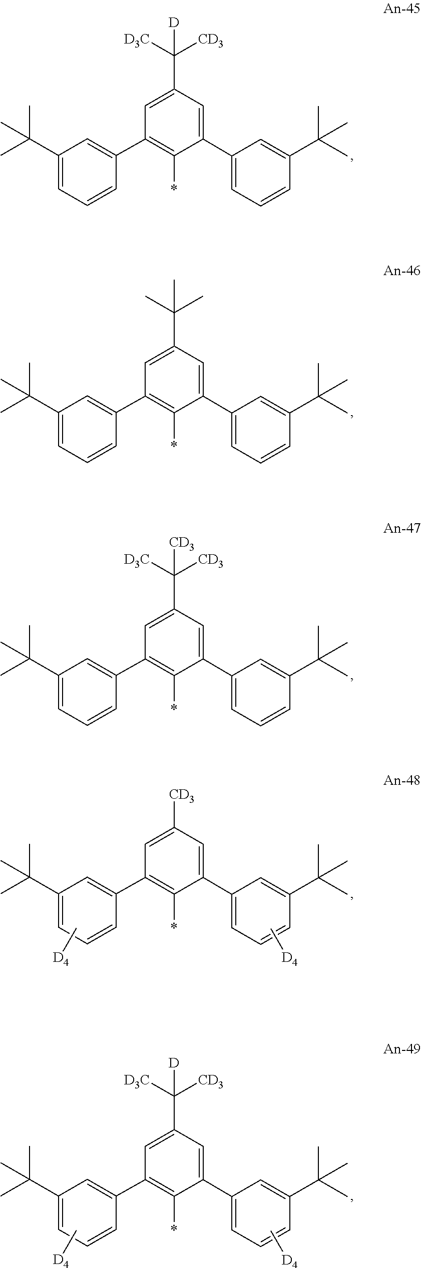 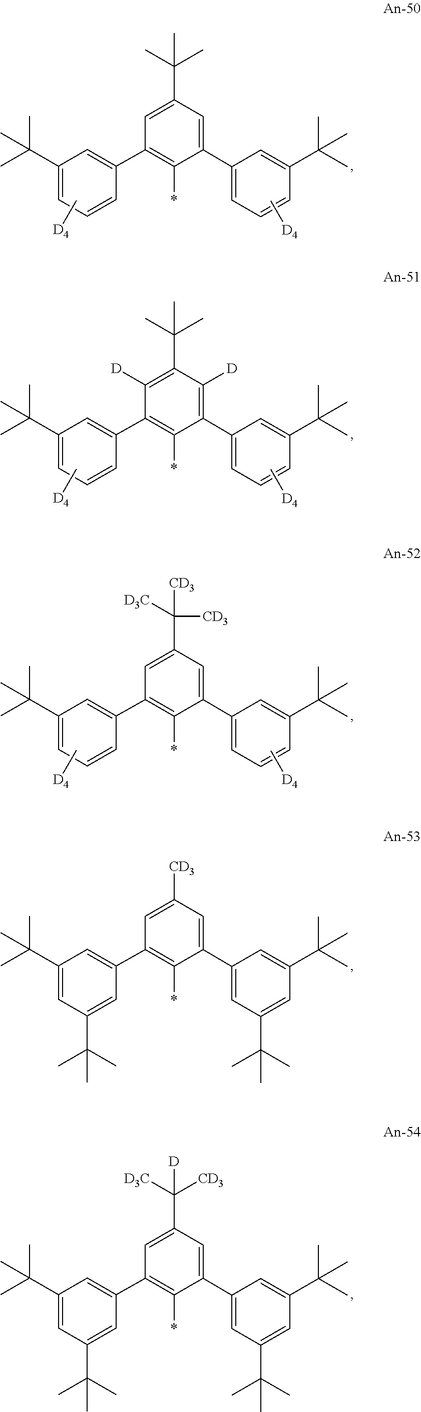 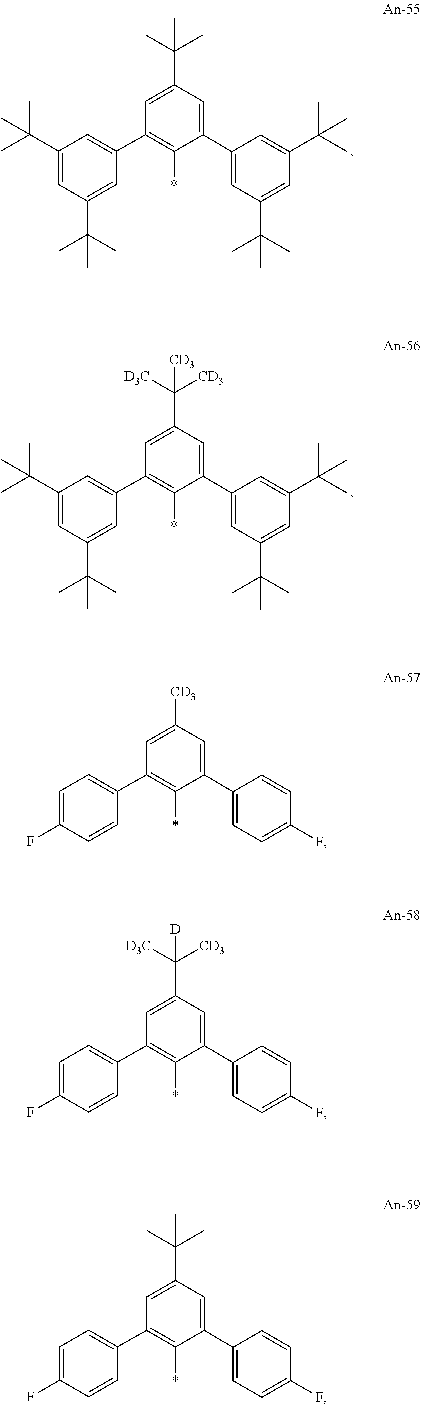 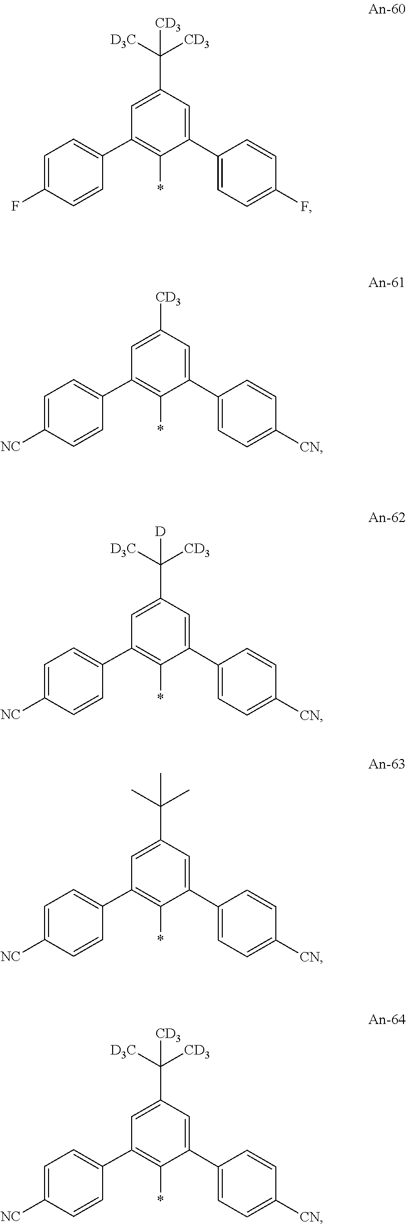 [SMILES: *c1c(-c2ccc(F)cc2)cc(C(C([2H])([2H])[2H])(C([2H])([2H])[2H])C([2H])([2H])[2H])cc1-c1ccc(F)cc1 ; *c1c(-c2ccc(C#N)cc2)cc(C([2H])([2H])[2H])cc1-c1ccc(C#N)cc1 ; *c1c(-c2ccc(C#N)cc2)cc(C([2H])(C([2H])([2H])[2H])C([2H])([2H])[2H])cc1-c1ccc(C#N)cc1 ; *c1c(-c2ccc(C#N)cc2)cc(C(C)(C)C)cc1-c1ccc(C#N)cc1 ; *c1c(-c2ccc(C#N)cc2)cc(C(C([2H])([2H])[2H])(C([2H])([2H])[2H])C([2H])([2H])[2H])cc1-c1ccc(C#N)cc1] 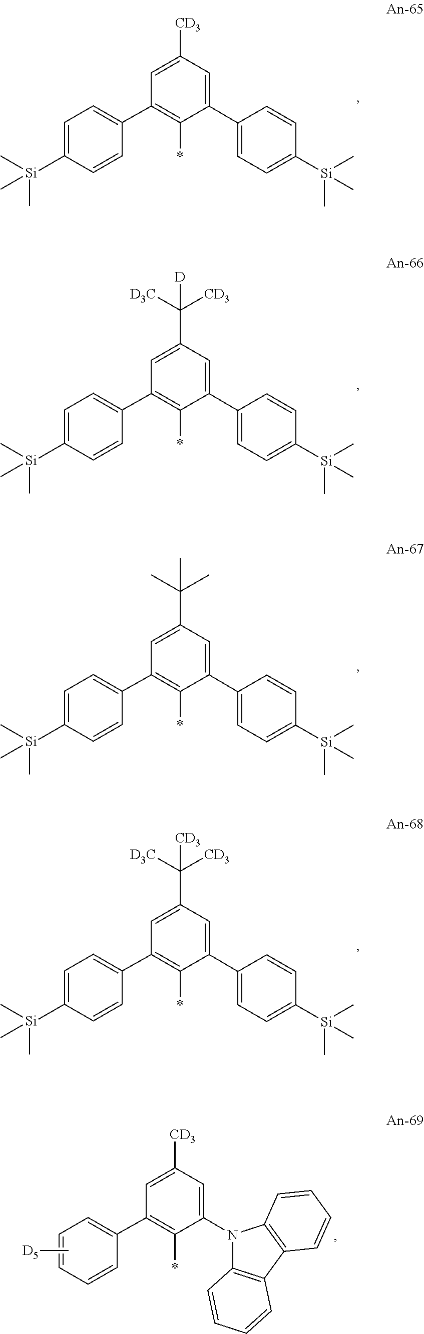 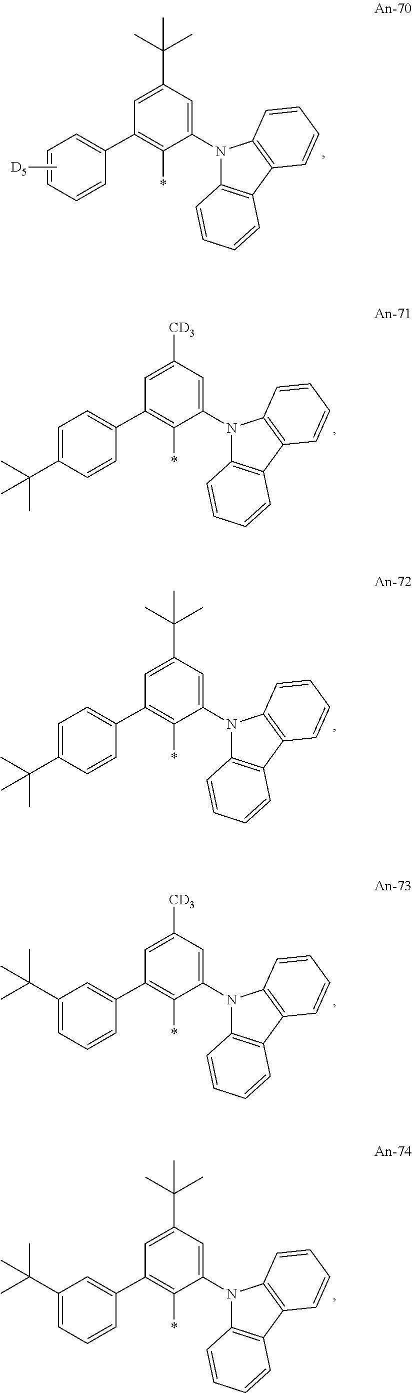 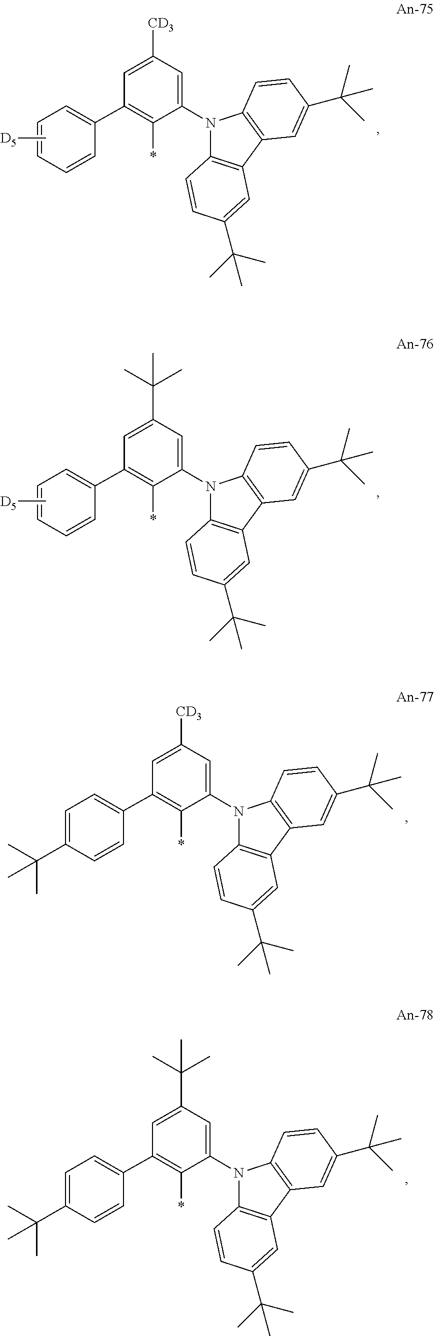 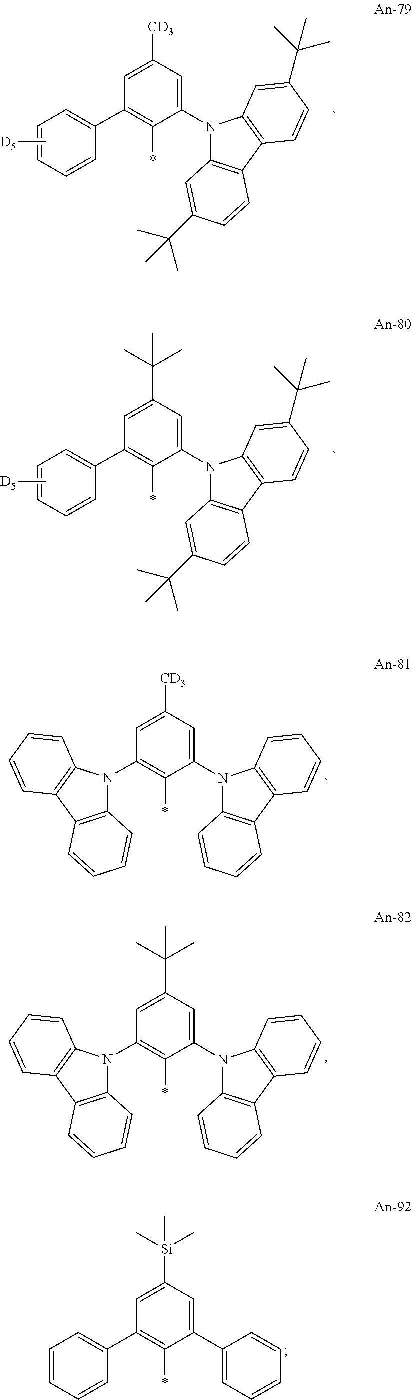
wherein optionally, hydrogens in structure An-1 to structure An-82, and structure An-92 can be partially or fully substituted with deuterium.

14. The organic electroluminescent device according to claim 1, wherein the first compound has a structure represented by Pt(Lₐ)(L_{b}) or Pd(Lₐ)(L_{b}), wherein Lₐ and L_{b} are a first ligand and a second ligand coordinated to the metal Pt or Pd, respectively, and Lₐ is selected from the group consisting of Lₐ1-1 to Lₐ1-76, Lₐ1-86 to Lₐ1-93, Lₐ2-1 to Lₐ2-42, Lₐ3-1 to Lₐ3-40, Lₐ4-1 to Lₐ4-17 and Lₐ4-19 to Lₐ4-53: 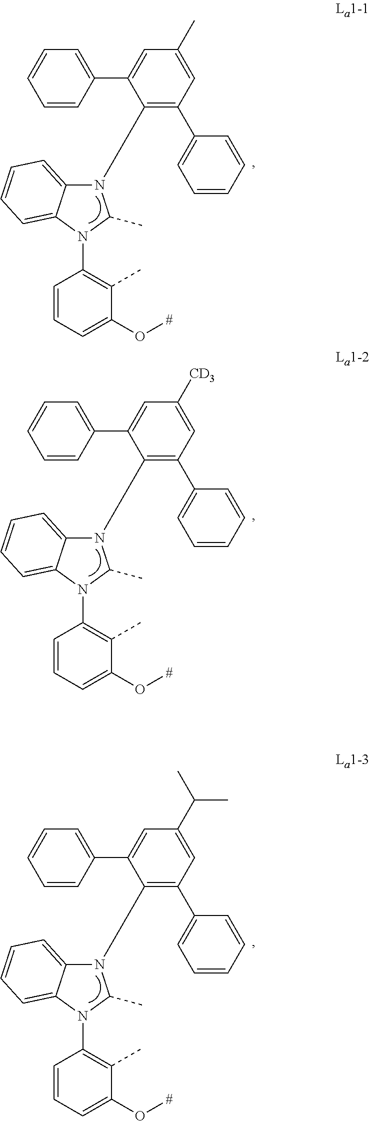 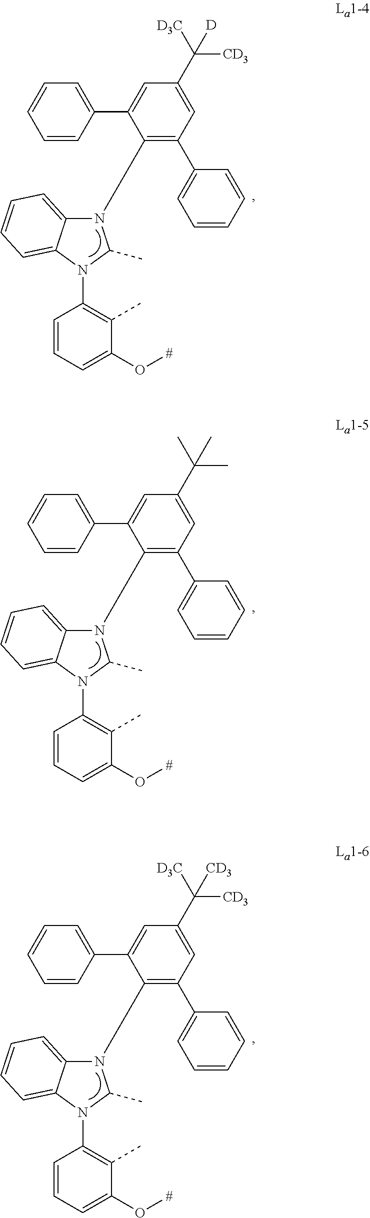 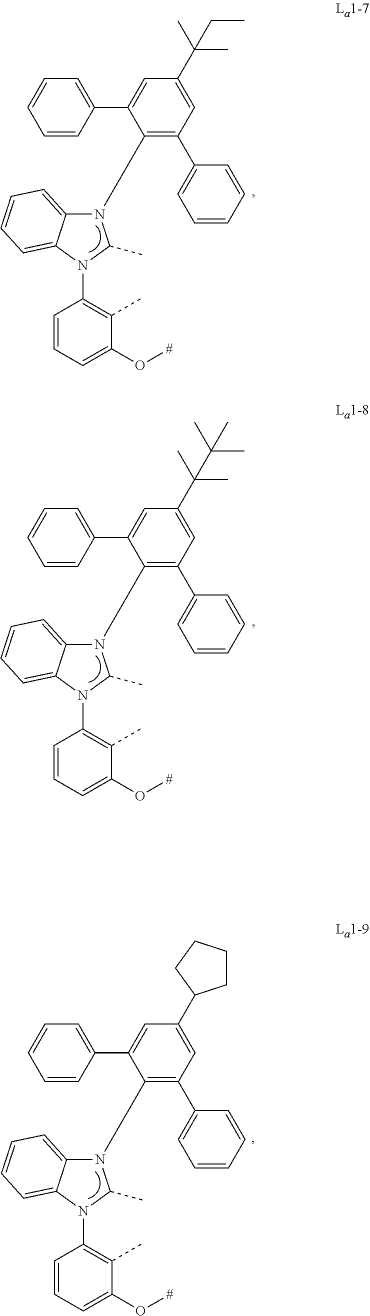 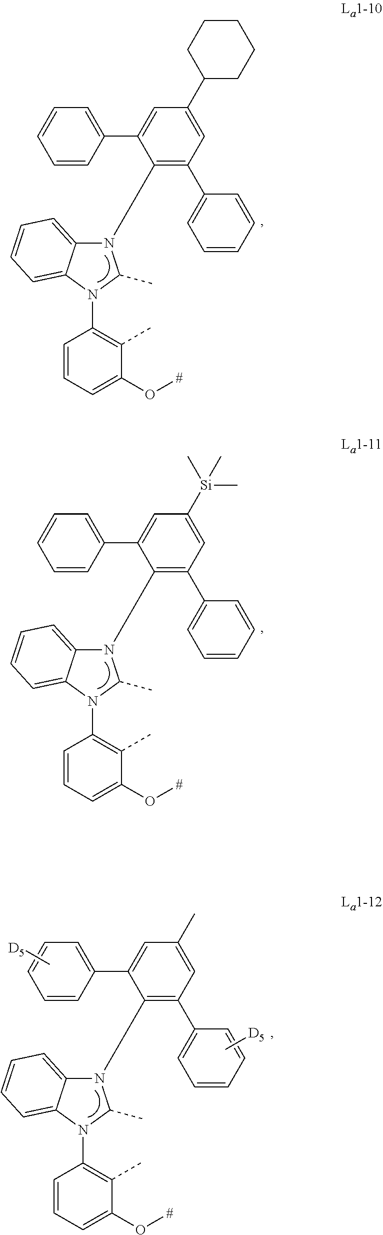 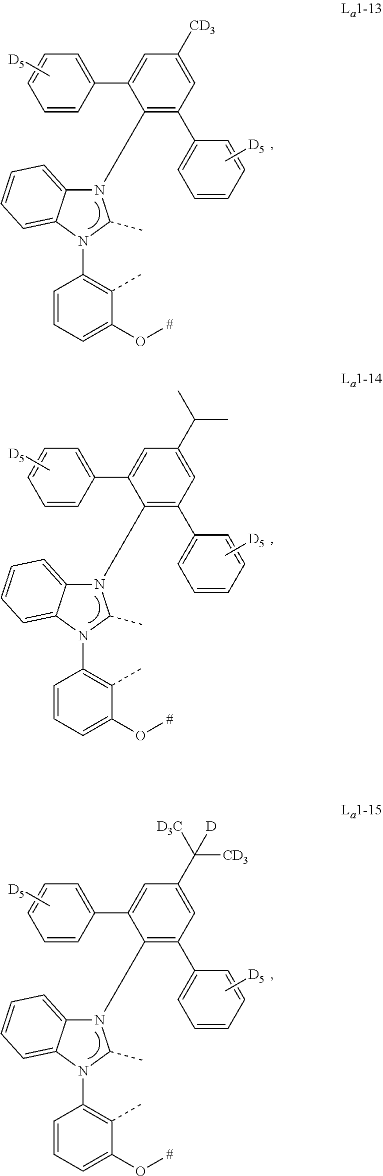 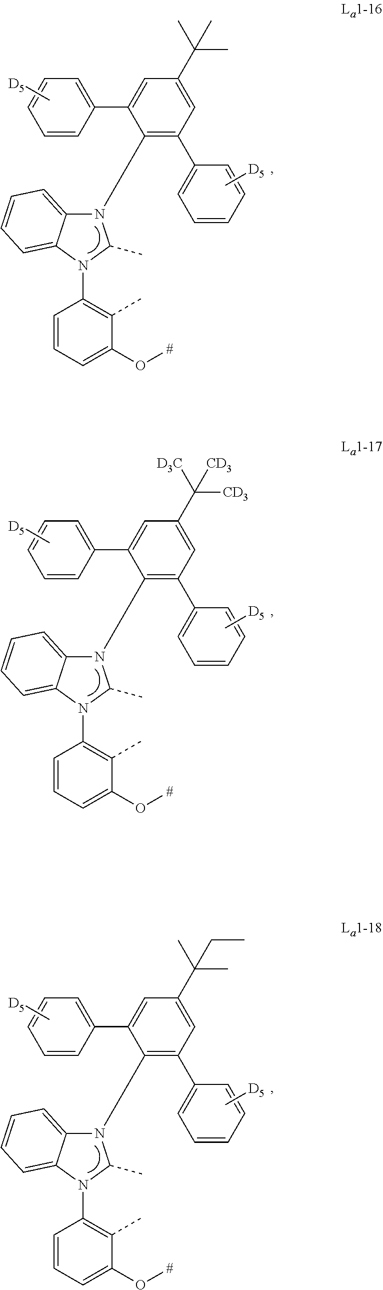 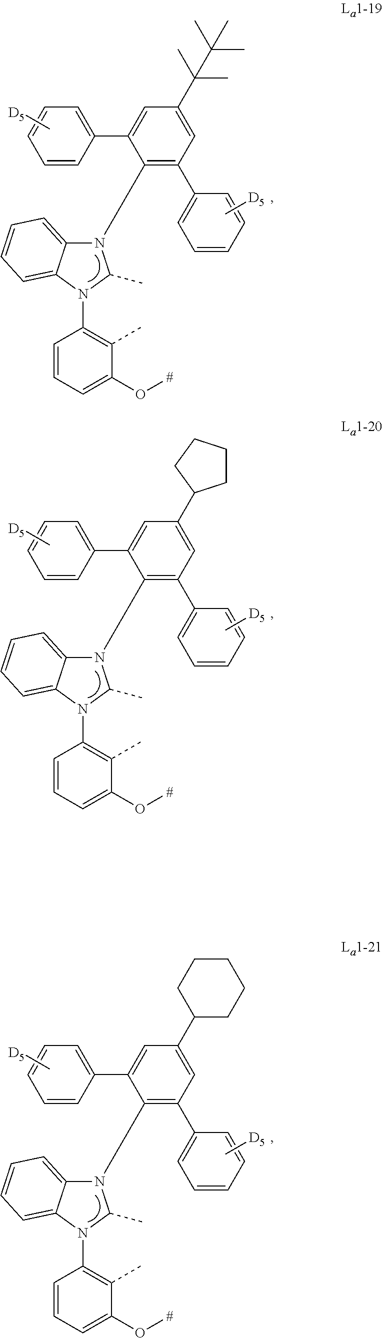 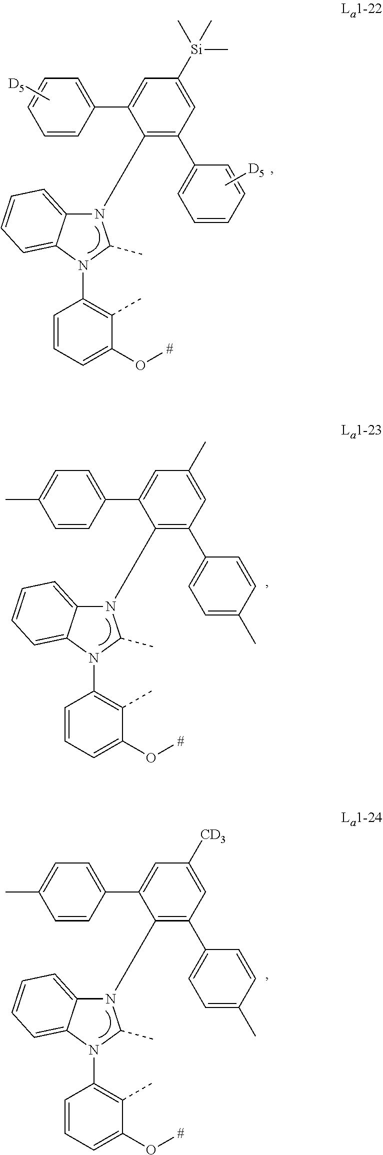 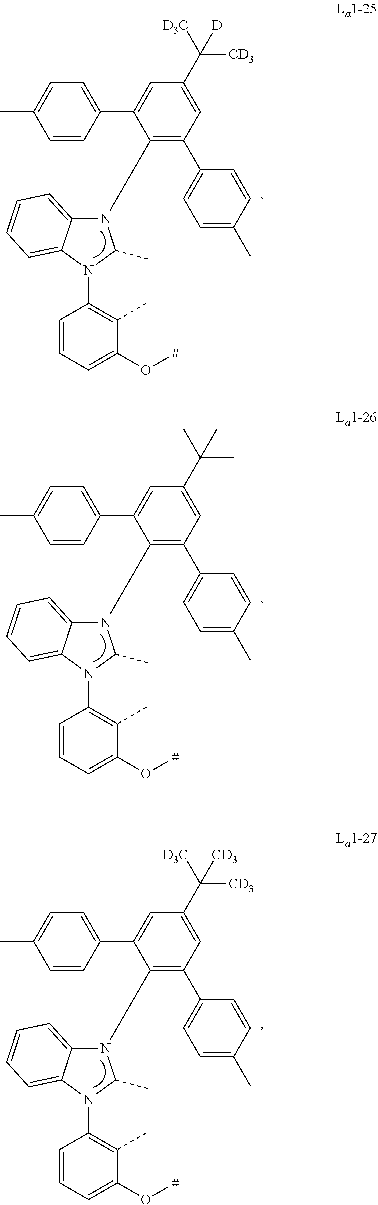 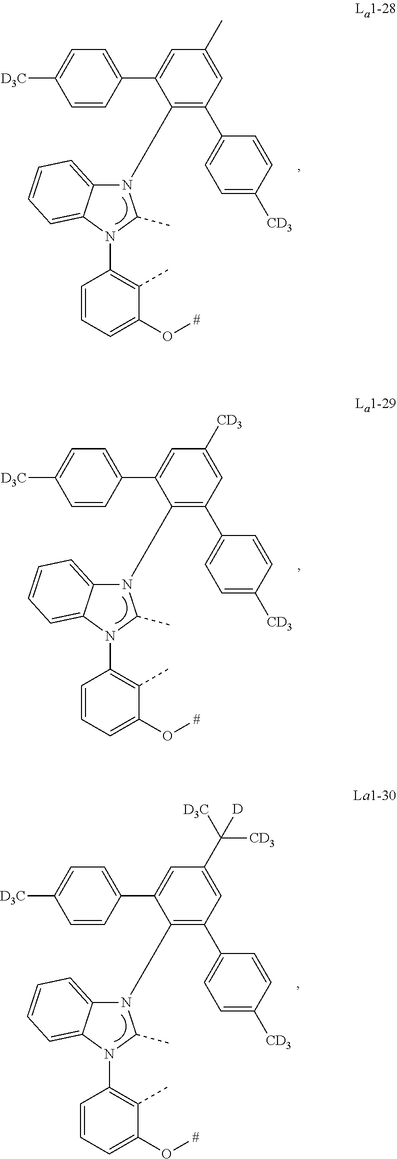 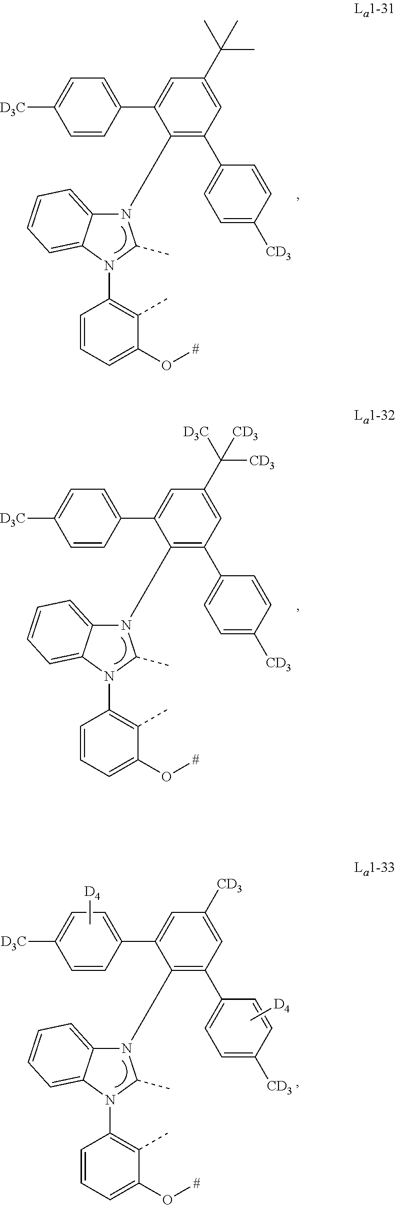 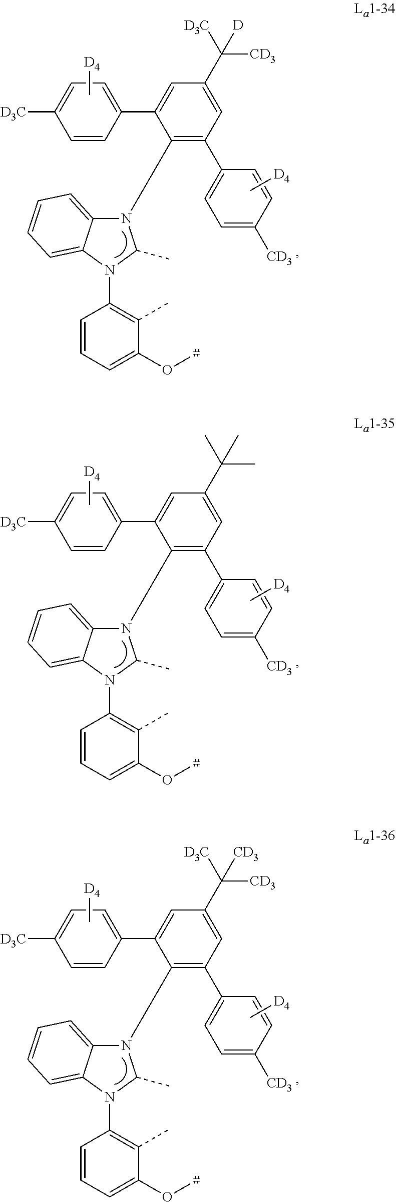 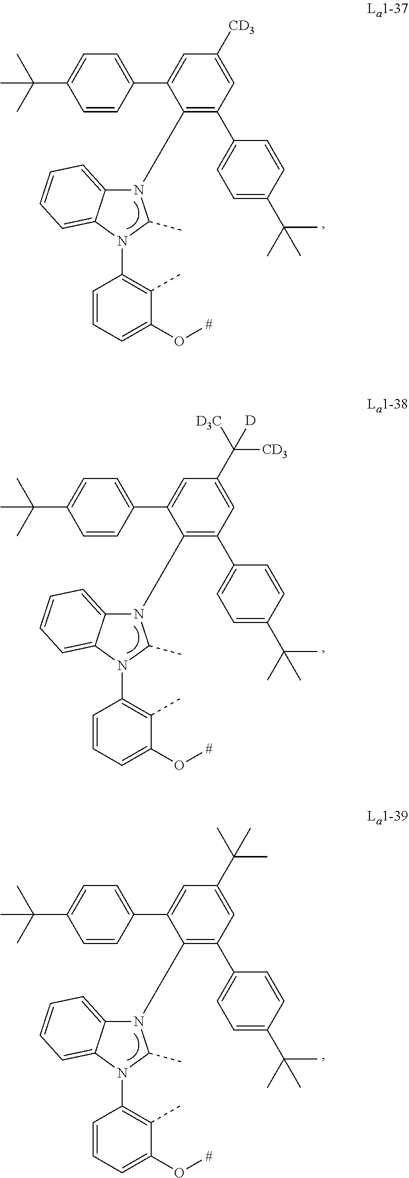 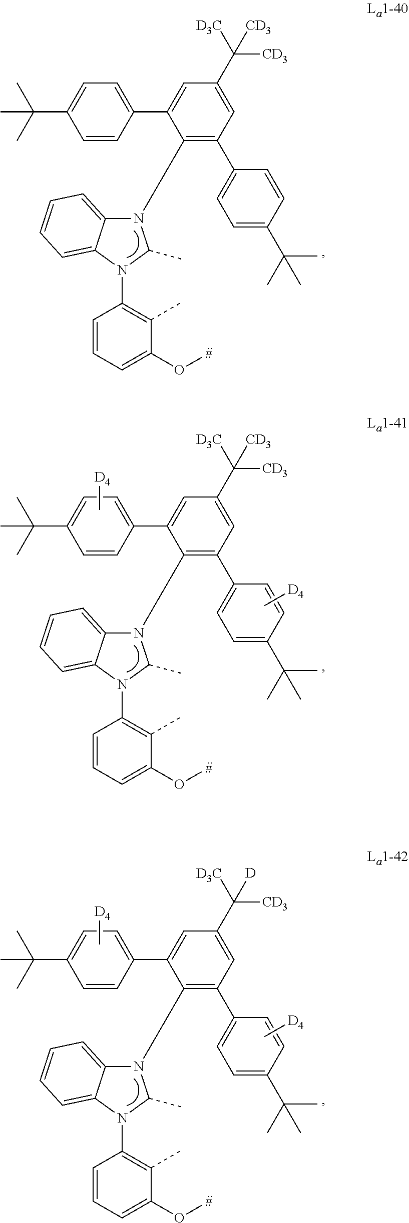 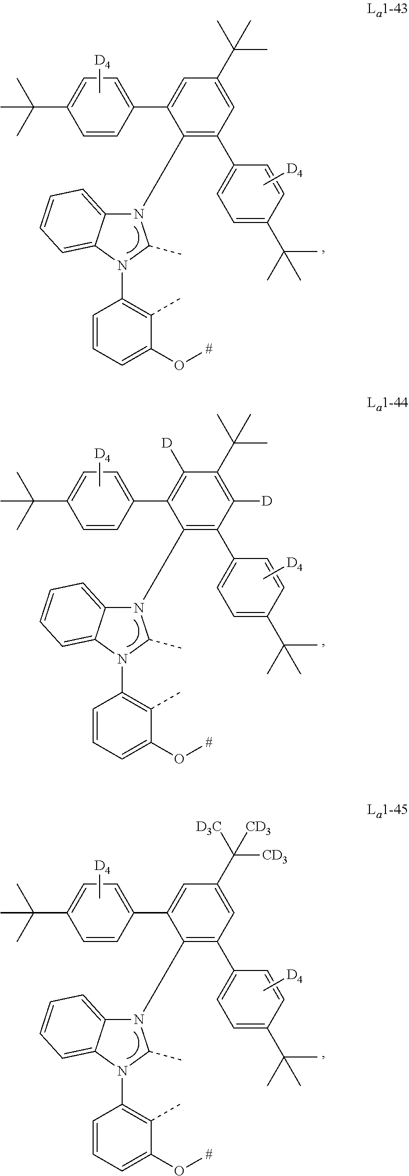 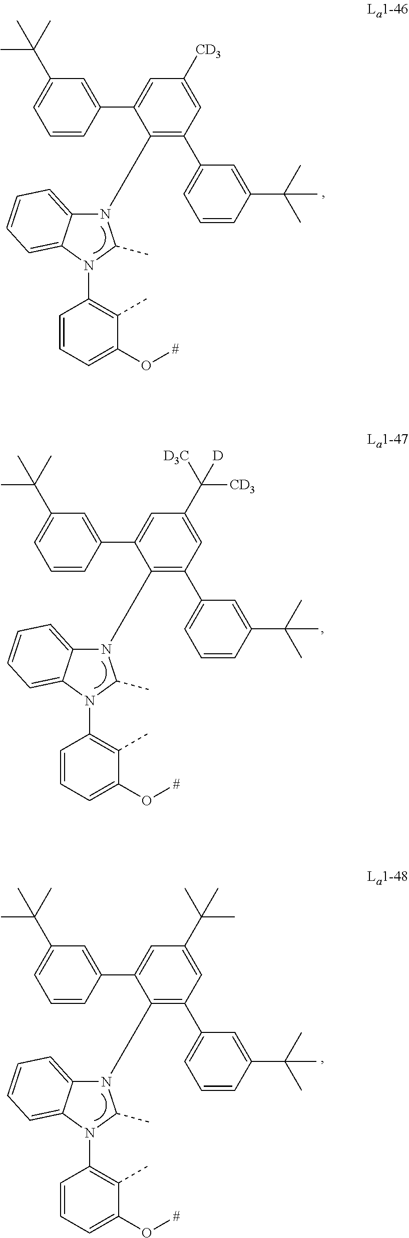 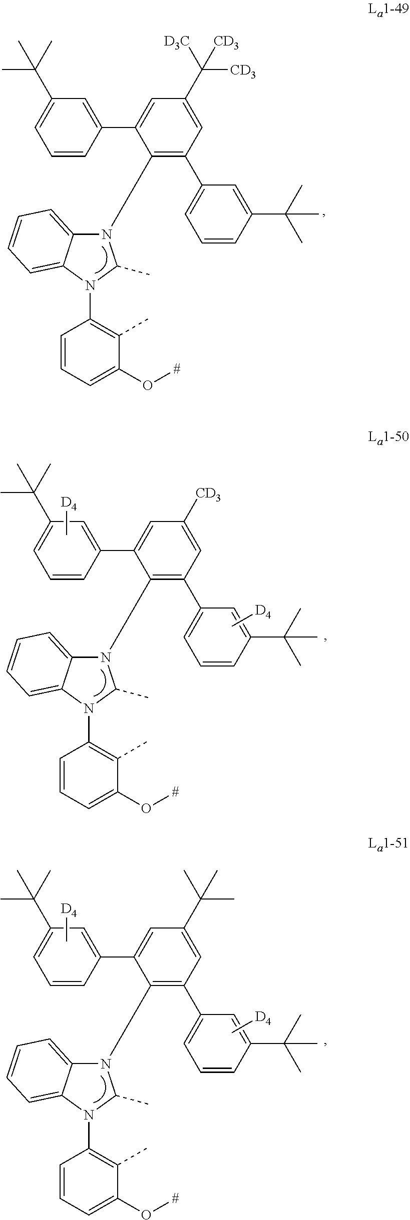 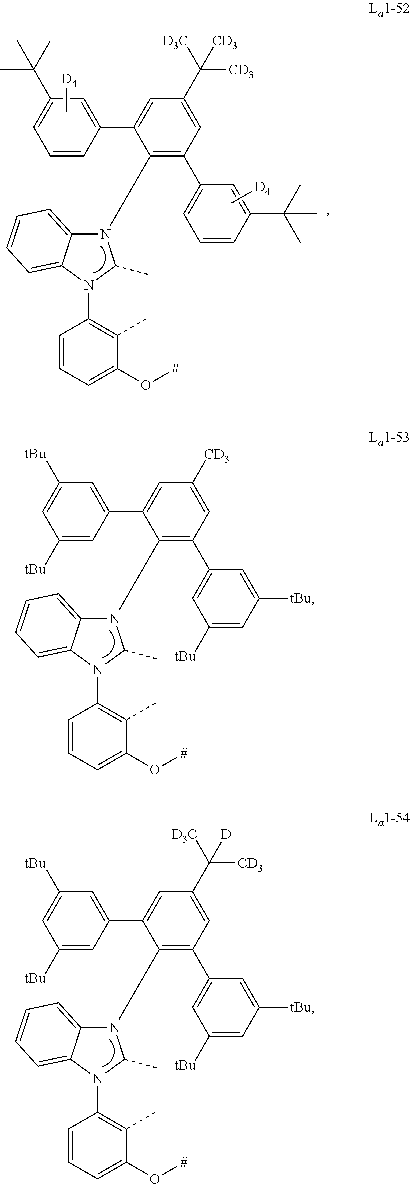 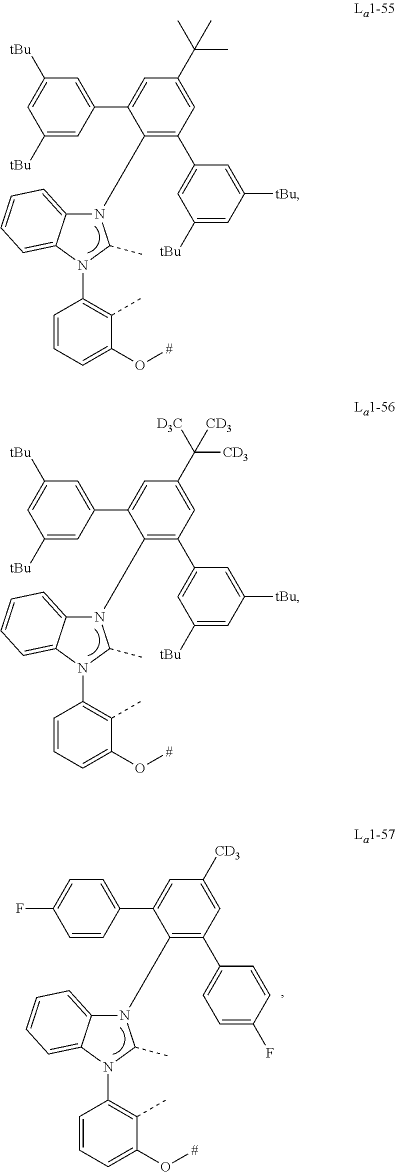 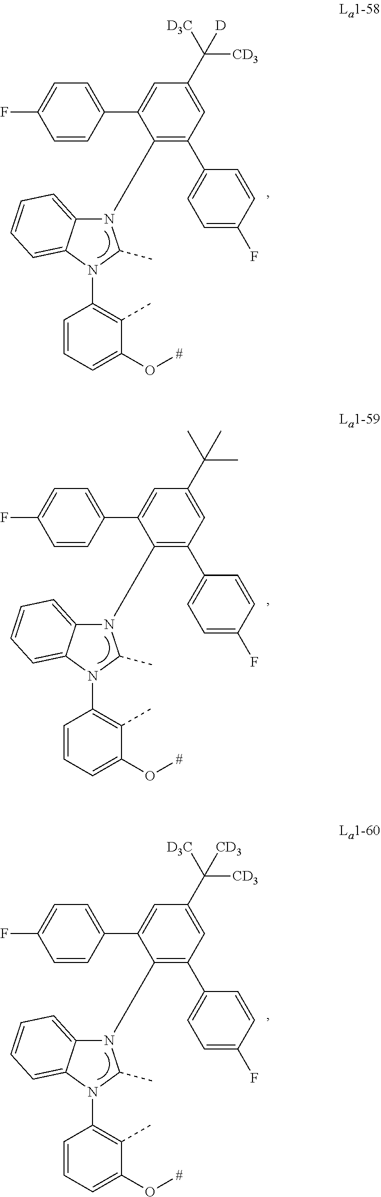 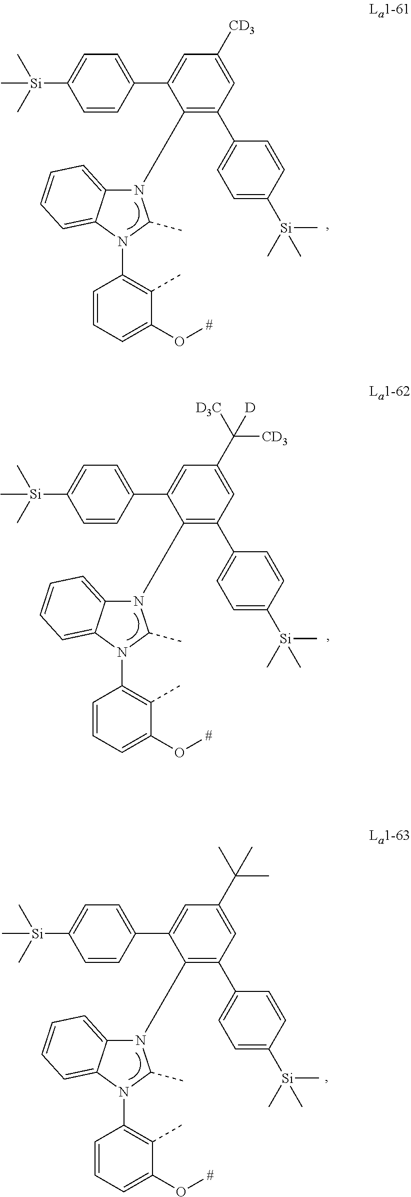 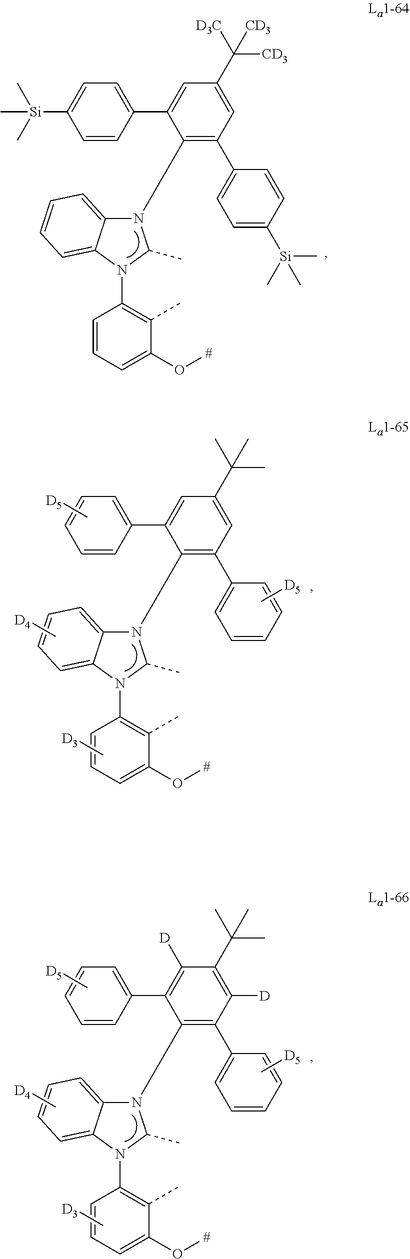 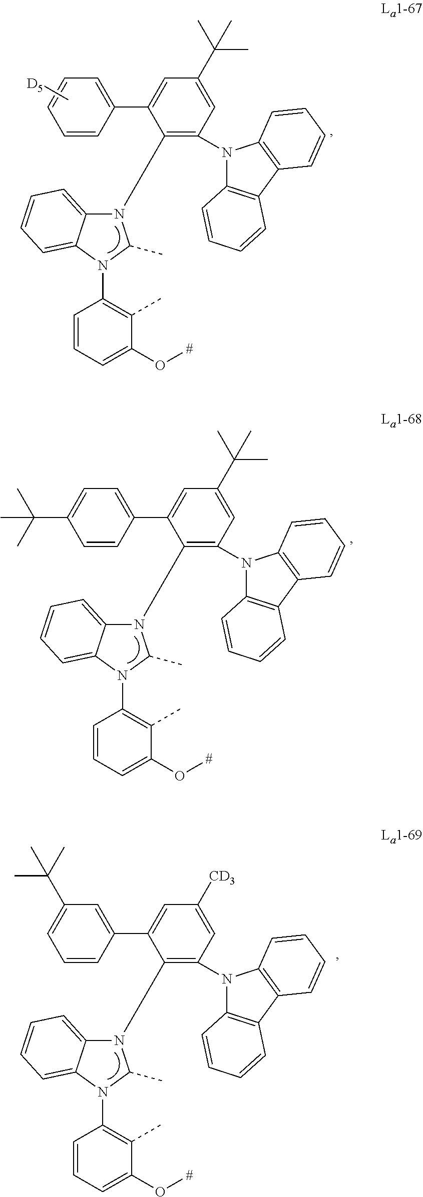 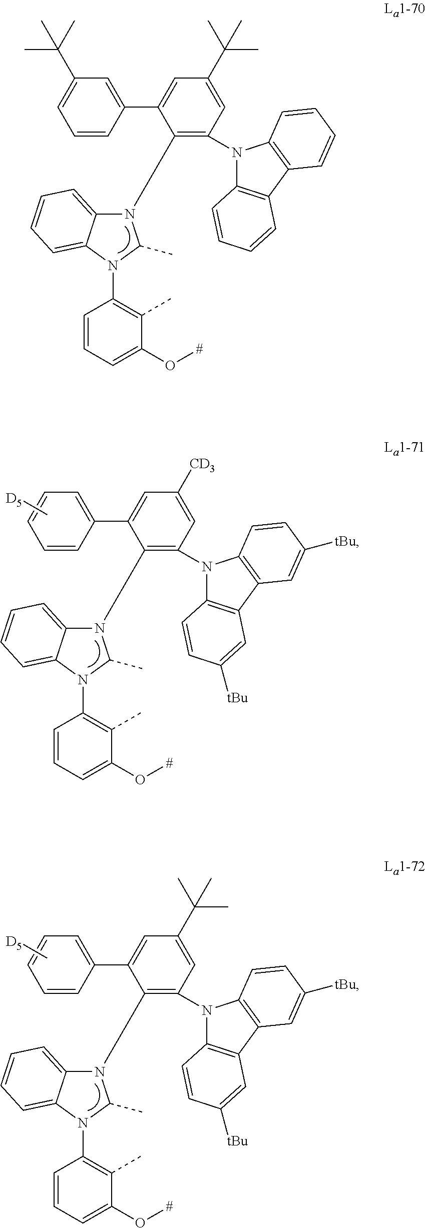 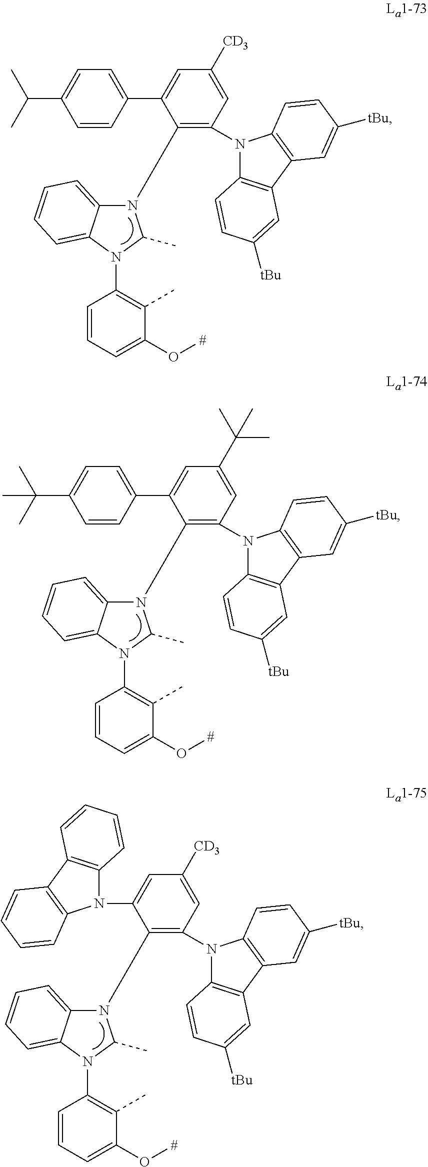 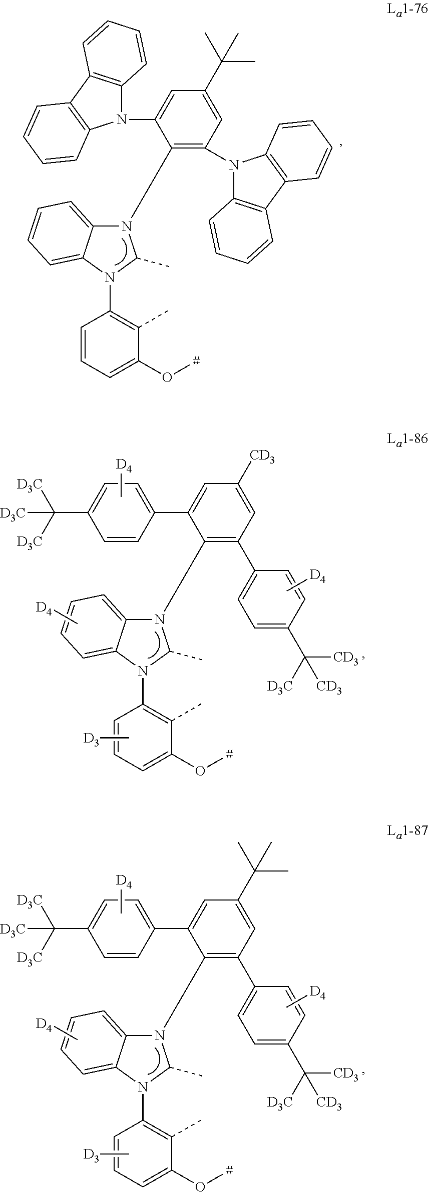 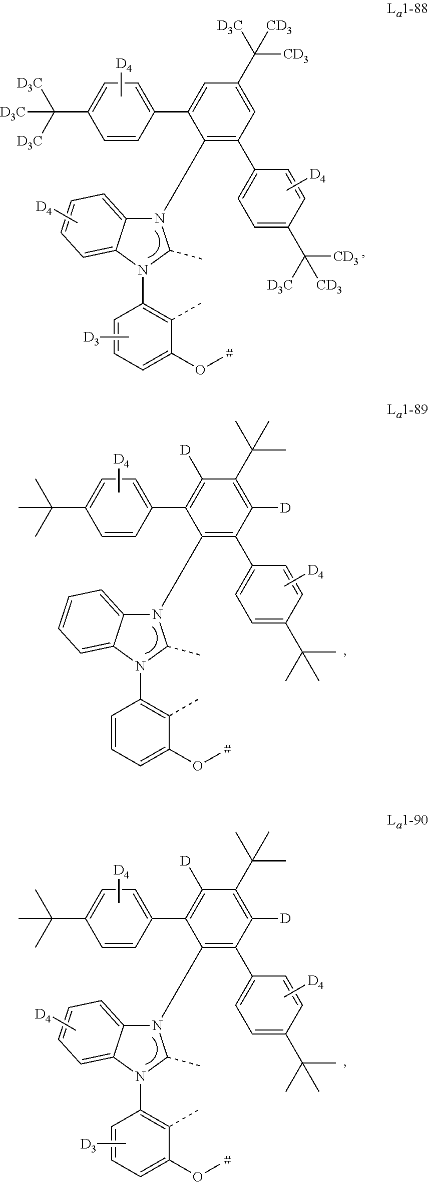 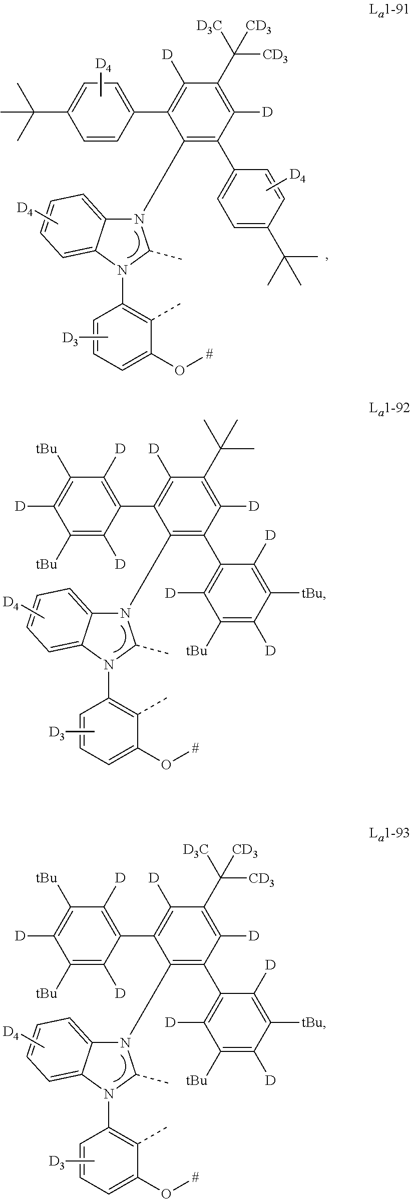 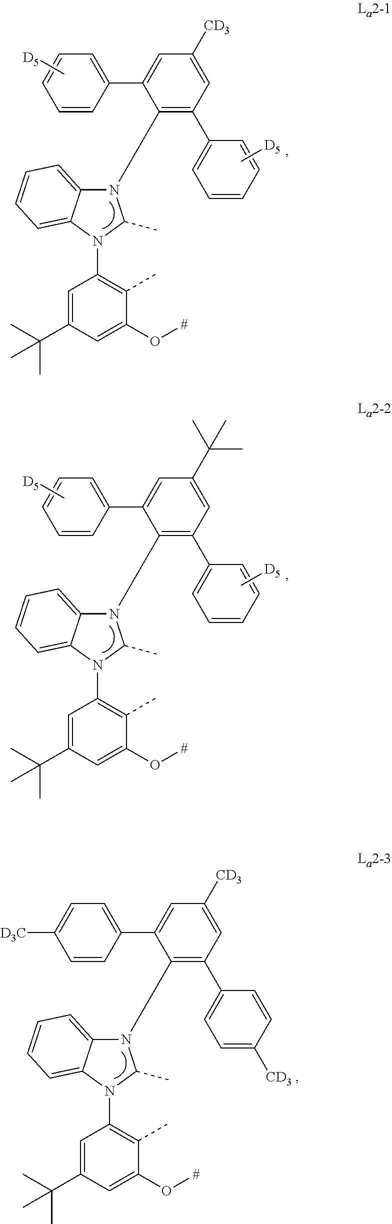 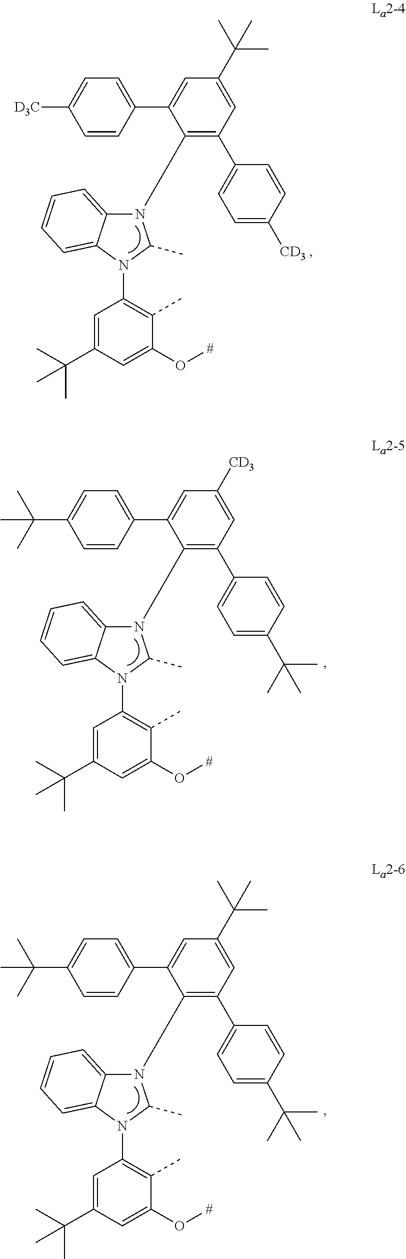 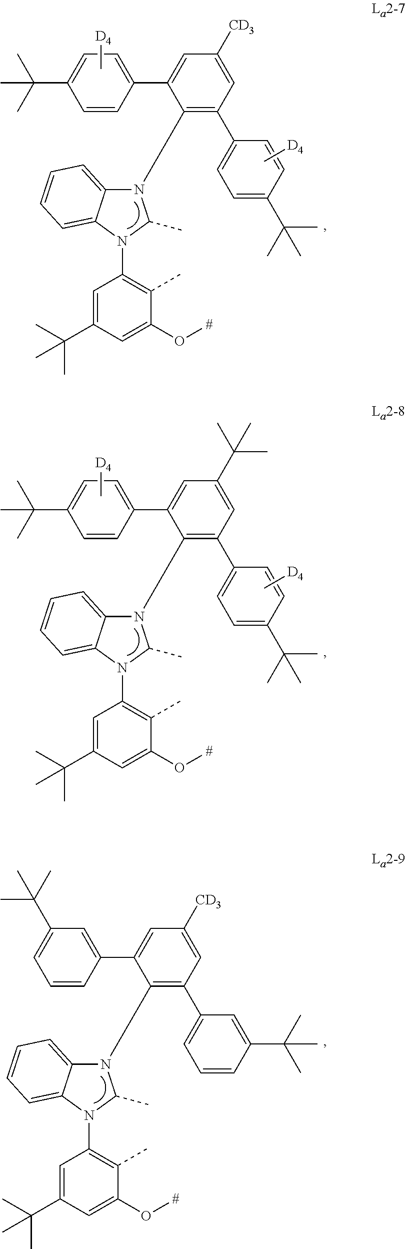 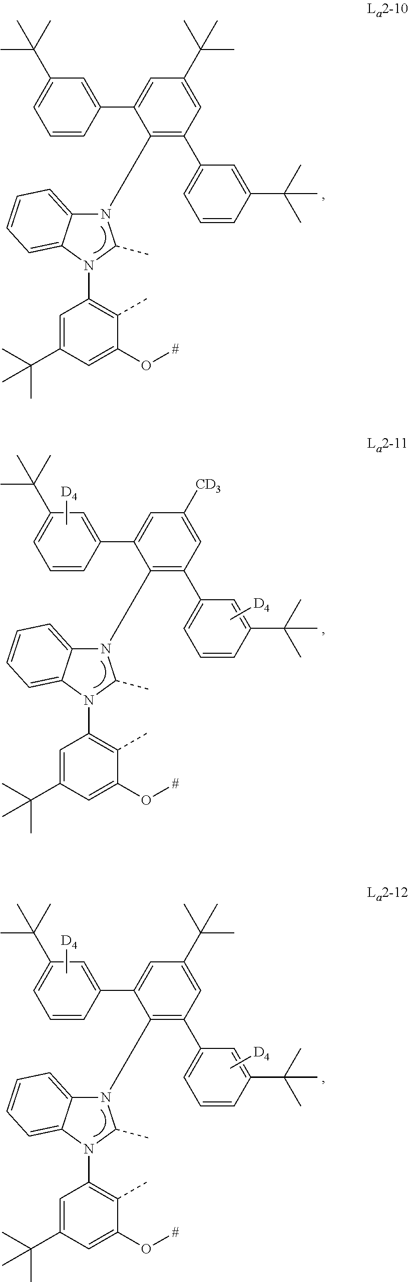 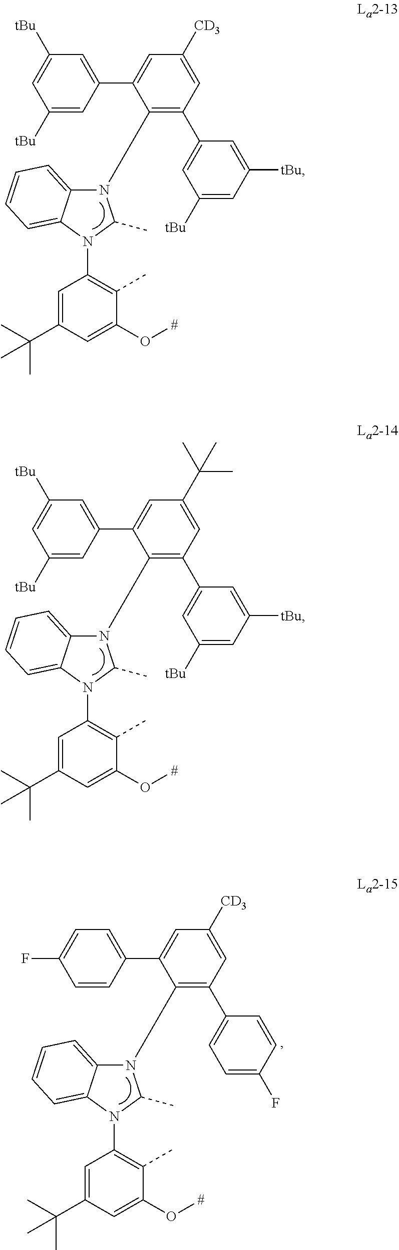 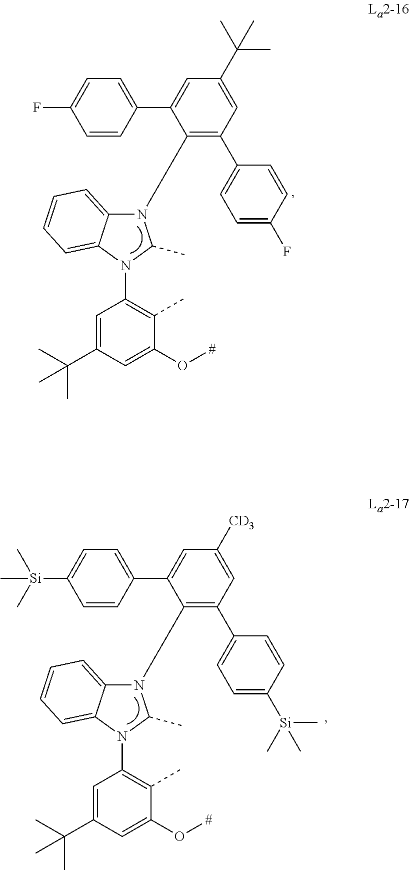 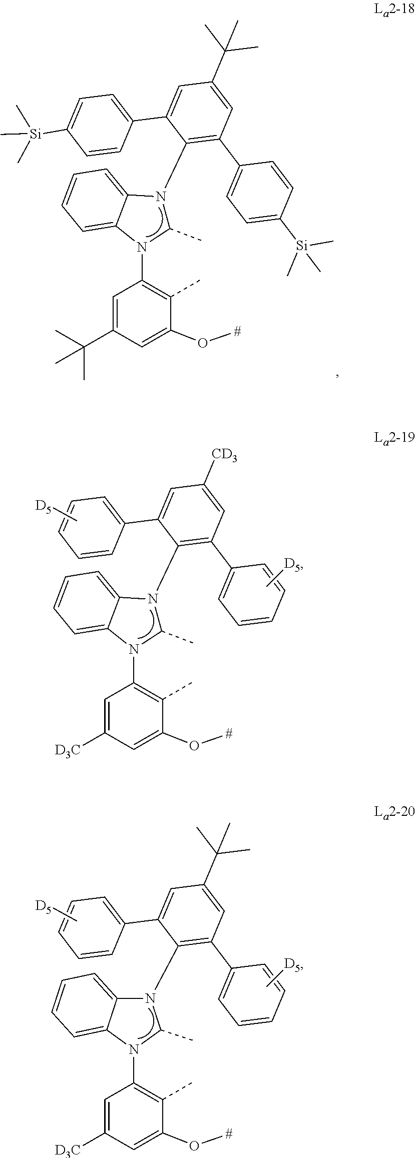 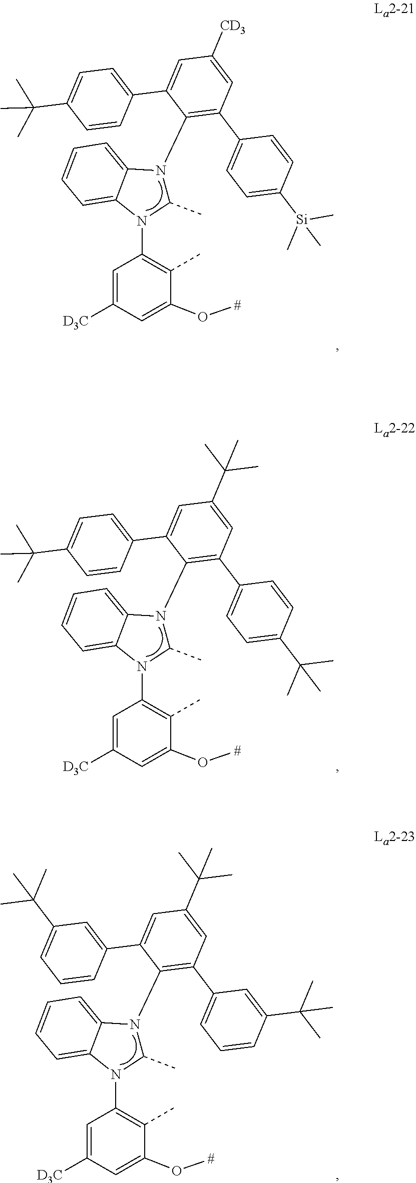 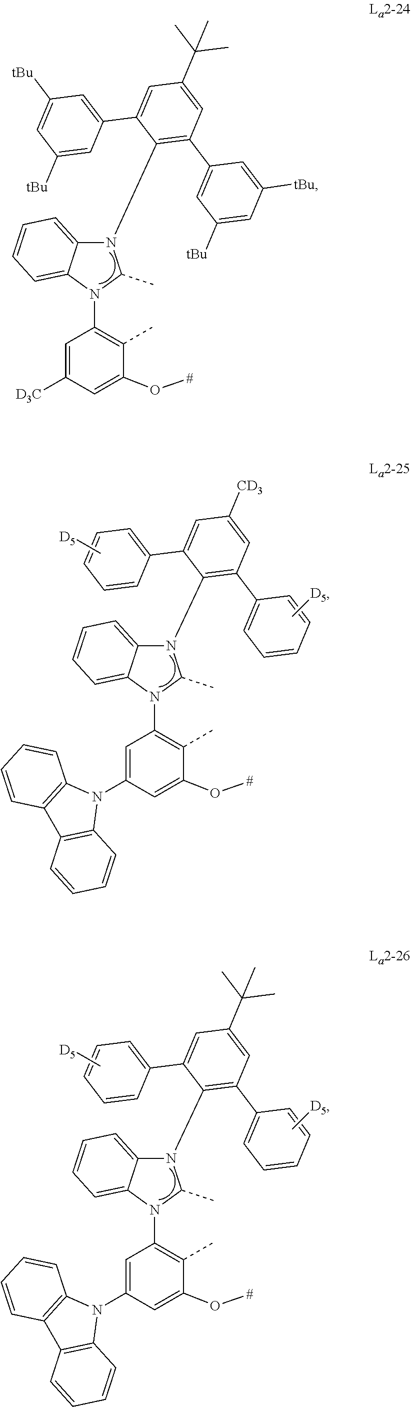 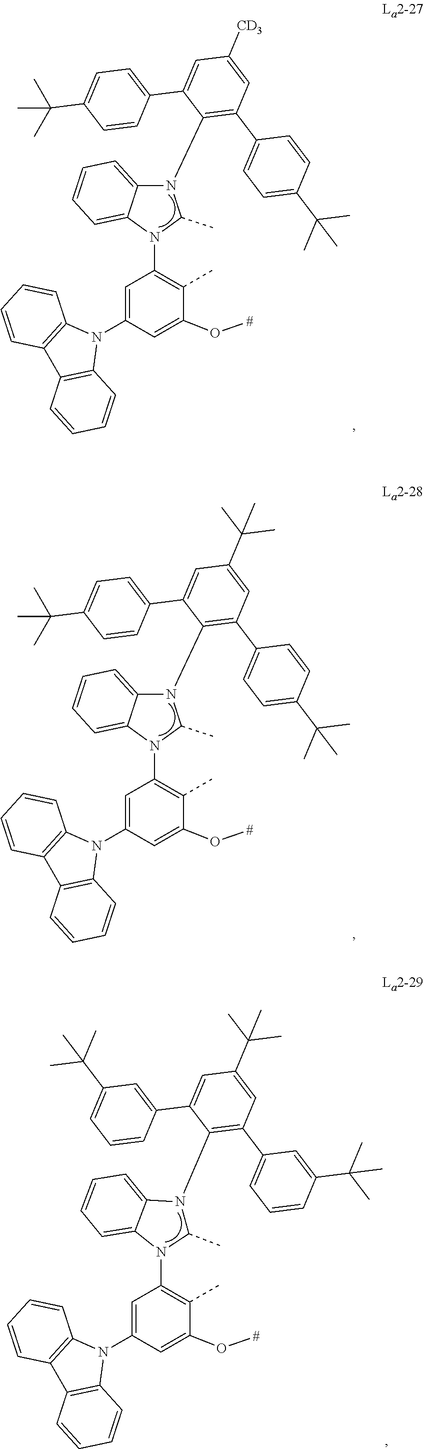 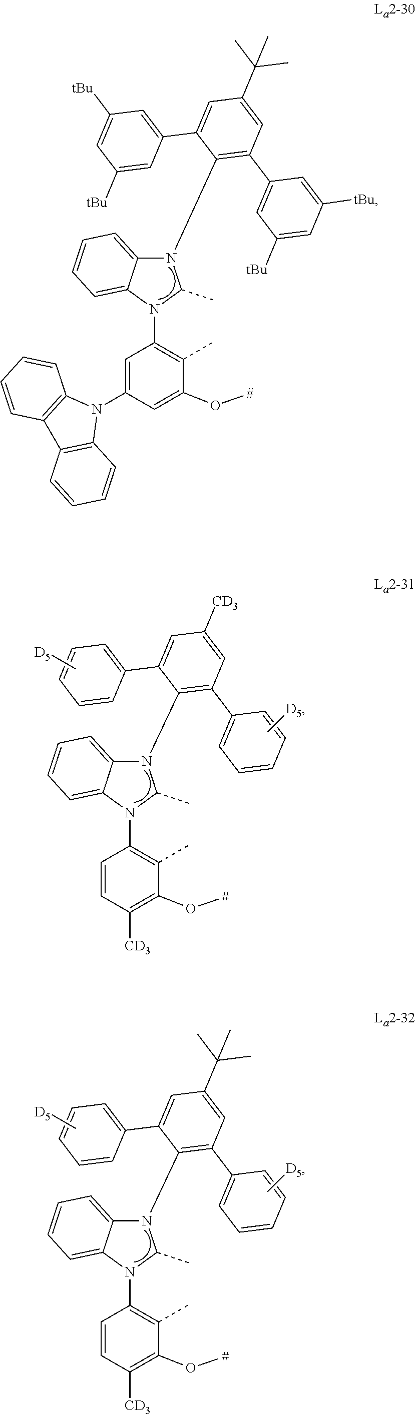 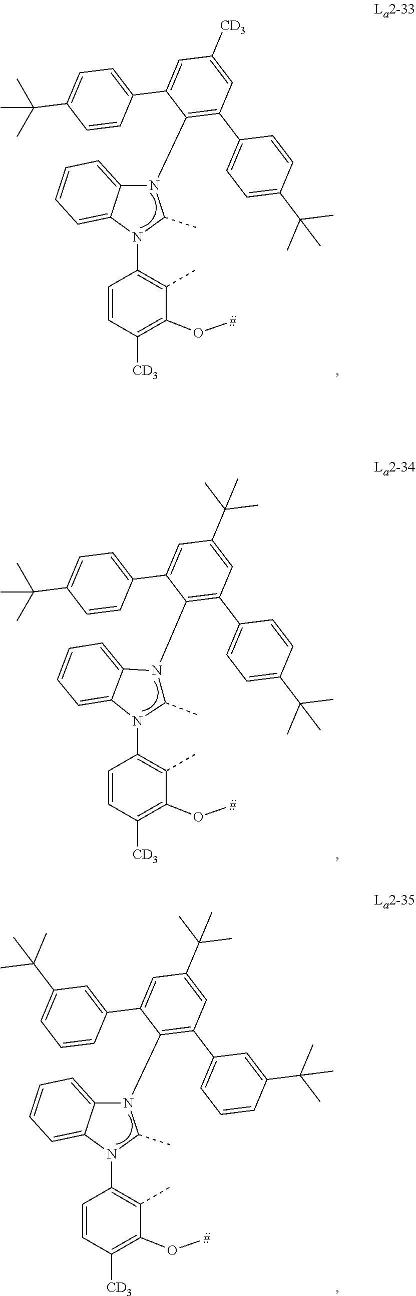 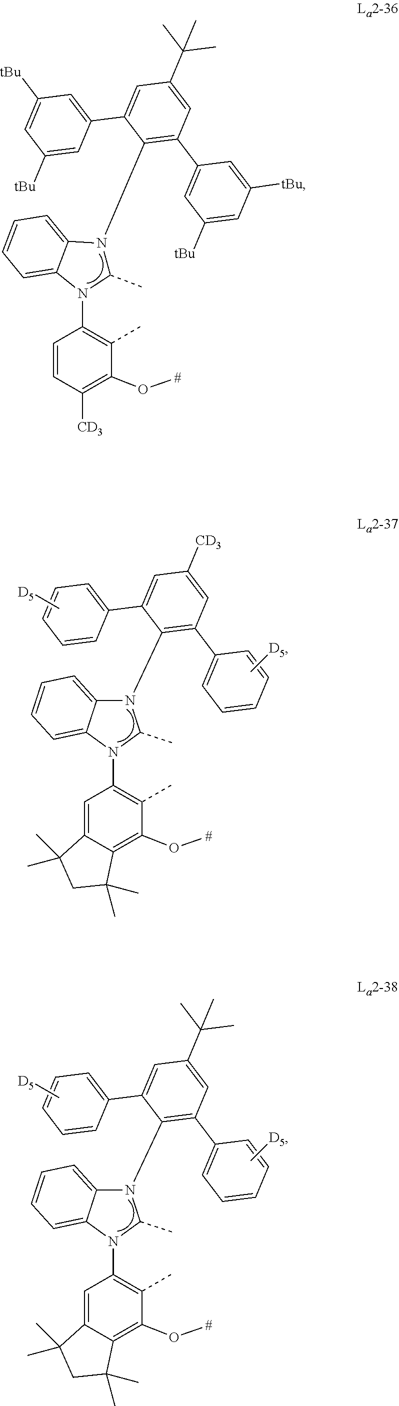 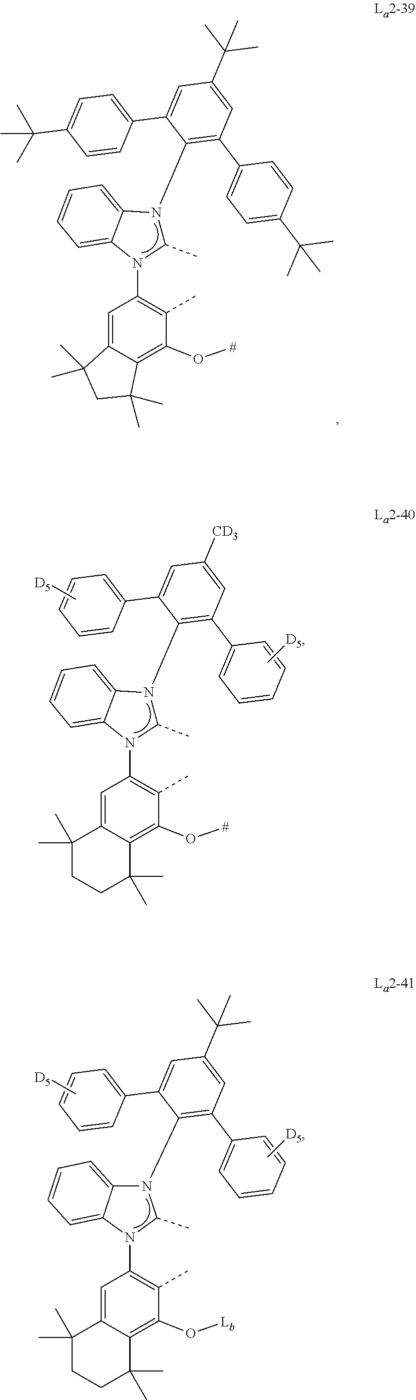 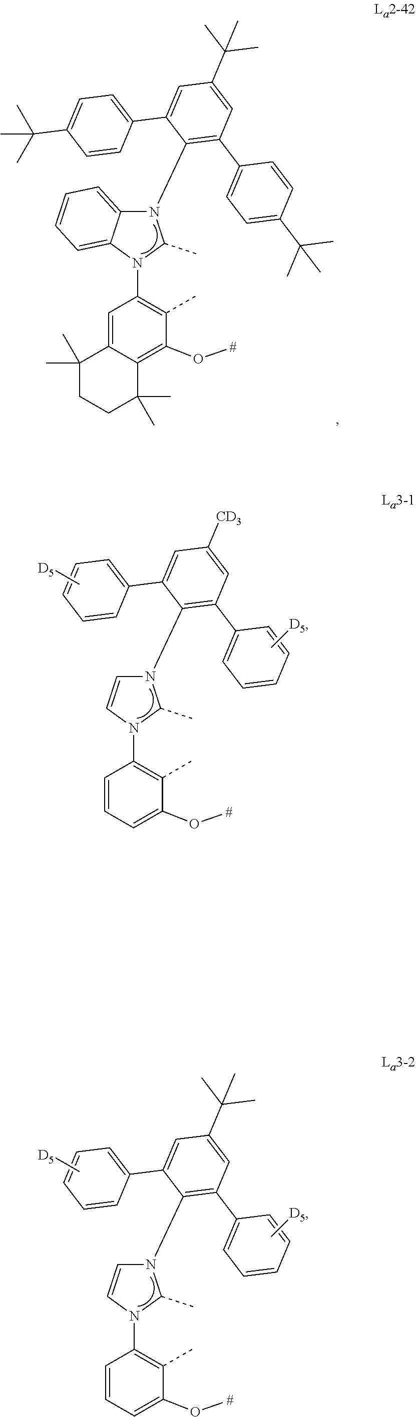 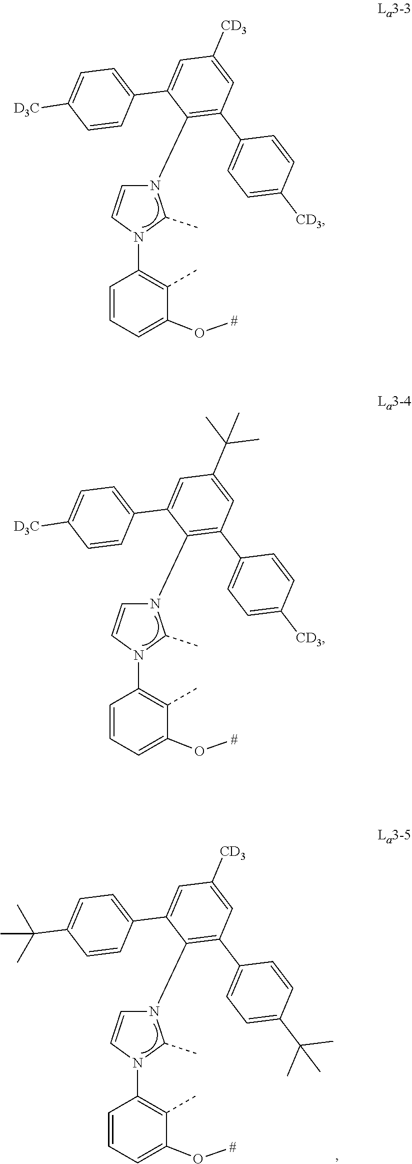 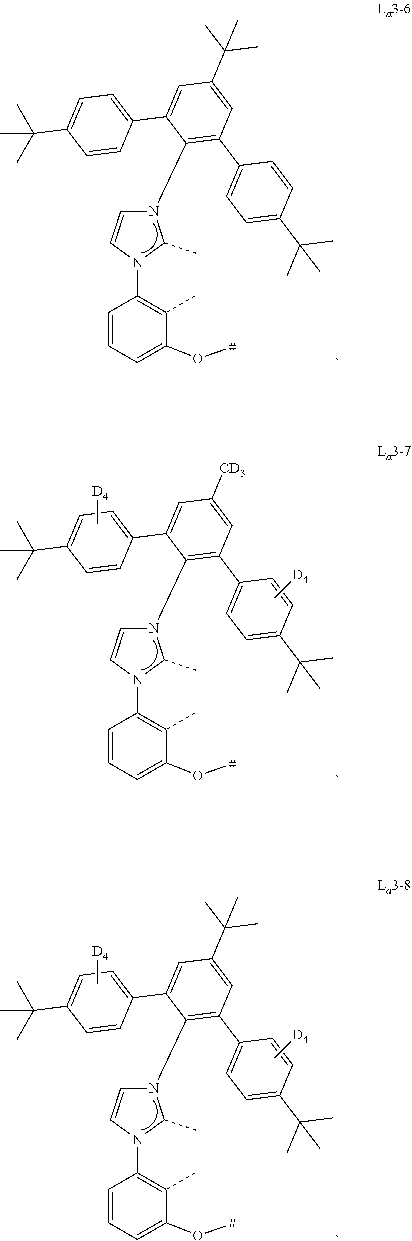 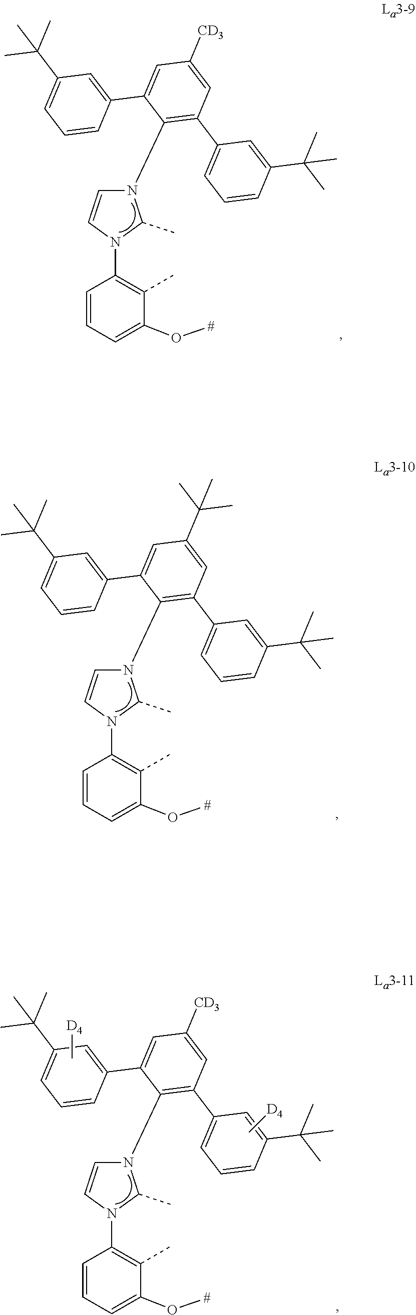 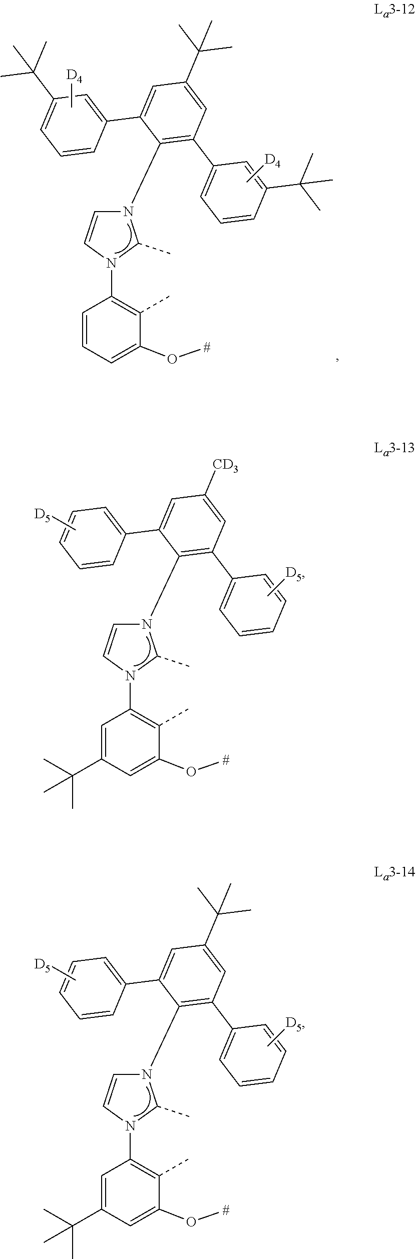 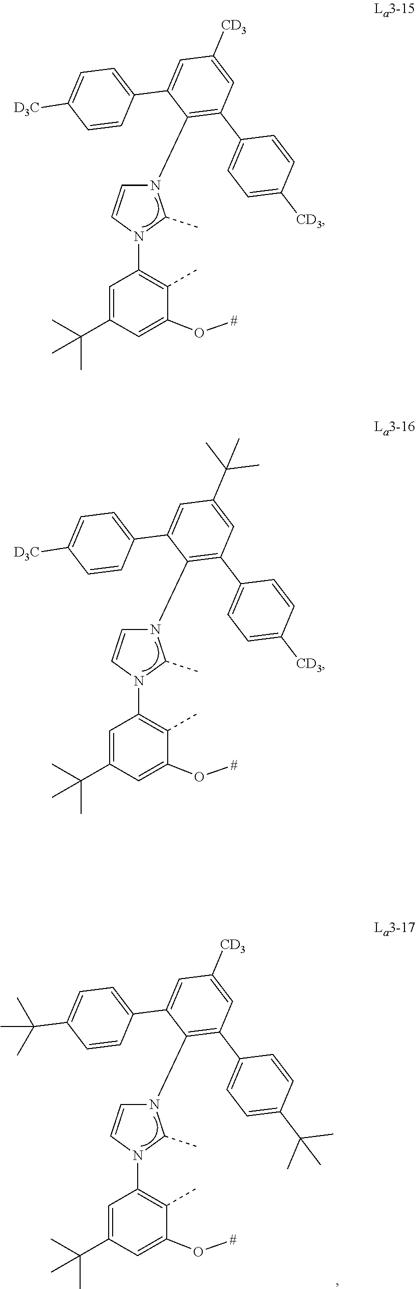 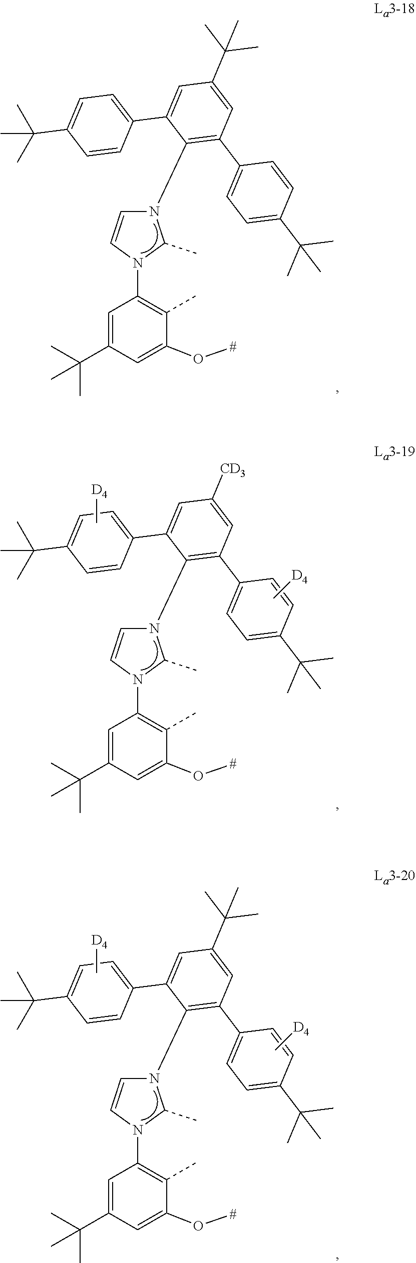 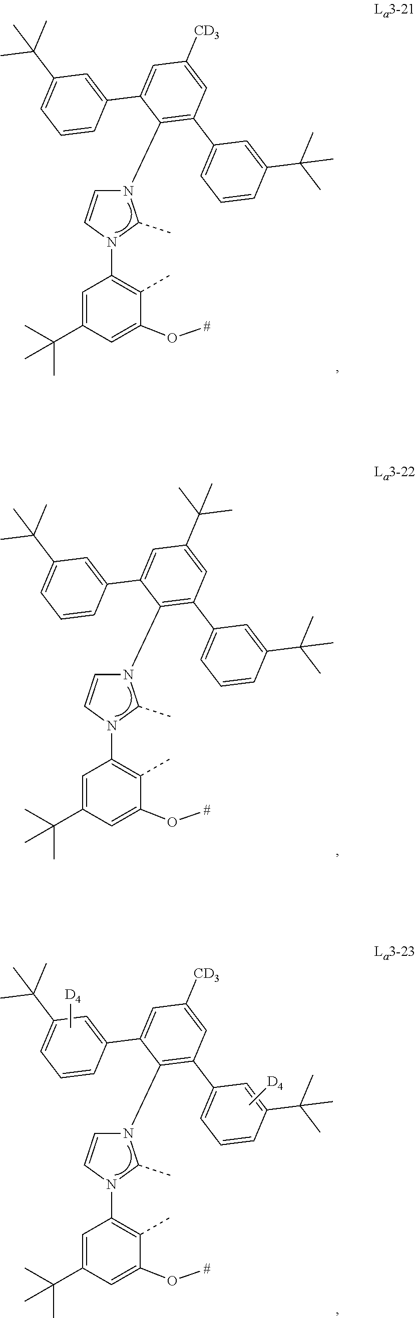 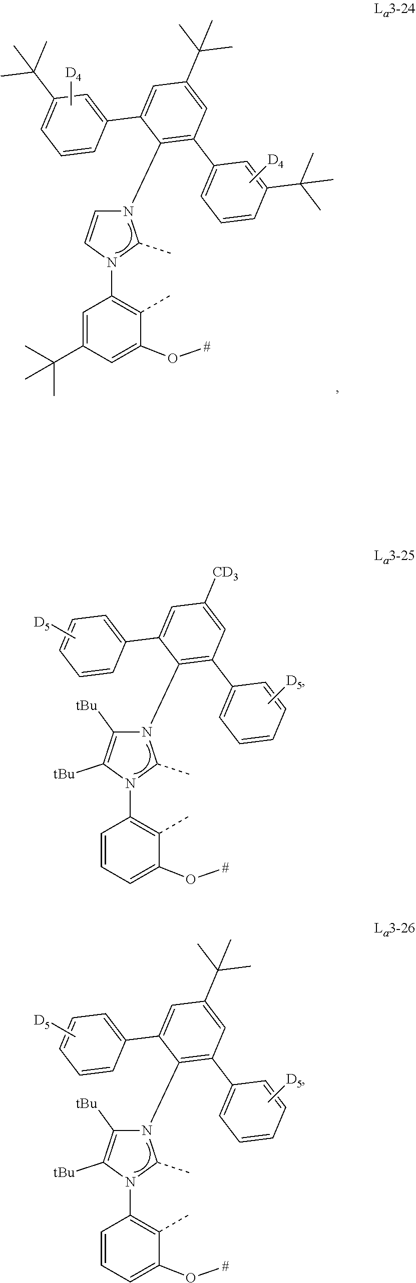 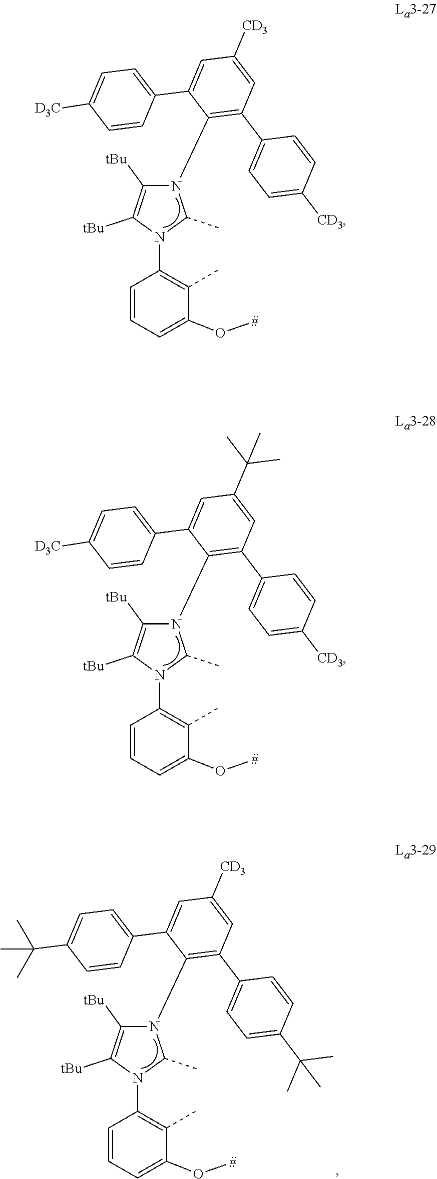 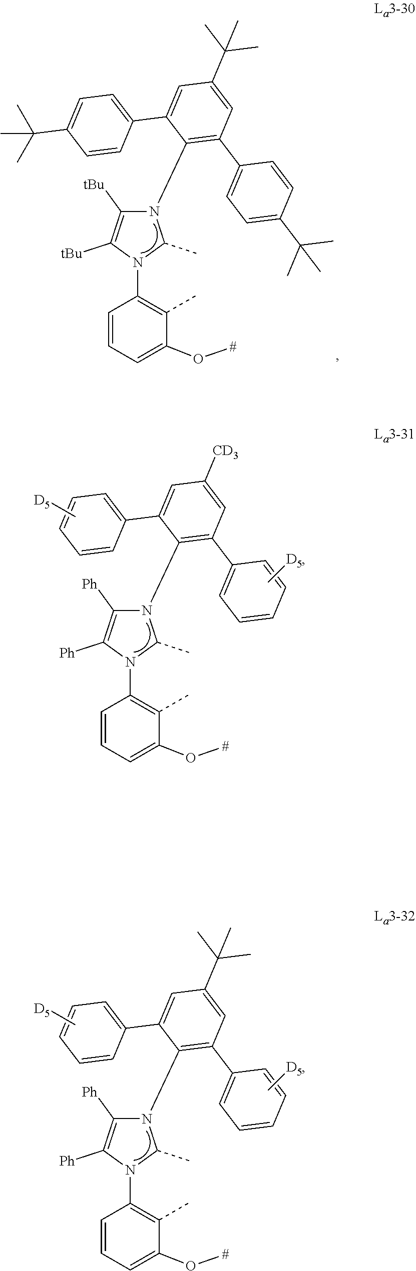 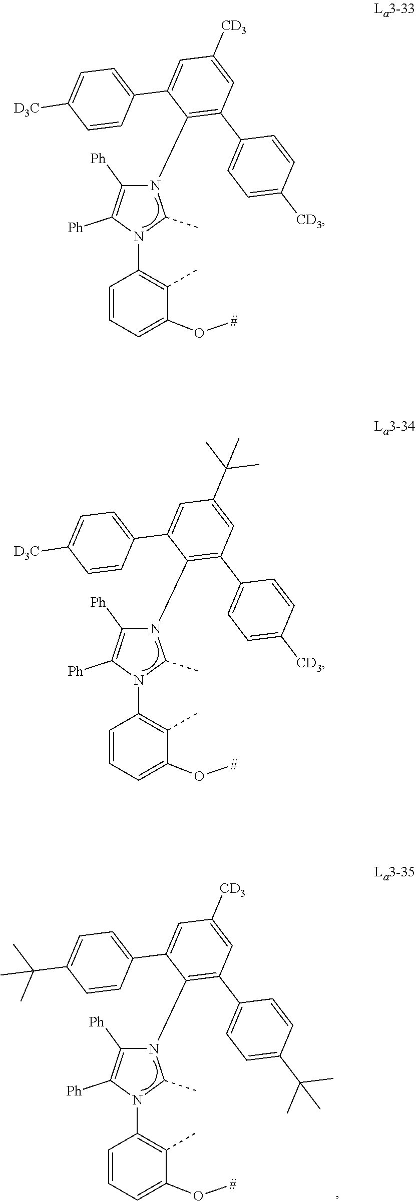 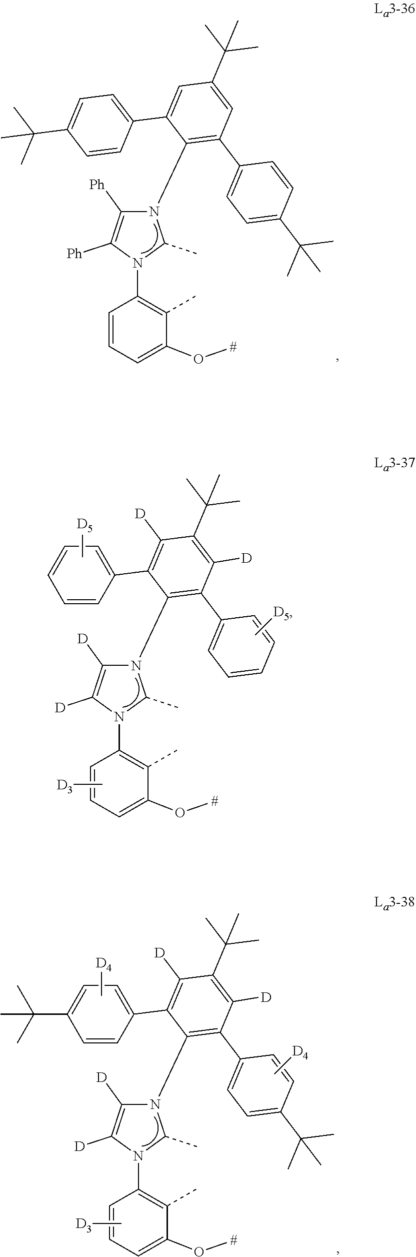 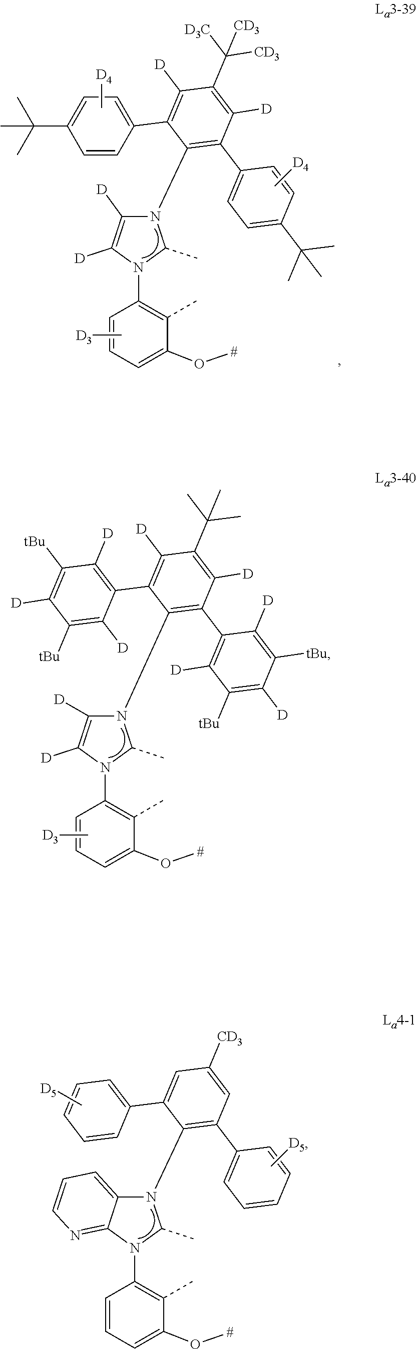 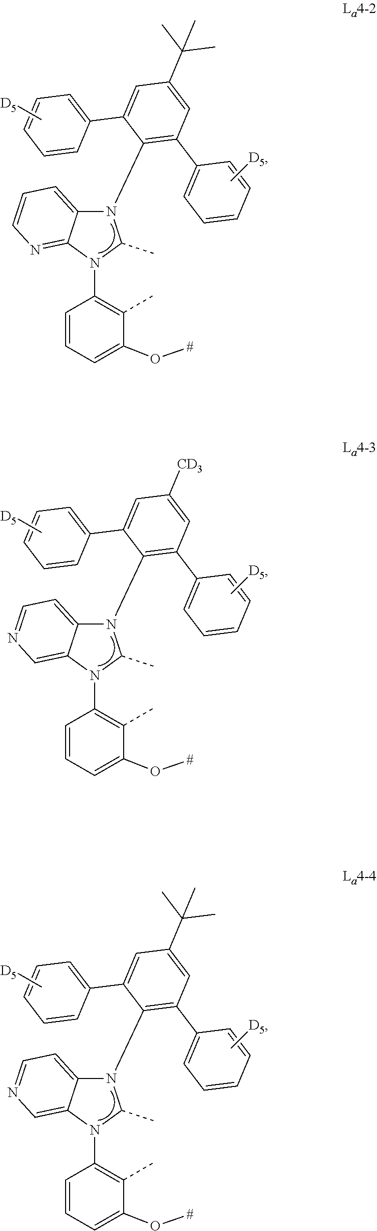 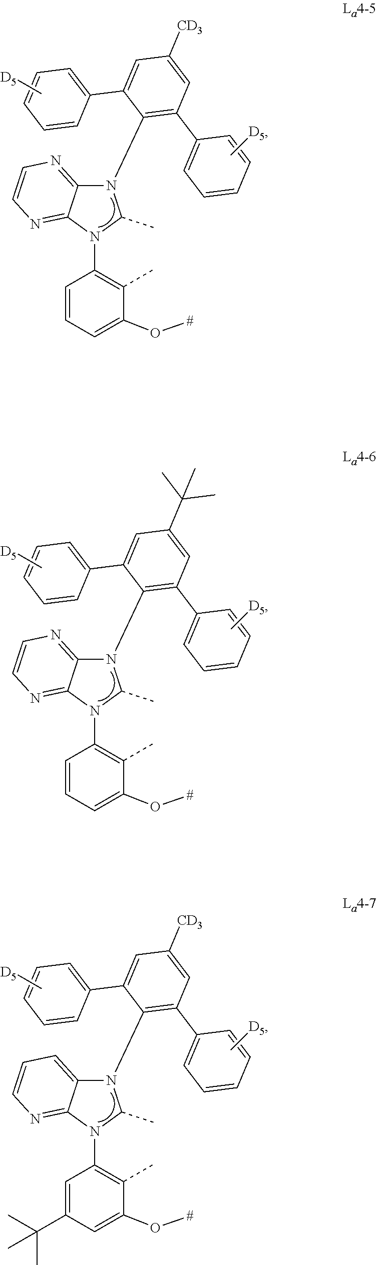 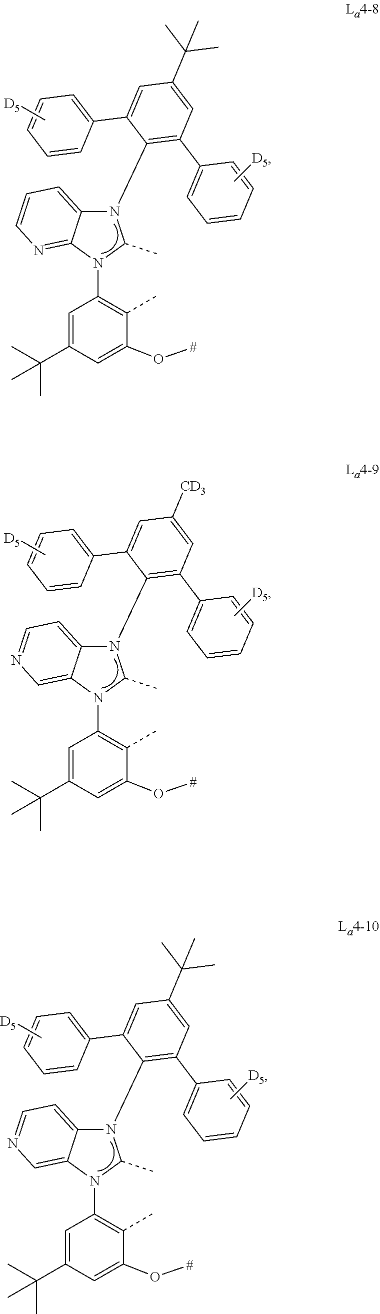 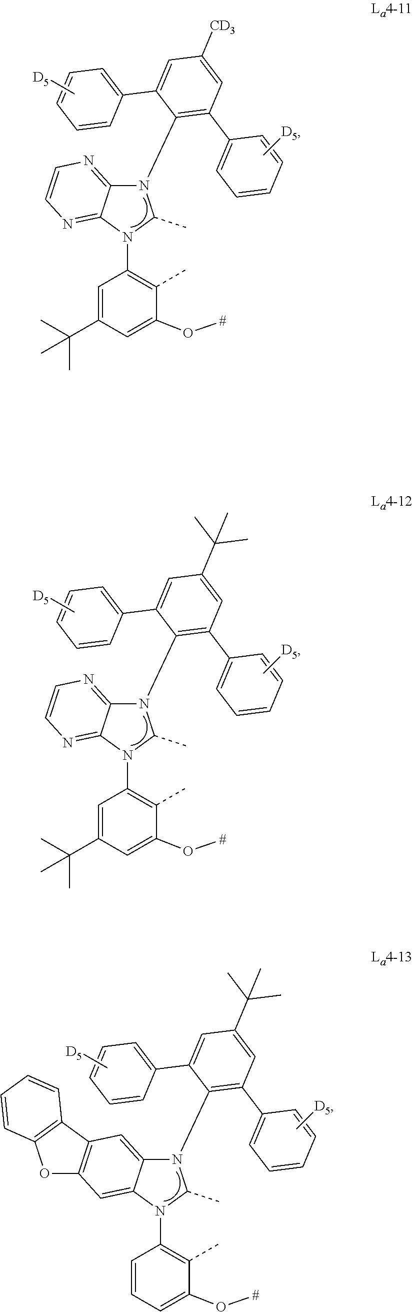 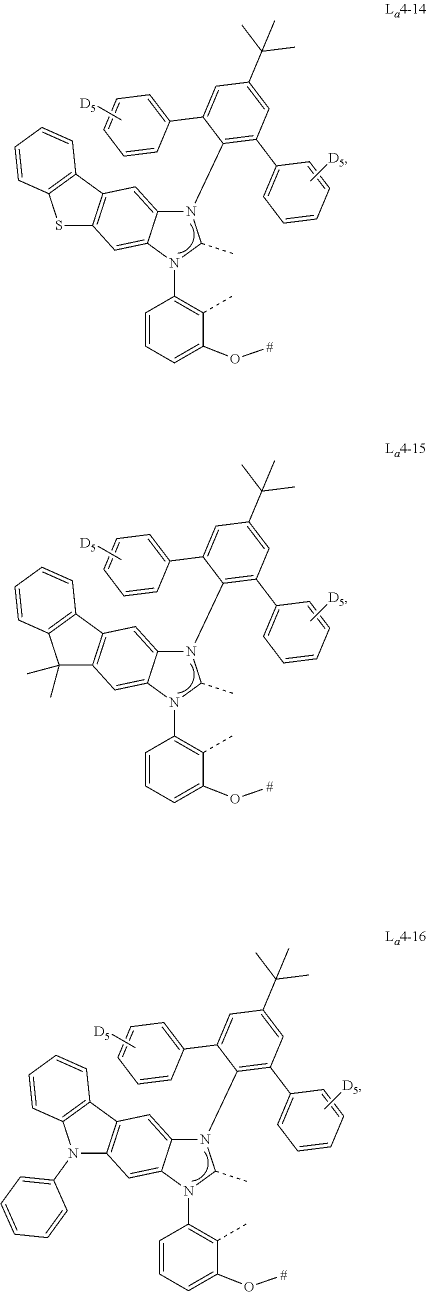 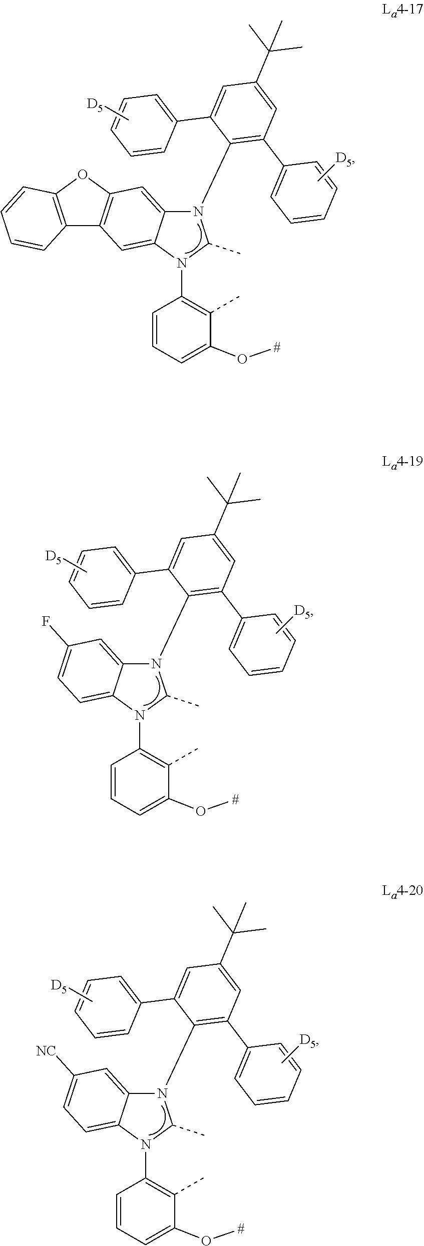 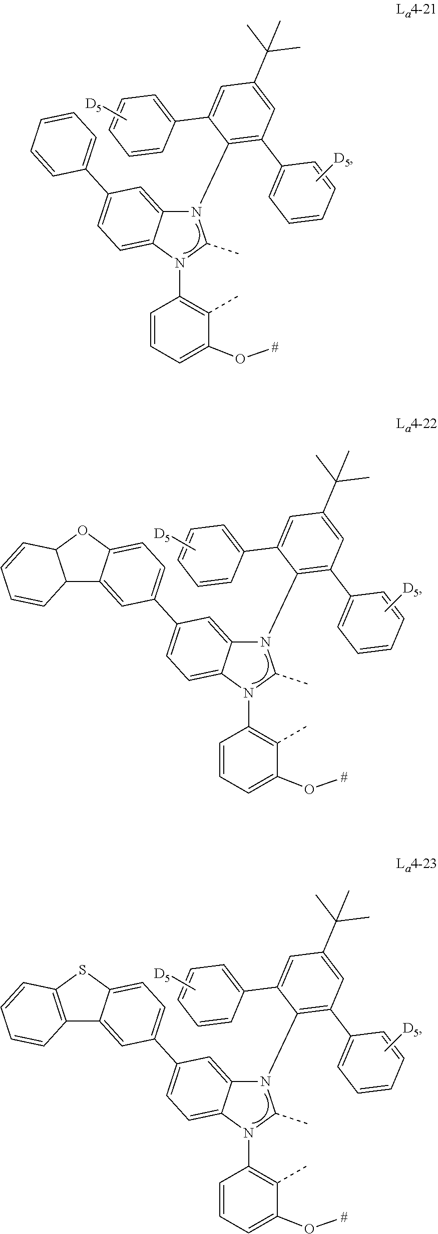 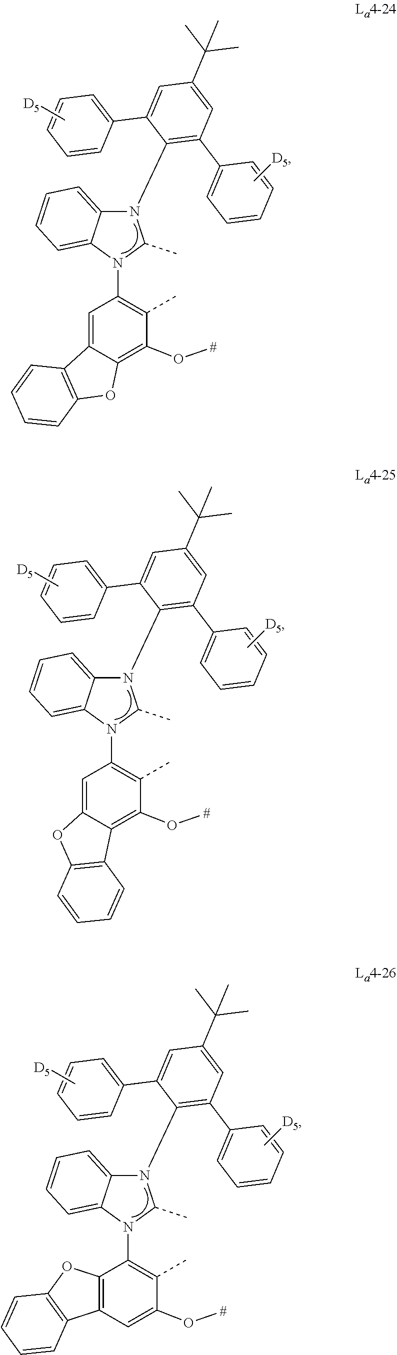 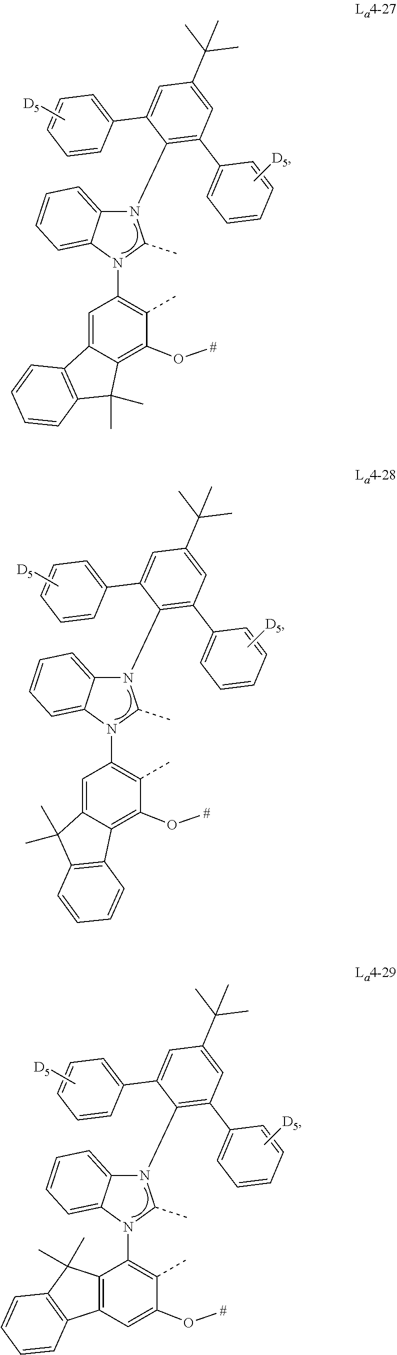 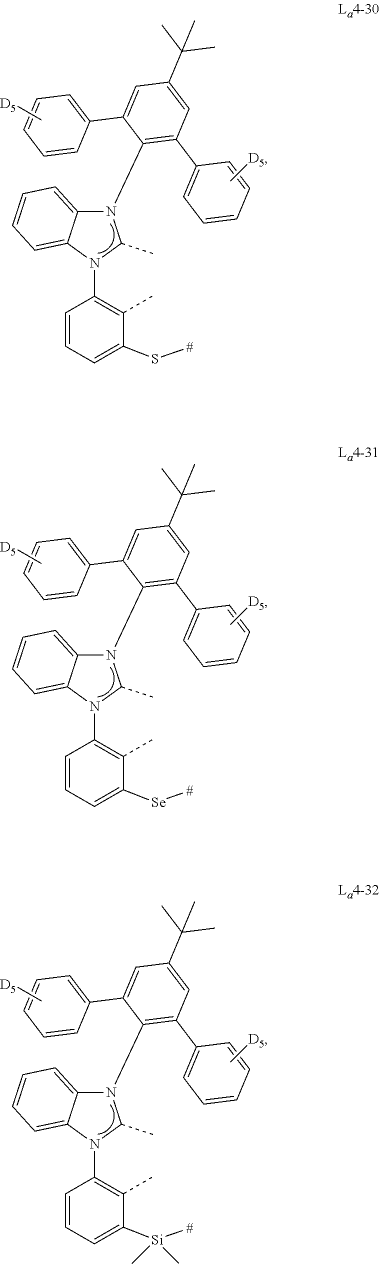 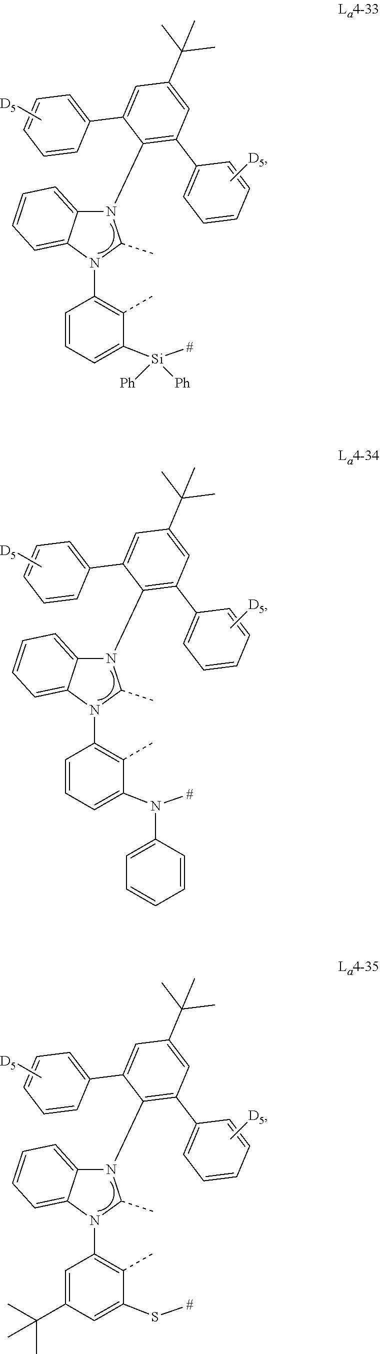 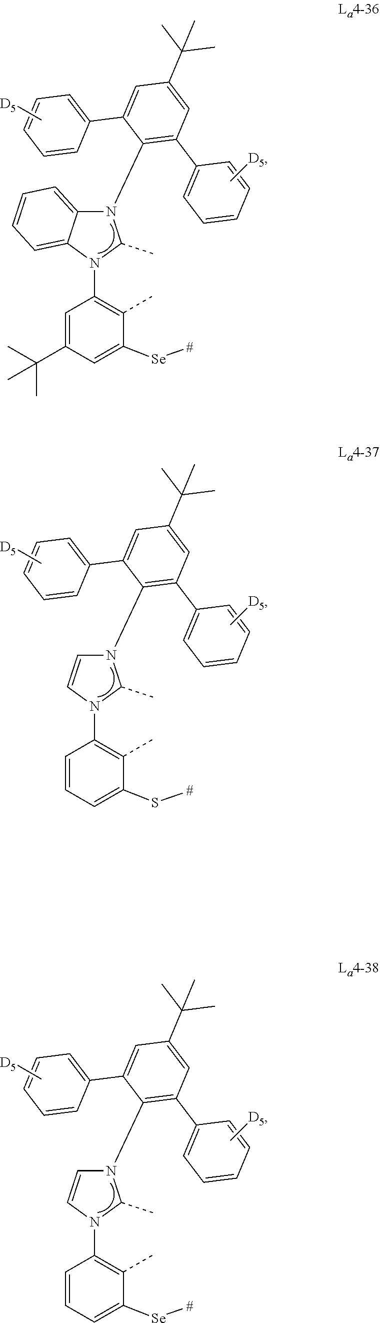 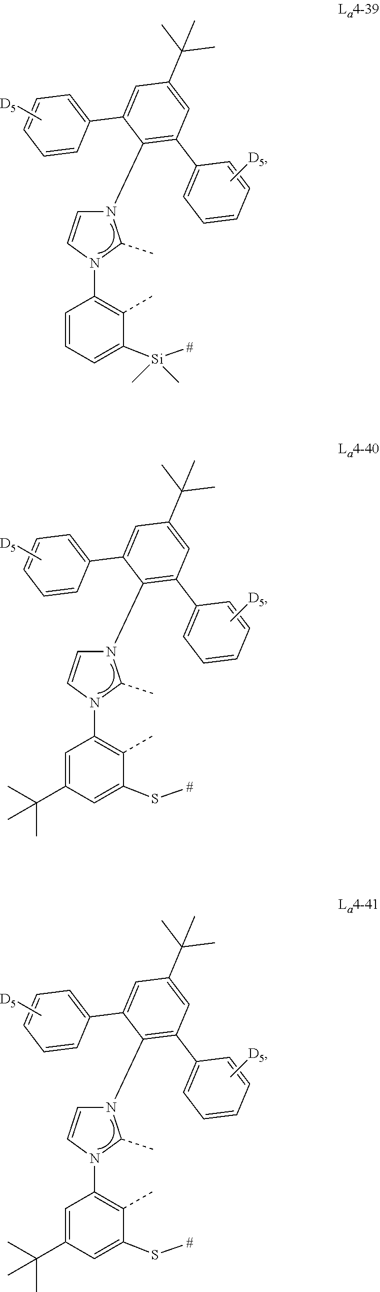 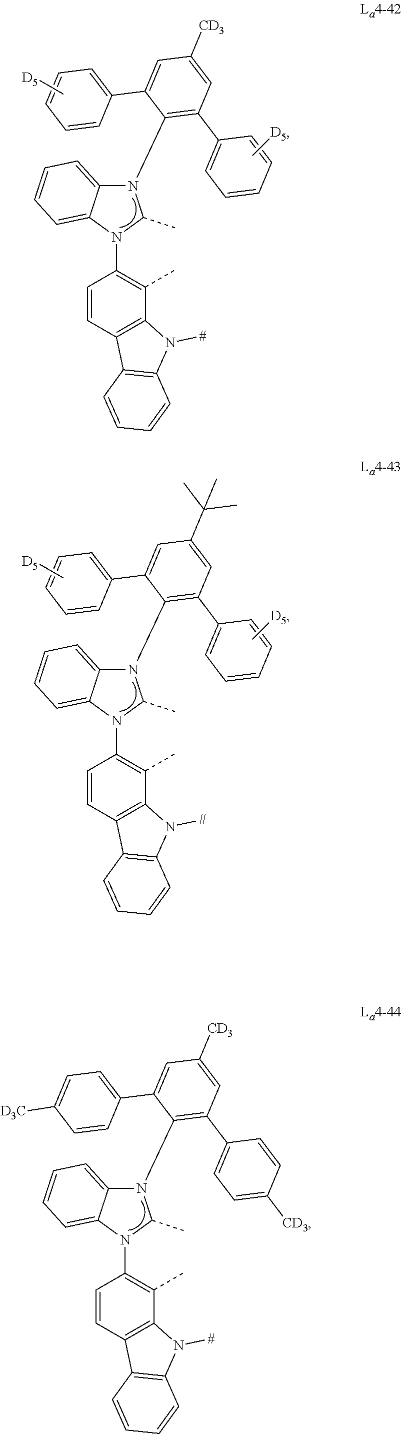 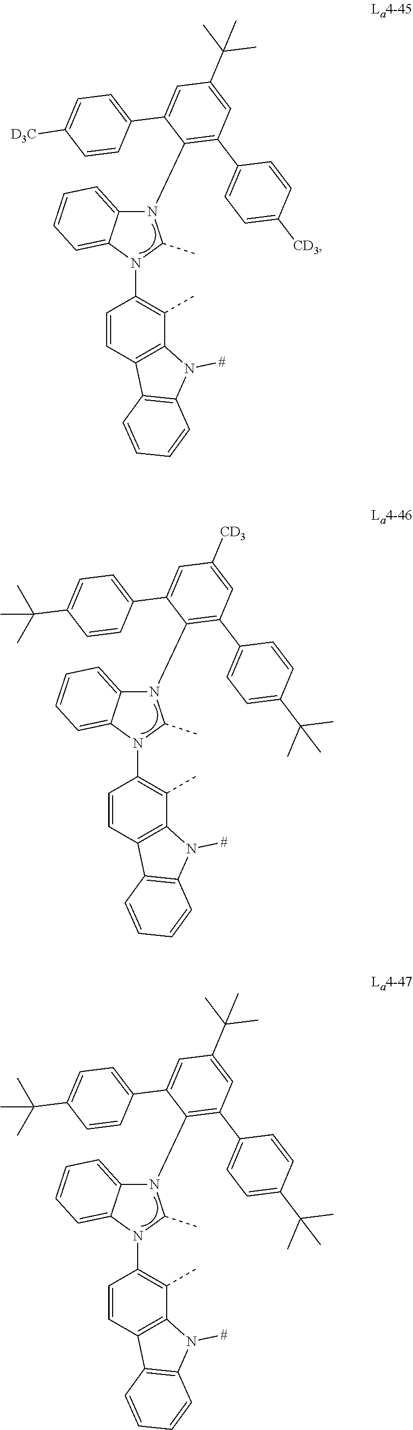 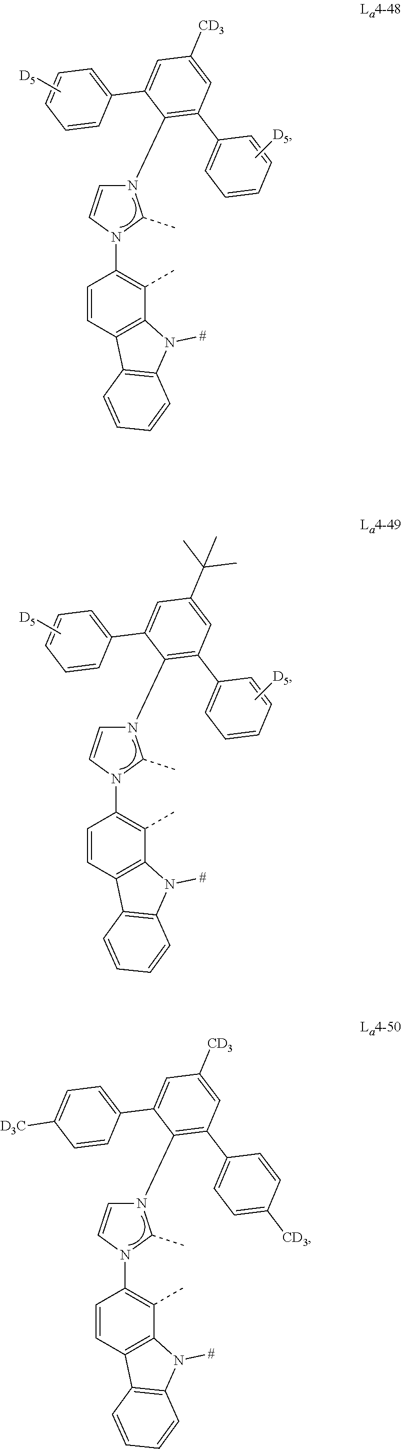 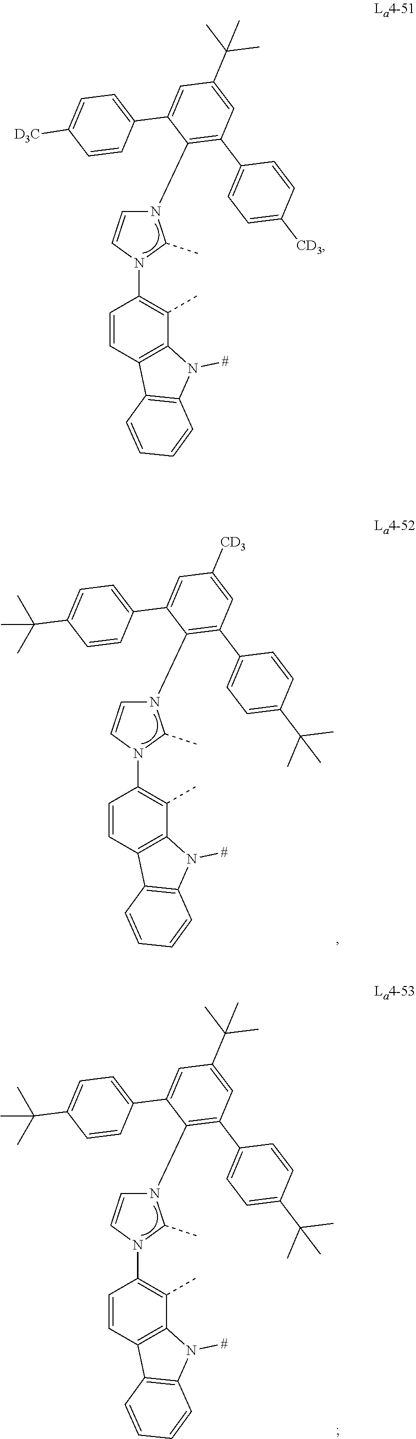
wherein in the structure of Lₐ, “tBu” represents t-butyl;
in the structure of Lₐ, “#” represents a position where the structure is joined to L_{b};
the ligand L_{b} is selected from the group consisting of L_{b}1-1 to L_{b}1-9, L_{b}1-12 to L_{b}1-22, L_{b}2-1 to L_{b}2-30, L_{b}3-1 to L_{b}3-26, L_{b}4-1 to L_{b}4-25 and L_{b}5-1 to L_{b}5-11: 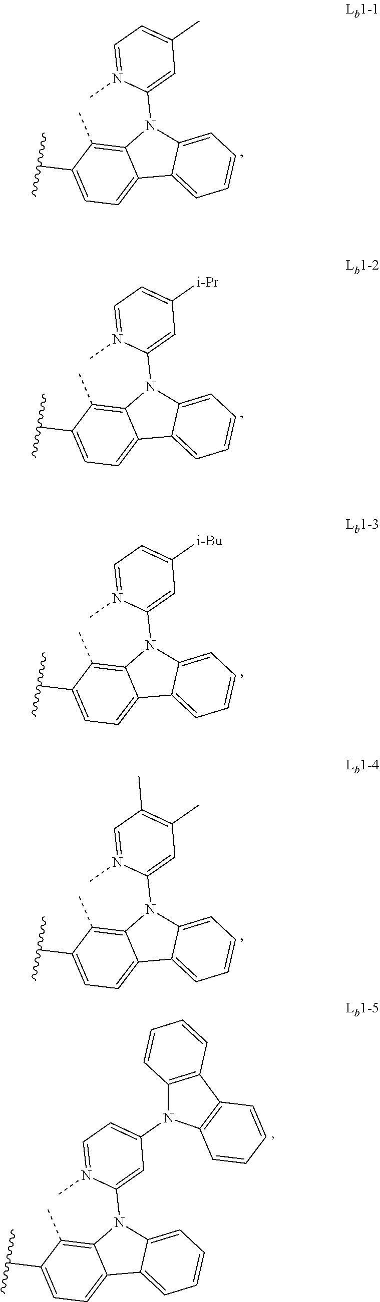 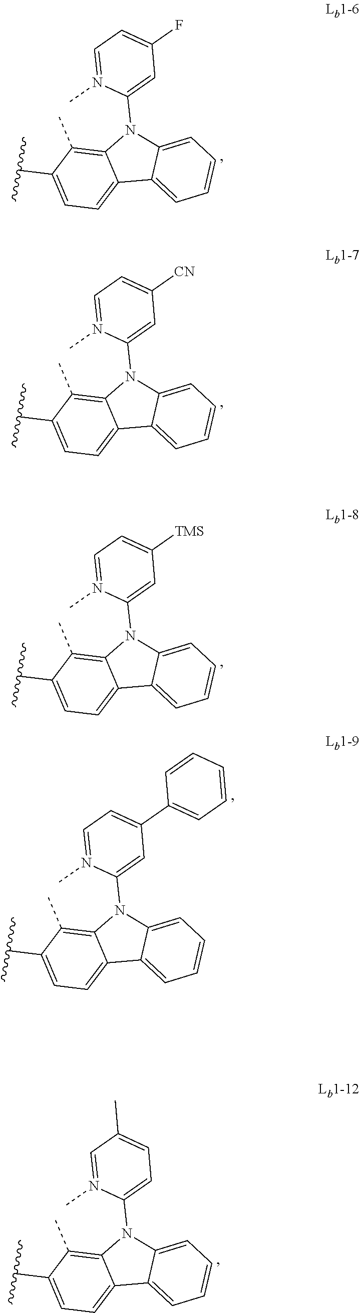 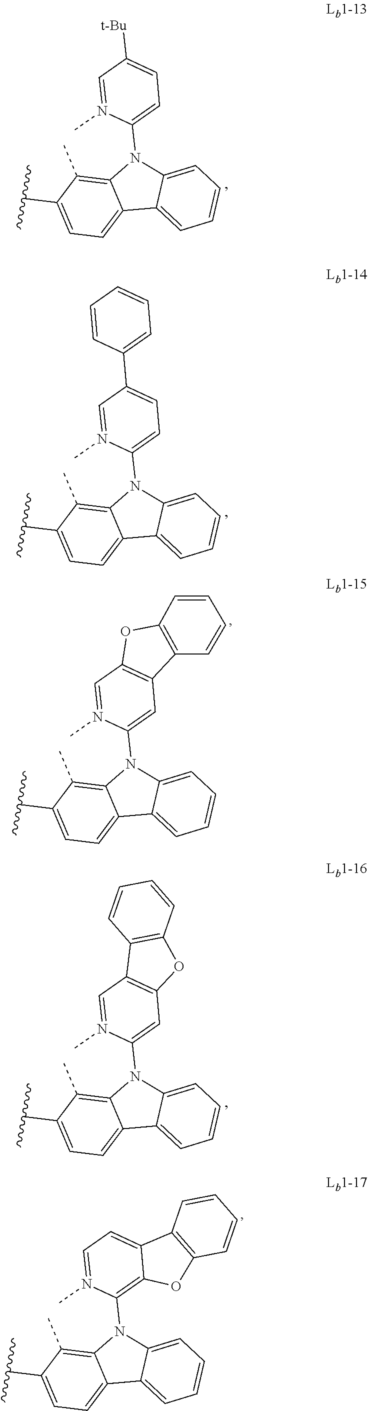 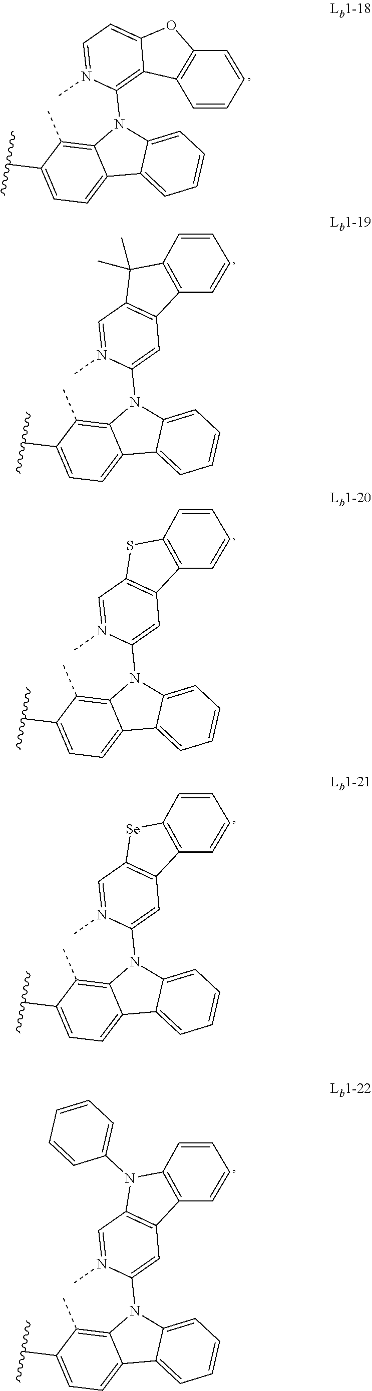 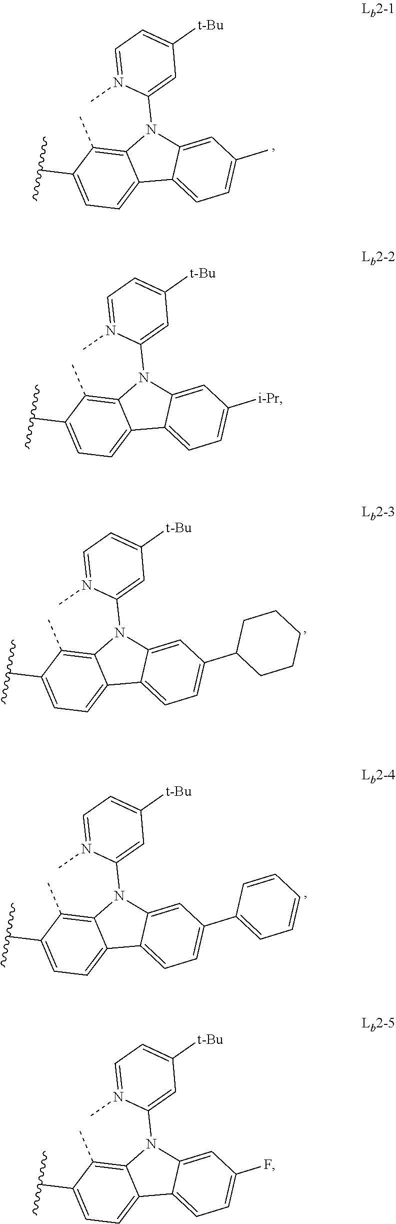 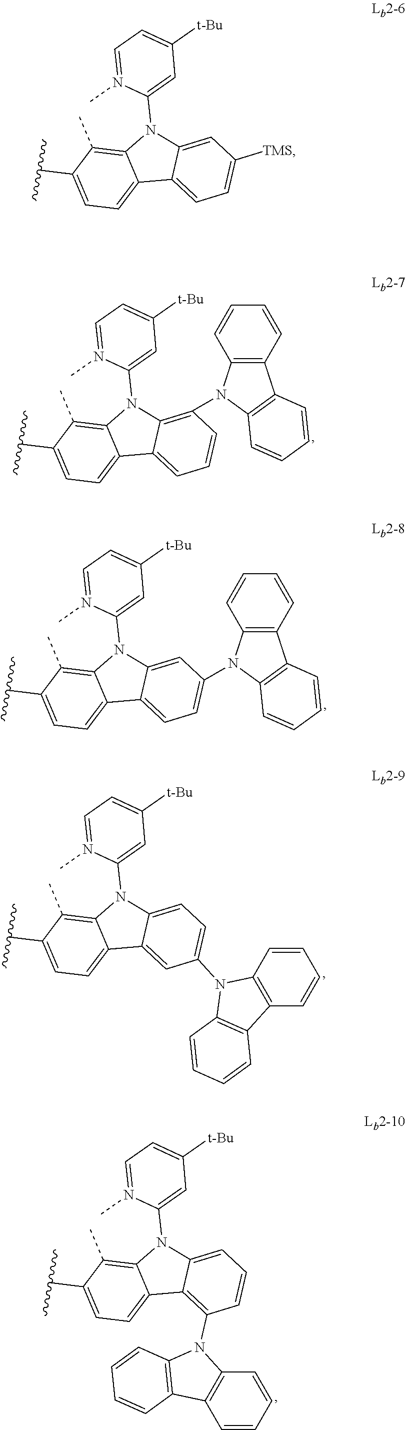 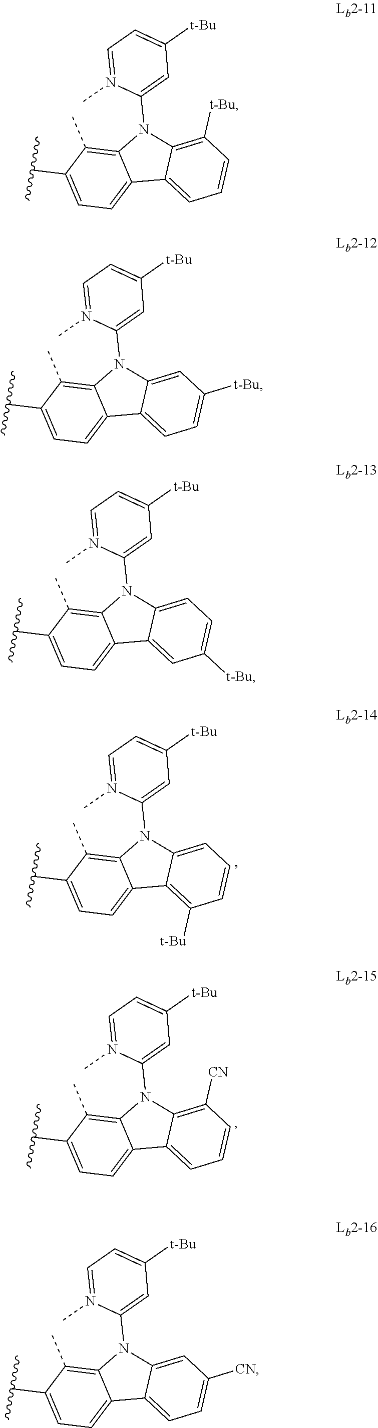 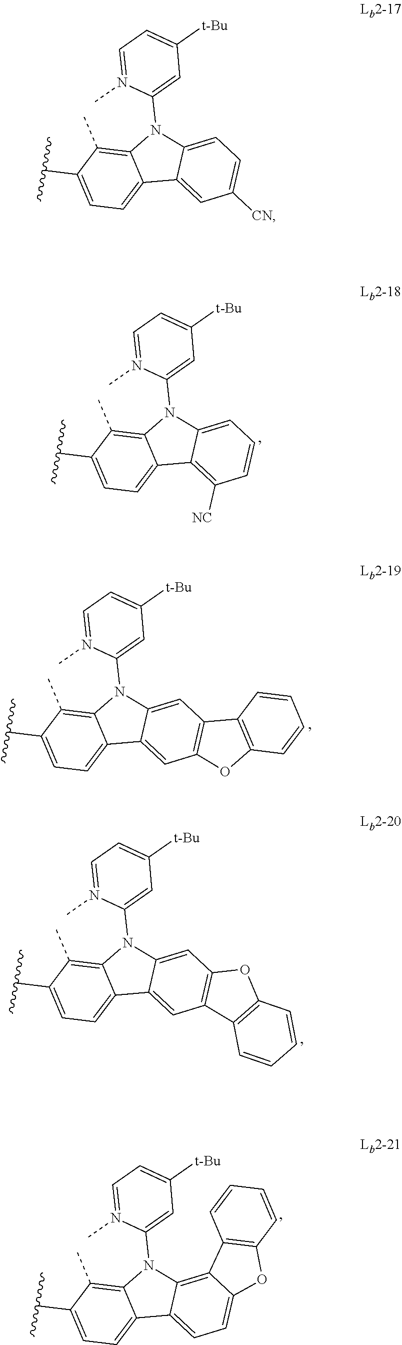 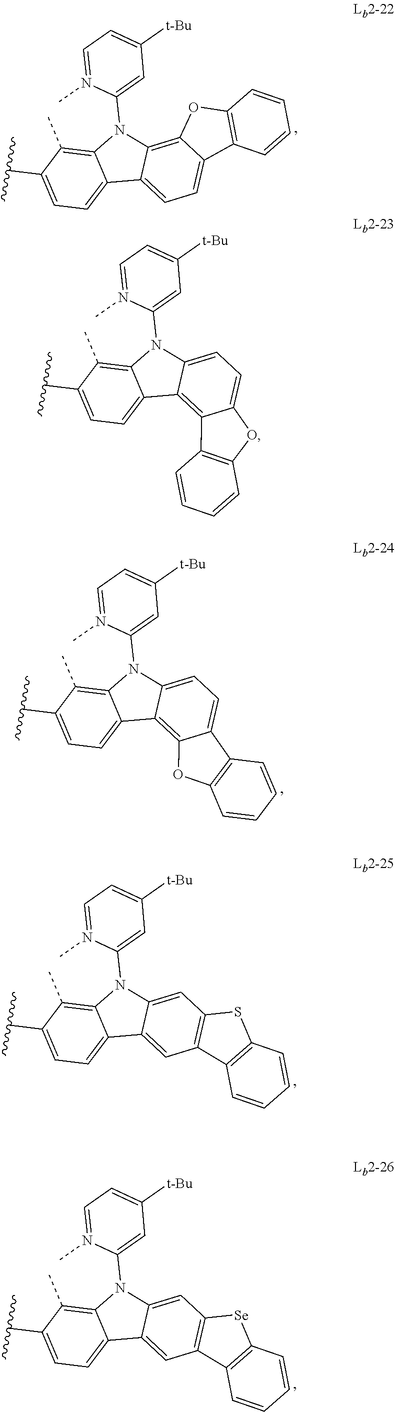 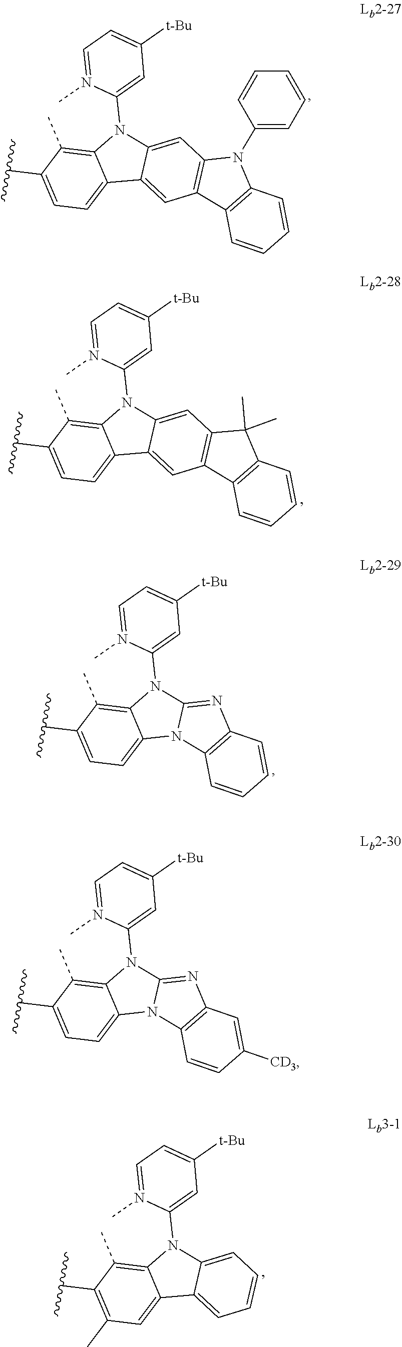 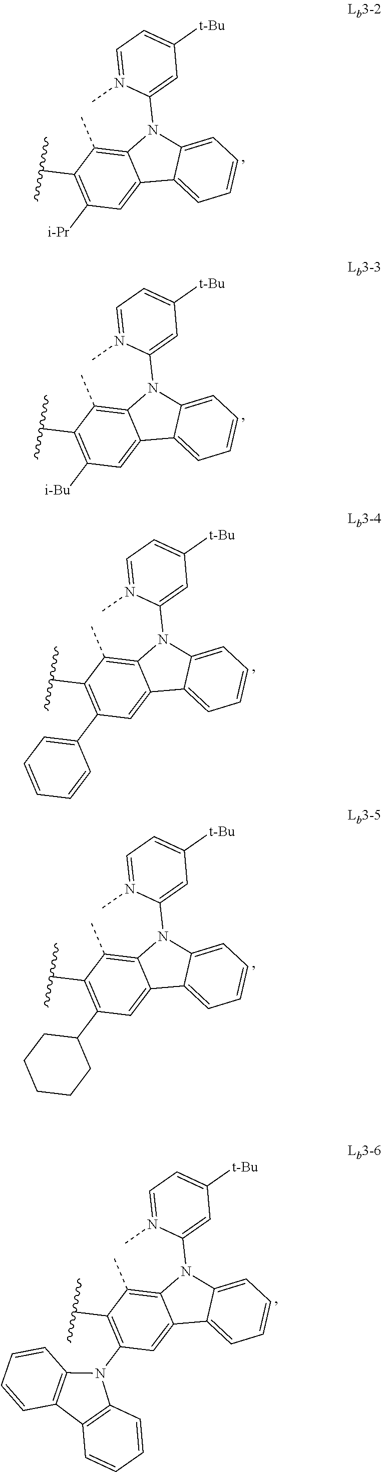 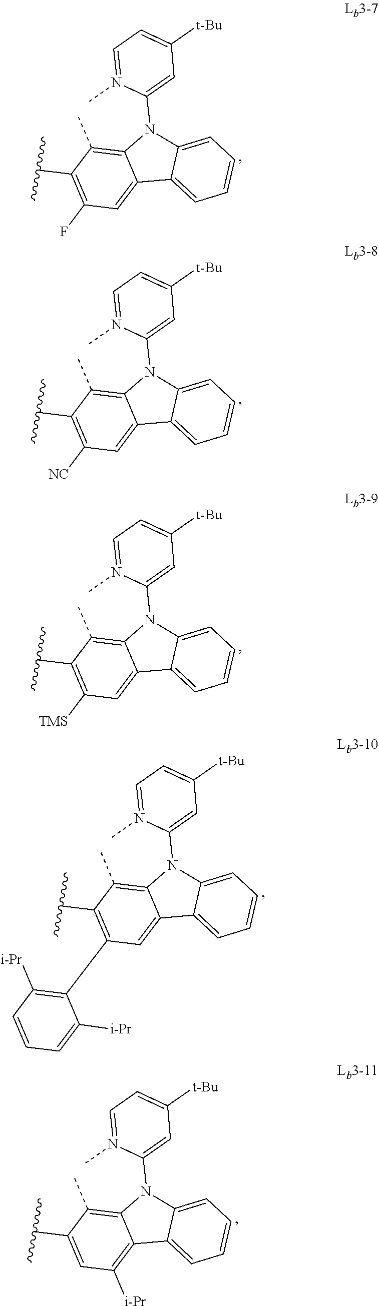 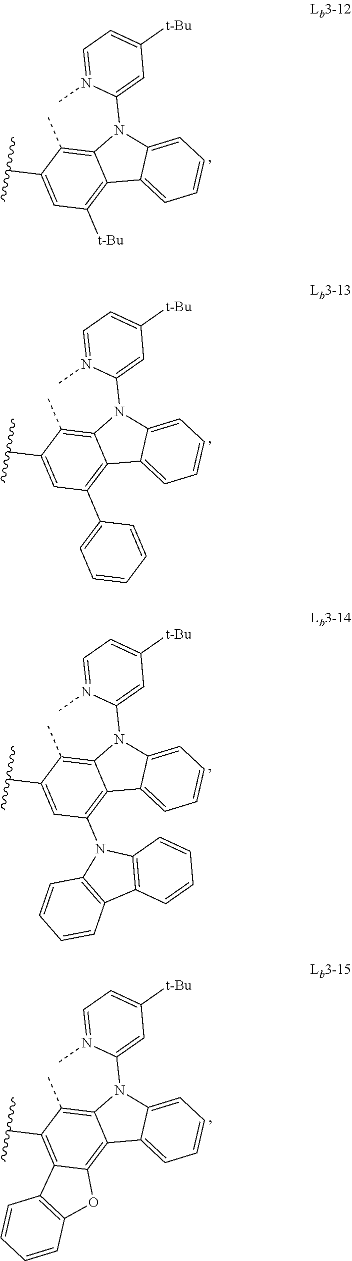 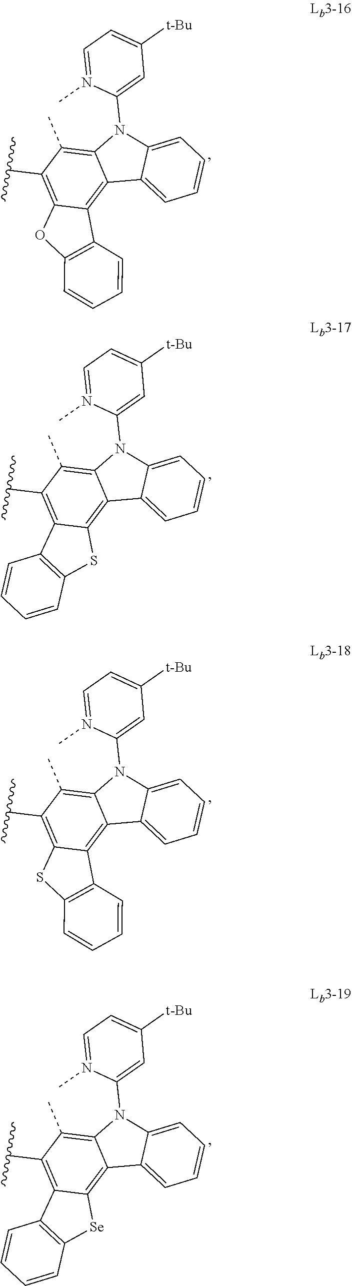 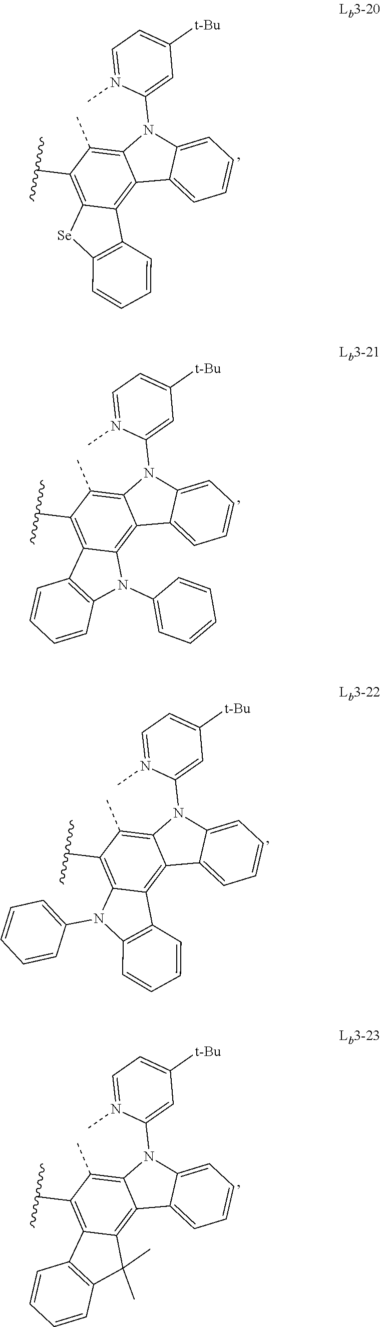 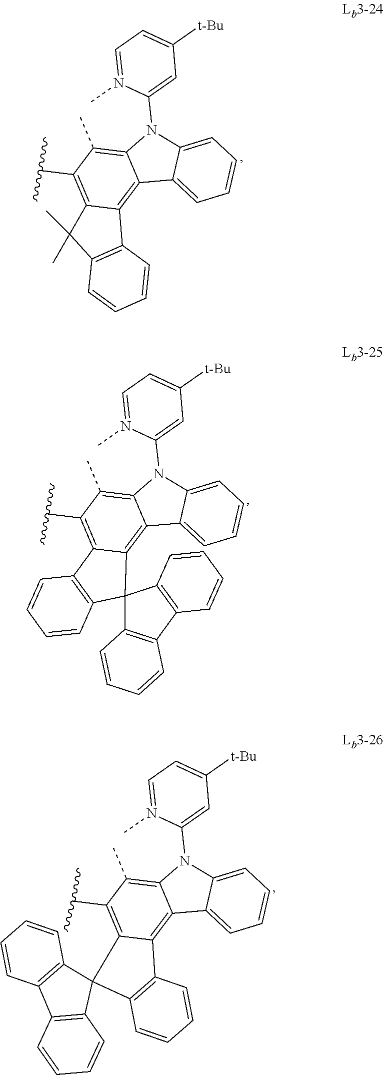 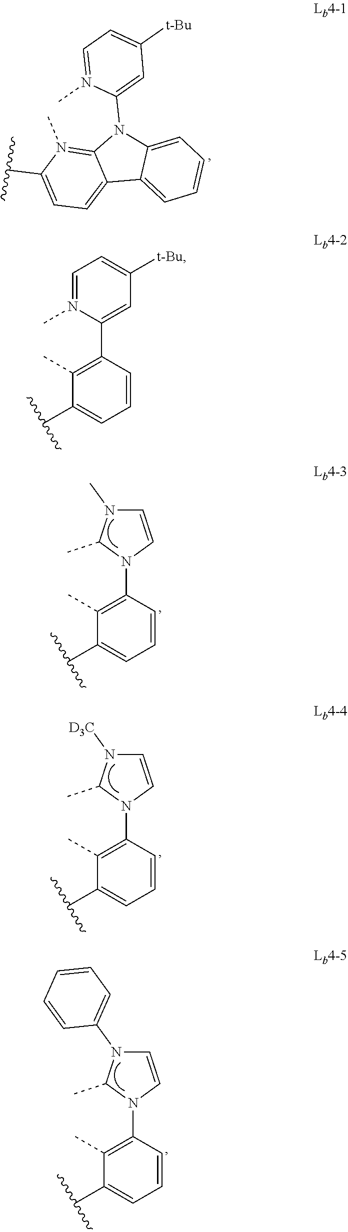 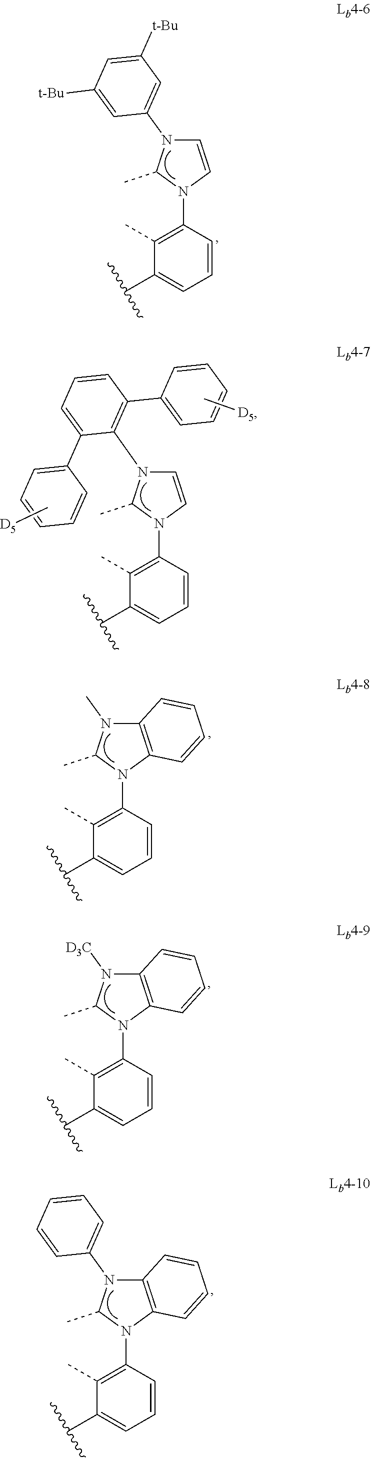 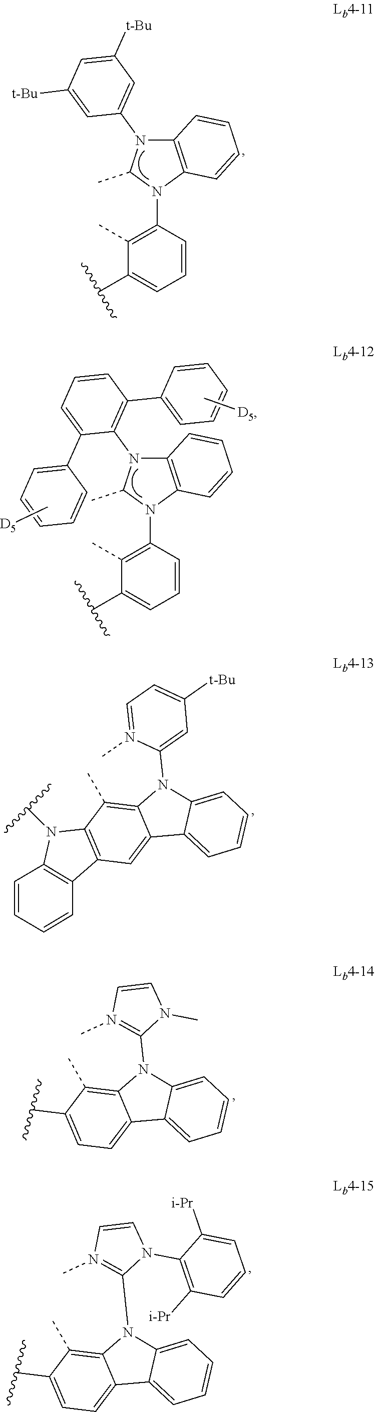 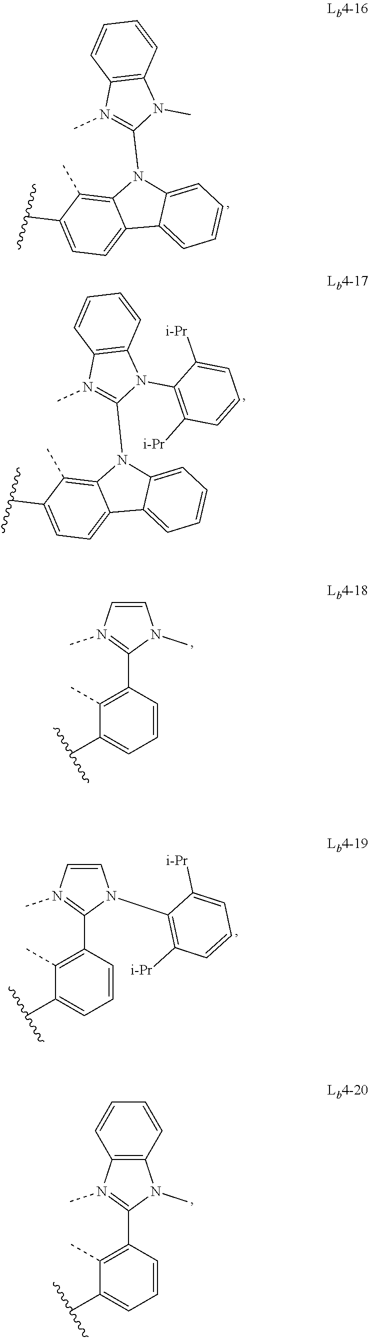 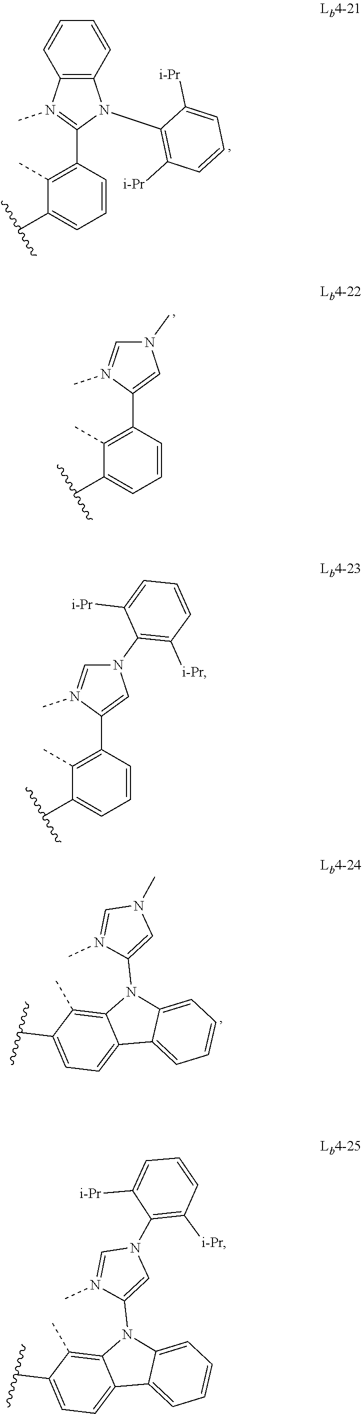 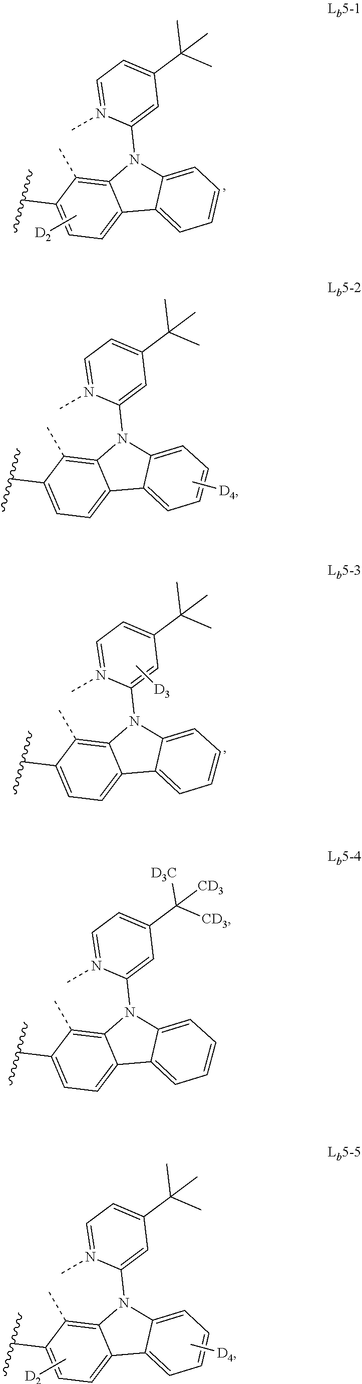 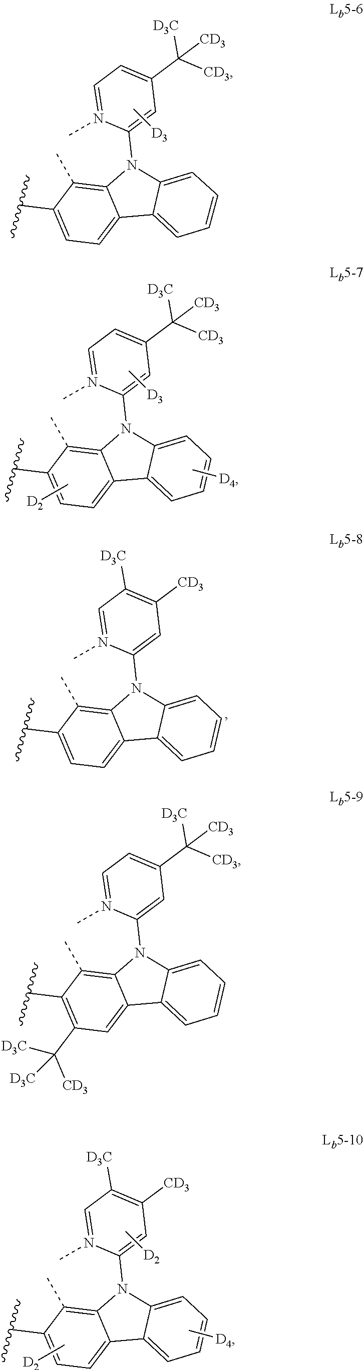 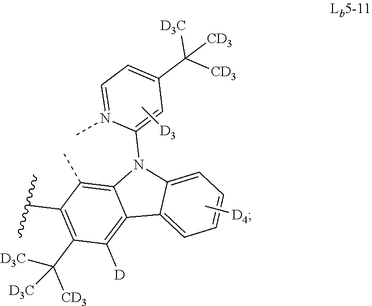
wherein in the structure of L_{b}, “t-Bu” represents t-butyl, “i-Pr” represents isopropyl, and “TMS” represents trimethylsilyl;
in the structure of L_{b}, “ [symbol] ” represents a position where the structure is joined to “#” in Lₐ;
preferably, the first compound is selected from the group consisting of Compound Pt1 to Compound Pt76, Compound Pt86 to Compound Pt180, Compound Pt182 to Compound Pt260, Compound Pt305 to Compound Pt680 and Compound Pd1 to Compound Pd24, wherein Compound Pt1 to Compound Pt76, Compound Pt86 to Compound Pt180, Compound Pt182 to Compound Pt260 and Compound Pt305 to Compound Pt680 each have a structure represented by Pt(Lₐ)(L_{b}), wherein Lₐ and L_{b} are selected from the structures shown in the following table, respectively:

| Compound | | | Compound | | |
|---|---|---|---|---|---|
| No. | Lₐ | L_{b} | No. | Lₐ | L_{b} |
| Pt1 | Lₐ1-1 | L_{b}1-3 | Pt2 | Lₐ1-2 | L_{b}1-3 |
| Pt3 | Lₐ1-3 | L_{b}1-3 | Pt4 | Lₐ1-4 | L_{b}1-3 |
| Pt5 | Lₐ1-5 | L_{b}1-3 | Pt6 | Lₐ1-6 | L_{b}1-3 |
| Pt7 | Lₐ1-7 | L_{b}1-3 | Pt8 | Lₐ1-8 | L_{b}1-3 |
| Pt9 | Lₐ1-9 | L_{b}1-3 | Pt10 | Lₐ1-10 | L_{b}1-3 |
| Pt11 | Lₐ1-11 | L_{b}1-3 | Pt12 | Lₐ1-12 | L_{b}1-3 |
| Pt13 | Lₐ1-13 | L_{b}1-3 | Pt14 | Lₐ1-14 | L_{b}1-3 |
| Pt15 | Lₐ1-15 | L_{b}1-3 | Pt16 | Lₐ1-16 | L_{b}1-3 |
| Pt17 | Lₐ1-17 | L_{b}1-3 | Pt18 | Lₐ1-18 | L_{b}1-3 |
| Pt19 | Lₐ1-19 | L_{b}1-3 | Pt20 | Lₐ1-20 | L_{b}1-3 |
| Pt21 | Lₐ1-21 | L_{b}1-3 | Pt22 | Lₐ1-22 | L_{b}1-3 |
| Pt23 | Lₐ1-23 | L_{b}1-3 | Pt24 | Lₐ1-24 | L_{b}1-3 |
| Pt25 | Lₐ1-25 | L_{b}1-3 | Pt26 | Lₐ1-26 | L_{b}1-3 |
| Pt27 | Lₐ1-27 | L_{b}1-3 | Pt28 | Lₐ1-28 | L_{b}1-3 |
| Pt29 | Lₐ1-29 | L_{b}1-3 | Pt30 | Lₐ1-30 | L_{b}1-3 |
| Pt31 | Lₐ1-31 | L_{b}1-3 | Pt32 | Lₐ1-32 | L_{b}1-3 |
| Pt33 | Lₐ1-33 | L_{b}1-3 | Pt34 | Lₐ1-34 | L_{b}1-3 |
| Pt35 | Lₐ1-35 | L_{b}1-3 | Pt36 | Lₐ1-36 | L_{b}1-3 |
| Pt37 | Lₐ1-37 | L_{b}1-3 | Pt38 | Lₐ1-38 | L_{b}1-3 |
| Pt39 | Lₐ1-39 | L_{b}1-3 | Pt40 | Lₐ1-40 | L_{b}1-3 |
| Pt41 | Lₐ1-41 | L_{b}1-3 | Pt42 | Lₐ1-42 | L_{b}1-3 |
| Pt43 | Lₐ1-43 | L_{b}1-3 | Pt44 | Lₐ1-44 | L_{b}1-3 |
| Pt45 | Lₐ1-45 | L_{b}1-3 | Pt46 | Lₐ1-46 | L_{b}1-3 |
| Pt47 | Lₐ1-47 | L_{b}1-3 | Pt48 | Lₐ1-48 | L_{b}1-3 |
| Pt49 | Lₐ1-49 | L_{b}1-3 | Pt50 | Lₐ1-50 | L_{b}1-3 |
| Pt51 | Lₐ1-51 | L_{b}1-3 | Pt52 | Lₐ1-52 | L_{b}1-3 |
| Pt53 | Lₐ1-53 | L_{b}1-3 | Pt54 | Lₐ1-54 | L_{b}1-3 |
| Pt55 | Lₐ1-55 | L_{b}1-3 | Pt56 | Lₐ1-56 | L_{b}1-3 |
| Pt57 | Lₐ1-57 | L_{b}1-3 | Pt58 | Lₐ1-58 | L_{b}1-3 |
| Pt59 | Lₐ1-59 | L_{b}1-3 | Pt60 | Lₐ1-60 | L_{b}1-3 |
| Pt61 | Lₐ1-61 | L_{b}1-3 | Pt62 | Lₐ1-62 | L_{b}1-3 |
| Pt63 | Lₐ1-63 | L_{b}1-3 | Pt64 | Lₐ1-64 | L_{b}1-3 |
| Pt65 | Lₐ1-65 | L_{b}1-3 | Pt66 | Lₐ1-66 | L_{b}1-3 |
| Pt67 | Lₐ1-67 | L_{b}1-3 | Pt68 | Lₐ1-68 | L_{b}1-3 |
| Pt69 | Lₐ1-69 | L_{b}1-3 | Pt70 | Lₐ1-70 | L_{b}1-3 |
| Pt71 | Lₐ1-71 | L_{b}1-3 | Pt72 | Lₐ1-72 | L_{b}1-3 |
| Pt73 | Lₐ1-73 | L_{b}1-3 | Pt74 | Lₐ1-74 | L_{b}1-3 |
| Pt75 | Lₐ1-75 | L_{b}1-3 | Pt76 | Lₐ1-76 | L_{b}1-3 |
| | | | Pt86 | Lₐ2-1 | L_{b}1-3 |
| Pt87 | Lₐ2-2 | L_{b}1-3 | Pt88 | Lₐ2-3 | L_{b}1-3 |
| Pt89 | Lₐ2-4 | L_{b}1-3 | Pt90 | Lₐ2-5 | L_{b}1-3 |
| Pt91 | Lₐ2-6 | L_{b}1-3 | Pt92 | Lₐ2-7 | L_{b}1-3 |
| Pt93 | Lₐ2-8 | L_{b}1-3 | Pt94 | Lₐ2-9 | L_{b}1-3 |
| Pt95 | Lₐ2-10 | L_{b}1-3 | Pt96 | Lₐ2-11 | L_{b}1-3 |
| Pt97 | Lₐ2-12 | L_{b}1-3 | Pt98 | Lₐ2-13 | L_{b}1-3 |
| Pt99 | Lₐ2-14 | L_{b}1-3 | Pt100 | Lₐ2-15 | L_{b}1-3 |
| Pt101 | Lₐ2-16 | L_{b}1-3 | Pt102 | Lₐ2-17 | L_{b}1-3 |
| Pt103 | Lₐ2-18 | L_{b}1-3 | Pt104 | Lₐ2-19 | L_{b}1-3 |
| Pt105 | Lₐ2-20 | L_{b}1-3 | Pt106 | Lₐ2-21 | L_{b}1-3 |
| Pt107 | Lₐ2-22 | L_{b}1-3 | Pt108 | Lₐ2-23 | L_{b}1-3 |
| Pt109 | Lₐ2-24 | L_{b}1-3 | Pt110 | Lₐ2-25 | L_{b}1-3 |
| Pt111 | Lₐ2-26 | L_{b}1-3 | Pt112 | Lₐ2-27 | L_{b}1-3 |
| Pt113 | Lₐ2-28 | L_{b}1-3 | Pt114 | Lₐ2-29 | L_{b}1-3 |
| Pt115 | Lₐ2-30 | L_{b}1-3 | Pt116 | Lₐ2-31 | L_{b}1-3 |
| Pt117 | Lₐ2-32 | L_{b}1-3 | Pt118 | Lₐ2-33 | L_{b}1-3 |
| Pt119 | Lₐ2-34 | L_{b}1-3 | Pt120 | Lₐ2-35 | L_{b}1-3 |
| Pt121 | Lₐ2-36 | L_{b}1-3 | Pt122 | Lₐ2-37 | L_{b}1-3 |
| Pt123 | Lₐ2-38 | L_{b}1-3 | Pt124 | Lₐ2-39 | L_{b}1-3 |
| Pt125 | Lₐ2-40 | L_{b}1-3 | Pt126 | Lₐ2-41 | L_{b}1-3 |
| Pt127 | Lₐ2-42 | L_{b}1-3 | Pt128 | Lₐ3-1 | L_{b}1-3 |
| Pt129 | Lₐ3-2 | L_{b}1-3 | Pt130 | Lₐ3-3 | L_{b}1-3 |
| Pt131 | Lₐ3-4 | L_{b}1-3 | Pt132 | Lₐ3-5 | L_{b}1-3 |
| Pt133 | Lₐ3-6 | L_{b}1-3 | Pt134 | Lₐ3-7 | L_{b}1-3 |
| Pt135 | Lₐ3-8 | L_{b}1-3 | Pt136 | Lₐ3-9 | L_{b}1-3 |
| Pt137 | Lₐ3-10 | L_{b}1-3 | Pt138 | Lₐ3-11 | L_{b}1-3 |
| Pt139 | Lₐ3-12 | L_{b}1-3 | Pt140 | Lₐ3-13 | L_{b}1-3 |
| Pt141 | Lₐ3-14 | L_{b}1-3 | Pt142 | Lₐ3-15 | L_{b}1-3 |
| Pt143 | Lₐ3-16 | L_{b}1-3 | Pt144 | Lₐ3-17 | L_{b}1-3 |
| Pt145 | Lₐ3-18 | L_{b}1-3 | Pt146 | Lₐ3-19 | L_{b}1-3 |
| Pt147 | Lₐ3-20 | L_{b}1-3 | Pt148 | Lₐ3-21 | L_{b}1-3 |
| Pt149 | Lₐ3-22 | L_{b}1-3 | Pt150 | Lₐ3-23 | L_{b}1-3 |
| Pt151 | Lₐ3-24 | L_{b}1-3 | Pt152 | Lₐ3-25 | L_{b}1-3 |
| Pt153 | Lₐ3-26 | L_{b}1-3 | Pt154 | Lₐ3-27 | L_{b}1-3 |
| Pt155 | Lₐ3-28 | L_{b}1-3 | Pt156 | Lₐ3-29 | L_{b}1-3 |
| Pt157 | Lₐ3-30 | L_{b}1-3 | Pt158 | Lₐ3-31 | L_{b}1-3 |
| Pt159 | Lₐ3-32 | L_{b}1-3 | Pt160 | Lₐ3-33 | L_{b}1-3 |
| Pt161 | Lₐ3-34 | L_{b}1-3 | Pt162 | Lₐ3-35 | L_{b}1-3 |
| Pt163 | Lₐ3-36 | L_{b}1-3 | Pt164 | Lₐ4-1 | L_{b}1-3 |
| Pt165 | Lₐ4-2 | L_{b}1-3 | Pt166 | Lₐ4-3 | L_{b}1-3 |
| Pt167 | Lₐ4-4 | L_{b}1-3 | Pt168 | Lₐ4-5 | L_{b}1-3 |
| Pt169 | Lₐ4-6 | L_{b}1-3 | Pt170 | Lₐ4-7 | L_{b}1-3 |
| Pt171 | Lₐ4-8 | L_{b}1-3 | Pt172 | Lₐ4-9 | L_{b}1-3 |
| Pt173 | Lₐ4-10 | L_{b}1-3 | Pt174 | Lₐ4-11 | L_{b}1-3 |
| Pt175 | Lₐ4-12 | L_{b}1-3 | Pt176 | Lₐ4-13 | L_{b}1-3 |
| Pt177 | Lₐ4-14 | L_{b}1-3 | Pt178 | Lₐ4-15 | L_{b}1-3 |
| Pt179 | Lₐ4-16 | L_{b}1-3 | Pt180 | Lₐ4-17 | L_{b}1-3 |
| | | | Pt182 | Lₐ4-19 | L_{b}1-3 |
| Pt183 | Lₐ4-20 | L_{b}1-3 | Pt184 | Lₐ4-21 | L_{b}1-3 |
| Pt185 | Lₐ4-22 | L_{b}1-3 | Pt186 | Lₐ4-23 | L_{b}1-3 |
| Pt187 | Lₐ4-24 | L_{b}1-3 | Pt188 | Lₐ4-25 | L_{b}1-3 |
| Pt189 | Lₐ4-26 | L_{b}1-3 | Pt190 | Lₐ4-27 | L_{b}1-3 |
| Pt191 | Lₐ4-28 | L_{b}1-3 | Pt192 | Lₐ4-29 | L_{b}1-3 |
| Pt193 | Lₐ4-30 | L_{b}1-3 | Pt194 | Lₐ4-31 | L_{b}1-3 |
| Pt195 | Lₐ4-32 | L_{b}1-3 | Pt196 | Lₐ4-33 | L_{b}1-3 |
| Pt197 | Lₐ4-34 | L_{b}1-3 | Pt198 | Lₐ4-35 | L_{b}1-3 |
| Pt199 | Lₐ4-36 | L_{b}1-3 | Pt200 | Lₐ4-37 | L_{b}1-3 |
| Pt201 | Lₐ4-38 | L_{b}1-3 | Pt202 | Lₐ4-39 | L_{b}1-3 |
| Pt203 | Lₐ4-40 | L_{b}1-3 | Pt204 | Lₐ4-41 | L_{b}1-3 |
| Pt205 | Lₐ4-42 | L_{b}1-3 | Pt206 | Lₐ4-43 | L_{b}1-3 |
| Pt207 | Lₐ4-44 | L_{b}1-3 | Pt208 | Lₐ4-45 | L_{b}1-3 |
| Pt209 | Lₐ4-46 | L_{b}1-3 | Pt210 | Lₐ4-47 | L_{b}1-3 |
| Pt211 | Lₐ4-48 | L_{b}1-3 | Pt212 | Lₐ4-49 | L_{b}1-3 |
| Pt213 | Lₐ4-50 | L_{b}1-3 | Pt214 | Lₐ4-51 | L_{b}1-3 |
| Pt215 | Lₐ4-52 | L_{b}1-3 | Pt216 | Lₐ4-53 | L_{b}1-3 |
| Pt217 | Lₐ1-16 | L_{b}1-5 | Pt218 | Lₐ1-35 | L_{b}1-5 |
| Pt219 | Lₐ1-37 | L_{b}1-5 | Pt220 | Lₐ1-39 | L_{b}1-5 |
| Pt221 | Lₐ1-43 | L_{b}1-5 | Pt222 | Lₐ1-44 | L_{b}1-5 |
| Pt223 | Lₐ1-48 | L_{b}1-5 | Pt224 | Lₐ1-51 | L_{b}1-5 |
| Pt225 | Lₐ1-55 | L_{b}1-5 | Pt226 | Lₐ1-59 | L_{b}1-5 |
| Pt227 | Lₐ1-65 | L_{b}1-5 | Pt228 | Lₐ2-1 | L_{b}1-5 |
| Pt229 | Lₐ2-2 | L_{b}1-5 | Pt230 | Lₐ2-8 | L_{b}1-5 |
| Pt231 | Lₐ2-10 | L_{b}1-5 | Pt232 | Lₐ2-14 | L_{b}1-5 |
| Pt233 | Lₐ2-16 | L_{b}1-5 | Pt234 | Lₐ2-20 | L_{b}1-5 |
| Pt235 | Lₐ2-23 | L_{b}1-5 | Pt236 | Lₐ2-26 | L_{b}1-5 |
| Pt237 | Lₐ2-32 | L_{b}1-5 | Pt238 | Lₐ2-34 | L_{b}1-5 |
| Pt239 | Lₐ2-38 | L_{b}1-5 | Pt240 | Lₐ2-41 | L_{b}1-5 |
| Pt241 | Lₐ3-2 | L_{b}1-5 | Pt242 | Lₐ3-6 | L_{b}1-5 |
| Pt243 | Lₐ3-10 | L_{b}1-5 | Pt244 | Lₐ3-14 | L_{b}1-5 |
| Pt245 | Lₐ3-18 | L_{b}1-5 | Pt246 | Lₐ3-22 | L_{b}1-5 |
| Pt247 | Lₐ3-24 | L_{b}1-5 | Pt248 | Lₐ4-2 | L_{b}1-5 |
| Pt249 | Lₐ4-6 | L_{b}1-5 | Pt250 | Lₐ4-10 | L_{b}1-5 |
| Pt251 | Lₐ4-12 | L_{b}1-5 | Pt252 | Lₐ4-30 | L_{b}1-5 |
| Pt253 | Lₐ4-31 | L_{b}1-5 | Pt254 | Lₐ4-32 | L_{b}1-5 |
| Pt255 | Lₐ4-33 | L_{b}1-5 | Pt256 | Lₐ4-38 | L_{b}1-5 |
| Pt257 | Lₐ4-39 | L_{b}1-5 | Pt258 | Lₐ4-43 | L_{b}1-5 |
| Pt259 | Lₐ4-47 | L_{b}1-5 | Pt260 | Lₐ4-49 | L_{b}1-5 |
| Pt305 | Lₐ1-16 | L_{b}2-9 | Pt306 | Lₐ1-35 | L_{b}2-9 |
| Pt307 | Lₐ1-37 | L_{b}2-9 | Pt308 | Lₐ1-39 | L_{b}2-9 |
| Pt309 | Lₐ1-43 | L_{b}2-9 | Pt310 | Lₐ1-44 | L_{b}2-9 |
| Pt311 | Lₐ1-48 | L_{b}2-9 | Pt312 | Lₐ1-51 | L_{b}2-9 |
| Pt313 | Lₐ1-55 | L_{b}2-9 | Pt314 | Lₐ1-59 | L_{b}2-9 |
| Pt315 | Lₐ1-63 | L_{b}2-9 | Pt316 | Lₐ2-1 | L_{b}2-9 |
| Pt317 | Lₐ2-2 | L_{b}2-9 | Pt318 | Lₐ2-8 | L_{b}2-9 |
| Pt319 | Lₐ2-10 | L_{b}2-9 | Pt320 | Lₐ2-14 | L_{b}2-9 |
| Pt321 | Lₐ2-16 | L_{b}2-9 | Pt322 | Lₐ2-20 | L_{b}2-9 |
| Pt323 | Lₐ2-23 | L_{b}1-9 | Pt324 | Lₐ2-26 | L_{b}1-9 |
| Pt325 | Lₐ2-32 | L_{b}2-9 | Pt326 | Lₐ2-34 | L_{b}2-9 |
| Pt327 | Lₐ2-38 | L_{b}2-9 | Pt328 | Lₐ2-41 | L_{b}2-9 |
| Pt329 | Lₐ3-2 | L_{b}2-9 | Pt330 | Lₐ3-6 | L_{b}2-9 |
| Pt331 | Lₐ3-10 | L_{b}2-9 | Pt332 | Lₐ3-14 | L_{b}2-9 |
| Pt333 | Lₐ3-18 | L_{b}2-9 | Pt334 | Lₐ3-22 | L_{b}2-9 |
| Pt335 | Lₐ3-24 | L_{b}2-9 | Pt336 | Lₐ4-2 | L_{b}2-9 |
| Pt337 | Lₐ4-6 | L_{b}2-9 | Pt338 | Lₐ4-10 | L_{b}2-9 |
| Pt339 | Lₐ4-12 | L_{b}2-9 | Pt340 | Lₐ4-30 | L_{b}2-9 |
| Pt341 | Lₐ4-31 | L_{b}2-9 | Pt342 | Lₐ4-32 | L_{b}2-9 |
| Pt343 | Lₐ4-33 | L_{b}2-9 | Pt344 | Lₐ4-38 | L_{b}2-9 |
| Pt345 | Lₐ4-39 | L_{b}2-9 | Pt346 | Lₐ4-43 | L_{b}2-9 |
| Pt347 | Lₐ4-47 | L_{b}2-9 | Pt348 | Lₐ4-49 | L_{b}2-9 |
| Pt349 | Lₐ1-16 | L_{b}2-13 | Pt350 | Lₐ1-35 | L_{b}2-13 |
| Pt351 | Lₐ1-37 | L_{b}2-13 | Pt352 | Lₐ1-39 | L_{b}2-13 |
| Pt353 | Lₐ1-43 | L_{b}2-13 | Pt354 | Lₐ1-44 | L_{b}2-13 |
| Pt355 | Lₐ1-48 | L_{b}2-13 | Pt356 | Lₐ1-51 | L_{b}2-13 |
| Pt357 | Lₐ1-55 | L_{b}2-13 | Pt358 | Lₐ1-59 | L_{b}2-13 |
| Pt359 | Lₐ1-65 | L_{b}2-13 | Pt360 | Lₐ2-1 | L_{b}2-13 |
| Pt361 | Lₐ2-2 | L_{b}2-13 | Pt362 | Lₐ2-8 | L_{b}2-13 |
| Pt363 | Lₐ2-10 | L_{b}2-13 | Pt364 | Lₐ2-14 | L_{b}2-13 |
| Pt365 | Lₐ2-16 | L_{b}2-13 | Pt366 | Lₐ2-20 | L_{b}2-13 |
| Pt367 | Lₐ2-23 | L_{b}2-13 | Pt368 | Lₐ2-26 | L_{b}2-13 |
| Pt369 | Lₐ2-32 | L_{b}2-13 | Pt370 | Lₐ2-34 | L_{b}2-13 |
| Pt371 | Lₐ2-38 | L_{b}2-13 | Pt372 | Lₐ2-41 | L_{b}2-13 |
| Pt373 | Lₐ3-2 | L_{b}2-13 | Pt374 | Lₐ3-6 | L_{b}2-13 |
| Pt375 | Lₐ3-10 | L_{b}2-13 | Pt376 | Lₐ3-14 | L_{b}2-13 |
| Pt377 | Lₐ3-18 | L_{b}2-13 | Pt378 | Lₐ3-22 | L_{b}2-13 |
| Pt379 | Lₐ3-24 | L_{b}2-13 | Pt380 | Lₐ4-2 | L_{b}2-13 |
| Pt381 | Lₐ4-6 | L_{b}2-13 | Pt382 | Lₐ4-10 | L_{b}2-13 |
| Pt383 | Lₐ4-12 | L_{b}2-13 | Pt384 | Lₐ4-30 | L_{b}2-13 |
| Pt385 | Lₐ4-31 | L_{b}2-13 | Pt386 | Lₐ4-32 | L_{b}2-13 |
| Pt387 | Lₐ4-33 | L_{b}2-13 | Pt388 | Lₐ4-38 | L_{b}2-13 |
| Pt389 | Lₐ4-39 | L_{b}2-13 | Pt390 | Lₐ4-43 | L_{b}2-13 |
| Pt391 | Lₐ4-47 | L_{b}2-13 | Pt392 | Lₐ4-49 | L_{b}2-13 |
| Pt393 | Lₐ1-16 | L_{b}2-29 | Pt394 | Lₐ1-35 | L_{b}2-29 |
| Pt395 | Lₐ1-37 | L_{b}2-29 | Pt396 | Lₐ1-39 | L_{b}2-29 |
| Pt397 | Lₐ1-43 | L_{b}2-29 | Pt398 | Lₐ1-44 | L_{b}2-29 |
| Pt399 | Lₐ1-48 | L_{b}2-29 | Pt400 | Lₐ1-51 | L_{b}2-29 |
| Pt401 | Lₐ1-55 | L_{b}2-29 | Pt402 | Lₐ1-59 | L_{b}2-29 |
| Pt403 | Lₐ1-65 | L_{b}2-29 | Pt404 | Lₐ2-1 | L_{b}2-29 |
| Pt405 | Lₐ2-2 | L_{b}2-29 | Pt406 | Lₐ2-8 | L_{b}2-29 |
| Pt407 | Lₐ2-10 | L_{b}2-29 | Pt408 | Lₐ2-14 | L_{b}2-29 |
| Pt409 | Lₐ2-16 | L_{b}2-29 | Pt410 | Lₐ2-20 | L_{b}2-29 |
| Pt411 | Lₐ2-23 | L_{b}2-29 | Pt412 | Lₐ2-26 | L_{b}2-29 |
| Pt413 | Lₐ2-32 | L_{b}2-29 | Pt414 | Lₐ2-34 | L_{b}2-29 |
| Pt415 | Lₐ2-38 | L_{b}2-29 | Pt416 | Lₐ2-41 | L_{b}2-29 |
| Pt417 | Lₐ3-2 | L_{b}2-29 | Pt418 | Lₐ3-6 | L_{b}2-29 |
| Pt419 | Lₐ3-10 | L_{b}2-29 | Pt420 | Lₐ3-14 | L_{b}2-29 |
| Pt421 | Lₐ3-18 | L_{b}2-29 | Pt422 | Lₐ3-22 | L_{b}2-29 |
| Pt423 | Lₐ3-24 | L_{b}2-29 | Pt424 | Lₐ4-2 | L_{b}2-29 |
| Pt425 | Lₐ4-6 | L_{b}2-29 | Pt426 | Lₐ4-10 | L_{b}2-29 |
| Pt427 | Lₐ4-12 | L_{b}2-29 | Pt428 | Lₐ4-30 | L_{b}2-29 |
| Pt429 | Lₐ4-31 | L_{b}2-29 | Pt430 | Lₐ4-32 | L_{b}2-29 |
| Pt431 | Lₐ4-33 | L_{b}2-29 | Pt432 | Lₐ4-38 | L_{b}2-29 |
| Pt433 | Lₐ4-39 | L_{b}2-29 | Pt434 | Lₐ4-43 | L_{b}2-29 |
| Pt435 | Lₐ4-47 | L_{b}2-29 | Pt436 | Lₐ4-49 | L_{b}2-29 |
| Pt437 | Lₐ1-16 | L_{b}3-3 | Pt438 | Lₐ1-35 | L_{b}3-3 |
| Pt439 | Lₐ1-37 | L_{b}3-3 | Pt440 | Lₐ1-39 | L_{b}3-3 |
| Pt441 | Lₐ1-43 | L_{b}3-3 | Pt442 | Lₐ1-44 | L_{b}3-3 |
| Pt443 | Lₐ1-48 | L_{b}3-3 | Pt444 | Lₐ1-51 | L_{b}3-3 |
| Pt445 | Lₐ1-55 | L_{b}3-3 | Pt446 | Lₐ1-59 | L_{b}3-3 |
| Pt447 | Lₐ1-63 | L_{b}3-3 | Pt448 | Lₐ2-1 | L_{b}3-3 |
| Pt449 | Lₐ2-2 | L_{b}3-3 | Pt450 | Lₐ2-8 | L_{b}3-3 |
| Pt451 | Lₐ2-10 | L_{b}3-3 | Pt452 | Lₐ2-14 | L_{b}3-3 |
| Pt453 | Lₐ2-16 | L_{b}3-3 | Pt454 | Lₐ2-20 | L_{b}3-3 |
| Pt455 | Lₐ2-23 | L_{b}3-3 | Pt456 | Lₐ2-26 | L_{b}3-3 |
| Pt457 | Lₐ2-32 | L_{b}3-3 | Pt458 | Lₐ2-34 | L_{b}3-3 |
| Pt459 | Lₐ2-38 | L_{b}3-3 | Pt460 | Lₐ2-41 | L_{b}3-3 |
| Pt461 | Lₐ3-2 | L_{b}3-3 | Pt462 | Lₐ3-6 | L_{b}3-3 |
| Pt463 | Lₐ3-10 | L_{b}3-3 | Pt464 | Lₐ3-14 | L_{b}3-3 |
| Pt465 | Lₐ3-18 | L_{b}3-3 | Pt466 | Lₐ3-22 | L_{b}3-3 |
| Pt467 | Lₐ3-24 | L_{b}3-3 | Pt468 | Lₐ4-2 | L_{b}3-3 |
| Pt469 | Lₐ4-6 | L_{b}3-3 | Pt470 | Lₐ4-10 | L_{b}3-3 |
| Pt471 | Lₐ4-12 | L_{b}3-3 | Pt472 | Lₐ4-30 | L_{b}3-3 |
| Pt473 | Lₐ4-31 | L_{b}3-3 | Pt474 | Lₐ4-32 | L_{b}3-3 |
| Pt475 | Lₐ4-33 | L_{b}3-3 | Pt476 | Lₐ4-38 | L_{b}3-3 |
| Pt477 | Lₐ4-39 | L_{b}3-3 | Pt478 | Lₐ4-43 | L_{b}3-3 |
| Pt479 | Lₐ4-47 | L_{b}3-3 | Pt480 | Lₐ4-49 | L_{b}3-3 |
| Pt481 | Lₐ1-16 | L_{b}3-6 | Pt482 | Lₐ1-35 | L_{b}3-6 |
| Pt483 | Lₐ1-37 | L_{b}3-6 | Pt484 | Lₐ1-39 | L_{b}3-6 |
| Pt485 | Lₐ1-43 | L_{b}3-6 | Pt486 | Lₐ1-44 | L_{b}3-6 |
| Pt487 | Lₐ1-48 | L_{b}3-6 | Pt488 | Lₐ1-51 | L_{b}3-6 |
| Pt489 | Lₐ1-55 | L_{b}3-6 | Pt490 | Lₐ1-59 | L_{b}3-6 |
| Pt491 | Lₐ1-65 | L_{b}3-6 | Pt492 | Lₐ2-1 | L_{b}3-6 |
| Pt493 | Lₐ2-2 | L_{b}3-6 | Pt494 | Lₐ2-8 | L_{b}3-6 |
| Pt495 | Lₐ2-10 | L_{b}3-6 | Pt496 | Lₐ2-14 | L_{b}3-6 |
| Pt497 | Lₐ2-16 | L_{b}3-6 | Pt498 | Lₐ2-20 | L_{b}3-6 |
| Pt499 | Lₐ2-23 | L_{b}3-6 | Pt500 | Lₐ2-26 | L_{b}3-6 |
| Pt501 | Lₐ2-32 | L_{b}3-6 | Pt502 | Lₐ2-34 | L_{b}3-6 |
| Pt503 | Lₐ2-38 | L_{b}3-6 | Pt504 | Lₐ2-41 | L_{b}3-6 |
| Pt505 | Lₐ3-2 | L_{b}3-6 | Pt506 | Lₐ3-6 | L_{b}3-6 |
| Pt507 | Lₐ3-10 | L_{b}3-6 | Pt508 | Lₐ3-14 | L_{b}3-6 |
| Pt509 | Lₐ3-18 | L_{b}3-6 | Pt510 | Lₐ3-22 | L_{b}3-6 |
| Pt511 | Lₐ3-24 | L_{b}3-6 | Pt512 | Lₐ4-2 | L_{b}3-6 |
| Pt513 | Lₐ4-6 | L_{b}3-6 | Pt514 | Lₐ4-10 | L_{b}3-6 |
| Pt515 | Lₐ4-12 | L_{b}3-6 | Pt516 | Lₐ4-30 | L_{b}3-6 |
| Pt517 | Lₐ4-31 | L_{b}3-6 | Pt518 | Lₐ4-32 | L_{b}3-6 |
| Pt519 | Lₐ4-33 | L_{b}3-6 | Pt520 | Lₐ4-38 | L_{b}3-6 |
| Pt521 | Lₐ4-39 | L_{b}3-6 | Pt522 | Lₐ4-43 | L_{b}3-6 |
| Pt523 | Lₐ4-47 | L_{b}3-6 | Pt524 | Lₐ4-49 | L_{b}3-6 |
| Pt525 | Lₐ1-16 | L_{b}4-11 | Pt526 | Lₐ1-35 | L_{b}4-11 |
| Pt527 | Lₐ1-37 | L_{b}4-11 | Pt528 | Lₐ1-39 | L_{b}4-11 |
| Pt529 | Lₐ1-43 | L_{b}4-11 | Pt530 | Lₐ1-44 | L_{b}4-11 |
| Pt531 | Lₐ1-48 | L_{b}4-11 | Pt532 | Lₐ1-51 | L_{b}4-11 |
| Pt533 | Lₐ1-55 | L_{b}4-11 | Pt534 | Lₐ1-59 | L_{b}4-11 |
| Pt535 | Lₐ1-65 | L_{b}4-11 | Pt536 | Lₐ2-1 | L_{b}4-11 |
| Pt537 | Lₐ2-2 | L_{b}4-11 | Pt538 | Lₐ2-8 | L_{b}4-11 |
| Pt539 | Lₐ2-10 | L_{b}4-11 | Pt540 | Lₐ2-14 | L_{b}4-11 |
| Pt541 | Lₐ2-16 | L_{b}4-11 | Pt542 | Lₐ2-20 | L_{b}4-11 |
| Pt543 | Lₐ2-23 | L_{b}4-11 | Pt544 | Lₐ2-26 | L_{b}4-11 |
| Pt545 | Lₐ2-32 | L_{b}4-11 | Pt546 | Lₐ2-34 | L_{b}4-11 |
| Pt547 | Lₐ2-38 | L_{b}4-11 | Pt548 | Lₐ2-41 | L_{b}4-11 |
| Pt549 | Lₐ3-2 | L_{b}4-11 | Pt550 | Lₐ3-6 | L_{b}4-11 |
| Pt551 | Lₐ3-10 | L_{b}4-11 | Pt552 | Lₐ3-14 | L_{b}4-11 |
| Pt553 | Lₐ3-18 | L_{b}4-11 | Pt554 | Lₐ3-22 | L_{b}4-11 |
| Pt555 | Lₐ3-24 | L_{b}4-11 | Pt556 | Lₐ4-2 | L_{b}4-11 |
| Pt557 | Lₐ4-6 | L_{b}4-11 | Pt558 | Lₐ4-10 | L_{b}4-11 |
| Pt559 | Lₐ4-12 | L_{b}4-11 | Pt560 | Lₐ4-30 | L_{b}4-11 |
| Pt561 | Lₐ4-31 | L_{b}4-11 | Pt562 | Lₐ4-32 | L_{b}4-11 |
| Pt563 | Lₐ4-33 | L_{b}4-11 | Pt564 | Lₐ4-38 | L_{b}4-11 |
| Pt565 | Lₐ4-39 | L_{b}4-11 | Pt566 | Lₐ4-43 | L_{b}4-11 |
| Pt567 | Lₐ4-47 | L_{b}4-11 | Pt568 | Lₐ4-49 | L_{b}4-11 |
| Pt569 | Lₐ1-16 | L_{b}5-5 | Pt570 | Lₐ1-35 | L_{b}5-5 |
| Pt571 | Lₐ1-37 | L_{b}5-5 | Pt572 | Lₐ1-39 | L_{b}5-5 |
| Pt573 | Lₐ1-43 | L_{b}5-5 | Pt574 | Lₐ1-44 | L_{b}5-5 |
| Pt575 | Lₐ1-48 | L_{b}5-5 | Pt576 | Lₐ1-51 | L_{b}5-5 |
| Pt577 | Lₐ1-55 | L_{b}5-5 | Pt578 | Lₐ1-59 | L_{b}5-5 |
| Pt579 | Lₐ1-65 | L_{b}5-5 | Pt580 | Lₐ2-1 | L_{b}5-5 |
| Pt581 | Lₐ2-2 | L_{b}5-5 | Pt582 | Lₐ2-8 | L_{b}5-5 |
| Pt583 | Lₐ2-10 | L_{b}5-5 | Pt584 | Lₐ2-14 | L_{b}5-5 |
| Pt585 | Lₐ2-16 | L_{b}5-5 | Pt586 | Lₐ2-20 | L_{b}5-5 |
| Pt587 | Lₐ2-23 | L_{b}5-5 | Pt588 | Lₐ2-26 | L_{b}5-5 |
| Pt589 | Lₐ2-32 | L_{b}5-5 | Pt590 | Lₐ2-34 | L_{b}5-5 |
| Pt591 | Lₐ2-38 | L_{b}5-5 | Pt592 | Lₐ2-41 | L_{b}5-5 |
| Pt593 | Lₐ3-2 | L_{b}5-5 | Pt594 | Lₐ3-6 | L_{b}5-5 |
| Pt595 | Lₐ3-10 | L_{b}5-5 | Pt596 | Lₐ3-14 | L_{b}5-5 |
| Pt597 | Lₐ3-18 | L_{b}5-5 | Pt598 | Lₐ3-22 | L_{b}5-5 |
| Pt599 | Lₐ3-24 | L_{b}5-5 | Pt600 | Lₐ4-2 | L_{b}5-5 |
| Pt601 | Lₐ4-6 | L_{b}5-5 | Pt602 | Lₐ4-10 | L_{b}5-5 |
| Pt603 | Lₐ4-12 | L_{b}5-5 | Pt604 | Lₐ4-30 | L_{b}5-5 |
| Pt605 | Lₐ4-31 | L_{b}5-5 | Pt606 | Lₐ4-32 | L_{b}5-5 |
| Pt607 | Lₐ4-33 | L_{b}5-5 | Pt608 | Lₐ4-38 | L_{b}5-5 |
| Pt609 | Lₐ4-39 | L_{b}5-5 | Pt610 | Lₐ4-43 | L_{b}5-5 |
| Pt611 | Lₐ4-47 | L_{b}5-5 | Pt612 | Lₐ4-49 | L_{b}5-5 |
| Pt613 | Lₐ1-16 | L_{b}5-10 | Pt614 | Lₐ1-35 | L_{b}5-10 |
| Pt615 | Lₐ1-37 | L_{b}5-10 | Pt616 | Lₐ1-39 | L_{b}5-10 |
| Pt617 | Lₐ1-43 | L_{b}5-10 | Pt618 | Lₐ1-44 | L_{b}5-10 |
| Pt619 | Lₐ1-48 | L_{b}5-10 | Pt620 | Lₐ1-51 | L_{b}5-10 |
| Pt621 | Lₐ1-55 | L_{b}5-10 | Pt622 | Lₐ1-59 | L_{b}5-10 |
| Pt623 | Lₐ1-65 | L_{b}5-10 | Pt624 | Lₐ2-1 | L_{b}5-10 |
| Pt625 | Lₐ2-2 | L_{b}5-10 | Pt626 | Lₐ2-8 | L_{b}5-10 |
| Pt627 | Lₐ2-10 | L_{b}5-10 | Pt628 | Lₐ2-14 | L_{b}5-10 |
| Pt629 | Lₐ2-16 | L_{b}5-10 | Pt630 | Lₐ2-20 | L_{b}5-10 |
| Pt631 | Lₐ2-23 | L_{b}5-10 | Pt632 | Lₐ2-26 | L_{b}5-10 |
| Pt633 | Lₐ2-32 | L_{b}5-10 | Pt634 | Lₐ2-34 | L_{b}5-10 |
| Pt635 | Lₐ2-38 | L_{b}5-10 | Pt636 | Lₐ2-41 | L_{b}5-10 |
| Pt637 | Lₐ3-2 | L_{b}5-10 | Pt638 | Lₐ3-6 | L_{b}5-10 |
| Pt639 | Lₐ3-10 | L_{b}5-10 | Pt640 | Lₐ3-14 | L_{b}5-10 |
| Pt641 | Lₐ3-18 | L_{b}5-10 | Pt642 | Lₐ3-22 | L_{b}5-10 |
| Pt643 | Lₐ3-24 | L_{b}5-10 | Pt644 | Lₐ4-2 | L_{b}5-10 |
| Pt645 | Lₐ4-6 | L_{b}5-10 | Pt646 | Lₐ4-10 | L_{b}5-10 |
| Pt647 | Lₐ4-12 | L_{b}5-10 | Pt648 | Lₐ4-30 | L_{b}5-10 |
| Pt649 | Lₐ4-31 | L_{b}5-10 | Pt650 | Lₐ4-32 | L_{b}5-10 |
| Pt651 | Lₐ4-33 | L_{b}5-10 | Pt652 | Lₐ4-38 | L_{b}5-10 |
| Pt653 | Lₐ4-39 | L_{b}5-10 | Pt654 | Lₐ4-43 | L_{b}5-10 |
| Pt655 | Lₐ4-47 | L_{b}5-10 | Pt656 | Lₐ4-49 | L_{b}5-10 |
| Pt657 | Lₐ1-86 | L_{b}1-3 | Pt658 | Lₐ1-87 | L_{b}1-3 |
| Pt659 | Lₐ1-88 | L_{b}1-3 | Pt660 | Lₐ1-89 | L_{b}1-3 |
| Pt661 | Lₐ1-90 | L_{b}1-3 | Pt662 | Lₐ1-91 | L_{b}1-3 |
| Pt663 | Lₐ1-92 | L_{b}1-3 | Pt664 | Lₐ1-93 | L_{b}1-3 |
| Pt665 | Lₐ3-37 | L_{b}1-3 | Pt666 | Lₐ3-38 | L_{b}1-3 |
| Pt667 | Lₐ3-39 | L_{b}1-3 | Pt668 | Lₐ3-40 | L_{b}1-3 |
| Pt669 | Lₐ1-86 | L_{b}5-5 | Pt670 | Lₐ1-87 | L_{b}5-5 |
| Pt671 | Lₐ1-88 | L_{b}5-5 | Pt672 | Lₐ1-89 | L_{b}5-5 |
| Pt673 | Lₐ1-90 | L_{b}5-5 | Pt674 | Lₐ1-91 | L_{b}5-5 |
| Pt675 | Lₐ1-92 | L_{b}5-5 | Pt676 | Lₐ1-93 | L_{b}5-5 |
| Pt677 | Lₐ3-37 | L_{b}5-5 | Pt678 | Lₐ3-38 | L_{b}5-5 |
| Pt679 | Lₐ3-39 | L_{b}5-5 | Pt680 | Lₐ3-40 | L_{b}5-5 |

wherein Compound Pd1 to Compound Pd24 each have a structure represented by Pd(Lₐ)(L_{b}), wherein Lₐ and L_{b} are selected from the structures shown in the following table, respectively:

| Compound | | | Compound | | |
|---|---|---|---|---|---|
| No. | Lₐ | L_{b} | No. | Lₐ | L_{b} |
| Pd1 | Lₐ1-16 | L_{b}1-3 | Pd2 | Lₐ1-35 | L_{b}1-3 |
| Pd3 | Lₐ1-37 | L_{b}1-3 | Pd4 | Lₐ1-39 | L_{b}1-3 |
| Pd5 | Lₐ1-43 | L_{b}1-3 | Pd6 | Lₐ1-44 | L_{b}1-3 |
| Pd7 | Lₐ1-48 | L_{b}1-3 | Pd8 | Lₐ1-51 | L_{b}1-3 |
| Pd9 | Lₐ1-55 | L_{b}1-3 | Pd10 | Lₐ1-59 | L_{b}1-3 |
| Pd11 | Lₐ1-63 | L_{b}1-3 | Pd12 | Lₐ2-1 | L_{b}1-3 |
| Pd13 | Lₐ2-2 | L_{b}1-3 | Pd14 | Lₐ2-8 | L_{b}1-3 |
| Pd15 | Lₐ2-10 | L_{b}1-3 | Pd16 | Lₐ2-14 | L_{b}1-3 |
| Pd17 | Lₐ2-16 | L_{b}1-3 | Pd18 | Lₐ2-20 | L_{b}1-3 |
| Pd19 | Lₐ2-23 | L_{b}1-3 | Pd20 | Lₐ2-26 | L_{b}1-3 |
| Pd21 | Lₐ2-32 | L_{b}1-3 | Pd22 | Lₐ2-34 | L_{b}1-3 |
| Pd23 | Lₐ2-38 | L_{b}1-3 | Pd24 | Lₐ2-41 | L_{b}1-3 |

15. The organic electroluminescent device according to claim 1, wherein the triplet energy level of the first host material is higher than 2.69 eV;
preferably, the first host material has a structure represented by any one of Formula 3 to Formula 5: 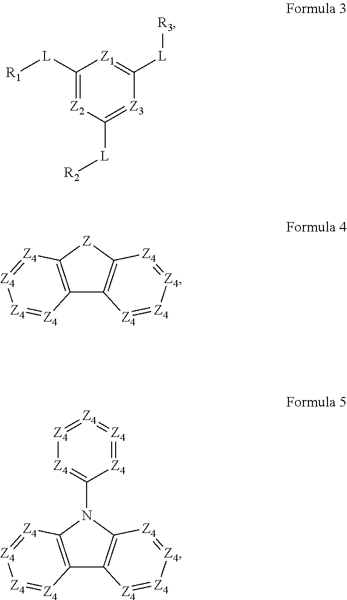
wherein in Formula 3, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
in Formula 4 or Formula 5, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₄ can be optionally joined to form a ring.

16. The organic electroluminescent device according to claim 15, wherein in Formula 3, at least two of Z₁ to Z₃ are N; preferably, Z₁ to Z₃ are N.

17. The organic electroluminescent device according to claim 15, wherein in Formula 3, L is, at each occurrence identically or differently, selected from the group consisting of: a single bond, substituted or unsubstituted arylene having 6 to 18 carbon atoms, substituted or unsubstituted heteroarylene having 3 to 18 carbon atoms and combinations thereof; and
preferably, L is, at each occurrence identically or differently, selected from the group consisting of: a single bond, phenylene, biphenylylene, fluorenylene, triphenylenylene, furanylene, thienylene, dibenzofuranylene, dibenzothienylene and combinations thereof.

18. The organic electroluminescent device according to claim 15, wherein R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, R₁ to R₄ are, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof; and
more preferably, R₁ to R₄ are, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl, triazinyl and combinations thereof.

19. The organic electroluminescent device according to claim 15, wherein the first host material is selected from the group consisting of Compound N-1-1 to Compound N-1-60 and Compound N-2-1 to Compound N-2-35: 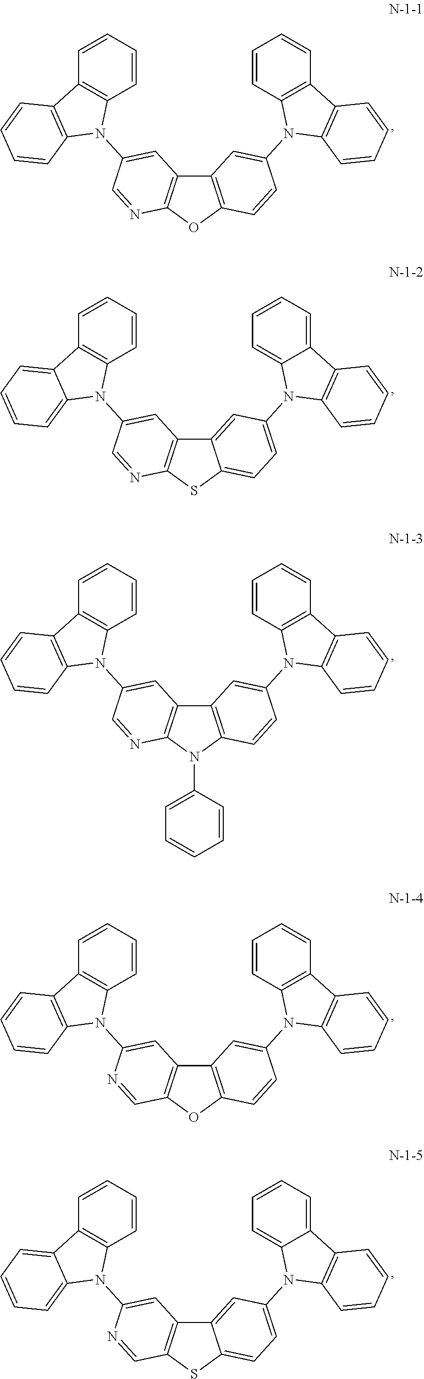 [SMILES: c1ccc2c(c1)c1ccccc1n2-c1ccc2oc3ncc(-n4c5ccccc5c5ccccc54)cc3c2c1 ; c1ccc2c(c1)c1ccccc1n2-c1ccc2sc3ncc(-n4c5ccccc5c5ccccc54)cc3c2c1 ; c1ccc(-n2c3ccc(-n4c5ccccc5c5ccccc54)cc3c3cc(-n4c5ccccc5c5ccccc54)cnc32)cc1 ; c1ccc2c(c1)c1ccccc1n2-c1ccc2oc3cnc(-n4c5ccccc5c5ccccc54)cc3c2c1 ; c1ccc2c(c1)c1ccccc1n2-c1ccc2sc3cnc(-n4c5ccccc5c5ccccc54)cc3c2c1] 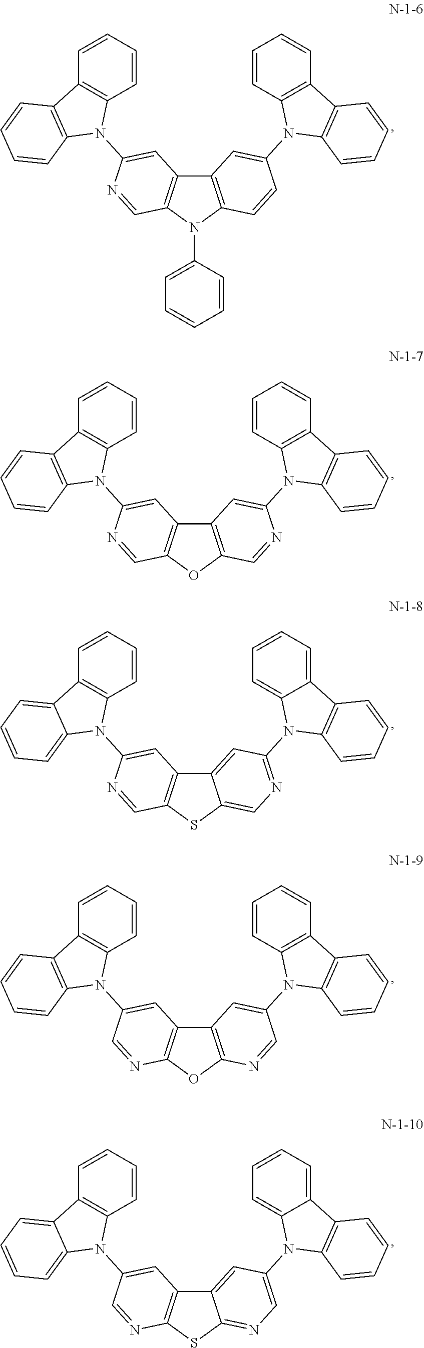 [SMILES: c1ccc(-n2c3ccc(-n4c5ccccc5c5ccccc54)cc3c3cc(-n4c5ccccc5c5ccccc54)ncc32)cc1 ; c1ccc2c(c1)c1ccccc1n2-c1cc2c(cn1)oc1cnc(-n3c4ccccc4c4ccccc43)cc12 ; c1ccc2c(c1)c1ccccc1n2-c1cc2c(cn1)sc1cnc(-n3c4ccccc4c4ccccc43)cc12 ; c1ccc2c(c1)c1ccccc1n2-c1cnc2oc3ncc(-n4c5ccccc5c5ccccc54)cc3c2c1 ; c1ccc2c(c1)c1ccccc1n2-c1cnc2sc3ncc(-n4c5ccccc5c5ccccc54)cc3c2c1] 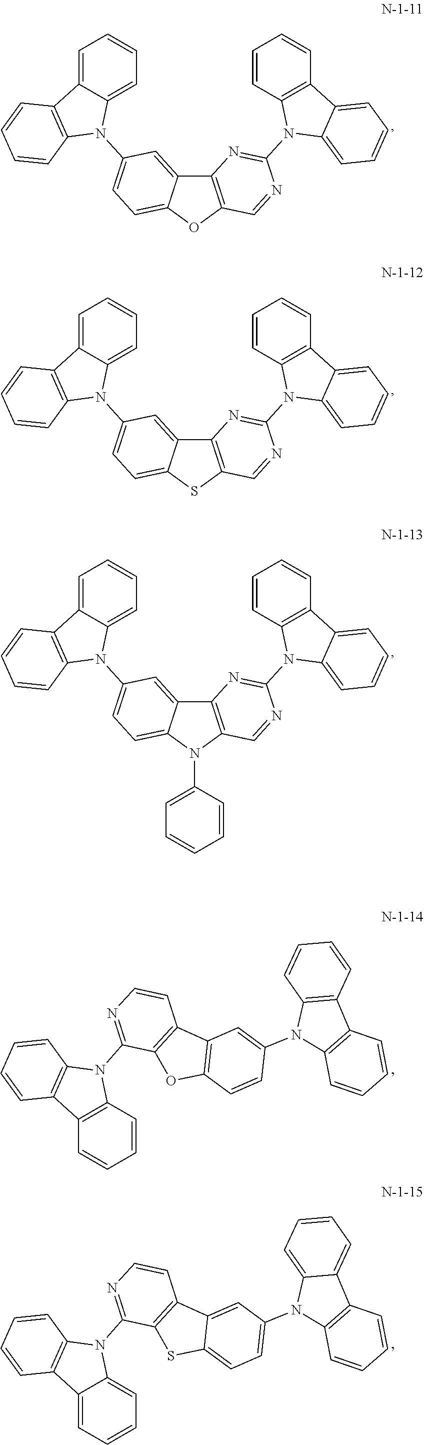 [SMILES: c1ccc2c(c1)c1ccccc1n2-c1ccc2oc3cnc(-n4c5ccccc5c5ccccc54)nc3c2c1 ; c1ccc2c(c1)c1ccccc1n2-c1ccc2sc3cnc(-n4c5ccccc5c5ccccc54)nc3c2c1 ; c1ccc(-n2c3ccc(-n4c5ccccc5c5ccccc54)cc3c3nc(-n4c5ccccc5c5ccccc54)ncc32)cc1 ; c1ccc2c(c1)c1ccccc1n2-c1ccc2oc3c(-n4c5ccccc5c5ccccc54)nccc3c2c1 ; c1ccc2c(c1)c1ccccc1n2-c1ccc2sc3c(-n4c5ccccc5c5ccccc54)nccc3c2c1] 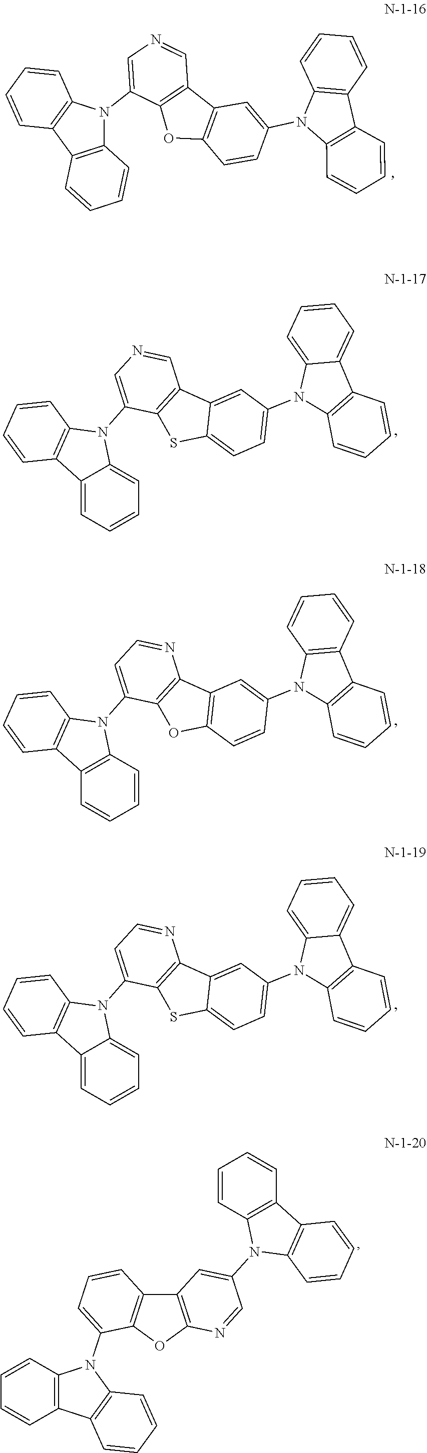 [SMILES: c1ccc2c(c1)c1ccccc1n2-c1ccc2oc3c(-n4c5ccccc5c5ccccc54)cncc3c2c1 ; c1ccc2c(c1)c1ccccc1n2-c1ccc2sc3c(-n4c5ccccc5c5ccccc54)cncc3c2c1 ; c1ccc2c(c1)c1ccccc1n2-c1ccc2oc3c(-n4c5ccccc5c5ccccc54)ccnc3c2c1 ; c1ccc2c(c1)c1ccccc1n2-c1ccc2sc3c(-n4c5ccccc5c5ccccc54)ccnc3c2c1 ; c1cc(-n2c3ccccc3c3ccccc32)c2oc3ncc(-n4c5ccccc5c5ccccc54)cc3c2c1] 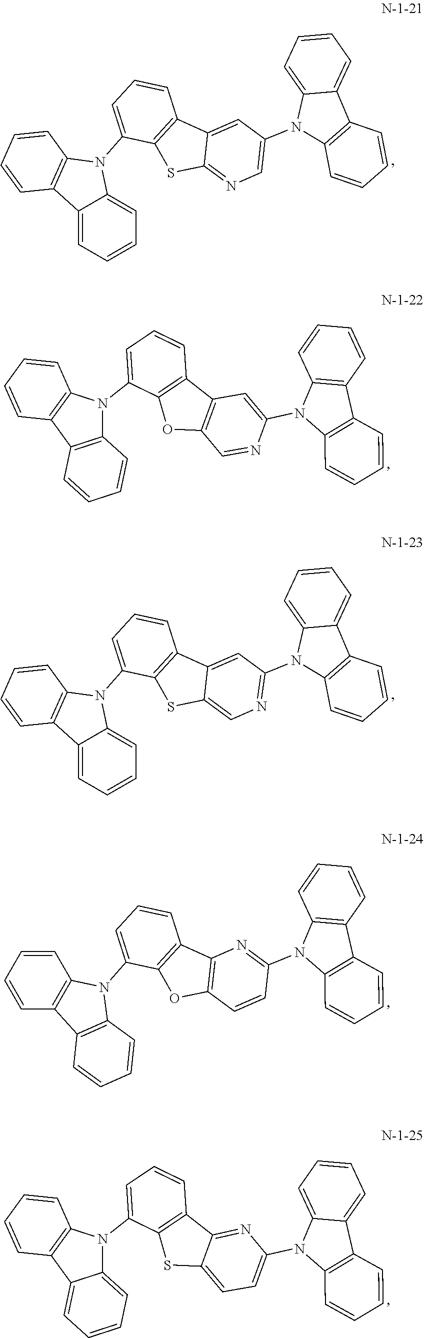 [SMILES: c1cc(-n2c3ccccc3c3ccccc32)c2sc3ncc(-n4c5ccccc5c5ccccc54)cc3c2c1 ; c1cc(-n2c3ccccc3c3ccccc32)c2oc3cnc(-n4c5ccccc5c5ccccc54)cc3c2c1 ; c1cc(-n2c3ccccc3c3ccccc32)c2sc3cnc(-n4c5ccccc5c5ccccc54)cc3c2c1 ; c1cc(-n2c3ccccc3c3ccccc32)c2oc3ccc(-n4c5ccccc5c5ccccc54)nc3c2c1 ; c1cc(-n2c3ccccc3c3ccccc32)c2sc3ccc(-n4c5ccccc5c5ccccc54)nc3c2c1] 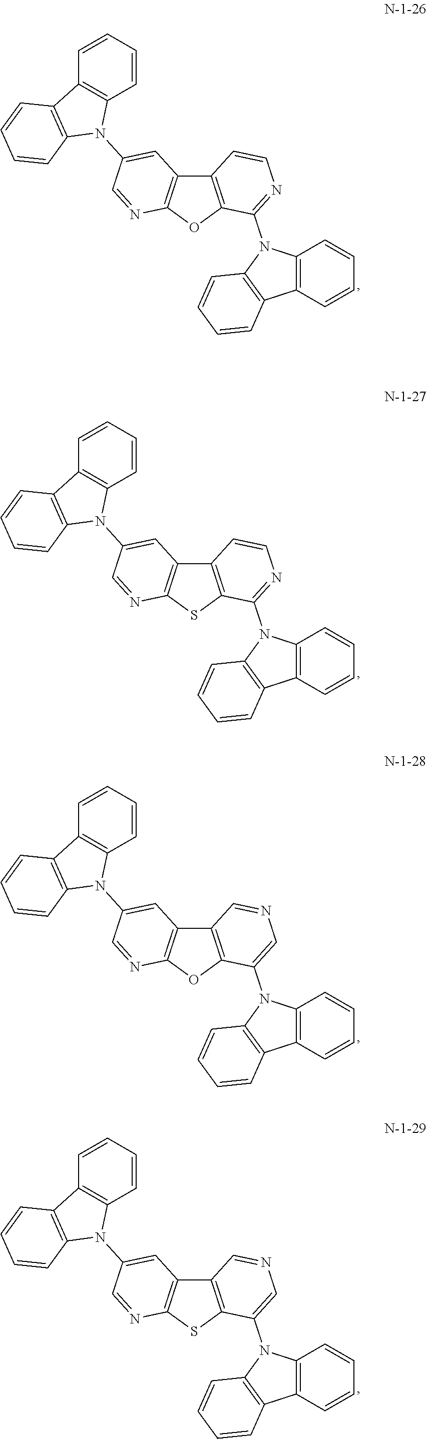 [SMILES: c1ccc2c(c1)c1ccccc1n2-c1cnc2oc3c(-n4c5ccccc5c5ccccc54)nccc3c2c1 ; c1ccc2c(c1)c1ccccc1n2-c1cnc2sc3c(-n4c5ccccc5c5ccccc54)nccc3c2c1 ; c1ccc2c(c1)c1ccccc1n2-c1cnc2oc3c(-n4c5ccccc5c5ccccc54)cncc3c2c1 ; c1ccc2c(c1)c1ccccc1n2-c1cnc2sc3c(-n4c5ccccc5c5ccccc54)cncc3c2c1] 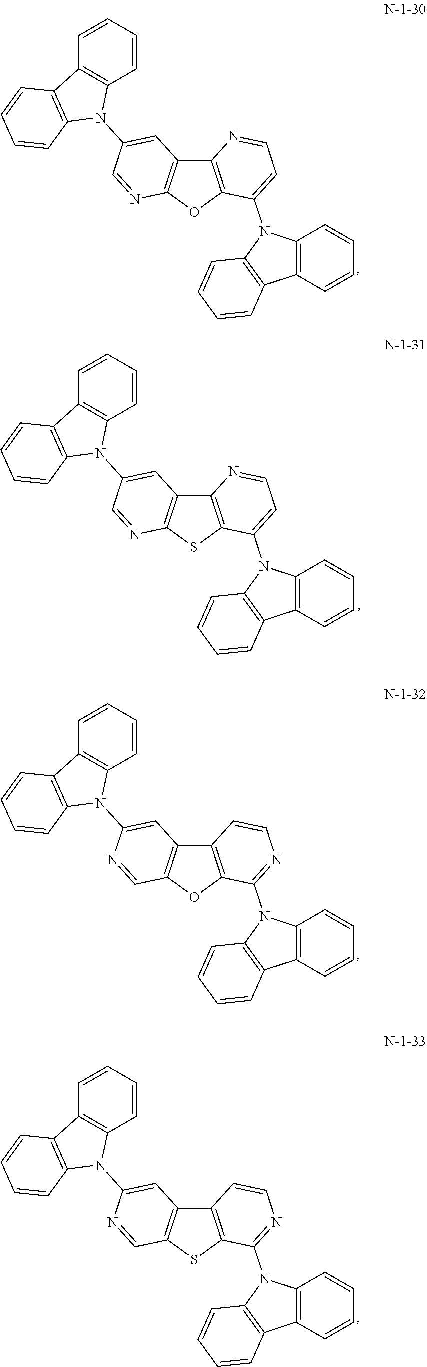 [SMILES: c1ccc2c(c1)c1ccccc1n2-c1cnc2oc3c(-n4c5ccccc5c5ccccc54)ccnc3c2c1 ; c1ccc2c(c1)c1ccccc1n2-c1cnc2sc3c(-n4c5ccccc5c5ccccc54)ccnc3c2c1 ; c1ccc2c(c1)c1ccccc1n2-c1cc2c(cn1)oc1c(-n3c4ccccc4c4ccccc43)nccc12 ; c1ccc2c(c1)c1ccccc1n2-c1cc2c(cn1)sc1c(-n3c4ccccc4c4ccccc43)nccc12] 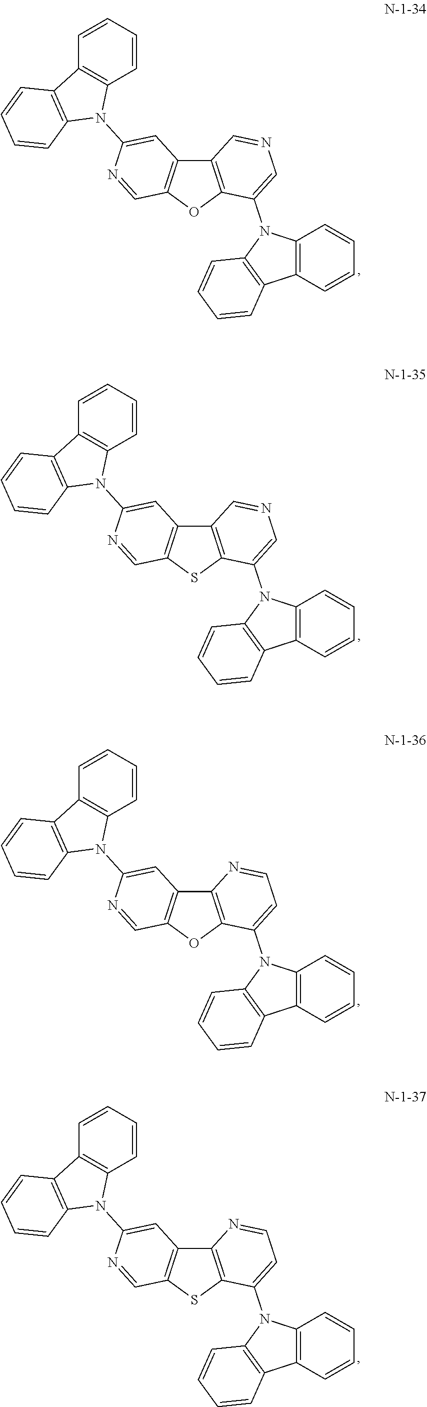 [SMILES: c1ccc2c(c1)c1ccccc1n2-c1cc2c(cn1)oc1c(-n3c4ccccc4c4ccccc43)cncc12 ; c1ccc2c(c1)c1ccccc1n2-c1cc2c(cn1)sc1c(-n3c4ccccc4c4ccccc43)cncc12 ; c1ccc2c(c1)c1ccccc1n2-c1cc2c(cn1)oc1c(-n3c4ccccc4c4ccccc43)ccnc12 ; c1ccc2c(c1)c1ccccc1n2-c1cc2c(cn1)sc1c(-n3c4ccccc4c4ccccc43)ccnc12] 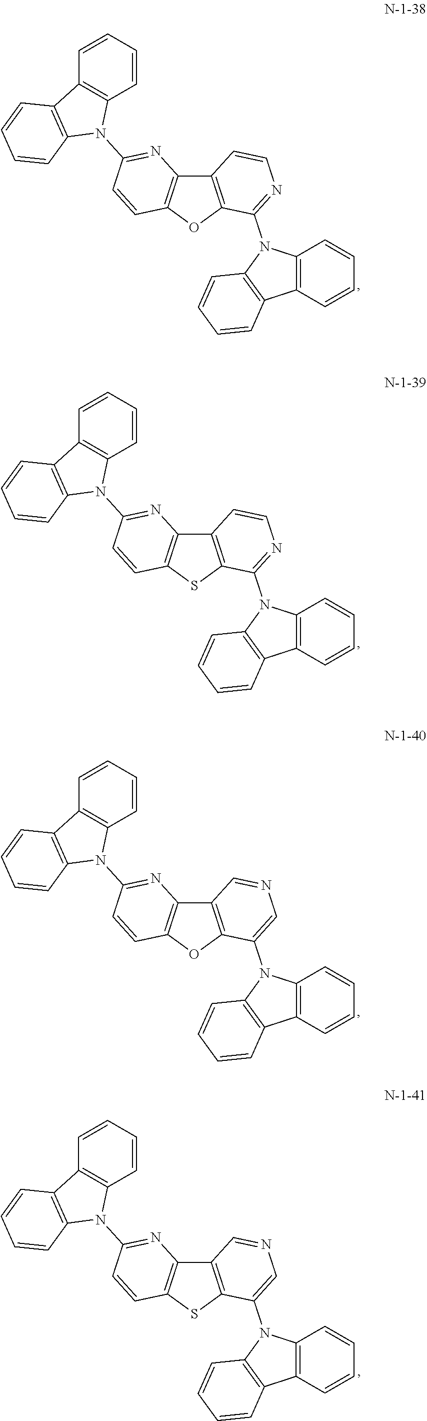 [SMILES: c1ccc2c(c1)c1ccccc1n2-c1ccc2oc3c(-n4c5ccccc5c5ccccc54)nccc3c2n1 ; c1ccc2c(c1)c1ccccc1n2-c1ccc2sc3c(-n4c5ccccc5c5ccccc54)nccc3c2n1 ; c1ccc2c(c1)c1ccccc1n2-c1ccc2oc3c(-n4c5ccccc5c5ccccc54)cncc3c2n1 ; c1ccc2c(c1)c1ccccc1n2-c1ccc2sc3c(-n4c5ccccc5c5ccccc54)cncc3c2n1] 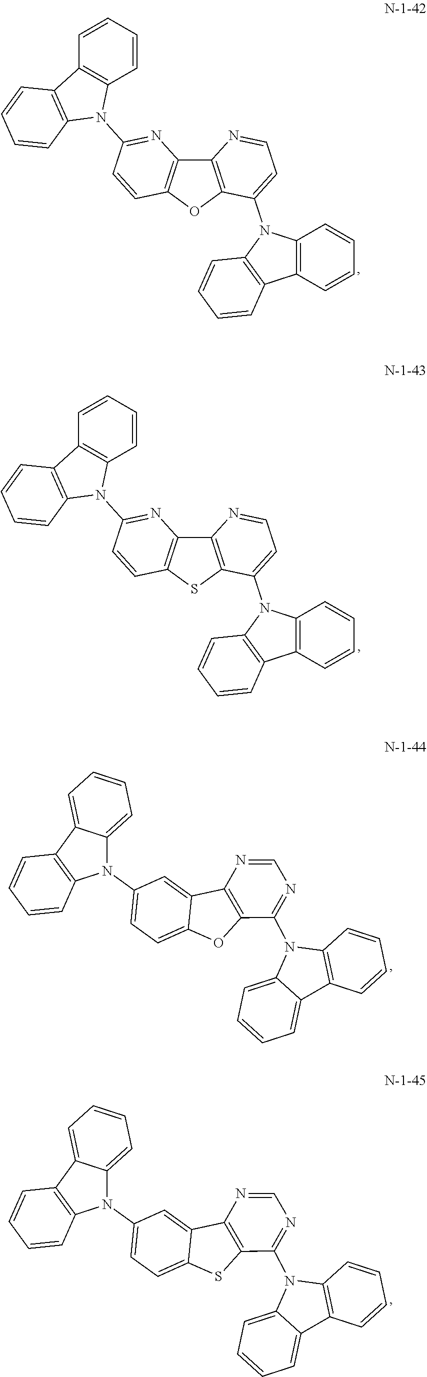 [SMILES: c1ccc2c(c1)c1ccccc1n2-c1ccc2oc3c(-n4c5ccccc5c5ccccc54)ccnc3c2n1 ; c1ccc2c(c1)c1ccccc1n2-c1ccc2sc3c(-n4c5ccccc5c5ccccc54)ccnc3c2n1 ; c1ccc2c(c1)c1ccccc1n2-c1ccc2oc3c(-n4c5ccccc5c5ccccc54)ncnc3c2c1 ; c1ccc2c(c1)c1ccccc1n2-c1ccc2sc3c(-n4c5ccccc5c5ccccc54)ncnc3c2c1] 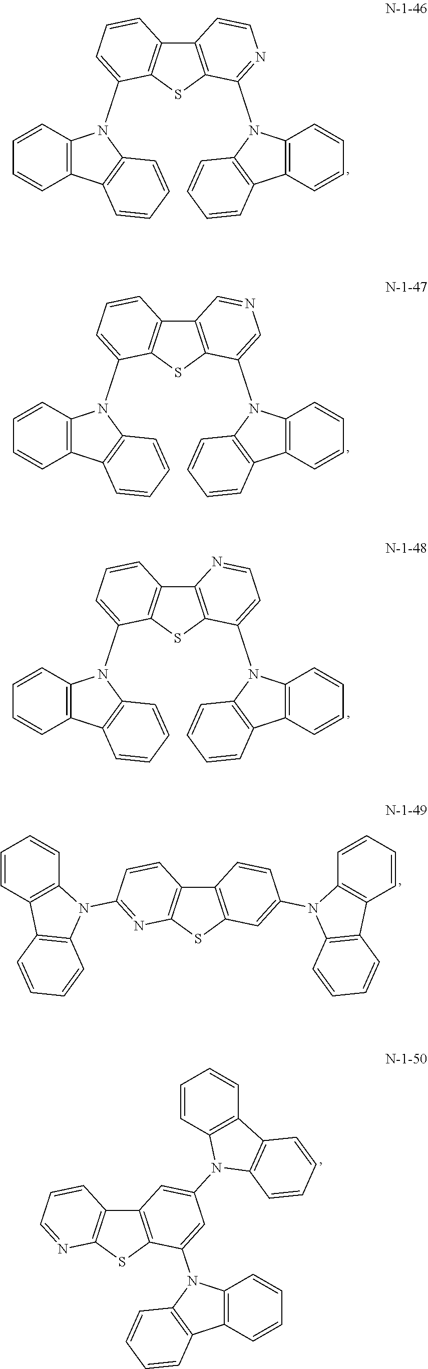 [SMILES: c1cc(-n2c3ccccc3c3ccccc32)c2sc3c(-n4c5ccccc5c5ccccc54)nccc3c2c1 ; c1cc(-n2c3ccccc3c3ccccc32)c2sc3c(-n4c5ccccc5c5ccccc54)cncc3c2c1 ; c1cc(-n2c3ccccc3c3ccccc32)c2sc3c(-n4c5ccccc5c5ccccc54)ccnc3c2c1 ; c1ccc2c(c1)c1ccccc1n2-c1ccc2c(c1)sc1nc(-n3c4ccccc4c4ccccc43)ccc12 ; c1cnc2sc3c(-n4c5ccccc5c5ccccc54)cc(-n4c5ccccc5c5ccccc54)cc3c2c1] 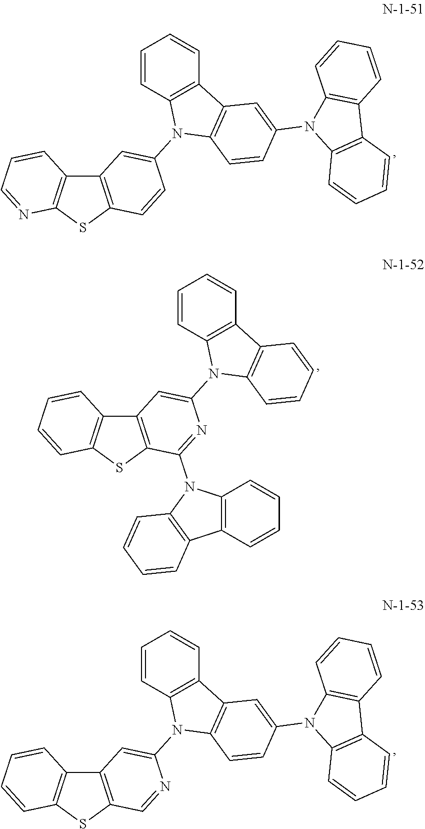 [SMILES: c1cnc2sc3ccc(-n4c5ccccc5c5cc(-n6c7ccccc7c7ccccc76)ccc54)cc3c2c1 ; c1ccc2c(c1)sc1c(-n3c4ccccc4c4ccccc43)nc(-n3c4ccccc4c4ccccc43)cc12 ; c1ccc2c(c1)sc1cnc(-n3c4ccccc4c4cc(-n5c6ccccc6c6ccccc65)ccc43)cc12] 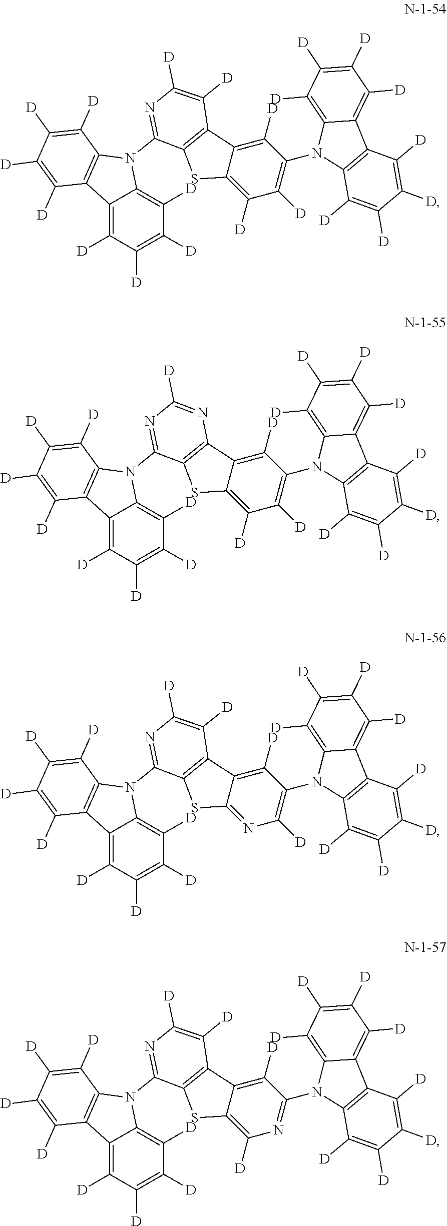 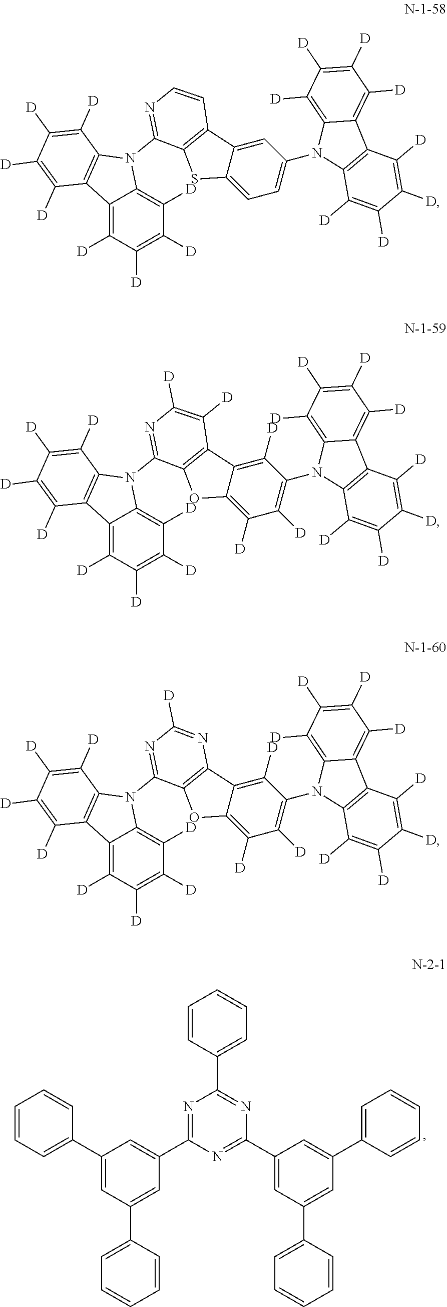 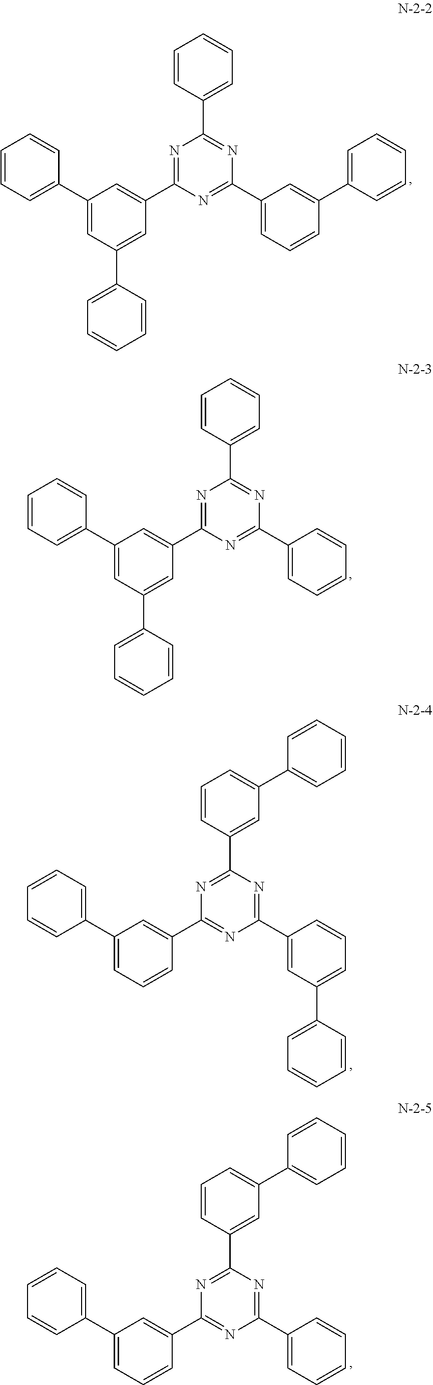 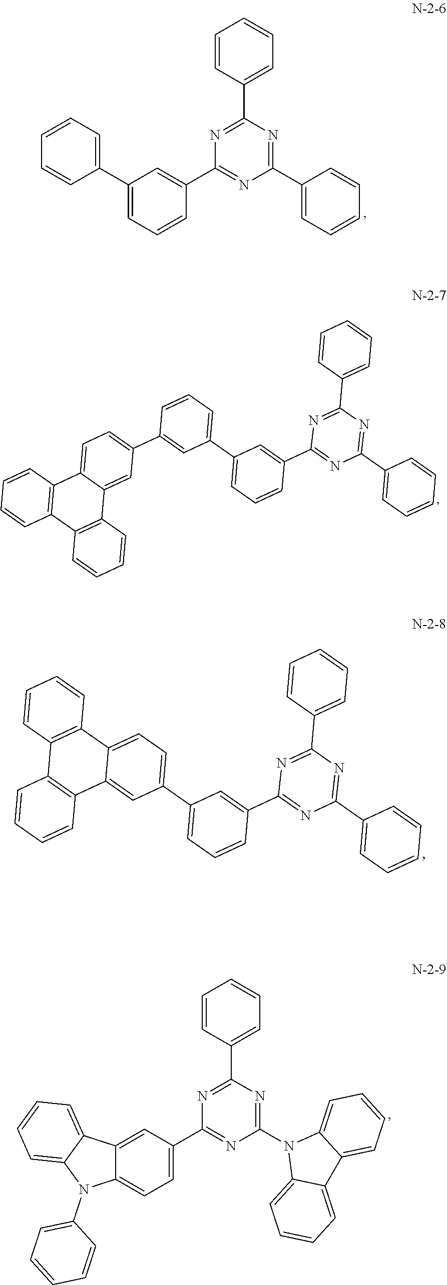 [SMILES: c1ccc(-c2cccc(-c3nc(-c4ccccc4)nc(-c4ccccc4)n3)c2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccc4c(c3)c3ccccc3n4-c3ccccc3)nc(-n3c4ccccc4c4ccccc43)n2)cc1] 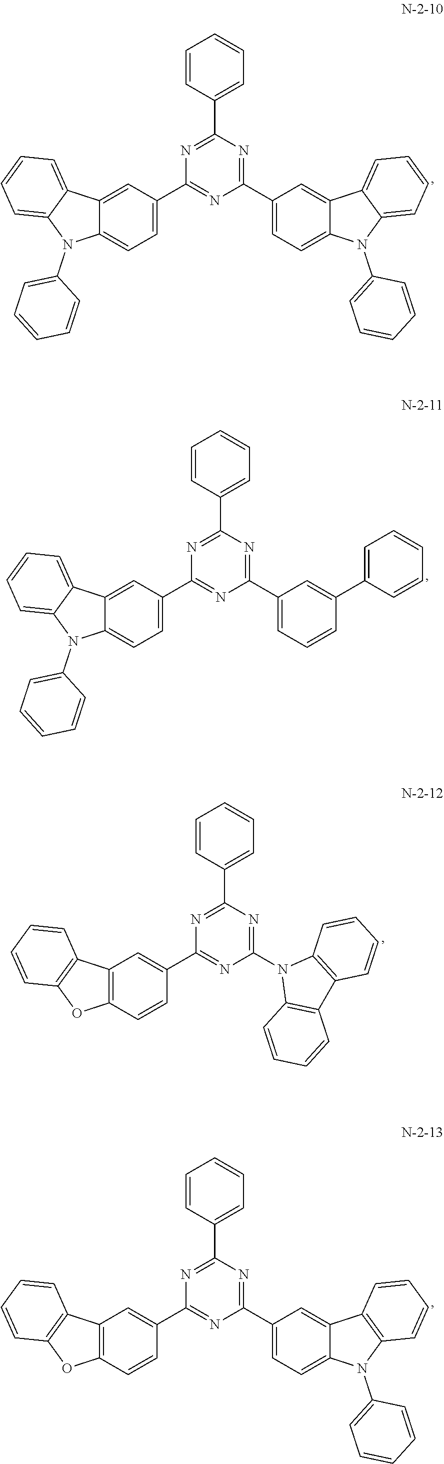 [SMILES: c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cccc(-c3nc(-c4ccccc4)nc(-c4ccc5c(c4)c4ccccc4n5-c4ccccc4)n3)c2)cc1 ; c1ccc(-c2nc(-c3ccc4oc5ccccc5c4c3)nc(-n3c4ccccc4c4ccccc43)n2)cc1 ; c1ccc(-c2nc(-c3ccc4oc5ccccc5c4c3)nc(-c3ccc4c(c3)c3ccccc3n4-c3ccccc3)n2)cc1] 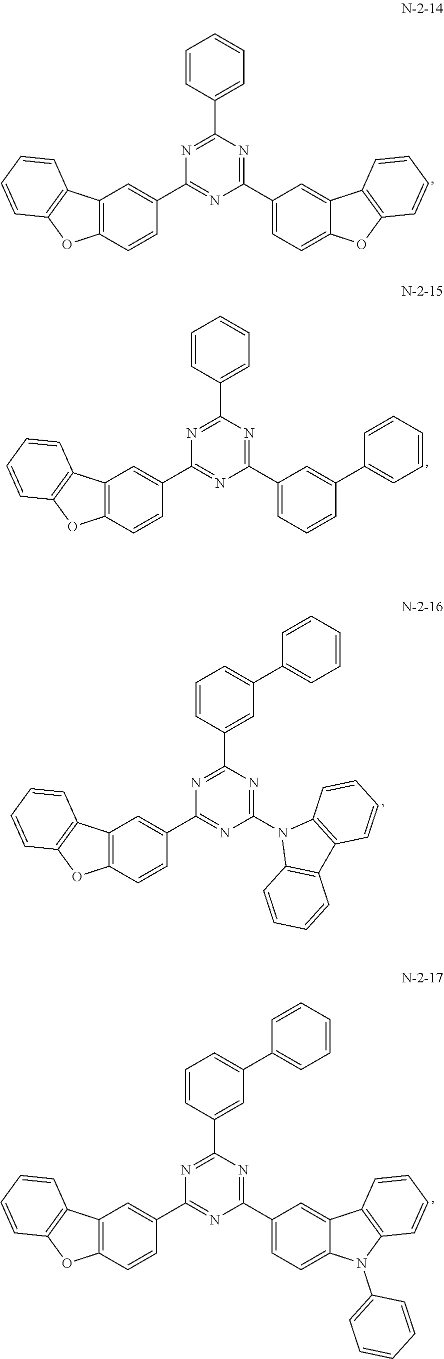 [SMILES: c1ccc(-c2nc(-c3ccc4oc5ccccc5c4c3)nc(-c3ccc4oc5ccccc5c4c3)n2)cc1 ; c1ccc(-c2cccc(-c3nc(-c4ccccc4)nc(-c4ccc5oc6ccccc6c5c4)n3)c2)cc1 ; c1ccc(-c2cccc(-c3nc(-c4ccc5oc6ccccc6c5c4)nc(-n4c5ccccc5c5ccccc54)n3)c2)cc1 ; c1ccc(-c2cccc(-c3nc(-c4ccc5oc6ccccc6c5c4)nc(-c4ccc5c(c4)c4ccccc4n5-c4ccccc4)n3)c2)cc1] 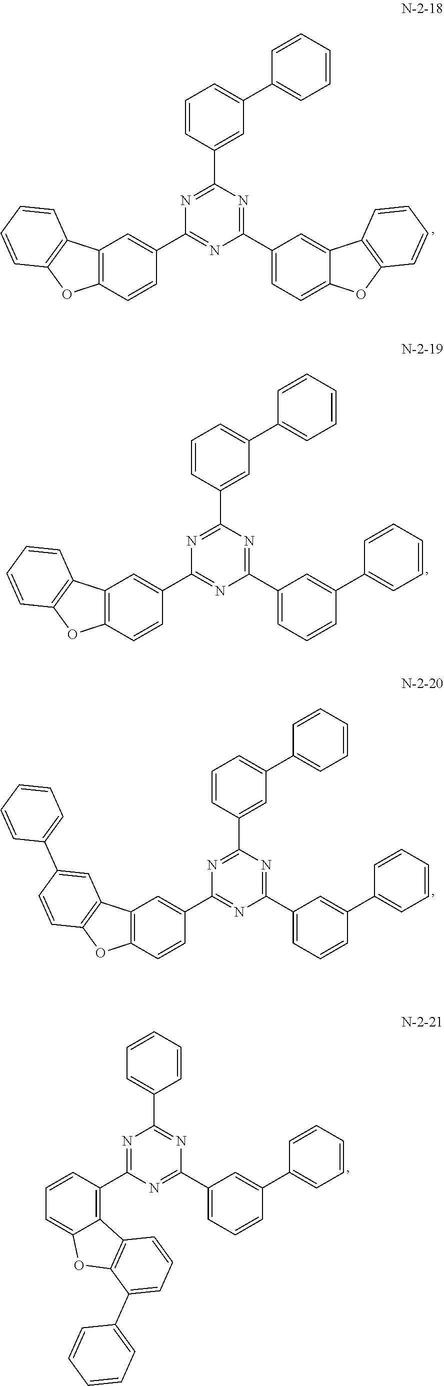 [SMILES: c1ccc(-c2cccc(-c3nc(-c4ccc5oc6ccccc6c5c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccc(-c7ccccc7)cc6c5c4)n3)c2)cc1 ; c1ccc(-c2cccc(-c3nc(-c4ccccc4)nc(-c4cccc5oc6c(-c7ccccc7)cccc6c45)n3)c2)cc1] 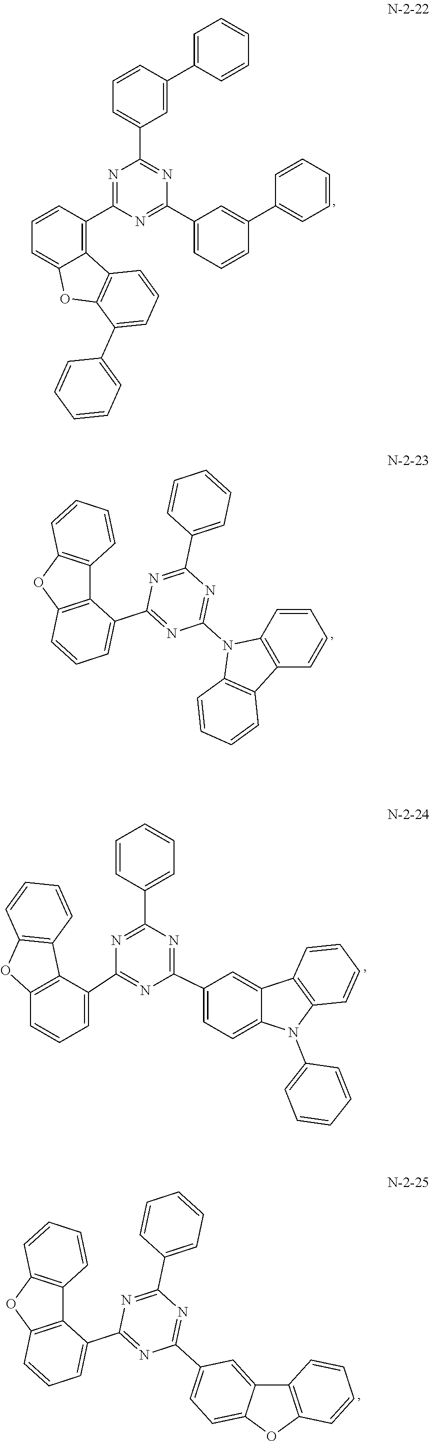 [SMILES: c1ccc(-c2cccc(-c3nc(-c4cccc(-c5ccccc5)c4)nc(-c4cccc5oc6c(-c7ccccc7)cccc6c45)n3)c2)cc1 ; c1ccc(-c2nc(-c3cccc4oc5ccccc5c34)nc(-n3c4ccccc4c4ccccc43)n2)cc1 ; c1ccc(-c2nc(-c3ccc4c(c3)c3ccccc3n4-c3ccccc3)nc(-c3cccc4oc5ccccc5c34)n2)cc1 ; c1ccc(-c2nc(-c3ccc4oc5ccccc5c4c3)nc(-c3cccc4oc5ccccc5c34)n2)cc1] 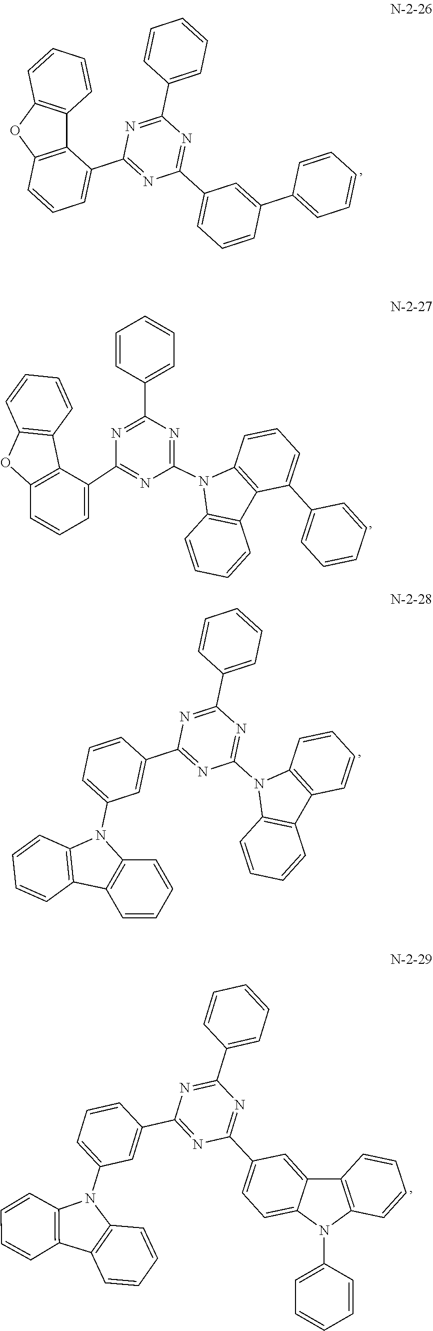 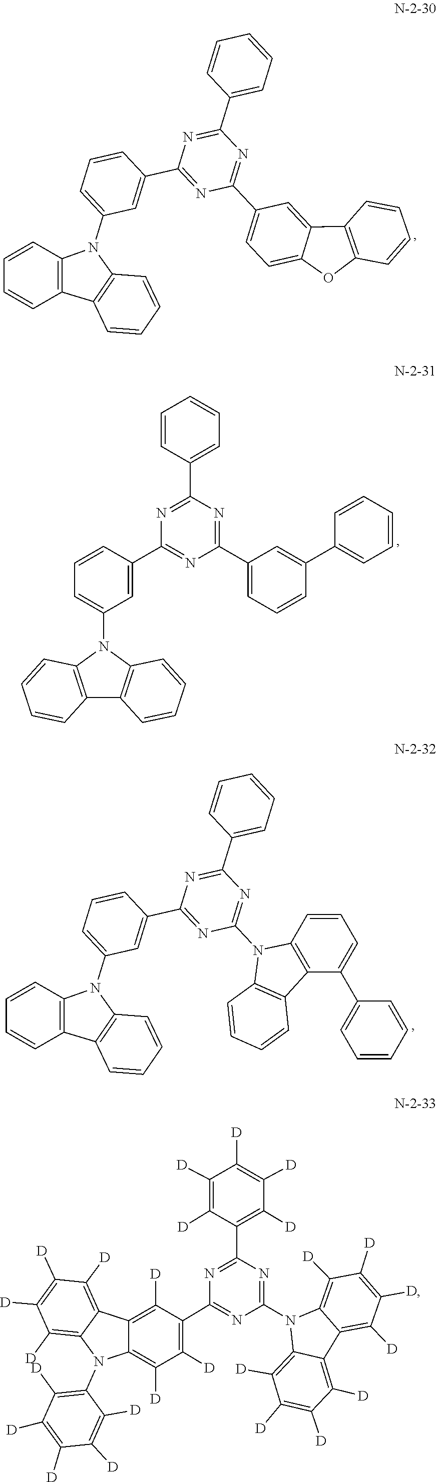 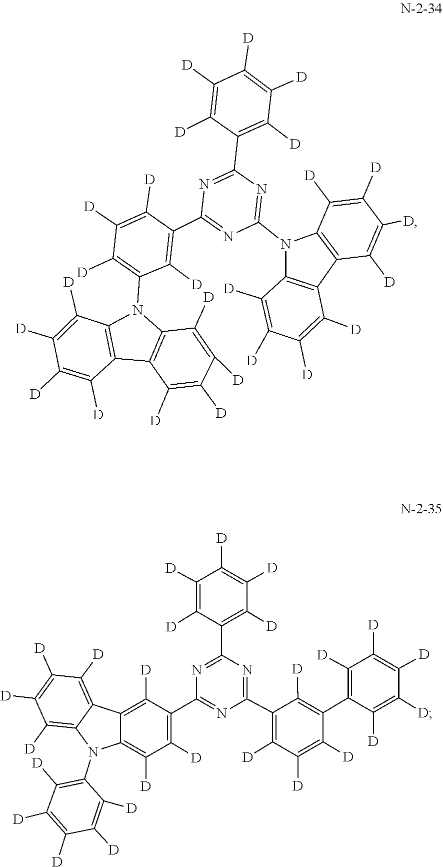
wherein optionally, hydrogens in the structures of Compound N-1-1 to Compound N-1-53, Compound N-1-58 and Compound N-2-1 to Compound N-2-32 can be partially or fully substituted with deuterium.

20. The organic electroluminescent device according to claim 1, wherein the triplet energy level of the second host material is higher than 2.69 eV;
preferably, the second host material has a structure represented by Formula 6: 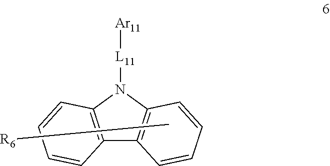
wherein in Formula 6,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₆ can be optionally joined to form a ring.

21. The organic electroluminescent device according to claim 20, wherein R₆ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
preferably, R₆ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms and combinations thereof; and
more preferably, R₆ is, at each occurrence identically or differently, selected from the group consisting of: hydrogen, deuterium, fluorine, a cyano group, phenyl, biphenyl, triphenylenyl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

22. The organic electroluminescent device according to claim 20, wherein the second host material is selected from the group consisting of Compound P-1 to Compound P-31: 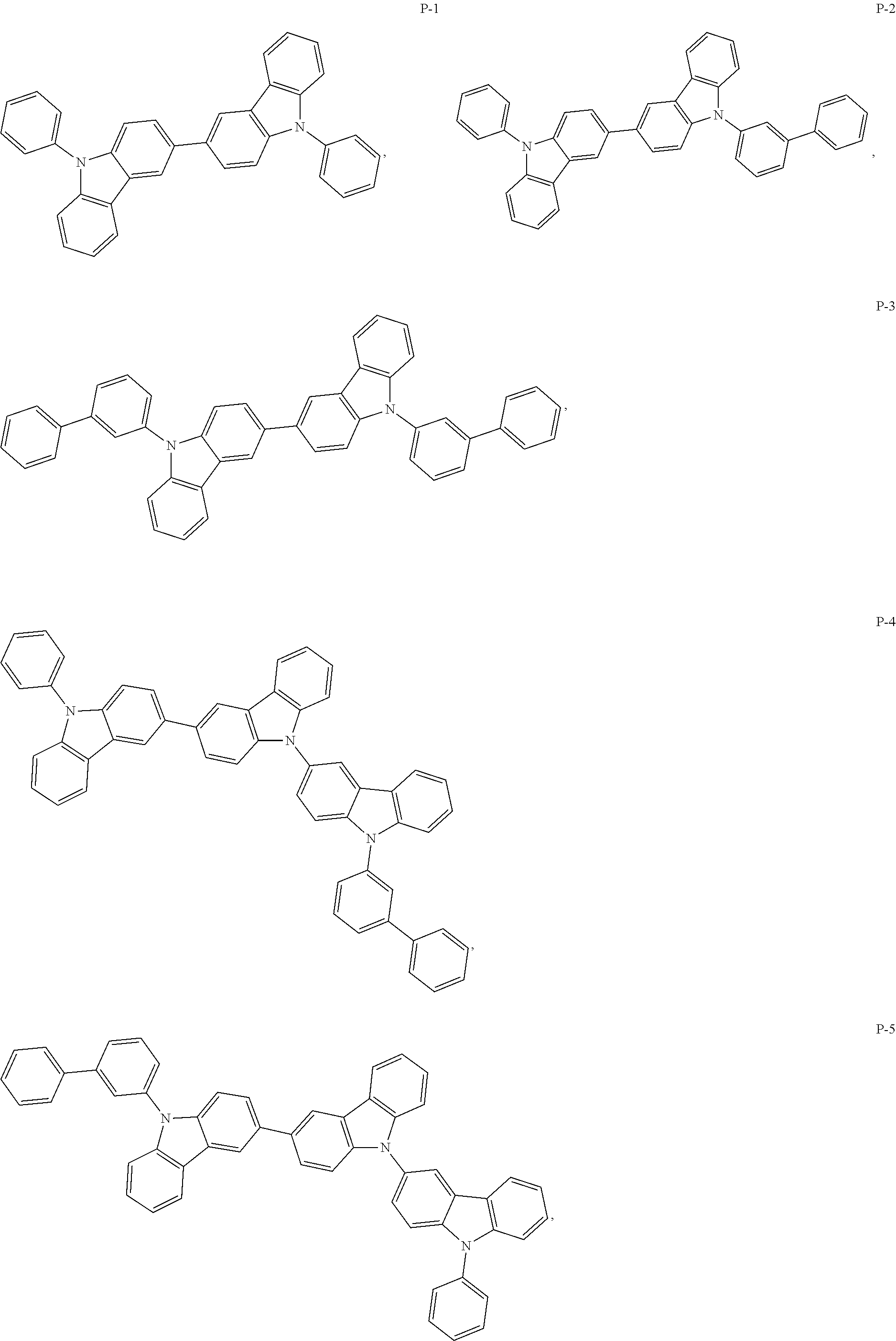 [SMILES: c1ccc(-n2c3ccccc3c3cc(-c4ccc5c(c4)c4ccccc4n5-c4ccccc4)ccc32)cc1 ; c1ccc(-c2cccc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-n5c6ccccc6c6cc(-c7ccc8c(c7)c7ccccc7n8-c7ccccc7)ccc65)ccc43)c2)cc1 ; c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1] 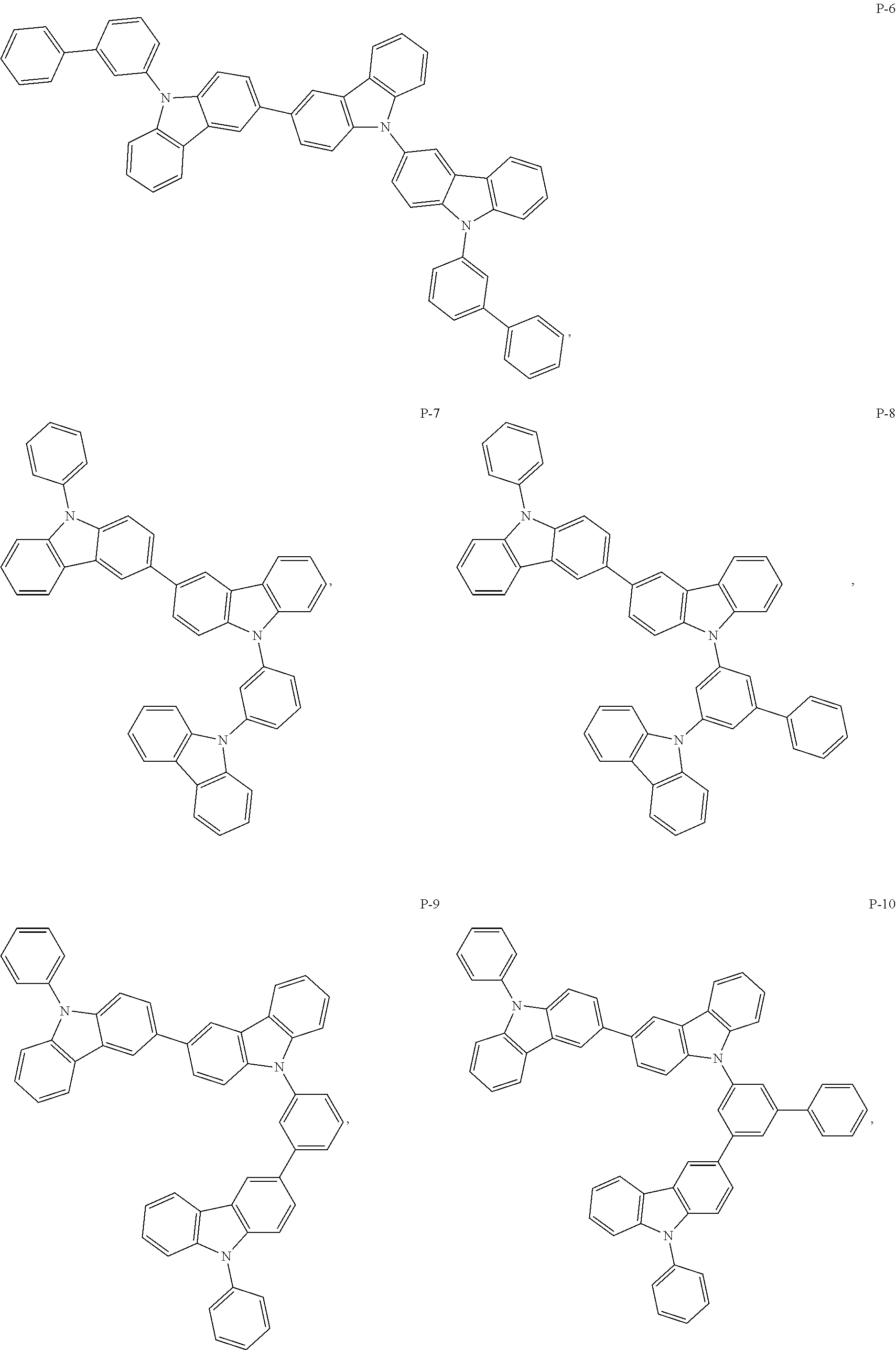 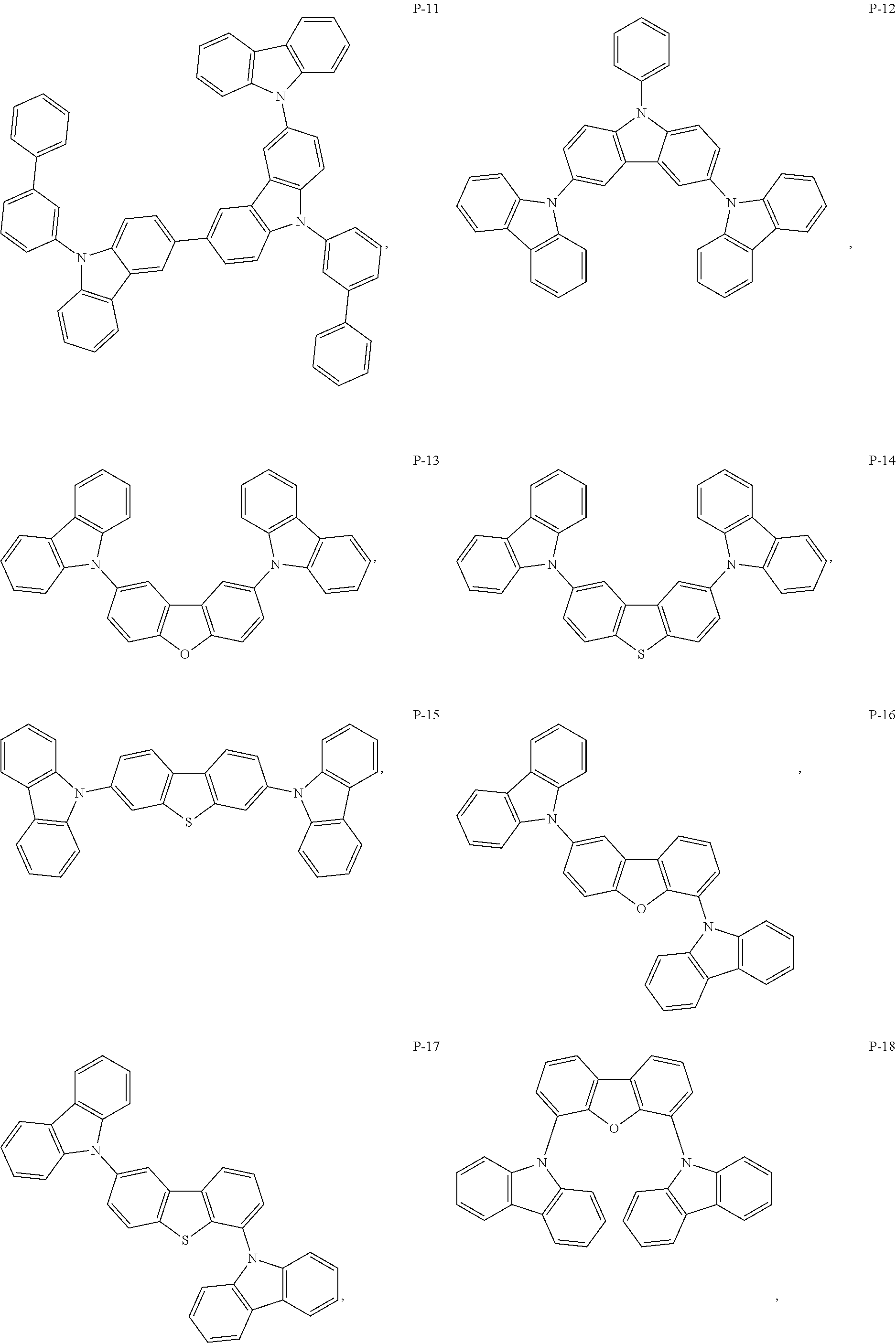 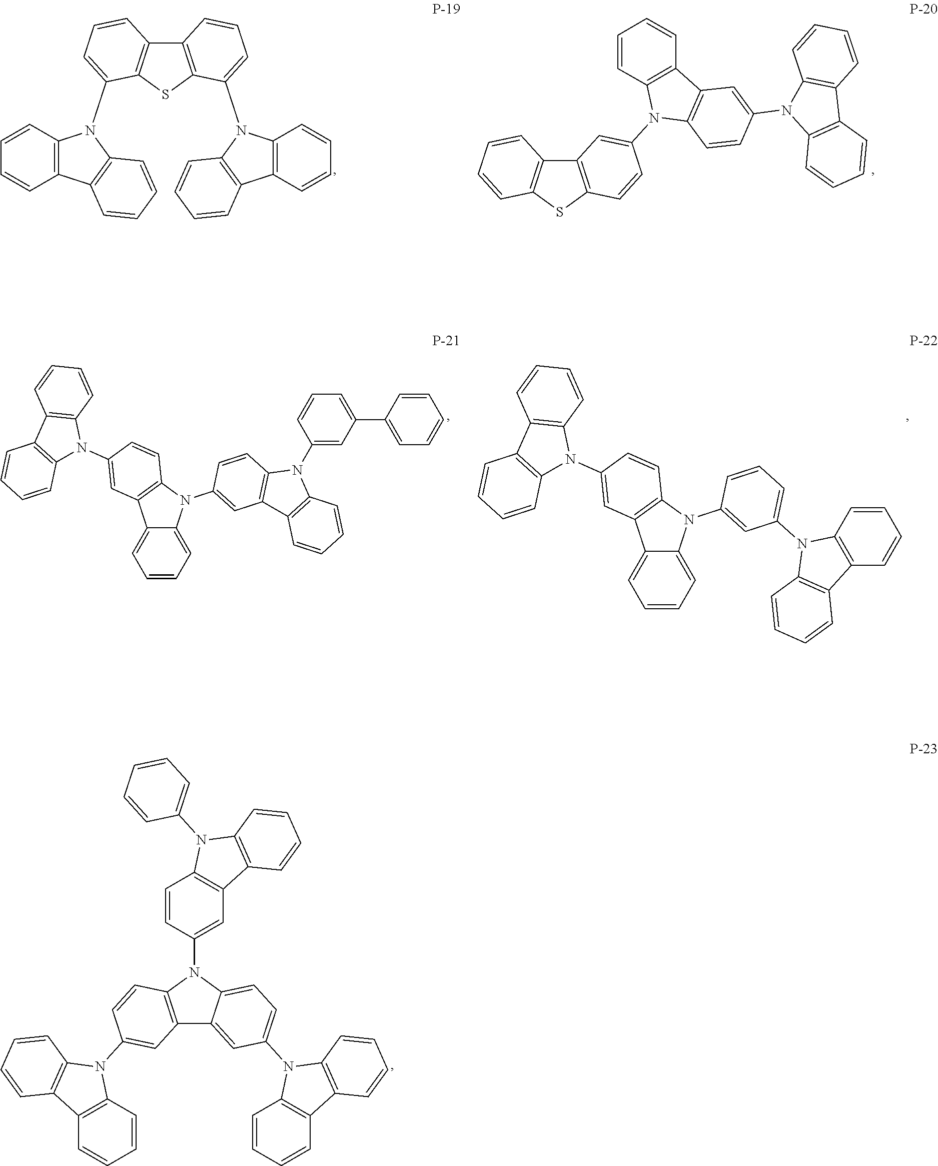 [SMILES: c1cc(-n2c3ccccc3c3ccccc32)c2sc3c(-n4c5ccccc5c5ccccc54)cccc3c2c1 ; c1ccc2c(c1)sc1ccc(-n3c4ccccc4c4cc(-n5c6ccccc6c6ccccc65)ccc43)cc12 ; c1ccc(-c2cccc(-n3c4ccccc4c4cc(-n5c6ccccc6c6cc(-n7c8ccccc8c8ccccc87)ccc65)ccc43)c2)cc1 ; c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccc(-n6c7ccccc7c7ccccc76)cc5c5cc(-n6c7ccccc7c7ccccc76)ccc54)ccc32)cc1] 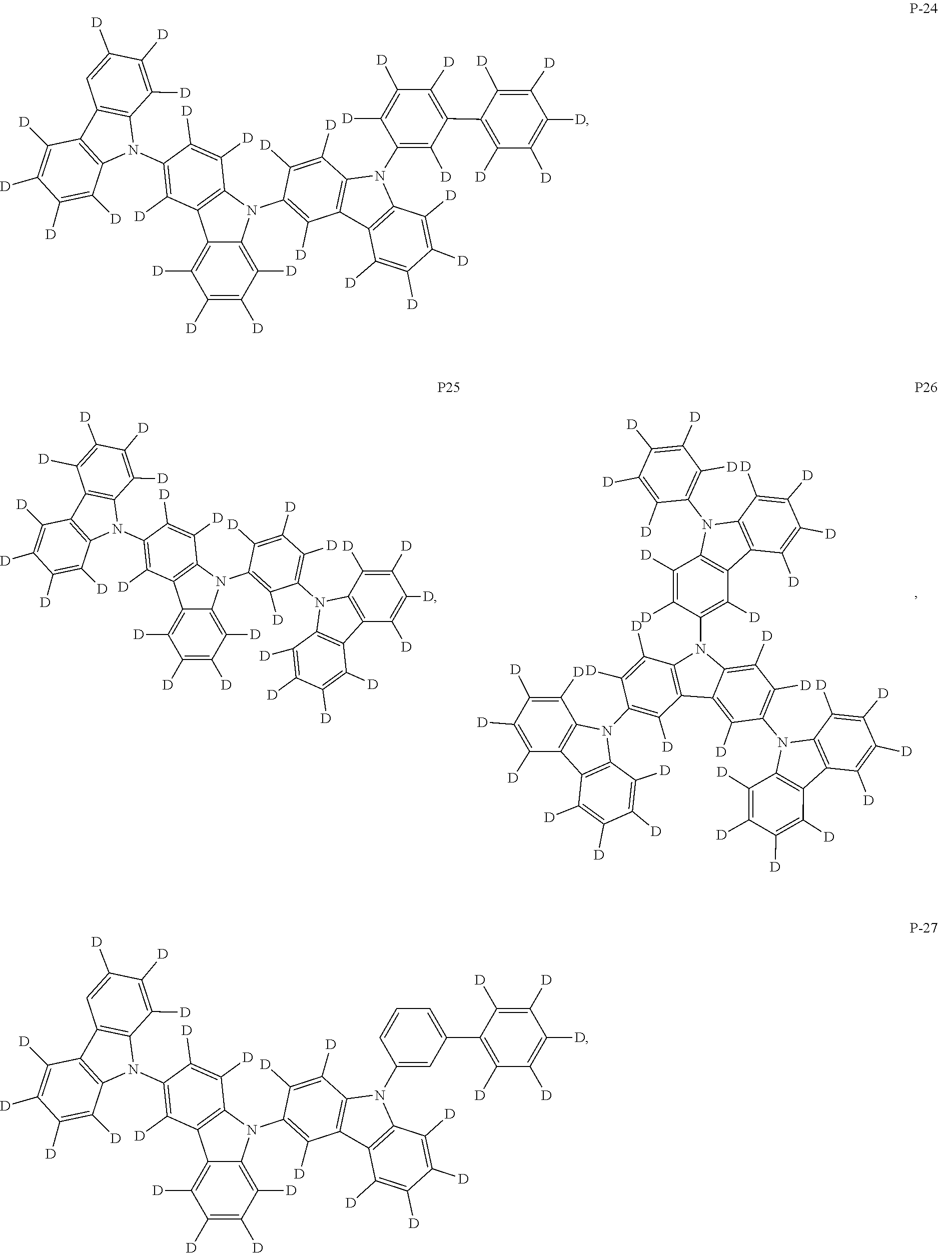 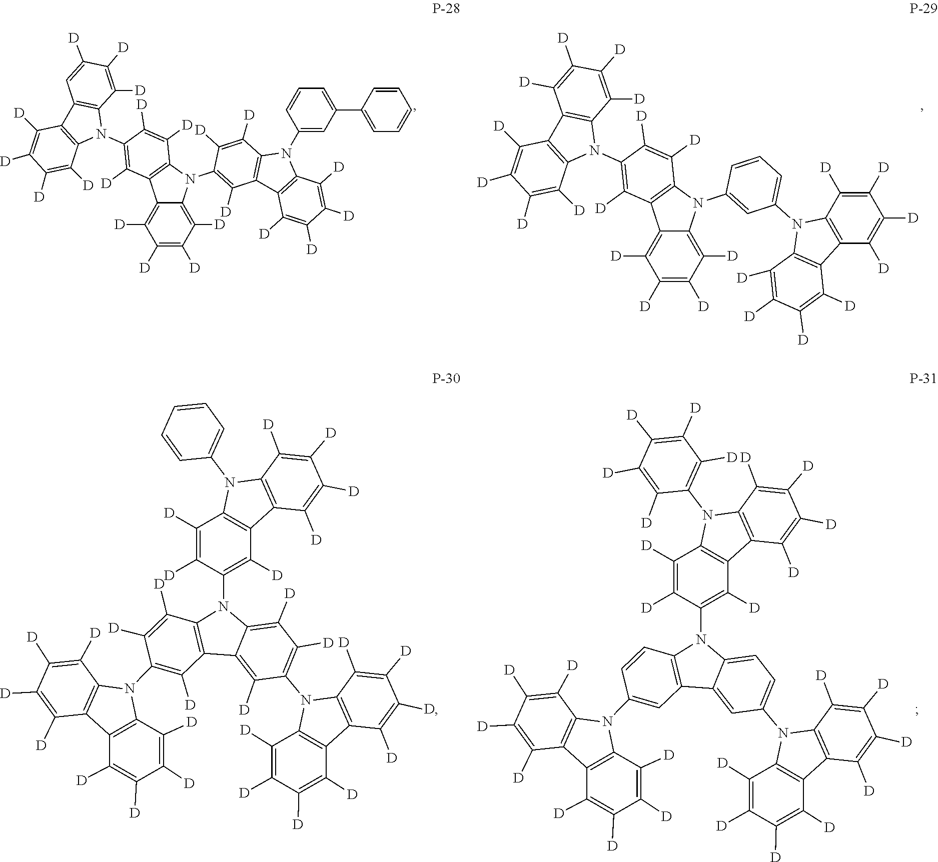
wherein optionally, hydrogens in the structures of the above Compound P-1 to Compound P-23 and Compound P-27 to Compound P-31 can be partially or fully substituted with deuterium.

23. The organic electroluminescent device according to claim 1, wherein the first compound is a phosphorescent material, the first host material is an n-type host material, and the second host material is a p-type host material.

24. The organic electroluminescent device according to claim 1, wherein the device emits blue light.

25. An electronic device, comprising the organic electroluminescent device according to claim 1.

26. A compound composition, comprising a first compound, a first host material and a second host material;
wherein a triplet energy level of the first host material and a triplet energy level of the second host material are both higher than a triplet energy level of the first compound;
wherein the first compound has a structure represented by Formula 1: 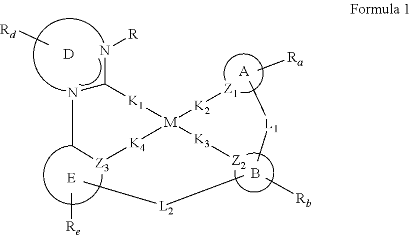
wherein in Formula 1, the ring A, the ring B and the ring E are, at each occurrence identically or differently, selected from an unsaturated carbocyclic ring having 5 to 30 carbon atoms, an unsaturated heterocyclic ring having 3 to 30 carbon atoms or a combination thereof; the ring D is, at each occurrence identically or differently, selected from an unsaturated heterocyclic ring having 3 to 30 carbon atoms;
the metal M is selected from a metal with a relative atomic mass greater than 40;
L₁ and L₂ are, at each occurrence identically or differently, selected from a single bond, O, S, Se, (SiR″R″)_{y}, PR″, NR″, substituted or unsubstituted arylene having 6 to 30 carbon atoms or a combination thereof;
y is 1, 2, 3, 4 or 5;
K₁ to K₄ are, at each occurrence identically or differently, selected from a single bond, O or S;
Z₁ to Z₃ are, at each occurrence identically or differently, selected from C or N;
R in Formula 1 has a structure represented by Formula 2: 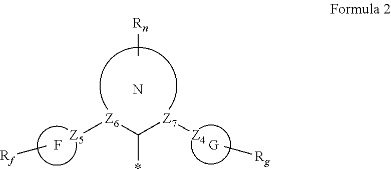
wherein in Formula 2, the ring F, the ring G and the ring N are, at each occurrence identically or differently, selected from an unsaturated carbocyclic ring having 5 to 30 carbon atoms, an unsaturated heterocyclic ring having 3 to 30 carbon atoms or a combination thereof;
Z₄ to Z₇ are, at each occurrence identically or differently, selected from C or N;
Rₐ, R_{b}, R_{d}, Rₑ, R_{f} and R_{g} represent, at each occurrence identically or differently, mono-substitution, multiple substitutions or non-substitution;
Rₙ represents, at each occurrence identically or differently, mono-substitution or multiple substitutions;
R″, Rₐ, R_{b}, R_{d}, Rₑ, R_{f}, R_{g} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one Rₙ on the ring N in Formula 2 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined; and
adjacent substituents R″, Rₐ, R_{b}, R_{d}, Rₑ, R_{f}, R_{g} and Rₙ can be optionally joined to form a ring.
